(19) United States
(12) Patent Application Publication
(10) Pub. No.: US 2025/0311528 A1
(43) Pub. Date: Oct. 2, 2025

(54) ORGANIC ELECTROLUMINESCENT DEVICE, ORGANIC LAYER, DISPLAY ASSEMBLY, AND ELECTRONIC DEVICE

(71) Applicant: BEIJING SUMMER SPROUT TECHNOLOGY CO., LTD., Beijing (CN)

(72) Inventors: Zhen WANG, Beijing (CN); Feng LI, Beijing (CN); Hongbo LI, Beijing (CN); Zheng WANG, Beijing (CN); Yang WANG, Beijing (CN); Xuan ZHANG, Beijing (CN); Wei CAI, Beijing (CN); Chi Yuen Raymond Kwong, Beijing (CN); Chuanjun XIA, Beijing (CN)

(21) Appl. No.: 19/090,157

(22) Filed: Mar. 25, 2025

(30) Foreign Application Priority Data
Mar. 26, 2024 (CN) 202410353140.0

(51) Int. Cl. H10K 50/11; C09K 11/06; H10K 85/30; H10K 85/60

(52) U.S. Cl. CPC H10K 50/11; C09K 11/06; H10K 85/342; H10K 85/654; C09K 2211/185

(57) ABSTRACT

Provided is an organic electroluminescent device and, in particular, an organic electroluminescent device comprising a metal complex having a ligand structure of Formula 1 and a first compound having a structure of Formula 2, an organic layer comprising the metal complex and the first compound, and a display assembly and electronic device comprising the organic electroluminescent device or organic layer. The organic electroluminescent device comprises an anode, a cathode, and an organic layer disposed between the anode and the cathode, wherein the organic layer comprises at least a first metal complex and a first compound; the first metal complex comprises a metal M and a ligand Lₐ coordinated to the metal Mₐ and Lₐ has a structure represented by Formula 1; and the first compound has a structure represented by Formula 2. The device has relatively good overall device performance, especially an improved device lifetime.

### CROSS-REFERENCE TO RELATED APPLICATION(S)

This application claims priority to Chinese Patent Application No. 202410353140.0 filed Mar. 26, 2024, the disclosure of which is incorporated herein by reference in its entirety.

### TECHNICAL FIELD

The present disclosure relates to an organic electroluminescent device. In particular, the present disclosure relates to an organic electroluminescent device and organic layer comprising a metal complex having a ligand structure of Formula 1 and a first compound having a structure of Formula 2, and a display assembly and electronic device comprising the organic electroluminescent device or organic layer.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron transport and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

A prior application US20240016057A1 of the applicant has disclosed an organic compound with a structure of the following formula:

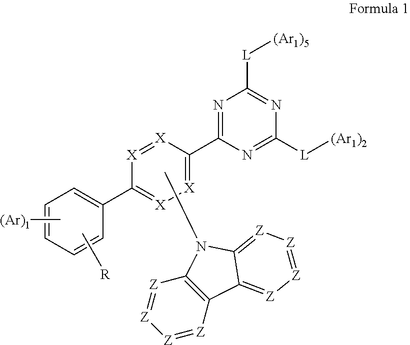

and an organic light-emitting device comprising the compound, wherein X is, at each occurrence identically or differently, selected from C, CRₓ, or N; Z is, at each occurrence identically or differently, selected from CR_{z} or N; and Ar is, at each occurrence identically or differently, selected from the following structure:

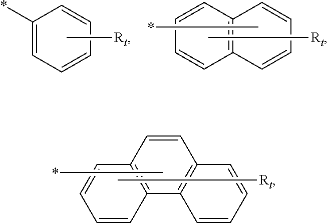

or a combination thereof. In the disclosed device examples, a metal complex of iridium is used as a light-emitting material. However, a use of the organic compound in combination with a metal complex of the present disclosure comprising a ligand having a particular structure of Formula 1 is not disclosed or taught.

Through in-depth researches, the inventors have found that an organic electroluminescent device comprising a first metal complex having a ligand structure of Formula 1 and a first compound having a structure of Formula 2 can have significantly improved overall performance.

### SUMMARY

The present disclosure aims to provide an organic electroluminescent device comprising a first metal complex having a ligand structure of Formula 1 and a first compound having a structure of Formula 2 to solve at least part of the preceding problems. The organic electroluminescent device has better performance and has a significant improvement especially in the device lifetime.

According to an embodiment of the present disclosure, an organic electroluminescent device is disclosed. The organic electroluminescent device comprises:
an anode,
a cathode, and
an organic layer disposed between the anode and the cathode, wherein the organic layer comprises at least a first metal complex and a first compound;
wherein the first metal complex comprises a metal M and a ligand Lₐ coordinated to the metal Mₐ and Lₐ has a structure represented by Formula 1:

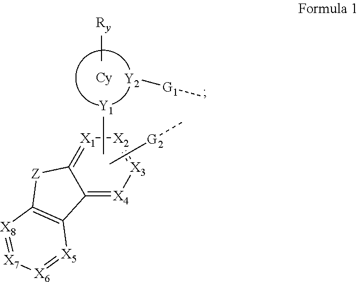

wherein the metal M is selected from a metal with a relative atomic mass greater than 40;
C_{y} is, at each occurrence identically or differently, selected from an aromatic ring having 6 to 24 ring atoms and comprising Y₁ and Y₂, a heteroaromatic ring having 5 to 24 ring atoms and comprising Y₁ and Y₂, or a combination thereof;
G₁ and G₂ are, at each occurrence identically or differently, selected from a single bond, O, or S;
X₁ to X₄ are, at each occurrence identically or differently, selected from C, CRₓ, or N, and one of X₁ to X₄ is selected from C and joined to Y₁;
when X₁, X₂, X₃ or X₄ joined to G₂ is selected from N, G₂ is selected from a single bond, and X₁, X₂, X₃, or X₄ is joined to the metal by forming a metal-nitrogen bond through G₂; or when X₁, X₂, X₃ or X₄ joined to G₂ is selected from C, G₂ is selected from a single bond, O, or S, and X₁, X₂, X₃, or X₄ is joined to the metal through G₂;
X₅ to X₈ are, at each occurrence identically or differently, selected from CRₓ, or N;
Z is, at each occurrence identically or differently, selected from the group consisting of O, S, Se, NR′, CR′R′, SiR′R′, and GeR′R′; when two R′ are present at the same time, the two R are the same or different;
Y₁ and Y₂ are, at each occurrence identically or differently, selected from C or N;
R_{y} represents, at each occurrence identically or differently, mono-substitution or multiple substitutions; when a plurality of R_{y} are present, the plurality of R_{y} are the same or different;
Rₓ, R′, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{y} can be optionally joined to form a ring;
adjacent substituents R′, Rₓ can be optionally joined to form a ring; and
the metal complex is not

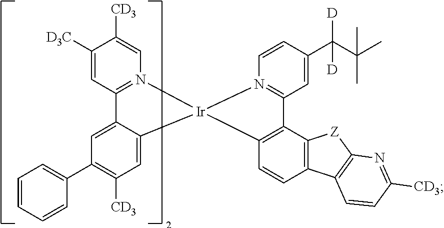

wherein the first compound has a structure represented by Formula 2:

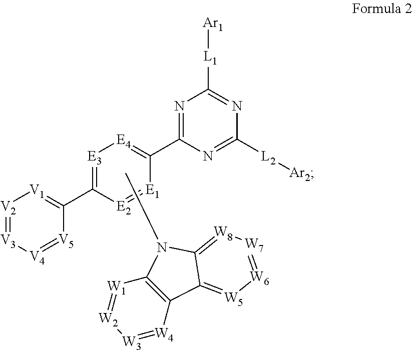

wherein in Formula 2,
E₁ to E₄ are, at each occurrence identically or differently, selected from C, CR_{c}, or N and
one of E₁ and E₂ is selected from C and joined to the structure

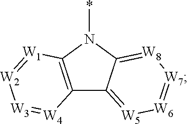

V₁ to V₅ are, at each occurrence identically or differently, selected from CRᵥ or N;
   W₁ to W₈ are, at each occurrence identically or differently, selected from CR_{w} or N;
   L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
   Ar₁ and Ar₂ are, at each occurrence identically or differently, selected from substituted or unsubstituted aryl having 6 to 30 carbon atoms, substituted or unsubstituted heteroaryl having 3 to 30 carbon atoms, or a combination thereof;
   R_{c}, Rᵥ, and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
   adjacent substituents R_{c} can be optionally joined to form a ring, adjacent substituents Rᵥ can be optionally joined to form a ring, and adjacent substituents R_{w} can be optionally joined to form a ring.

According to another embodiment of the present disclosure, a composition is further disclosed. The composition comprises a first metal complex having a structure of Formula 1 and a first compound having a structure of Formula 2.

According to another embodiment of the present disclosure, an organic layer is further disclosed. The organic layer comprises the composition according to the preceding embodiment.

According to another embodiment of the present disclosure, a display assembly is further disclosed. The display assembly comprises the described organic electroluminescent device or the described organic layer.

According to another embodiment of the present disclosure, an electronic device is further disclosed. The electronic device comprises the described organic electroluminescent device, the described organic layer, or the described display assembly.

The present disclosure provides the organic electroluminescent device comprising the first metal complex having the ligand structure of Formula 1 and the first compound having the structure of Formula 2. The device has relatively good overall device performance, especially an improved device lifetime.

### BRIEF DESCRIPTION OF DRAWINGS

FIG. 1 is a schematic diagram of an organic light-emitting device that may comprise a compound and a compound combination disclosed herein.

FIG. 2 is a schematic diagram of another organic light-emitting device that may comprise a compound and a compound combination disclosed herein.

### DETAILED DESCRIPTION

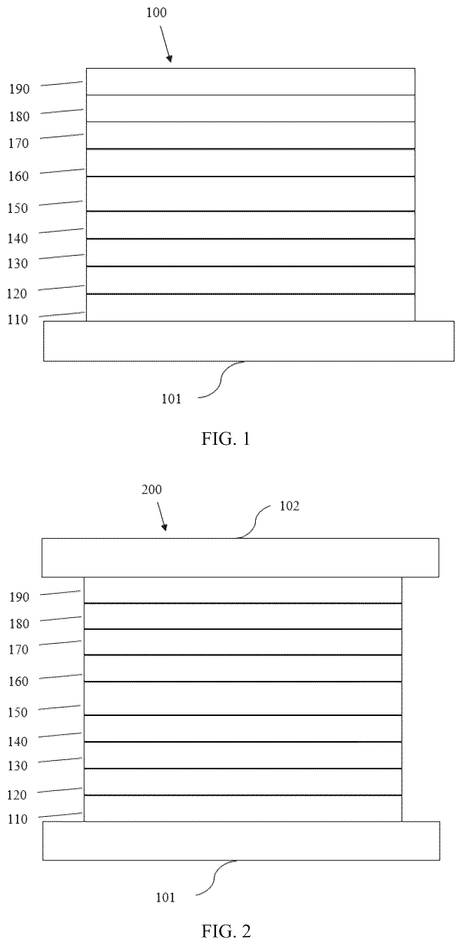

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly on the exterior of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEsr). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcvlcohexvl, 1-adamantyl, 2-adamantyl, 1-norbomyl, 2-norbomvl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbomenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group or an aromatic ring- as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl or a heteroaromatic ring—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethvlsilyl, ethyldimethylsilyl, tripropylsilyl, tributvlsilyl, triisopropylsilyl, methyldiisopropylsilyl, dimethylisopropylsilyl, tri-t-butylsilyl, triisobutvlsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethvlgermanyl, ethvldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refer to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

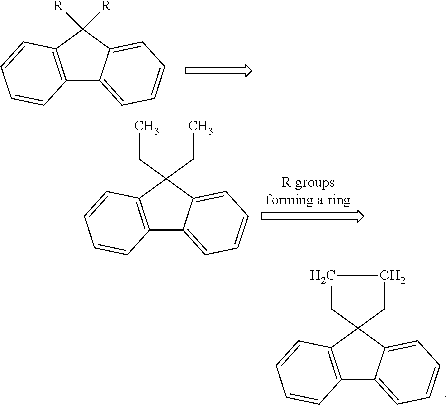

The expression that adjacent substituents can be optionally joined to form a ring is also intended to mean that two substituents bonded to carbon atoms which are directly bonded to each other are joined to each other via a chemical bond to form a ring, which can be exemplified by the following formula:

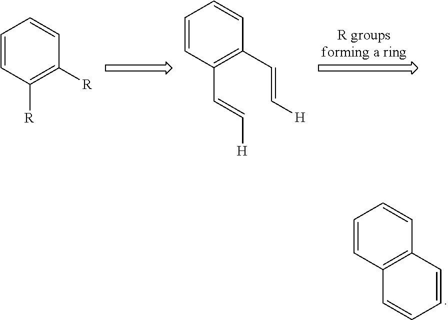

The expression that adjacent substituents can be optionally joined to form a ring is also intended to mean that two substituents bonded to a further distant carbon atom are joined to each other via a chemical bond to form a ring, which can be exemplified by the following formula:

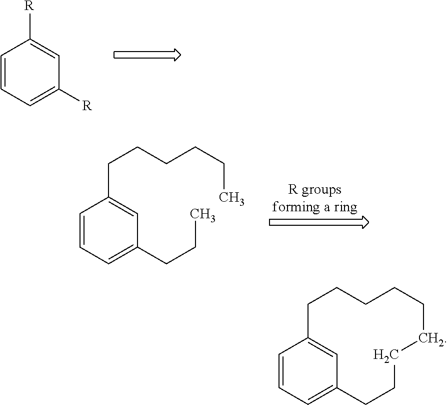

Furthermore, the expression that adjacent substituents can be optionally joined to form a ring is also intended to mean that, in the case where one of the two adjacent substituents represents hydrogen, the second substituent is bonded at a position at which the hydrogen atom is bonded, thereby forming a ring. This is exemplified by the following formula:

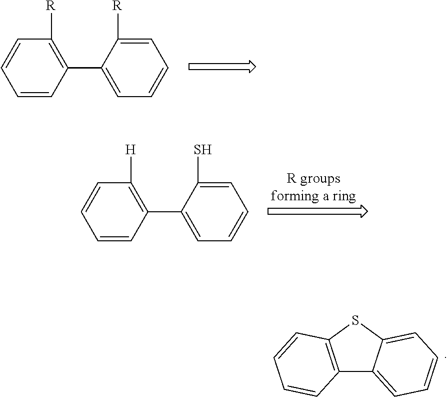

According to an embodiment of the present disclosure, an organic electroluminescent device is disclosed. The organic electroluminescent device comprises:
an anode,
a cathode, and
an organic layer disposed between the anode and the cathode, wherein the organic layer comprises at least a first metal complex and a first compound;
wherein the first metal complex comprises a metal M and a ligand Lₐ coordinated to the metal M, and Lₐ has a structure represented by Formula 1:

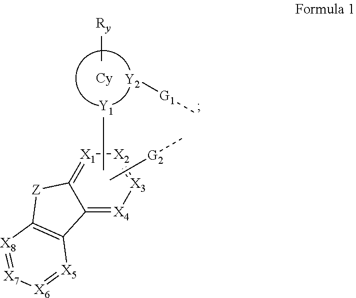

Wherein the metal M is selected from a metal with a relative atomic mass greater than 40;
C_{y} is, at each occurrence identically or differently, selected from an aromatic ring having 6 to 24 ring atoms and comprising Y₁ and Y₂, a heteroaromatic ring having 5 to 24 ring atoms and comprising Y₁ and Y₂, or a combination thereof;
G₁ and G₂ are, at each occurrence identically or differently, selected from a single bond, O, or S;
X₁ to X₄ are, at each occurrence identically or differently, selected from C, CRₓ, or N, and one of X₁ to X₄ is selected from C and joined to Y₁;
when X₁, X₂, X₃ or X₄ joined to G₂ is selected from N, G₂ is selected from a single bond, and X₁, X₂, X₃, or X₄ is joined to the metal by forming a metal-nitrogen bond through G₂; or
when X₁, X₂, X₃ or X₄ joined to G₂ is selected from C, G₂ is selected from a single bond, O, or S, and X₁, X₂, X₃, or X₄ is joined to the metal through G₂;
X₅ to X₈ are, at each occurrence identically or differently, selected from CRₓ, or N;
Z is, at each occurrence identically or differently, selected from the group consisting of O, S, Se, NR′, CR′R′, SiR′R′, and GeR′R′; when two R′ are present at the same time, the two R′ are the same or different;
Y₁ and Y₂ are, at each occurrence identically or differently, selected from C or N;
R_{y} represents, at each occurrence identically or differently, mono-substitution or multiple substitutions; when a plurality of R_{y} are present, the plurality of R_{y} are the same or different;
Rₓ, R′, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{y} can be optionally joined to form a ring;
adjacent substituents R′, Rₓ can be optionally joined to form a ring; and
the metal complex is not

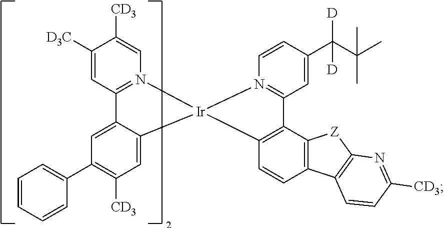

wherein the first compound has a structure represented by Formula 2:
wherein in Formula 2,

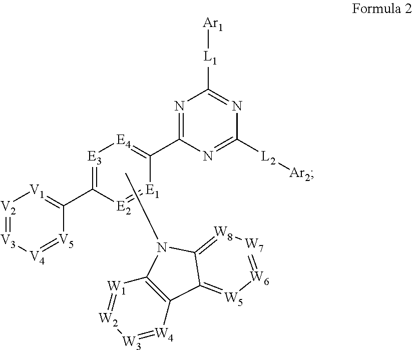

E₁ to E₄ are, at each occurrence identically or differently, selected from C, CR_{c}, or N, and
one of E₁ and E₂ is selected from C and joined to the structure

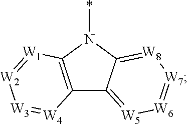

V₁ to V₅ are, at each occurrence identically or differently, selected from CRᵥ or N;
   W₁ to W₈ are, at each occurrence identically or differently, selected from CRₓ, or N;
   L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
   Ar₁ and Ar₂ are, at each occurrence identically or differently, selected from substituted or unsubstituted aryl having 6 to 30 carbon atoms, substituted or unsubstituted heteroaryl having 3 to 30 carbon atoms, or a combination thereof;
   R_{c}, Rᵥ, and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
   adjacent substituents R_{c} can be optionally joined to form a ring, adjacent substituents Rᵥ can be optionally joined to form a ring, and adjacent substituents R_{w} can be optionally joined to form a ring.

In the present disclosure, the expression that “adjacent substituents R_{y} can be optionally joined to form a ring” is intended to mean that any one or more of groups of adjacent substituents, such as two substituents R_{y}, can be joined to form a ring. Obviously, it is also possible that none of these substituents are joined to form a ring.

In the present disclosure, the expression that “adjacent substituents R′, Rₓ can be optionally joined to form a ring” is intended to mean that any one or more of groups of adjacent substituents, such as two substituents R′, two substituents Rₓ, and substituents R′ and Rₓ, can be joined to form a ring. Obviously, it is also possible that none of these substituents are joined to form a ring.

In the present disclosure, the expression that “adjacent substituents R_{c} can be optionally joined to form a ring” is intended to mean that any one or more of groups of adjacent substituents, such as two substituents R_{c}, can be joined to form a ring. Obviously, it is also possible that none of these substituents are joined to form a ring.

In the present disclosure, the expression that “adjacent substituents Rᵥ can be optionally joined to form a ring” is intended to mean that any one or more of groups of adjacent substituents, such as two substituents Rᵥ, can be joined to form a ring. Obviously, it is also possible that none of these substituents are joined to form a ring.

In the present disclosure, the expression that “adjacent substituents R_{w} can be optionally joined to form a ring” is intended to mean that any one or more of groups of adjacent substituents, such as two substituents R_{w}, can be joined to form a ring. Obviously, it is also possible that none of these substituents are joined to form a ring.

According to an embodiment of the present disclosure, in the metal complex, C_{y} is, at each occurrence identically or differently, selected from any structure in the group consisting of the following:

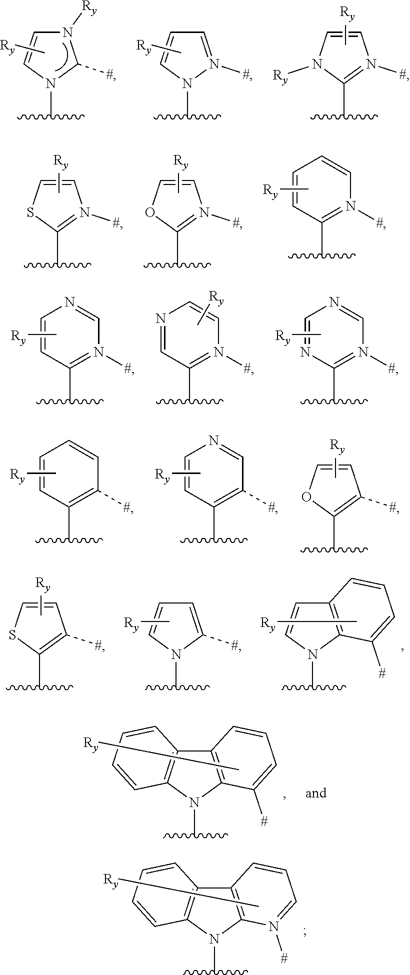

wherein
R_{y} represents, at each occurrence identically or differently, mono-substitution or multiple substitutions; when a plurality of R_{y} are present in any structure, the plurality of R_{y} are the same or different;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfonyl group, a sulfonyl group, a phosphino group, and combinations thereof;
adjacent substituents R_{y} can be optionally joined to form a ring; and
“#” represents a position where the metal M is joined at, and

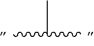

represents a position where X₁, X₂, X₃, or X₄ is joined at.

According to an embodiment of the present disclosure, the metal complex has a general formula of M(Lₐ)ₘ(L_{b})ₙ(L_{c})_{q};
Lₐ, L_{b}, and L_{c} are a first ligand, a second ligand and a third ligand coordinated to the metal M, respectively, and L_{c} is the same as or different from Lₐ or L_{b}; wherein Lₐ, L_{b}, and L_{c} can be optionally joined to form a multidentate ligand;
m is selected from 1, 2, or 3, n is selected from 0, 1, or 2, q is selected from 0, 1, or 2, and m+n+q is equal to an oxidation state of the metal M; when m is greater than or equal to 2, a plurality of Lₐ are the same or different; when n is equal to 2, two L_{b} are the same or different; when q is equal to 2, two L_{c} are the same or different;
L_{b} and L_{c} are, at each occurrence identically or differently, selected from a structure represented by any one of the group consisting of the following:

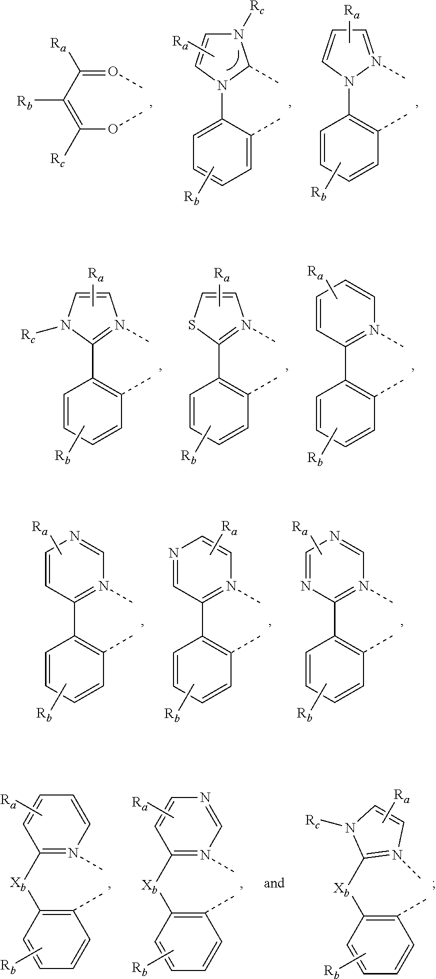

wherein
X_{b} is, at each occurrence identically or differently, selected from the group consisting of: O, S, Se, NR_{N1}, and CR_{C1}R_{C2};
Rₐ and R_{b} represent, at each occurrence identically or differently, mono-substitution, multiple substitutions, or non-substitution;
Rₐ, R_{b}, R_{c}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{C1}, and R_{C2} can be optionally joined to form a ring.

In the present disclosure, the expression that “adjacent substituents Rₐ, R_{b}, R_{c}, R_{N1}, R_{C1}, and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring.

For example, adjacent substituents Rₐ, R_{b} in

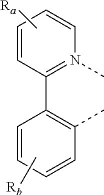

can be optionally joined to form a ring. When Rₐ is optionally joined to form a ring,

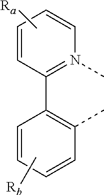

may form a structure of

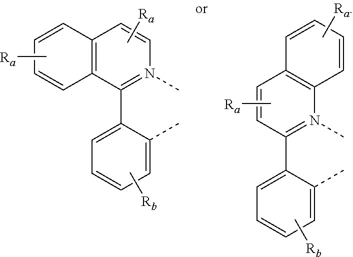

Obviously, it is also possible that none of these substituents are joined to form a ring.

According to an embodiment of the present disclosure, in the metal complex, the metal M is, at each occurrence identically or differently, selected from the group consisting of Cu. Ag, Au, Ru, Rh, Pd, Os, Ir, and Pt.

According to an embodiment of the present disclosure, in the metal complex, the metal M is, at each occurrence identically or differently, selected from Pt or Ir.

According to an embodiment of the present disclosure, the metal complex has a general formula of Ir(Lₐ)ₘ(L_{b})₃₋ₘ and has a structure represented by Formula 5:

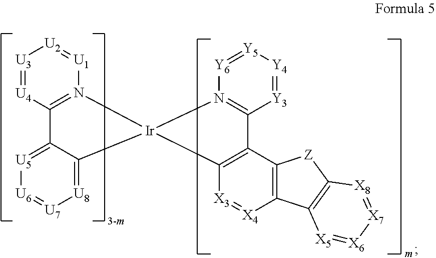

wherein
m is selected from 1, 2, or 3; when m is selected from 1, two L_{b} are the same or different; when m is selected from 2 or 3, a plurality of Lₐ are the same or different;
Z is selected from the group consisting of O, S, Se, NR′, CR′R′, SiR′R′, and GeR′R′; when two R′ are present at the same time, the two R′ are the same or different;
U₁ to U₈ are, at each occurrence identically or differently, selected from CRₐ or N;
X₃ to X₈ are, at each occurrence identically or differently, selected from CRₓ or N;
Y₃ to Y₆ are, at each occurrence identically or differently, selected from CR_{y} or N;
Rₓ, R′, R_{y}, and Rₐ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one of Y₃ to Y₆ is selected from CR_{y}, and the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵤ can be optionally joined to form a ring;
adjacent substituents R_{y} can be optionally joined to form a ring; and
adjacent substituents R′ and Rₓ can be optionally joined to form a ring.

In the present disclosure, the expression that “adjacent substituents Rᵤ can be optionally joined to form a ring” is intended to mean that any one or more of groups of adjacent substituents, such as two substituents Rₐ, can be joined to form a ring. Obviously, it is also possible that none of these substituents are joined to form a ring.

In the present disclosure, the expression that “adjacent substituents R_{y} can be optionally joined to form a ring” is intended to mean that any one or more of groups of adjacent substituents, such as two substituents R_{y}, can be joined to form a ring. Obviously, it is also possible that none of these substituents are joined to form a ring.

In the present disclosure, the expression that “adjacent substituents R′ and Rₓ can be optionally joined to form a ring” is intended to mean that any one or more of groups of adjacent substituents, such as two substituents R′, two substituents R_{y} and substituents R′ and Rₓ, can be joined to form a ring. Obviously, it is also possible that none of these substituents are joined to form a ring.

According to an embodiment of the present disclosure, m is selected from 1.

According to an embodiment of the present disclosure, in the metal complex, Z is, at each occurrence identically or differently, selected from O or S; preferably, Z is selected from O.

According to an embodiment of the present disclosure, in the metal complex, at least one of Y₃ to Y₆ is selected from CR_{y}, and the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, at least one of Y₃ to Y₆ is selected from CR_{y}, and the R_{y} is, at each occurrence identically or differently, selected from the group consisting of; deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, and combinations thereof.

According to an embodiment of the present disclosure, at least one of Y₄ and Y₅ is selected from CR_{y}, and the R_{y} is, at each occurrence identically or differently, selected from the group consisting of: substituted or unsubstituted alkyl having 3 to 6 carbon atoms, substituted or unsubstituted cycloalkyl having 3 to 6 ring carbon atoms, and combinations thereof.

According to an embodiment of the present disclosure, in the metal complex, X₃ to X₈ are, at each occurrence identically or differently, selected from CRₓ.

According to an embodiment of the present disclosure, in the metal complex, at least one of X₃ to X₈ is selected from CRₓ, and the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, and combinations thereof.

According to an embodiment of the present disclosure, at least one of X₃ to X₈ is selected from CRₓ, and the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, cyano, and combinations thereof.

According to an embodiment of the present disclosure, X₄ is selected from CRₓ, and the Rₓ is selected from the group consisting of: deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and/or X₈ is selected from CRₓ, and the Rₓ is selected from deuterium, substituted or unsubstituted aryl having 6 to 18 carbon atoms, substituted or unsubstituted heteroaryl having 3 to 18 carbon atoms, or a combination thereof.

According to an embodiment of the present disclosure, in the metal complex, at least one of X₅ to X₈ is CRₓ, and the Rₓ is cyano or fluorine.

According to an embodiment of the present disclosure, at least one of X₇ and X₈ is CRₓ and the Rₓ is cyano or fluorine.

According to an embodiment of the present disclosure, X₇ is CRₓ, and the Rₓ is cyano.

According to an embodiment of the present disclosure, in the metal complex, at least two of X₃ to X₈ are selected from CRₓ, one of the Rₓ is cyano or fluorine, and another one of the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least two of X₃ to X₈ are selected from CRₓ, one of the Rₓ is cyano or fluorine, and another one of the Rₓ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, X₇ is selected from CRₓ, and the Rₓ is cyano or fluorine; X₈ is selected from CRₓ, and the Rₓ is selected from deuterium, substituted or unsubstituted aryl having 6 to 18 carbon atoms, substituted or unsubstituted heteroaryl having 3 to 18 carbon atoms, or a combination thereof.

According to an embodiment of the present disclosure, in the metal complex, U₁ to U₈ are, at each occurrence identically or differently, selected from CRᵤ, and the Rᵤ is selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, and combinations thereof.

According to an embodiment of the present disclosure, Rᵤ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, and combinations thereof.

According to an embodiment of the present disclosure, Rᵤ is, at each occurrence identically or differently, selected from the group consisting of: hydrogen, deuterium, fluorine, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

According to an embodiment of the present disclosure, in the metal complex, at least one or at least two of U₁ to U₈ are selected from CRᵤ, and the Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of the Rᵤ is at least 4.

According to an embodiment of the present disclosure, at least one or at least two of U₁ to U₄ and/or U₅ to U₈ are selected from CRₓ, the Rₓ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of the Rᵤ is at least 4.

According to an embodiment of the present disclosure, in the metal complex, at least one of U₁ to U₄ is selected from CRₓ, at least one of Y₃ to Y₆ is selected from CR_{y}, and the Rᵤ and the R_{y} are selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, at least one of U₅ to U₈ is selected from CRₓ, at least one of Y₃ to Y₅ is selected from CR_{y}, and the Rᵤ and the R_{y} are selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, at least one of U₁ to U₄ is selected from CRₓ, at least one of U₅ to U₈ is selected from CRᵤ, at least one of Y₃ to Y₆ is selected from CR_{y}, and the Rᵤ and the R_{y} are selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, in the metal complex, at least one of U₂, U₃, U₆, and U₇ is selected from CRₓ, at least one of Y₄ and Y₅ is selected from CR_{y}, and the Rᵤ and the R_{y} are selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, at least one of U₂ and U₃ is selected from CRᵤ, at least one of U₆ and U₇ is selected from CRₓ, at least one of Y₄ and Y₅ is selected from CR_{y}, and the Rᵤ and the R_{y} are selected from substituted or unsubstituted alkyl having 1 to 20 carbon atoms, substituted or unsubstituted cycloalkyl having 3 to 20 ring carbon atoms, or a combination thereof.

According to an embodiment of the present disclosure, U₃ is selected from CRᵤ, U₆ is selected from CRᵤ, Y₅ is selected from CR_{y}, and the Rᵤ and the R_{y} are selected from substituted or unsubstituted alkyl having 1 to 20 carbon atoms, substituted or unsubstituted cycloalkyl having 3 to 20 ring carbon atoms, or a combination thereof; and the total number of carbon atoms in the Rᵤ is greater than or equal to 4, and the total number of carbon atoms in the R_{y} is greater than or equal to 4.

According to an embodiment of the present disclosure, U₂ is selected from CRᵤ, U₆ is selected from CRᵤ, Y₄ is selected from CR_{y}, and the Rᵤ and the R_{y} are selected from substituted or unsubstituted alkyl having 1 to 20 carbon atoms, substituted or unsubstituted cycloalkyl having 3 to 20 ring carbon atoms, or a combination thereof; and the number of carbon atoms in the Rᵤ in each of U₂ and U₆ is greater than or equal to 4, and the number of carbon atoms in the R_{y} in Y₄ is greater than or equal to 4.

According to an embodiment of the present disclosure, in the metal complex, Lₐ is, at each occurrence identically or differently, selected from the group consisting of Lₐ₁ to Lₐ₁₄₇₄;
wherein Lₐ₁ to Lₐ₁₄₇₄ each have the following structure:

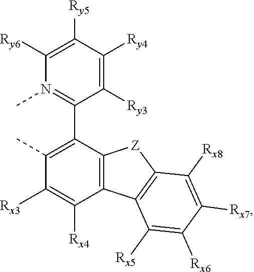

wherein R_{y3} to R_{y6}, Rₓ₃ to Rₓ₈, and Z are selected from atoms or groups in the table of claim 11.

According to an embodiment of the present disclosure, in the metal complex. L_{b} is, at each occurrence identically or differently, selected from the group consisting of L_{b1} to L_{b160}, wherein the structures of L_{b1} to L_{b160} are shown in claim 12.

According to an embodiment of the present disclosure, hvdrogens in L_{b1} to L_{b18}, L_{b20} to L_{b26}, and L_{b31} to L_{b160} can be partially or fully substituted with deuterium.

According to an embodiment of the present disclosure, the metal complex has a structure of Ir(Lₐ)(L_{b})₂, wherein the two L_{b} are the same or different, Lₐ is, at each occurrence identically or differently, selected from the group consisting of Lₐ₁ to Lₐ₁₄₇₄, and L_{b} is, at each occurrence identically or differently, selected from one or two of the group consisting of L_{b1} to L_{b160}.

According to an embodiment of the present disclosure, the metal complex is selected from the group consisting of Metal Complex 1 to Metal Complex 1516, and Metal Complex 1 to Metal Complex 1516 each have a structure of Ir(Lₐ)(L_{b})₂, wherein the two L_{b} are the same, and Lₐ and L_{b} are selected from respective structures in the table of claim 13.

According to an embodiment of the present disclosure, E₁ to E₄ are, at each occurrence identically or differently, selected from C or CR_{c}, and one of E₁ and E₂ is selected from C and joined to the structure

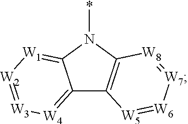

and/or V₁ to V₅ are, at each occurrence identically or differently, selected from CRᵥ; and/or W₁ to W₈ are, at each occurrence identically or differently, selected from CR_{w}.

According to an embodiment of the present disclosure, Ar₁ and Ar₂ are, at each occurrence identically or differently, selected from substituted or unsubstituted aryl having 6 to 20 carbon atoms, substituted or unsubstituted heteroaryl having 3 to 20 carbon atoms, or a combination thereof.

According to an embodiment of the present disclosure, Ar₁ and Ar₂ are, at each occurrence identically or differently, selected from the group consisting of: substituted or unsubstituted phenyl, substituted or unsubstituted naphthyl, substituted or unsubstituted phenanthryl, substituted or unsubstituted biphenyl, substituted or unsubstituted terphenyl, substituted or unsubstituted triphenylene, substituted or unsubstituted fluorenyl, substituted or unsubstituted carbazolyl, substituted or unsubstituted dibenzofuryl, substituted or unsubstituted dibenzothienyl, and combinations thereof.

According to an embodiment of the present disclosure, L₁ and L₂ are, at each occurrence identically or differently, selected from a single bond, substituted or unsubstituted arylene having 6 to 20 carbon atoms, substituted or unsubstituted heteroarylene having 3 to 20 carbon atoms, or a combination thereof.

According to an embodiment of the present disclosure, L₁ and L₂ are, at each occurrence identically or differently, selected from a single bond, substituted or unsubstituted phenylene, substituted or unsubstituted biphenylene, substituted or unsubstituted naphthylene, substituted or unsubstituted pyridylene, or a combination thereof.

According to an embodiment of the present disclosure, L₁ and L₂ are, at each occurrence identically or differently, selected from a single bond, substituted or unsubstituted phenylene, or a combination thereof.

According to an embodiment of the present disclosure, R_{c}, Rᵥ, and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 20 carbon atoms, substituted or unsubstituted heteroaryl having 3 to 20 carbon atoms, cyano, and combinations thereof.

According to an embodiment of the present disclosure, R_{c}, Rᵥ, and R_{w} are, at each occurrence identically or differently, selected from the group consisting of: hydrogen, deuterium, fluorine, substituted or unsubstituted phenyl, substituted or unsubstituted naphthyl, substituted or unsubstituted biphenyl, substituted or unsubstituted terphenyl, substituted or unsubstituted triphenylene, substituted or unsubstituted fluorenyl, substituted or unsubstituted carbazolyl, substituted or unsubstituted dibenzofuryl, substituted or unsubstituted dibenzothienyl, cyano, and combinations thereof.

According to an embodiment of the present disclosure, the first compound is selected from the group consisting of Compound B-1 to Compound B-230, wherein Compound B-1 to Compound B-230 are selected from the structures in claim 18.

According to an embodiment of the present disclosure, hydrogens in Compound B-1 to Compound B-230 can be partially or fully substituted with deuterium.

According to an embodiment of the present disclosure, the organic layer further comprises a second compound, and the second compound comprises at least one chemical group selected from the group consisting of: benzene, pyridine, arylamine, carbazole, azacarbazole, indolocarbazole, dibenzothiophene, azadibenzothiophene, dibenzofuran, azadibenzofuran, dibenzoselenophene, triphenylene, fluorene, silafluorene, naphthalene, phenanthrene, and combinations thereof.

According to an embodiment of the present disclosure, the second compound comprises at least one chemical group selected from the group consisting of: benzene, arylamine, carbazole, indolocarbazole, fluorene, dibenzothiophene, dibenzofuran, and combinations thereof.

According to an embodiment of the present disclosure, the second compound has a structure represented by Formula 3 or Formula 4:

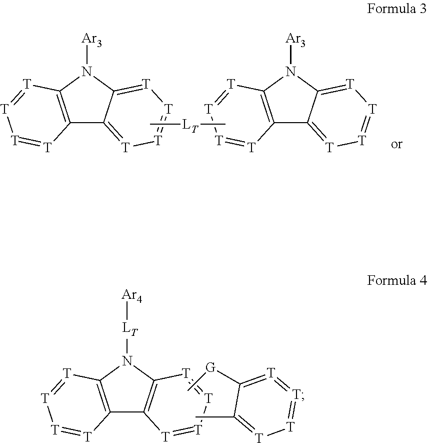

wherein
G is, at each occurrence identically or differently, selected from C(R_{g})₂, NR_{g}, O, or S;
L_{T} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof,
T is, at each occurrence identically or differently, selected from C, CRₜ, or N;
Rₜ and R_{g} are, at each occurrence identically or differently, selected from the group consisting of; hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₃ and Ar₄ are, at each occurrence identically or differently, selected from substituted or unsubstituted aryl having 6 to 30 carbon atoms, substituted or unsubstituted heteroaryl having 3 to 30 carbon atoms, or a combination thereof, and
adjacent substituents Rₜ, R_{g} can be optionally joined to form a ring.

In the present disclosure, the expression that “adjacent substituents Rₜ, R_{g}, can be optionally joined to form a ring” is intended to mean that any one or more of groups of adjacent substituents, such as two substituents Rₜ, two substituents R_{g}, and substituents Rₜ and R_{g}, can be joined to form a ring. Obviously, it is also possible that none of these substituents are joined to form a ring.

According to an embodiment of the present disclosure, the second compound has a structure represented by one of Formula 3-a to Formula 3-j and Formula 4-a to Formula 4-f:

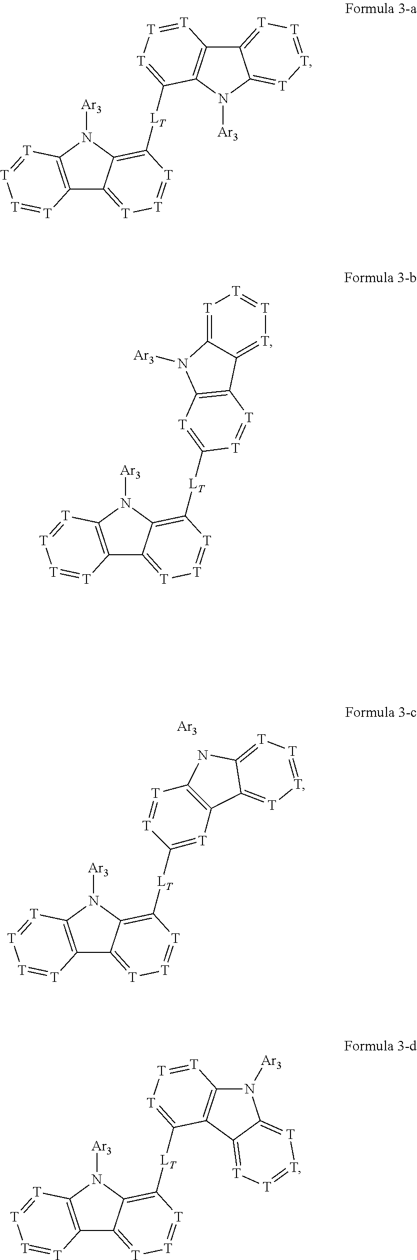

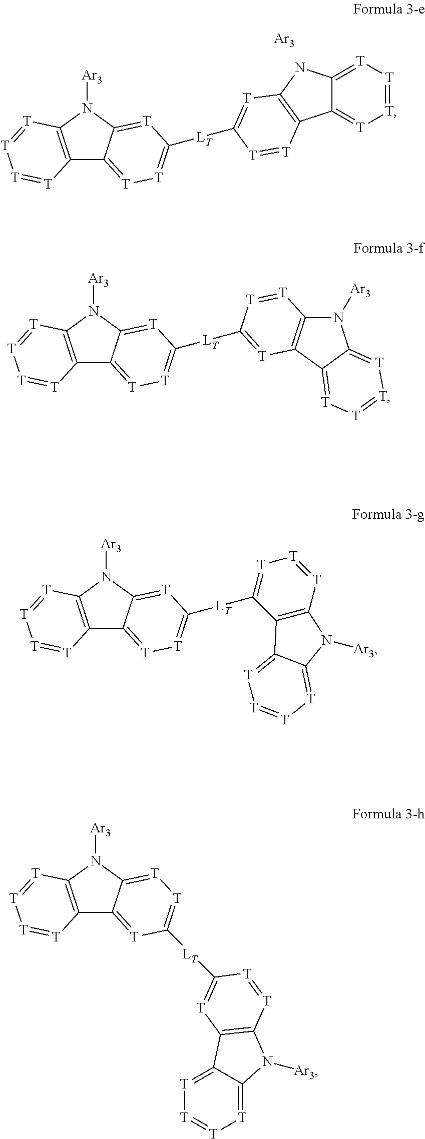

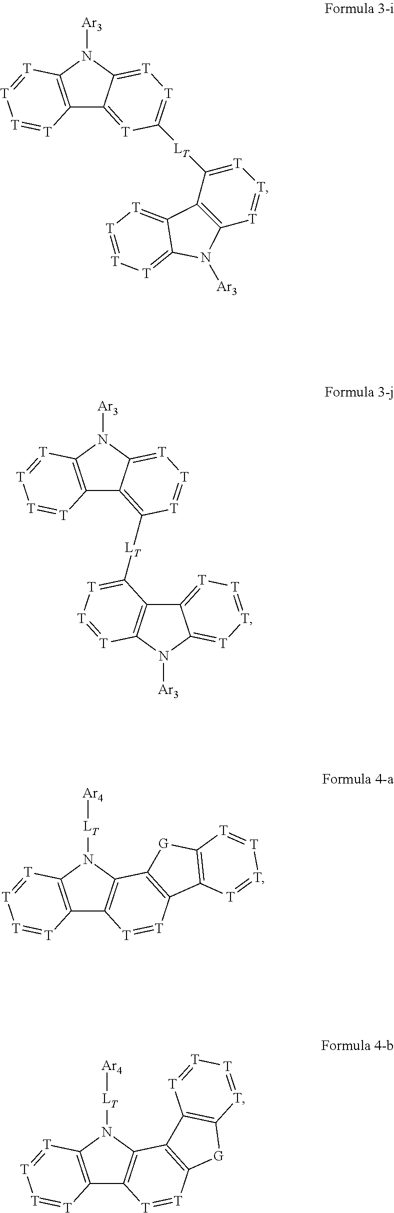

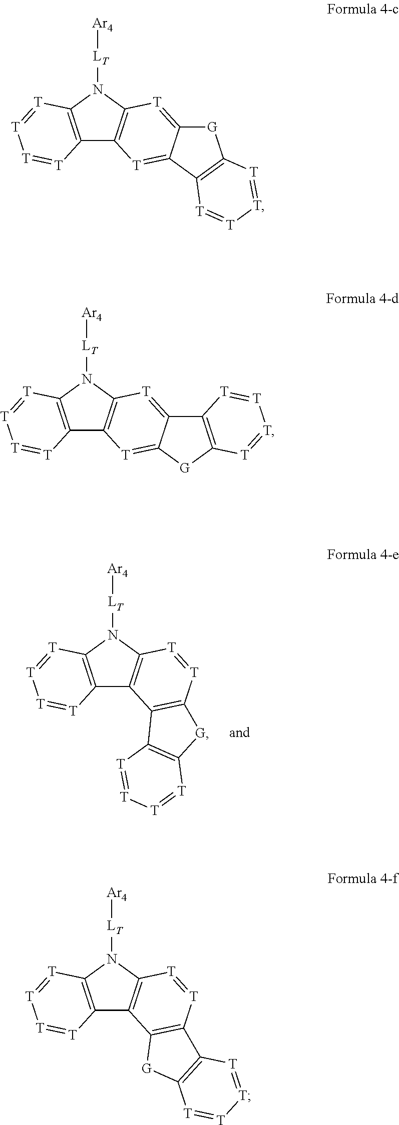

wherein
T is, at each occurrence identically or diferently, selected from CRₜ or N;
G is, at each occurrence identically or differently, selected from C(R_{g})₂, NR_{g}, O, or S; when a plurality of R_{g} are present at the same time, the plurality of R_{g} are the same or different;
L_{T} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
Ar₃ and Ar₄ are, at each occurrence identically or differently, selected from substituted or unsubstituted aryl having 6 to 30 carbon atoms, substituted or unsubstituted heteroaryl having 3 to 30 carbon atoms, or a combination thereof;
Rₜ and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₜ, R_{g} can be optionally joined to form a ring.

According to an embodiment of the present disclosure, the second compound is selected from the group consisting of Compound PH-1 to Compound PH-115, wherein Compound PH-1 to Compound PH-115 are selected from the structures in claim 21.

According to another embodiment of the present disclosure, hydrogens in Compound PH-1 to Compound PH-115 can be partially or fully substituted with deuterium.

According to another embodiment of the present disclosure, a composition is further disclosed. The composition comprises a first metal complex having a structure of Formula 1 and a first compound having a structure of Formula 2.

According to another embodiment of the present disclosure, an organic layer is further disclosed. The organic layer comprises the composition according to the preceding embodiment.

According to another embodiment of the present disclosure, a display assembly is further disclosed. The display assembly comprises the described organic electroluminescent device or the described organic layer.

According to another embodiment of the present disclosure, an electronic device is further disclosed. The electronic device comprises the described organic electroluminescent device, the described organic layer, or the described display assembly.

Combination with Other Materials

The materials described in the present disclosure for a particular layer in an organic light-emitting device can be used in combination with various other materials present in the device. The combinations of these materials are described in more detail in U.S. Pat. Pub. No. 20160359122 at paragraphs 0132-0161, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Pat. Pub. No. 20150349273, which is incorporated herein by reference in its entirety. The materials described or referred to in the disclosure are non-limiting examples of materials that may be useful in combination with the compounds disclosed herein, and one of skill in the art can readily consult the literature to identify other materials that may be useful in combination.

With reference to preparation methods in the related art or prior applications of the applicant, the first metal complex, the first compound, and the second compound that are used in the present disclosure can be easily obtained. For example, the first metal complex of the present disclosure can be prepared with reference to CN111518139A (or related reference US20200251666A1), CN115557997A, and CN115700256A, the first compound of the present disclosure can be prepared with reference to US20240016057A1 and CN117327056A, and the second compound of the present disclosure can be prepared with reference to US2019198780A1 and CN115368293A. Methods for preparing the first metal complex, the first compound, and the second compound are not repeated here. The documents listed above are merely exemplary, and other documents can be easily obtained by those skilled in the art.

A method for preparing an electroluminescent device is not limited herein. The preparation methods in the following examples are merely examples and are not to be construed as limiting. Based on the related art, those skilled in the art can make reasonable improvements on the preparation methods in the following examples. For example, the proportions of various materials in an emissive layer are not particularly limited. Those skilled in the art can reasonably select the proportions within a certain range based on the related art. For example, taking the total weight of the materials in the emissive layer for reference, a host material may account for 80% to 99% and an emissive material may account for 1% to 20%; or the host material may account for 90% to 99% and the emissive material may account for 1% to 10%; or the host material may account for 94% to 99% and the emissive material may account for 1% to 6%. Further, the host material may include one material or two materials, where the ratio of two host materials may be 99:1 to 1:99 in the host material; or the ratio may be 80:20 to 20:80; or the ratio may be 60:40 to 40:60. In the embodiments of the device, the characteristics of the device are tested using conventional equipment in the art (including, but not limited to, evaporation deposition system produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art.

### Device Example

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.1 to 2 Angstroms per second and a vacuum degree of about 10⁻⁸ Torr. Compound HT and Compound HT1 were co-deposited (at a weight ratio of 97:3) for use as a hole injection layer (HIL) with a thickness of 100 Å. Compound HT was used as a hole transporting layer (HTL) with a thickness of 350 Å. Compound PH-1 was used as an electron blocking layer (EBL) with a thickness of 50 Å. Metal Complex 1182 was doped in Compound PH-94 and Compound B-10, which were co-deposited for use as an emissive layer (EML) with a thickness of 400 Å, where the weight ratio of Compound PH-94, Compound B-10, and Metal Complex 1182 was 71:23:6. Compound HB was used as a hole blocking layer (HBL) with a thickness of 50 Å. On the HBL. Compound ET and 8-hydroxyquinolinolato-lithium (Liq) were co-deposited (at a weight ratio of 40:60) for use as an electron transporting layer (ETL) with a thickness of 350 Å. Finally, 8-hydroxyquinolinolato-lithium (Liq) was deposited for use as an electron injection layer with a thickness of 1 nm and Al was deposited for use as a cathode with a thickness of 120 nm. The device was transferred back to the glovebox and encapsulated with a glass lid to complete the device.

### Device Comparative Example 1

Device Comparative Example 1 was prepared by the same method as Device Example 1, except that in the EML, Metal Complex 1182 was replaced with Compound GD1.

### Device Comparative Example 2

Device Comparative Example 2 was prepared by the same method as Device Example 1, except that in the EML, Metal Complex 1182 was replaced with Compound GD2.

### Device Example 2

Device Example 2 was prepared by the same method as Device Example 1, except that in the EML Compound B-1 was replaced with Compound B-145 and Metal Complex 1182 was replaced with Metal Complex 1183.

### Device Example 3

Device Example 3 was prepared by the same method as Device Example 1, except that in the EML, Compound PH-94 was replaced with Compound PH-47 and Metal Complex 1182 was replaced with Metal Complex 1183.

### Device Example 4

Device Example 4 was prepared by the same method as Device Example 2 except that in the EML, Compound PH-94 was replaced with Compound PH-75 and Compound B-145 was replaced with Compound B-12.

Detailed structures and thicknesses of layers of the devices are shown in the following table. A layer using more than one material is obtained by doping different compounds at their weight ratio as recorded.

TABLE 1
Part of device structures of Device Examples 1 to 4 and Comparative Examples 1 and 2

| Device ID | HIL | HTL | EBL | EML | HBL | ETL |
|---|---|---|---|---|---|---|
| Example 1 | Compound | Compound | Compound | Compound PH- | Compound | Compound |
| | HT:Compound | HT (350 | PH-1 | 94:Compound | HB (50 | ET:Liq |
| | HT1 (97:3) | Å) | (50 Å) | B-10:Metal | Å) | (40:60) |
| | (100 Å) | | | Complex 1182 | | (350 Å) |
| | | | | (71:23:6) | | |
| | | | | (400 Å) | | |
| Comparative | Compound | Compound | Compound | Compound | Compound | Compound |
| Example 1 | HT:Compound | HT (350 | PH-1 | PH-94:Compound | HB (50 | ET:Liq |
| | HT1 (97:3) | Å) | (50 Å) | B-10:Compound | Å) | (40:60) |
| | (100 Å) | | | GD1 (71:23:6) | | (350 Å) |
| | | | | (400 Å) | | |
| Comparative | Compound | Compound | Compound | Compound PH- | Compound | Compound |
| Example 2 | HT:Compound | HT (350 | PH-1 | 94:Compound | HB (50 | ET:Liq |
| | HT1 (97:3) | Å) | (50 Å) | B-10:Compound | Å) | (40:60) |
| | (100 Å) | | | GD2 (71:23:6) | | (350 Å) |
| | | | | (400 Å) | | |
| Example 2 | Compound | Compound | Compound | Compound PH- | Compound | Compound |
| | HT:Compound | HT (350 | PH-1 | 94:Compound | HB (50 | ET:Liq |
| | HT1 (97:3) | Å) | (50 Å) | B-145:Metal | Å) | (40:60) |
| | (100 Å) | | | Complex | | (350 Å) |
| | | | | 1183(71:23:6) | | |
| | | | | (400 Å) | | |
| Example 3 | Compound | Compound | Compound | Compound PH- | Compound | Compound |
| | HT:Compound | HT (350 | PH-1 | 47:Compound | HB (50 | ET:Liq |
| | HT1 (97:3) | Å) | (50 Å) | B-10:Metal | Å) | (40:60) |
| | (100 Å) | | | Complex 1183 | | (350 Å) |
| | | | | (71:23:6) | | |
| | | | | (400 Å) | | |
| Example 4 | Compound | Compound | Compound | Compound PH- | Compound | Compound |
| | HT:Compound | HT (350 | PH-1 | 75:Compound | HB (50 | ET:Liq |
| | HT1 (97:3) | Å) | (50 Å) | B-12:Metal | Å) | (40:60) |
| | (100 Å) | | | Complex 1183 | | (350 Å) |
| | | | | (71:23:6) | | |
| | | | | (400 Å) | | |

The materials used in the devices have the following structures:

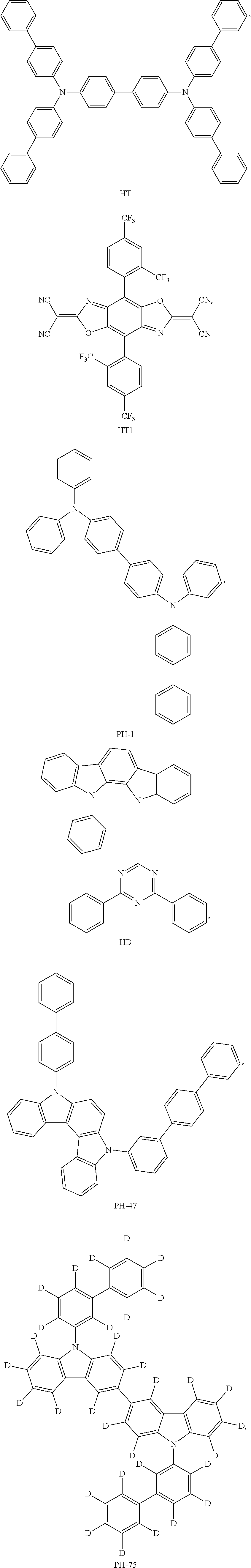

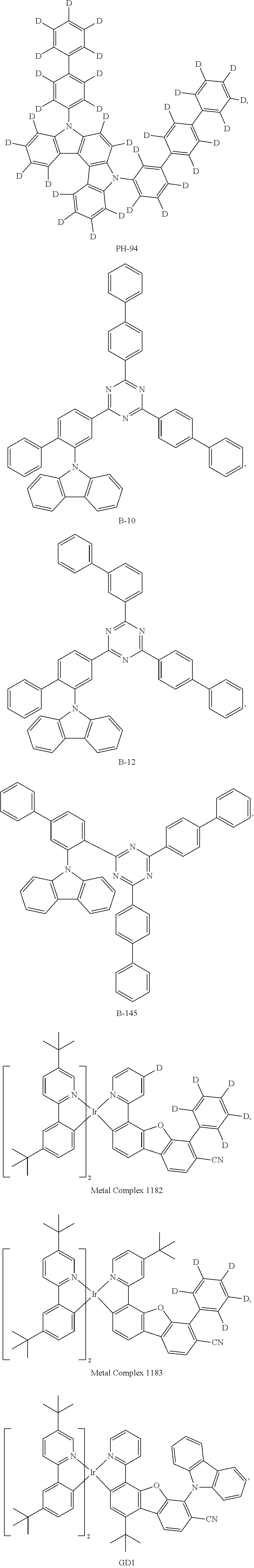

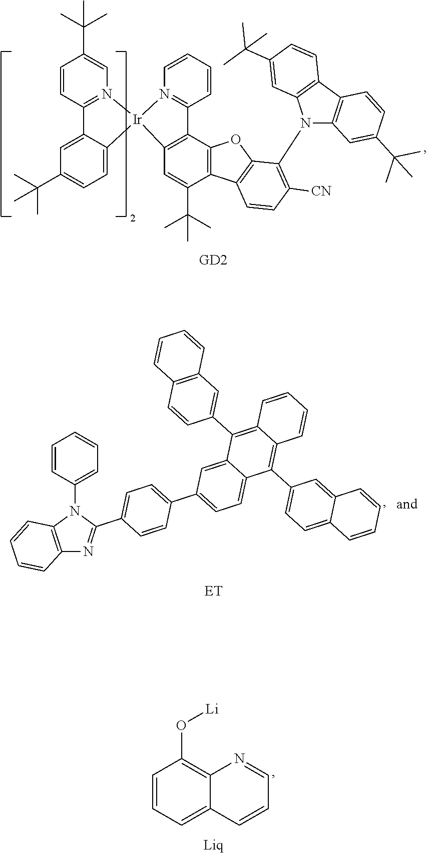

The current-voltage-luminance (IVL) characteristics of the devices were measured. CIE data and external quantum efficiency (EQE) were measured at a constant current density of 15 mA/cm²; and device lifetimes (LT97) were measured at a constant current density of 80 mA/cm². The data are shown in Table 2.

TABLE 2
Device data of Examples 1 to 4 and Comparative Examples 1 and 2

| Device ID | CIE (x, y) | EQE (%) | LT97 (h) |
|---|---|---|---|
| Example 1 | (0.364, 0.618) | 23.5 | 103 |
| Comparative | (0,312, 0.654) | 23.8 | 42 |
| Example 1 | | | |
| Comparative | (0.297, 0.664) | 25.7 | 20 |
| Example 2 | | | |
| Example 2 | (0.340, 0.635) | 24.7 | 133 |
| Example 3 | (0.341, 0.634) | 24.2 | 67 |
| Example 4 | (0.337, 0.637) | 24.2 | 75 |

### DISCUSSION

In Example 1, Comparative Example 1, and Comparative Example 2, Example 1 and Comparative Example 1 had basically the same efficiency which was at an extremely high level, and the device lifetime of Example 1 was significantly increased by 1.45 times longer compared with that of Comparative Example 1. Compared with Comparative Example 2, Example 1 had slightly reduced efficiency which was still at an extremely high level, and the device lifetime of Example 1 was significantly increased by 4.15 times longer compared with that of Comparative Example 2. Differences between Example 1 and Comparative Examples 1 and 2 lie only in different first metal complexes in the emissive layer, indicating that a combination of the first metal complex and the first compound of the present disclosure has unexpectedly good performance, especially in improving the device lifetime.

In Example 2 to Example 4, the emissive layers all used the first compound of the present disclosure and the first metal complex of the present disclosure, and the devices all had extremely high efficiency and relatively long lifetimes as the device in Example 1.

### Device Example 5

Device Example 5 was prepared by the same method as Device Example 1, except that in the EML, Metal Complex 1182 was replaced with Metal Complex 1183.

### Device Example 6

Device Example 6 was prepared by the same method as Device Example 5, except that in the EML, Compound PH-94 was replaced with Compound PH-115 and Compound B-10 was replaced with Compound B-6 and the weight ratio ofthe EML was changed to 66:28:6.

### Device Comparative Example 3

Device Comparative Example 3 was prepared by the same method as Device Example 5 except that in the EML, Compound B-1 was replaced with Compound C-1.

### Device Comparative Example

Device Comparative Example 4 was prepared by the same method as Device Example 5, except that in the EML, Metal Complex 1183 was replaced with Compound GD3.

### Device Comparative Example 5

Device Comparative Example 5 was prepared by the same method as Device Comparative Example 3, except that in the EML, Metal Complex 1183 was replaced with Compound GD3.

Detailed structures and thicknesses of layers of the devices are shown in the following table. A layer using more than one material is obtained by doping different compounds at their weight ratio as recorded.

TABLE 3
Part of device structures of Device Example 5 and 6 and Comparative Examples 3 to 5

| Device ID | HIL | HTL | EBL | EML | HBL | ETL |
|---|---|---|---|---|---|---|
| Example 5 | Compound | Compound | Compound | Compound | Compound | Compound |
| | HT:Compound | HT (350 | PH-1 | PH-94:Compound | HB (50 | ET:Liq |
| | HT1 (97:3) | Å) | (50 Å) | B-10:Metal | Å) | (40:60) |
| | (100 Å) | | | Complex 1183 | | (350 Å) |
| | | | | (71:23:6) (400 Å) | | |
| Example 6 | Compound | Compound | Compound | Compound | Compound | Compound |
| | HT:Compound | HT (350 | PH-1 | PH-115:Compound | HB (50 | ET:Liq |
| | HT1 (97:3) | Å) | (50 Å) | B-6:Metal | Å) | (40:60) |
| | (100 Å) | | | Complex 1183 | | (350 Å) |
| | | | | (66:28:6) (400 Å) | | |
| Comparative | Compound | Compound | Compound | Compound | Compound | Compound |
| Example 3 | HT:Compound | HT (350 | PH-1 | PH-94:Compound | HB (50 | ET:Liq |
| | HT1 (97:3) | Å) | (50 Å) | C-1:Metal | Å) | (40:60) |
| | (100 Å) | | | Complex 1183 | | (350 Å) |
| | | | | (71:23:6) (400 Å) | | |
| Comparative | Compound | Compound | Compound | Compound | Compound | Compound |
| Example 4 | HT:Compound | HT (350 | PH-1 | PH-94:Compound | HB (50 | ET:Liq |
| | HT1 (97:3) | Å) | (50 Å) | B-10:Compound | Å) | (40:60) |
| | (100 Å) | | | GD3 (71:23:6) | | (350 Å) |
| | | | | (400 Å) | | |
| Comparative | Compound | Compound | Compound | Compound | Compound | Compound |
| Example 5 | HT:Compound | HT (350 | PH-1 | PH-94:Compound | HB (50 | ET:Liq |
| | HT1 (97:3) | Å) | (50 Å) | C-1:Compound | Å) | (40:60) |
| | (100 Å) | | | GD3 (71:23:6) | | (350 Å) |
| | | | | (400 Å) | | |

The new materials used in the devices have the following structures:

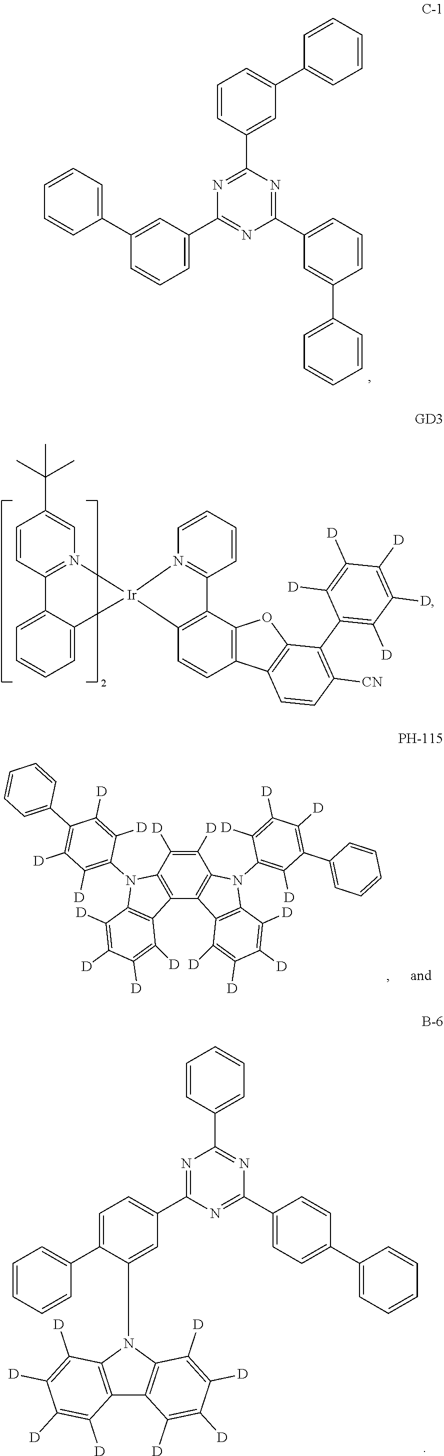

Table 4 shows CIE data and EQE measured at a constant current density of 15 mA/cm² and device lifetimes (LT97) measured at a luminance of 11500 cd/nM².

TABLE 4
Device data of Examples 5 and 6 and Comparative Examples 3 to 5

| Device ID | CIE (x, y) | EQE (%) | LT97 (h) |
|---|---|---|---|
| Example 5 | (0.341, 0.634) | 24.3 | 3105 |
| Example 6 | (0.337, 0.637) | 24.1 | 3461 |
| Comparative | (0.334, 0.640) | 24.6 | 1767 |
| Example 3 | | | |
| Comparative | (0.346, 0.632) | 22.3 | 974 |
| Example 4 | | | |
| Comparative | (0.339, 0.637) | 22.1 | 854 |
| Example 5 | | | |

### DISCUSSION

Example 5 and Comparative Example 3 both used the first metal complex 1183 of the present disclosure in the emissive layers and differed only in that the emissive layers used different first compounds and Example 5 used the first compound of the present disclosure. As can be seen from the device results, Example 5 and Comparative Example 3 had basically the same efficiency which was at an extremely high level, and the device lifetime of Example 5 was significantly increased by 75.7% compared with that of Comparative Example 3.

Example 5 and Comparative Example 4 both used the first compound B-10 of the present disclosure in the emissive layers and differed only in that the emissive layers used different metal complexes and Example 5 used the metal complex of the present disclosure. As can be seen from the device results, Example 5 had slightly higher efficiency than Comparative Example 4; and the device lifetime of Example 5 was significantly increased by 2.19 times longer compared with that of Comparative Example 4.

As can be seen from the above data, when the first metal complex of the present disclosure is matched with the first compound of the present disclosure, the device lifetime is significantly improved, and the device effect is better.

Secondly. Comparative Example 5 used a metal complex not belonging to the present disclosure and a first compound not belonging to the present disclosure.

Comparative Example 3 and Comparative Example 5 differed only in that Comparative Example 3 used the first metal complex of the present disclosure. As can be seen from the results, the lifetime LT97 of Comparative Example 3 was increased by only 793 h and by 1.07 times longer.

Comparative Example 4 and Comparative Example 5 differed only in that Comparative Example 4 used the first compound of the present disclosure. As can be seen from the results, the lifetime of Comparative Example 4 was increased by 120 h and by only 14%.

Example 5 and Comparative Example 5 differed in that Example 5 used both the first metal complex of the present disclosure and the first compound of the present disclosure. As can be seen from the results, the lifetime of Example 5 was increased by 2251 h and by 2.64 times longer.

It can be seen that compared with Comparative Examples 3 and 4, Example 5 has a significantly improved lifetime, achieving the effect that “1+1>2”. This indicates that the first metal complex and the first compound of the present disclosure, when matched for use, can effectively improve the device performance and achieve unexpected technical effects.

Therefore, the comparisons of the above data all indicate that the first compound and the first metal complex of the present disclosure are more matched, and their combination can more significantly improve the device performance and especially achieve a very long device lifetime, proving the unique advantages of the combination of the first compound and the first metal complex selected in the present disclosure. Further, when the first metal complex and the first compound of the present disclosure are matched with a different second compound in Example 6, the device lifetime is also significantly improved.

To conclude, the combination of the first compound selected in the present disclosure with the particular first metal complex of the present disclosure can significantly improve the device lifetime while maintaining extremely high device efficiency, can achieve better device performance, and has unexpected unique advantages. Thus, a good combination of materials in the emissive layer is provided for the industry.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising:
an anode,
a cathode, and
an organic layer disposed between the anode and the cathode, wherein the organic layer comprises at least a first metal complex and a first compound,
wherein the first metal complex comprises a metal M and a ligand Lₐ coordinated to the metal M, and Lₐ has a structure represented by Formula 1: 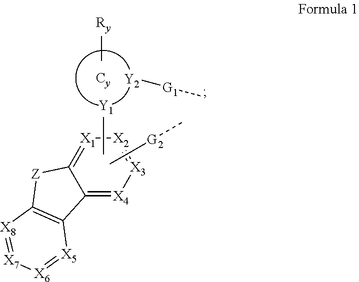
wherein the metal M is selected from a metal with a relative atomic mass greater than 40;
C_{y} is, at each occurrence identically or differently, selected from an aromatic ring having 6 to 24 ring atoms and comprising Y₁ and Y₂, a heteroaromatic ring having 5 to 24 ring atoms and comprising Y₁ and Y₂, or a combination thereof;
G₁ and G₂ are, at each occurrence identically or differently, selected from a single bond, O, or S;
X₁ to X₄ are, at each occurrence identically or differently, selected from C, CRₓ, or N, and one of X₁ to X₄ is selected from C and joined to Y₁;
when X₁, X₂, X₃ or X₄ joined to G₂ is selected from N, G₂ is selected from a single bond, and X₁, X₂, X₃, or X₄ is joined to the metal by forming a metal-nitrogen bond through G₂; or when X₁, X₂, X₃ or X₄ joined to G₂ is selected from C, G₂ is selected from a single bond, O, or S, and X₁, X₂, X₃, or X₄ is joined to the metal through G₂;
X₅ to X₈ are, at each occurrence identically or differently, selected from CRₓ or N;
Z is, at each occurrence identically or differently, selected from the group consisting of O, S, Se, NR′, CR′R′, SiR′R′, and GeR′R′; when two R′ are present at the same time, the two R′ are the same or different;
Y₁ and Y₂ are, at each occurrence identically or differently, selected from C or N;
R_{y} represents, at each occurrence identically or differently, mono-substitution or multiple substitutions, when a plurality of R_{y} are present, the plurality of R_{y} are the same or different;
Rₓ, R′, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof,
at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{y} can be optionally joined to form a ring;
adjacent substituents R′, Rₓ can be optionally joined to form a ring; and
the metal complex is not 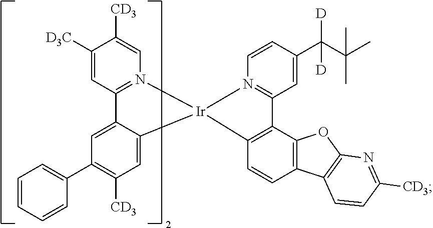
wherein the first compound has a structure represented by Formula 2: 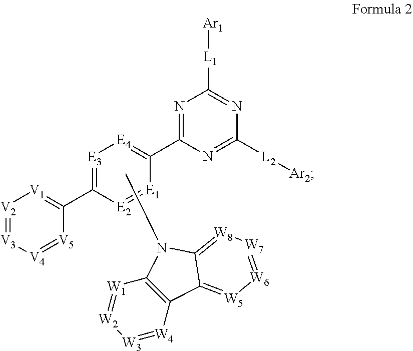
wherein in Formula 2, E₁ to E₄ are, at each occurrence identically or differently, selected from C, CR_{c}, or N;
V₁ to V₅ are, at each occurrence identically or differently, selected from CRᵥ or N;
W₁ to W₈ are, at each occurrence identically or differently, selected from CRₓ, or N,
L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms, or a combination thereof;
R_{c}, Rᵥ, and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{c} can be optionally joined to form a ring, adjacent substituents Rᵥ can be optionally joined to form a ring, and adjacent substituents R_{w} can be optionally joined to form a ring.

2. The organic electroluminescent device according to claim 1, wherein C_{y} is, at each occurrence identically or differently, selected from any structure in the group consisting of the following: 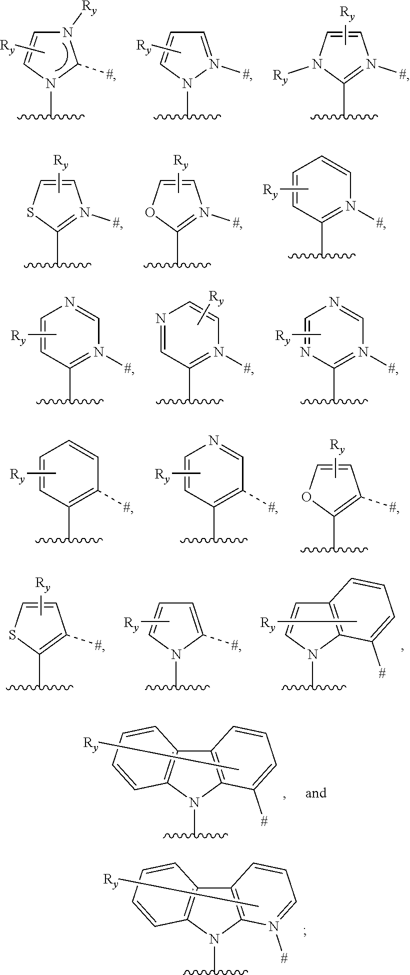
wherein
R_{y} represents, at each occurrence identically or differently, mono-substitution or multiple substitutions; when a plurality of R_{y} are present in any structure, the plurality of R_{y} are the same or different;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{y} can be optionally joined to form a ring; and
“#” represents a position where the metal M is joined at, and 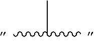
represents a position where X₁, X₂, X₃, or X₄ is joined at.

3. The organic electroluminescent device according to claim 1, wherein the metal complex has a general formula of M(Lₐ)ₘ(L_{b})ₙ(L_{c})_{q}; wherein the metal M is, at each occurrence identically or differently, selected from the group consisting of Cu, Ag, Au, Ru, Rh, Pd, Os, Ir, and Pt; preferably, the metal M is, at each occurrence identically or differently, selected from Pt or Ir;
Lₐ, L_{b}, and L_{c} are a first ligand, a second ligand and a third ligand coordinated to the metal M, respectively, and L_{c} is the same as or different from Lₐ or L_{b}; wherein Lₐ, L_{b} and L_{c} can be optionally joined to form a multidentate ligand;
m is selected from 1, 2, or 3, n is selected from 0, 1, or 2, q is selected from 0, 1, or 2, and m+n+q is equal to an oxidation state of the metal M; when m is greater than or equal to 2, a plurality of Lₐ are the same or different; when n is equal to 2, two L_{b} are the same or different; when q is equal to 2, two L_{c} are the same or different;
L_{b} and Lₐ are, at each occurrence identically or differently, selected from a structure represented by any one of the group consisting of the following: 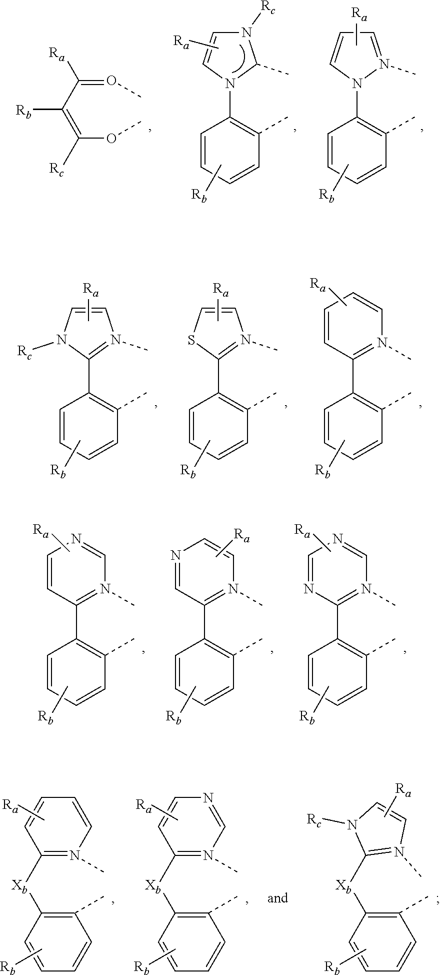
wherein
X_{b} is, at each occurrence identically or differently, selected from the group consisting of: O, S, Se, NR_{N1}, and CR_{C1}R_{C2};
Rₐ and R_{b} represent, at each occurrence identically or differently, mono-substitution, multiple substitutions, or non-substitution;
Rₐ, R_{b}, R_{c}, R_{N1}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{C1}, and R_{C2} can be optionally joined to form a ring.

4. The organic electroluminescent device according to claim 3, wherein the metal complex has a general formula of Ir(Lₐ)ₘ(L_{b})₃₋ₘ and has a structure represented by Formula 5: 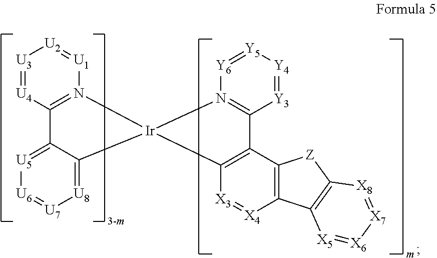
wherein
m is selected from 1, 2, or 3; when m is selected from 1, two L_{b} are the same or different; when m is selected from 2 or 3, a plurality of Lₐ are the same or different;
Z is selected from the group consisting of O, S, Se, NR′, CR′R′, SiR′R′, and GeR′R′; when two R′ are present at the same time, the two R′ are the same or different;
U₁ to U₈ are, at each occurrence identically or differently, selected from CRᵤ or N;
X₃ to X₈ are, at each occurrence identically or differently, selected from CRₓ or N;
Y₃ to Y₆ are, at each occurrence identically or differently, selected from CR_{y} or N;
Rₓ, R′, R_{y}, and R_{c} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one of Y₃ to Y₆ is selected from CR_{y}, and the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵤ can be optionally joined to form a ring;
adjacent substituents R_{y} can be optionally joined to form a ring; and
adjacent substituents R′ and Rₓ can be optionally joined to form a ring.

5. The organic electroluminescent device according to claim 4, wherein Z is, at each occurrence identically or differently, selected from O or S; preferably, Z is selected from O.

6. The organic electroluminescent device according to claim 4, wherein Y₃ to Y₆ are, at each occurrence identically or differently, selected from CR_{y} or N; at least one of Y₃ to Y₆ is selected from CR_{y}, and the R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, Y₃ to Y₆ are, at each occurrence identically or differently, selected from CR_{y} or N; at least one of Y₃ to Y₆ is selected from CR_{y}, and the R_{y} is, at each occurrence identically or differently, selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, and combinations thereof;
more preferably, Y₃ to Y₆ are, at each occurrence identically or differently, selected from CR_{y} or N; at least one of Y₄ and Y₅ is selected from CR_{y}, and the R_{y} is, at each occurrence identically or differently, selected from the group consisting of; substituted or unsubstituted alkyl having 3 to 6 carbon atoms, substituted or unsubstituted cycloalkyl having 3 to 6 ring carbon atoms, and combinations thereof.

7. The organic electroluminescent device according to claim 1, wherein X₃ to X₈ are, at each occurrence identically or differently, selected from CRₓ;
preferably, at least one of X₃ to X₈ is selected from CRₓ, and the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, cyano, and combinations thereof;
more preferably, at least one of X₃ to X₈ is selected from CRₓ, and the Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, cyano, and combinations thereof;
more preferably, X₄ is selected from CRₓ, and the Rₓ is selected from the group consisting of; deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and/or X₈ is selected from CRₓ, and the Rₓ is selected from deuterium, substituted or unsubstituted aryl having 6 to 18 carbon atoms, substituted or unsubstituted heteroaryl having 3 to 18 carbon atoms, or a combination thereof.

8. The organic electroluminescent device according to claim 1, wherein at least one of X₅ to X₈ is CRₓ, and the Rₓ is cyano or fluorine;
preferably, at least one of X₇ and X₈ is CRₓ, and the Rₓ is cyano or fluorine;
more preferably, X₇ is CRₓ, and the Rₓ is cyano.

9. The organic electroluminescent device according to claim 4, wherein U₁ to U₈ are, at each occurrence identically or differently, selected from CRᵤ, and the Rᵤ is selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, and combinations thereof;
preferably, Rᵤ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 12 carbon atoms, substituted or unsubstituted alkylgermanyl having 3 to 12 carbon atoms, and combinations thereof;
more preferably, Rᵤ is, at each occurrence identically or differently, selected from the group consisting of: hydrogen, deuterium, fluorine, methyl, ethyl, propyl, isopropyl, n-butyl, isobutyl, neopentyl, t-butyl, cyclopentyl, cyclohexyl, deuterated methyl, deuterated ethyl, deuterated propyl, deuterated isopropyl, deuterated n-butyl, deuterated isobutyl, deuterated neopentyl, deuterated t-butyl, deuterated cyclopentyl, deuterated cyclohexyl, phenyl, pyridyl, trimethylsilyl, trimethylgermanyl, and combinations thereof.

10. The organic electroluminescent device according to claim 4, wherein at least one or at least two of U₁ to U₈ are selected from CRᵤ, the Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of the Rᵤ is at least 4;
preferably, at least one or at least two of U₁ to U₄ and/or U₅ to U₈ are selected from CRᵤ, the Rᵤ is selected from substituted or unsubstituted alkyl having 1 to 20 carbon atoms, substituted or unsubstituted cycloalkyl having 3 to 20 ring carbon atoms, or a combination thereof, and the total number of carbon atoms in all of the Rᵤ is at least 4.

11. The organic electroluminescent device according to claim 1, wherein in the metal complex, Lₐ is, at each occurrence identically or differently, selected from the group consisting of Lₐ₁ to Lₐ₁₄₇₄;
wherein Lₐ₁ to Lₐ₁₄₁₁ each have the following structure: 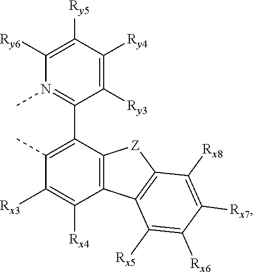
wherein R_{y3} to R_{y6}, Rₓ₃ to Rₓ₈, and Z are selected from atoms or groups in the following table:

| Lₐ | R_{y3} | R_{y4} | R_{y5} | R_{y6} | Rₓ₃ | Rₓ₄ | Rₓ₅ | Rₓ₆ | Rₓ₇ | Rₓ₈ | Z |
|---|---|---|---|---|---|---|---|---|---|---|---|
| Lₐ₁ | D | H | H | H | H | H | H | H | H | H | O |
| Lₐ₂ | H | D | H | H | H | H | H | H | H | H | O |
| Lₐ₃ | H | H | D | H | H | H | H | H | H | H | O |
| Lₐ₄ | H | H | H | D | H | H | H | H | H | H | O |
| Lₐ₅ | H | Rₙ₁ | H | H | H | H | H | H | H | H | O |
| Lₐ₆ | H | Rₙ₂ | H | H | H | H | H | H | H | H | O |
| Lₐ₇ | H | Rₙ₃ | H | H | H | H | H | H | H | H | O |
| Lₐ₈ | H | Rₙ₄ | H | H | H | H | H | H | H | H | O |
| Lₐ₉ | H | Rₙ₅ | H | H | H | H | H | H | H | H | O |
| Lₐ₁₀ | H | Rₙ₆ | H | H | H | H | H | H | H | H | O |
| Lₐ₁₁ | H | Rₙ₇ | H | H | H | H | H | H | H | H | O |
| Lₐ₁₂ | H | Rₙ₈ | H | H | H | H | H | H | H | H | O |
| Lₐ₁₃ | H | Rₙ₉ | H | H | H | H | H | H | H | H | O |
| Lₐ₁₄ | H | Rₙ₁₀ | H | H | H | H | H | H | H | H | O |
| Lₐ₁₅ | H | Rₙ₁₁ | H | H | H | H | H | H | H | H | O |
| Lₐ₁₆ | H | Rₙ₁₂ | H | H | H | H | H | H | H | H | O |
| Lₐ₁₇ | H | Rₙ₁₄ | H | H | H | H | H | H | H | H | O |
| Lₐ₁₈ | H | Rₙ₁₆ | H | H | H | H | H | H | H | H | O |
| Lₐ₁₉ | H | Rₙ₂₃ | H | H | H | H | H | H | H | H | O |
| Lₐ₂₀ | H | H | Rₙ₁ | H | H | H | H | H | H | H | O |
| Lₐ₂₁ | H | H | Rₙ₂ | H | H | H | H | H | H | H | O |
| Lₐ₂₂ | H | H | Rₙ₃ | H | H | H | H | H | H | H | O |
| Lₐ₂₃ | H | H | Rₙ₄ | H | H | H | H | H | H | H | O |
| Lₐ₂₄ | H | H | Rₙ₅ | H | H | H | H | H | H | H | O |
| Lₐ₂₅ | H | H | Rₙ₆ | H | H | H | H | H | H | H | O |
| Lₐ₂₆ | H | H | Rₙ₇ | H | H | H | H | H | H | H | O |
| Lₐ₂₇ | H | H | Rₙ₈ | H | H | H | H | H | H | H | O |
| Lₐ₂₈ | H | H | Rₙ₉ | H | H | H | H | H | H | H | O |
| Lₐ₂₉ | H | H | Rₙ₁₀ | H | H | H | H | H | H | H | O |
| Lₐ₃₀ | H | H | Rₙ₁₁ | H | H | H | H | H | H | H | O |
| Lₐ₃₁ | H | H | Rₙ₁₂ | H | H | H | H | H | H | H | O |
| Lₐ₃₂ | H | H | Rₙ₁₄ | H | H | H | H | H | H | H | O |
| Lₐ₃₃ | H | H | Rₙ₁₆ | H | H | H | H | H | H | H | O |
| Lₐ₃₄ | H | H | Rₙ₂₃ | H | H | H | H | H | H | H | O |
| Lₐ₃₅ | H | Rₙ₁₂ | Rₙ₂ | H | H | H | H | H | H | H | O |
| Lₐ₃₆ | H | Rₙ₁₆ | Rₙ₂ | H | H | H | H | H | H | H | O |
| Lₐ₃₇ | H | Rₙ₂ | Rₙ₂ | H | H | H | H | H | H | H | O |
| Lₐ₃₈ | D | Rₙ₂ | Rₙ₂ | H | H | H | H | H | H | H | O |
| Lₐ₃₉ | H | D | H | H | H | Rₙ₅ | H | H | H | H | O |
| Lₐ₄₀ | H | H | D | H | H | Rₙ₅ | H | H | H | H | O |
| Lₐ₄₁ | H | Rₙ₁ | H | H | H | Rₙ₅ | H | H | H | H | O |
| Lₐ₄₂ | H | Rₙ₂ | H | H | H | Rₙ₅ | H | H | H | H | O |
| Lₐ₄₃ | H | Rₙ₃ | H | H | H | Rₙ₅ | H | H | H | H | O |
| Lₐ₄₄ | H | Rₙ₄ | H | H | H | Rₙ₅ | H | H | H | H | O |
| Lₐ₄₅ | H | Rₙ₅ | H | H | H | Rₙ₅ | H | H | H | H | O |
| Lₐ₄₆ | H | Rₙ₆ | H | H | H | Rₙ₅ | H | H | H | H | O |
| Lₐ₄₇ | H | Rₙ₇ | H | H | H | Rₙ₅ | H | H | H | H | O |
| Lₐ₄₈ | H | Rₙ₈ | H | H | H | Rₙ₅ | H | H | H | H | O |
| Lₐ₄₉ | H | Rₙ₉ | H | H | H | Rₙ₅ | H | H | H | H | O |
| Lₐ₅₀ | H | Rₙ₁₀ | H | H | H | Rₙ₅ | H | H | H | H | O |
| Lₐ₅₁ | H | Rₙ₁₁ | H | H | H | Rₙ₅ | H | H | H | H | O |
| Lₐ₅₂ | H | Rₙ₁₂ | H | H | H | Rₙ₅ | H | H | H | H | O |
| Lₐ₅₃ | H | Rₙ₁₄ | H | H | H | Rₙ₅ | H | H | H | H | O |
| Lₐ₅₄ | H | Rₙ₁₆ | H | H | H | Rₙ₅ | H | H | H | H | O |
| Lₐ₅₅ | H | Rₙ₂₃ | H | H | H | Rₙ₅ | H | H | H | H | O |
| Lₐ₅₆ | H | H | Rₙ₁ | H | H | Rₙ₅ | H | H | H | H | O |
| Lₐ₅₇ | H | H | Rₙ₂ | H | H | Rₙ₅ | H | H | H | H | O |
| Lₐ₅₈ | H | H | Rₙ₃ | H | H | Rₙ₅ | H | H | H | H | O |
| Lₐ₅₉ | H | H | Rₙ₄ | H | H | Rₙ₅ | H | H | H | H | O |
| Lₐ₆₀ | H | H | Rₙ₅ | H | H | Rₙ₅ | H | H | H | H | O |
| Lₐ₆₁ | H | H | Rₙ₆ | H | H | Rₙ₅ | H | H | H | H | O |
| Lₐ₆₂ | H | H | Rₙ₇ | H | H | Rₙ₅ | H | H | H | H | O |
| Lₐ₆₃ | H | H | Rₙ₈ | H | H | Rₙ₅ | H | H | H | H | O |
| Lₐ₆₄ | H | H | Rₙ₉ | H | H | Rₙ₅ | H | H | H | H | O |
| Lₐ₆₅ | H | H | Rₙ₁₀ | H | H | Rₙ₅ | H | H | H | H | O |
| Lₐ₆₆ | H | H | Rₙ₁₁ | H | H | Rₙ₅ | H | H | H | H | O |
| Lₐ₆₇ | H | H | Rₙ₁₂ | H | H | Rₙ₅ | H | H | H | H | O |
| Lₐ₆₈ | H | H | Rₙ₁₄ | H | H | Rₙ₅ | H | H | H | H | O |
| Lₐ₆₉ | H | H | Rₙ₁₆ | H | H | Rₙ₅ | H | H | H | H | O |
| Lₐ₇₀ | H | H | Rₙ₂₃ | H | H | Rₙ₅ | H | H | H | H | O |
| Lₐ₇₁ | H | Rₙ₁₂ | Rₙ₂ | H | H | Rₙ₅ | H | H | H | H | O |
| Lₐ₇₂ | H | Rₙ₁₆ | Rₙ₂ | H | H | Rₙ₅ | H | H | H | H | O |
| Lₐ₇₃ | H | Rₙ₂ | Rₙ₂ | H | H | Rₙ₅ | H | H | H | H | O |
| Lₐ₇₄ | D | Rₙ₂ | Rₙ₂ | H | H | Rₙ₅ | H | H | H | H | O |
| Lₐ₇₅ | H | D | H | H | H | Rₙ₉ | H | H | H | H | O |
| Lₐ₇₆ | H | H | D | H | H | Rₙ₉ | H | H | H | H | O |
| Lₐ₇₇ | H | Rₙ₁ | H | H | H | Rₙ₉ | H | H | H | H | O |
| Lₐ₇₈ | H | Rₙ₂ | H | H | H | Rₙ₉ | H | H | H | H | O |
| Lₐ₇₉ | H | Rₙ₃ | H | H | H | Rₙ₉ | H | H | H | H | O |
| Lₐ₈₀ | H | Rₙ₄ | H | H | H | Rₙ₉ | H | H | H | H | O |
| Lₐ₈₁ | H | Rₙ₅ | H | H | H | Rₙ₉ | H | H | H | H | O |
| Lₐ₈₂ | H | Rₙ₆ | H | H | H | Rₙ₉ | H | H | H | H | O |
| Lₐ₈₃ | H | Rₙ₇ | H | H | H | Rₙ₉ | H | H | H | H | O |
| Lₐ₈₄ | H | Rₙ₈ | H | H | H | Rₙ₉ | H | H | H | H | O |
| Lₐ₈₅ | H | Rₙ₉ | H | H | H | Rₙ₉ | H | H | H | H | O |
| Lₐ₈₆ | H | Rₙ₁₀ | H | H | H | Rₙ₉ | H | H | H | H | O |
| Lₐ₈₇ | H | Rₙ₁₁ | H | H | H | Rₙ₉ | H | H | H | H | O |
| Lₐ₈₈ | H | Rₙ₁₂ | H | H | H | Rₙ₉ | H | H | H | H | O |
| Lₐ₈₉ | H | Rₙ₁₄ | H | H | H | Rₙ₉ | H | H | H | H | O |
| Lₐ₉₀ | H | Rₙ₁₆ | H | H | H | Rₙ₉ | H | H | H | H | O |
| Lₐ₉₁ | H | Rₙ₂₃ | H | H | H | Rₙ₉ | H | H | H | H | O |
| Lₐ₉₂ | H | H | Rₙ₁ | H | H | Rₙ₉ | H | H | H | H | O |
| Lₐ₉₃ | H | H | Rₙ₂ | H | H | Rₙ₉ | H | H | H | H | O |
| Lₐ₉₄ | H | H | Rₙ₃ | H | H | Rₙ₉ | H | H | H | H | O |
| Lₐ₉₅ | H | H | Rₙ₄ | H | H | Rₙ₉ | H | H | H | H | O |
| Lₐ₉₆ | H | H | Rₙ₅ | H | H | Rₙ₉ | H | H | H | H | O |
| Lₐ₉₇ | H | H | Rₙ₆ | H | H | Rₙ₉ | H | H | H | H | O |
| Lₐ₉₈ | H | H | Rₙ₇ | H | H | Rₙ₉ | H | H | H | H | O |
| Lₐ₉₉ | H | H | Rₙ₈ | H | H | Rₙ₉ | H | H | H | H | O |
| Lₐ₁₀₀ | H | H | Rₙ₉ | H | H | Rₙ₉ | H | H | H | H | O |
| Lₐ₁₀₁ | H | H | Rₙ₁₀ | H | H | Rₙ₉ | H | H | H | H | O |
| Lₐ₁₀₂ | H | H | Rₙ₁₁ | H | H | Rₙ₉ | H | H | H | H | O |
| Lₐ₁₀₃ | H | H | Rₙ₁₂ | H | H | Rₙ₉ | H | H | H | H | O |
| Lₐ₁₀₄ | H | H | Rₙ₁₄ | H | H | Rₙ₉ | H | H | H | H | O |
| Lₐ₁₀₅ | H | H | Rₙ₁₆ | H | H | Rₙ₉ | H | H | H | H | O |
| Lₐ₁₀₆ | H | H | Rₙ₂₃ | H | H | Rₙ₉ | H | H | H | H | O |
| Lₐ₁₀₇ | H | Rₙ₁₂ | Rₙ₂ | H | H | Rₙ₉ | H | H | H | H | O |
| Lₐ₁₀₈ | H | Rₙ₁₆ | Rₙ₂ | H | H | Rₙ₉ | H | H | H | H | O |
| Lₐ₁₀₉ | H | Rₙ₂ | Rₙ₂ | H | H | Rₙ₉ | H | H | H | H | O |
| Lₐ₁₁₀ | D | Rₙ₂ | Rₙ₂ | H | H | Rₙ₉ | H | H | H | H | O |
| Lₐ₁₁₁ | H | D | H | H | H | Rₙ₁₁ | H | H | H | H | O |
| Lₐ₁₁₂ | H | H | D | H | H | Rₙ₁₁ | H | H | H | H | O |
| Lₐ₁₁₃ | H | Rₙ₁ | H | H | H | Rₙ₁₁ | H | H | H | H | O |
| Lₐ₁₁₄ | H | Rₙ₂ | H | H | H | Rₙ₁₁ | H | H | H | H | O |
| Lₐ₁₁₅ | H | Rₙ₃ | H | H | H | Rₙ₁₁ | H | H | H | H | O |
| Lₐ₁₁₆ | H | Rₙ₄ | H | H | H | Rₙ₁₁ | H | H | H | H | O |
| Lₐ₁₁₇ | H | Rₙ₅ | H | H | H | Rₙ₁₁ | H | H | H | H | O |
| Lₐ₁₁₈ | H | Rₙ₆ | H | H | H | Rₙ₁₁ | H | H | H | H | O |
| Lₐ₁₁₉ | H | Rₙ₇ | H | H | H | Rₙ₁₁ | H | H | H | H | O |
| Lₐ₁₂₀ | H | Rₙ₈ | H | H | H | Rₙ₁₁ | H | H | H | H | O |
| Lₐ₁₂₁ | H | Rₙ₉ | H | H | H | Rₙ₁₁ | H | H | H | H | O |
| Lₐ₁₂₂ | H | Rₙ₁₀ | H | H | H | Rₙ₁₁ | H | H | H | H | O |
| Lₐ₁₂₃ | H | Rₙ₁₁ | H | H | H | Rₙ₁₁ | H | H | H | H | O |
| Lₐ₁₂₄ | H | Rₙ₁₂ | H | H | H | Rₙ₁₁ | H | H | H | H | O |
| Lₐ₁₂₅ | H | Rₙ₁₄ | H | H | H | Rₙ₁₁ | H | H | H | H | O |
| Lₐ₁₂₆ | H | Rₙ₁₆ | H | H | H | Rₙ₁₁ | H | H | H | H | O |
| Lₐ₁₂₇ | H | Rₙ₂₃ | H | H | H | Rₙ₁₁ | H | H | H | H | O |
| Lₐ₁₂₈ | H | H | Rₙ₁ | H | H | Rₙ₁₁ | H | H | H | H | O |
| Lₐ₁₂₉ | H | H | Rₙ₂ | H | H | Rₙ₁₁ | H | H | H | H | O |
| Lₐ₁₃₀ | H | H | Rₙ₃ | H | H | Rₙ₁₁ | H | H | H | H | O |
| Lₐ₁₃₁ | H | H | Rₙ₄ | H | H | Rₙ₁₁ | H | H | H | H | O |
| Lₐ₁₃₂ | H | H | Rₙ₅ | H | H | Rₙ₁₁ | H | H | H | H | O |
| Lₐ₁₃₃ | H | H | Rₙ₆ | H | H | Rₙ₁₁ | H | H | H | H | O |
| Lₐ₁₃₄ | H | H | Rₙ₇ | H | H | Rₙ₁₁ | H | H | H | H | O |
| Lₐ₁₃₅ | H | H | Rₙ₈ | H | H | Rₙ₁₁ | H | H | H | H | O |
| Lₐ₁₃₆ | H | H | Rₙ₉ | H | H | Rₙ₁₁ | H | H | H | H | O |
| Lₐ₁₃₇ | H | H | Rₙ₁₀ | H | H | Rₙ₁₁ | H | H | H | H | O |
| Lₐ₁₃₈ | H | H | Rₙ₁₁ | H | H | Rₙ₁₁ | H | H | H | H | O |
| Lₐ₁₃₉ | H | H | Rₙ₁₂ | H | H | Rₙ₁₁ | H | H | H | H | O |
| Lₐ₁₄₀ | H | H | Rₙ₁₄ | H | H | Rₙ₁₁ | H | H | H | H | O |
| Lₐ₁₄₁ | H | H | Rₙ₁₆ | H | H | Rₙ₁₁ | H | H | H | H | O |
| Lₐ₁₄₂ | H | H | Rₙ₂₃ | H | H | Rₙ₁₁ | H | H | H | H | O |
| Lₐ₁₄₃ | H | Rₙ₁₂ | Rₙ₂ | H | H | Rₙ₁₁ | H | H | H | H | O |
| Lₐ₁₄₄ | H | Rₙ₁₆ | Rₙ₂ | H | H | Rₙ₁₁ | H | H | H | H | O |
| Lₐ₁₄₅ | H | Rₙ₂ | Rₙ₂ | H | H | Rₙ₁₁ | H | H | H | H | O |
| Lₐ₁₄₆ | D | Rₙ₂ | Rₙ₂ | H | H | Rₙ₁₁ | H | H | H | H | O |
| Lₐ₁₄₇ | H | D | H | H | H | Rₙ₁₂ | H | H | H | H | O |
| Lₐ₁₄₈ | H | H | D | H | H | Rₙ₁₂ | H | H | H | H | O |
| Lₐ₁₄₉ | H | Rₙ₁ | H | H | H | Rₙ₁₂ | H | H | H | H | O |
| Lₐ₁₅₀ | H | Rₙ₂ | H | H | H | Rₙ₁₂ | H | H | H | H | O |
| Lₐ₁₅₁ | H | Rₙ₃ | H | H | H | Rₙ₁₂ | H | H | H | H | O |
| Lₐ₁₅₂ | H | Rₙ₄ | H | H | H | Rₙ₁₂ | H | H | H | H | O |
| Lₐ₁₅₃ | H | Rₙ₅ | H | H | H | Rₙ₁₂ | H | H | H | H | O |
| Lₐ₁₅₄ | H | Rₙ₆ | H | H | H | Rₙ₁₂ | H | H | H | H | O |
| Lₐ₁₅₅ | H | Rₙ₇ | H | H | H | Rₙ₁₂ | H | H | H | H | O |
| Lₐ₁₅₆ | H | Rₙ₈ | H | H | H | Rₙ₁₂ | H | H | H | H | O |
| Lₐ₁₅₇ | H | Rₙ₉ | H | H | H | Rₙ₁₂ | H | H | H | H | O |
| Lₐ₁₅₈ | H | Rₙ₁₀ | H | H | H | Rₙ₁₂ | H | H | H | H | O |
| Lₐ₁₅₉ | H | Rₙ₁₁ | H | H | H | Rₙ₁₂ | H | H | H | H | O |
| Lₐ₁₆₀ | H | Rₙ₁₂ | H | H | H | Rₙ₁₂ | H | H | H | H | O |
| Lₐ₁₆₁ | H | Rₙ₁₄ | H | H | H | Rₙ₁₂ | H | H | H | H | O |
| Lₐ₁₆₂ | H | Rₙ₁₆ | H | H | H | Rₙ₁₂ | H | H | H | H | O |
| Lₐ₁₆₃ | H | Rₙ₂₃ | H | H | H | Rₙ₁₂ | H | H | H | H | O |
| Lₐ₁₆₄ | H | H | Rₙ₁ | H | H | Rₙ₁₂ | H | H | H | H | O |
| Lₐ₁₆₅ | H | H | Rₙ₂ | H | H | Rₙ₁₂ | H | H | H | H | O |
| Lₐ₁₆₆ | H | H | Rₙ₃ | H | H | Rₙ₁₂ | H | H | H | H | O |
| Lₐ₁₆₇ | H | H | Rₙ₄ | H | H | Rₙ₁₂ | H | H | H | H | O |
| Lₐ₁₆₈ | H | H | Rₙ₅ | H | H | Rₙ₁₂ | H | H | H | H | O |
| Lₐ₁₆₉ | H | H | Rₙ₆ | H | H | Rₙ₁₂ | H | H | H | H | O |
| Lₐ₁₇₀ | H | H | Rₙ₇ | H | H | Rₙ₁₂ | H | H | H | H | O |
| Lₐ₁₇₁ | H | H | Rₙ₈ | H | H | Rₙ₁₂ | H | H | H | H | O |
| Lₐ₁₇₂ | H | H | Rₙ₉ | H | H | Rₙ₁₂ | H | H | H | H | O |
| Lₐ₁₇₃ | H | H | Rₙ₁₀ | H | H | Rₙ₁₂ | H | H | H | H | O |
| Lₐ₁₇₄ | H | H | Rₙ₁₁ | H | H | Rₙ₁₂ | H | H | H | H | O |
| Lₐ₁₇₅ | H | H | Rₙ₁₂ | H | H | Rₙ₁₂ | H | H | H | H | O |
| Lₐ₁₇₆ | H | H | Rₙ₁₄ | H | H | Rₙ₁₂ | H | H | H | H | O |
| Lₐ₁₇₇ | H | H | Rₙ₁₆ | H | H | Rₙ₁₂ | H | H | H | H | O |
| Lₐ₁₇₈ | H | H | Rₙ₂₃ | H | H | Rₙ₁₂ | H | H | H | H | O |
| Lₐ₁₇₉ | H | Rₙ₁₂ | Rₙ₂ | H | H | Rₙ₁₂ | H | H | H | H | O |
| Lₐ₁₈₀ | H | Rₙ₁₆ | Rₙ₂ | H | H | Rₙ₁₂ | H | H | H | H | O |
| Lₐ₁₈₁ | H | Rₙ₂ | Rₙ₂ | H | H | Rₙ₁₂ | H | H | H | H | O |
| Lₐ₁₈₂ | D | Rₙ₂ | Rₙ₂ | H | H | Rₙ₁₂ | H | H | H | H | O |
| Lₐ₁₈₃ | H | D | H | H | H | H | H | H | CN | H | O |
| Lₐ₁₈₄ | H | H | D | H | H | H | H | H | CN | H | O |
| Lₐ₁₈₅ | H | Rₙ₁ | H | H | H | H | H | H | CN | H | O |
| Lₐ₁₈₆ | H | Rₙ₂ | H | H | H | H | H | H | CN | H | O |
| Lₐ₁₈₇ | H | Rₙ₃ | H | H | H | H | H | H | CN | H | O |
| Lₐ₁₈₈ | H | Rₙ₄ | H | H | H | H | H | H | CN | H | O |
| Lₐ₁₈₉ | H | Rₙ₅ | H | H | H | H | H | H | CN | H | O |
| Lₐ₁₉₀ | H | Rₙ₆ | H | H | H | H | H | H | CN | H | O |
| Lₐ₁₉₁ | H | Rₙ₇ | H | H | H | H | H | H | CN | H | O |
| Lₐ₁₉₂ | H | Rₙ₈ | H | H | H | H | H | H | CN | H | O |
| Lₐ₁₉₃ | H | Rₙ₉ | H | H | H | H | H | H | CN | H | O |
| Lₐ₁₉₄ | H | Rₙ₁₀ | H | H | H | H | H | H | CN | H | O |
| Lₐ₁₉₅ | H | Rₙ₁₁ | H | H | H | H | H | H | CN | H | O |
| Lₐ₁₉₆ | H | Rₙ₁₂ | H | H | H | H | H | H | CN | H | O |
| Lₐ₁₉₇ | H | Rₙ₁₄ | H | H | H | H | H | H | CN | H | O |
| Lₐ₁₉₈ | H | Rₙ₁₆ | H | H | H | H | H | H | CN | H | O |
| Lₐ₁₉₉ | H | Rₙ₂₃ | H | H | H | H | H | H | CN | H | O |
| Lₐ₂₀₀ | H | H | Rₙ₁ | H | H | H | H | H | CN | H | O |
| Lₐ₂₀₁ | H | H | Rₙ₂ | H | H | H | H | H | CN | H | O |
| Lₐ₂₀₂ | H | H | Rₙ₃ | H | H | H | H | H | CN | H | O |
| Lₐ₂₀₃ | H | H | Rₙ₄ | H | H | H | H | H | CN | H | O |
| Lₐ₂₀₄ | H | H | Rₙ₅ | H | H | H | H | H | CN | H | O |
| Lₐ₂₀₅ | H | H | Rₙ₅ | H | H | H | H | H | CN | H | O |
| Lₐ₂₀₆ | H | H | Rₙ₇ | H | H | H | H | H | CN | H | O |
| Lₐ₂₀₇ | H | H | Rₙ₈ | H | H | H | H | H | CN | H | O |
| Lₐ₂₀₈ | H | H | Rₙ₉ | H | H | H | H | H | CN | H | O |
| Lₐ₂₀₉ | H | H | Rₙ₁₀ | H | H | H | H | H | CN | H | O |
| Lₐ₂₁₀ | H | H | Rₙ₁₁ | H | H | H | H | H | CN | H | O |
| Lₐ₂₁₁ | H | H | Rₙ₁₂ | H | H | H | H | H | CN | H | O |
| Lₐ₂₁₂ | H | H | Rₙ₁₄ | H | H | H | H | H | CN | H | O |
| Lₐ₂₁₃ | H | H | Rₙ₁₆ | H | H | H | H | H | CN | H | O |
| Lₐ₂₁₄ | H | H | Rₙ₂₃ | H | H | H | H | H | CN | H | O |
| Lₐ₂₁₅ | H | Rₙ₁₂ | Rₙ₂ | H | H | H | H | H | CN | H | O |
| Lₐ₂₁₆ | H | Rₙ₁₆ | Rₙ₂ | H | H | H | H | H | CN | H | O |
| Lₐ₂₁₇ | H | Rₙ₂ | Rₙ₂ | H | H | H | H | H | CN | H | O |
| Lₐ₂₁₈ | D | Rₙ₂ | Rₙ₂ | D | H | H | H | H | CN | H | O |
| Lₐ₂₁₉ | H | D | H | H | H | Rₙ₄ | H | H | CN | H | O |
| Lₐ₂₂₀ | H | D | H | H | H | Rₙ₅ | H | H | CN | H | O |
| Lₐ₂₂₁ | H | D | H | H | H | Rₙ₇ | H | H | CN | H | O |
| Lₐ₂₂₂ | H | D | H | H | H | Rₙ₉ | H | H | CN | H | O |
| Lₐ₂₂₃ | H | Rₙ₂ | H | H | H | Rₙ₄ | H | H | CN | H | O |
| Lₐ₂₂₄ | H | Rₙ₂ | H | H | H | Rₙ₅ | H | H | CN | H | O |
| Lₐ₂₂₅ | H | Rₙ₂ | H | H | H | Rₙ₇ | H | H | CN | H | O |
| Lₐ₂₂₆ | H | Rₙ₂ | H | H | H | Rₙ₉ | H | H | CN | H | O |
| Lₐ₂₂₇ | H | Rₙ₄ | H | H | H | Rₙ₄ | H | H | CN | H | O |
| Lₐ₂₂₈ | H | Rₙ₄ | H | H | H | Rₙ₅ | H | H | CN | H | O |
| Lₐ₂₂₉ | H | Rₙ₄ | H | H | H | Rₙ₇ | H | H | CN | H | O |
| Lₐ₂₃₀ | H | Rₙ₄ | H | H | H | Rₙ₉ | H | H | CN | H | O |
| Lₐ₂₃₁ | H | Rₙ₅ | H | H | H | Rₙ₄ | H | H | CN | H | O |
| Lₐ₂₃₂ | H | Rₙ₅ | H | H | H | Rₙ₅ | H | H | CN | H | O |
| Lₐ₂₃₃ | H | Rₙ₅ | H | H | H | Rₙ₇ | H | H | CN | H | O |
| Lₐ₂₃₄ | H | Rₙ₅ | H | H | H | Rₙ₉ | H | H | CN | H | O |
| Lₐ₂₃₅ | H | Rₙ₉ | H | H | H | Rₙ₄ | H | H | CN | H | O |
| Lₐ₂₃₆ | H | Rₙ₉ | H | H | H | Rₙ₅ | H | H | CN | H | O |
| Lₐ₂₃₇ | H | Rₙ₉ | H | H | H | Rₙ₇ | H | H | CN | H | O |
| Lₐ₂₃₈ | H | Rₙ₉ | H | H | H | Rₙ₉ | H | H | CN | H | O |
| Lₐ₂₃₉ | H | Rₙ₁₂ | H | H | H | Rₙ₄ | H | H | CN | H | O |
| Lₐ₂₄₀ | H | Rₙ₁₂ | H | H | H | Rₙ₅ | H | H | CN | H | O |
| Lₐ₂₄₁ | H | Rₙ₁₂ | H | H | H | Rₙ₇ | H | H | CN | H | O |
| Lₐ₂₄₂ | H | Rₙ₁₂ | H | H | H | Rₙ₉ | H | H | CN | H | O |
| Lₐ₂₄₃ | H | Rₙ₁₄ | H | H | H | Rₙ₄ | H | H | CN | H | O |
| Lₐ₂₄₄ | H | Rₙ₁₄ | H | H | H | Rₙ₅ | H | H | CN | H | O |
| Lₐ₂₄₅ | H | Rₙ₁₄ | H | H | H | Rₙ₇ | H | H | CN | H | O |
| Lₐ₂₄₆ | H | Rₙ₁₄ | H | H | H | Rₙ₉ | H | H | CN | H | O |
| Lₐ₂₄₇ | H | Rₙ₁₆ | H | H | H | Rₙ₄ | H | H | CN | H | O |
| Lₐ₂₄₈ | H | Rₙ₁₆ | H | H | H | Rₙ₅ | H | H | CN | H | O |
| Lₐ₂₄₉ | H | Rₙ₁₆ | H | H | H | Rₙ₇ | H | H | CN | H | O |
| Lₐ₂₅₀ | H | Rₙ₁₆ | H | H | H | Rₙ₉ | H | H | CN | H | O |
| Lₐ₂₅₁ | H | Rₙ₂₃ | H | H | H | Rₙ₄ | H | H | CN | H | O |
| Lₐ₂₅₂ | H | Rₙ₂₃ | H | H | H | Rₙ₅ | H | H | CN | H | O |
| Lₐ₂₅₃ | H | Rₙ₂₃ | H | H | H | Rₙ₇ | H | H | CN | H | O |
| Lₐ₂₅₄ | H | Rₙ₂₃ | H | H | H | Rₙ₉ | H | H | CN | H | O |
| Lₐ₂₅₅ | H | H | Rₙ₂ | H | H | Rₙ₄ | H | H | CN | H | O |
| Lₐ₂₅₆ | H | H | Rₙ₂ | H | H | Rₙ₅ | H | H | CN | H | O |
| Lₐ₂₅₇ | H | H | Rₙ₂ | H | H | Rₙ₇ | H | H | CN | H | O |
| Lₐ₂₅₈ | H | H | Rₙ₂ | H | H | Rₙ₉ | H | H | CN | H | O |
| Lₐ₂₅₉ | H | H | Rₙ₅ | H | H | Rₙ₄ | H | H | CN | H | O |
| Lₐ₂₆₀ | H | H | Rₙ | H | H | Rₙ₅ | H | H | CN | H | O |
| Lₐ₂₆₁ | H | H | Rₙ₅ | H | H | Rₙ₇ | H | H | CN | H | O |
| Lₐ₂₆₂ | H | H | Rₙ₅ | H | H | Rₙ₉ | H | H | CN | H | O |
| Lₐ₂₆₃ | H | H | Rₙ₉ | H | H | Rₙ₄ | H | H | CN | H | O |
| Lₐ₂₆₄ | H | H | Rₙ₉ | H | H | Rₙ₅ | H | H | CN | H | O |
| Lₐ₂₆₅ | H | H | Rₙ₉ | H | H | Rₙ₇ | H | H | CN | H | O |
| Lₐ₂₆₆ | H | H | Rₙ₉ | H | H | Rₙ₉ | H | H | CN | H | O |
| Lₐ₂₆₇ | H | H | Rₙ₁₂ | H | H | Rₙ₄ | H | H | CN | H | O |
| Lₐ₂₆₈ | H | H | Rₙ₁₂ | H | H | Rₙ₅ | H | H | CN | H | O |
| Lₐ₂₆₉ | H | H | Rₙ₁₂ | H | H | Rₙ₇ | H | H | CN | H | O |
| Lₐ₂₇₀ | H | H | Rₙ₁₂ | H | H | Rₙ₉ | H | H | CN | H | O |
| Lₐ₂₇₁ | H | Rₙ₂ | Rₙ₂ | H | H | Rₙ₄ | H | H | CN | H | O |
| Lₐ₂₇₂ | H | Rₙ₁₂ | Rₙ₂ | H | H | Rₙ₄ | H | H | CN | H | O |
| Lₐ₂₇₃ | H | Rₙ₁₆ | Rₙ₂ | H | H | Rₙ₄ | H | H | CN | H | O |
| Lₐ₂₇₄ | H | Rₙ₂ | Rₙ₂ | H | H | Rₙ₅ | H | H | CN | H | O |
| Lₐ₂₇₅ | H | Rₙ₁₂ | Rₙ₂ | H | H | Rₙ₅ | H | H | CN | H | O |
| Lₐ₂₇₆ | H | Rₙ₁₆ | Rₙ₂ | H | H | Rₙ₅ | H | H | CN | H | O |
| Lₐ₂₇₇ | H | Rₙ₂ | Rₙ₂ | H | H | Rₙ₇ | H | H | CN | H | O |
| Lₐ₂₇₈ | H | Rₙ₁₂ | Rₙ₂ | H | H | Rₙ₇ | H | H | CN | H | O |
| Lₐ₂₇₉ | H | Rₙ₁₆ | Rₙ₂ | H | H | Rₙ₇ | H | H | CN | H | O |
| Lₐ₂₈₀ | H | Rₙ₂ | Rₙ₂ | H | H | Rₙ₉ | H | H | CN | H | O |
| Lₐ₂₈₁ | H | Rₙ₁₂ | Rₙ₂ | H | H | Rₙ₉ | H | H | CN | H | O |
| Lₐ₂₈₂ | H | Rₙ₁₆ | Rₙ₂ | H | H | Rₙ₉ | H | H | CN | H | O |
| Lₐ₂₈₃ | H | D | H | H | H | H | H | H | CN | D | O |
| Lₐ₂₈₄ | H | H | D | H | H | H | H | H | CN | D | O |
| Lₐ₂₈₅ | H | Rₙ₁ | H | H | H | H | H | H | CN | D | O |
| Lₐ₂₈₆ | H | Rₙ₂ | H | H | H | H | H | H | CN | D | O |
| Lₐ₂₈₇ | H | Rₙ₃ | H | H | H | H | H | H | CN | D | O |
| Lₐ₂₈₈ | H | Rₙ₄ | H | H | H | H | H | H | CN | D | O |
| Lₐ₂₈₉ | H | Rₙ₅ | H | H | H | H | H | H | CN | D | O |
| Lₐ₂₉₀ | H | Rₙ₆ | H | H | H | H | H | H | CN | D | O |
| Lₐ₂₉₁ | H | Rₙ₇ | H | H | H | H | H | H | CN | D | O |
| Lₐ₂₉₂ | H | Rₙ₈ | H | H | H | H | H | H | CN | D | O |
| Lₐ₂₉₃ | H | Rₙ₉ | H | H | H | H | H | H | CN | D | O |
| Lₐ₂₉₄ | H | Rₙ₁₀ | H | H | H | H | H | H | CN | D | O |
| Lₐ₂₉₅ | H | Rₙ₁₁ | H | H | H | H | H | H | CN | D | O |
| Lₐ₂₉₆ | H | Rₙ₁₂ | H | H | H | H | H | H | CN | D | O |
| Lₐ₂₉₇ | H | Rₙ₁₄ | H | H | H | H | H | H | CN | D | O |
| Lₐ₂₉₈ | H | Rₙ₁₆ | H | H | H | H | H | H | CN | D | O |
| Lₐ₂₉₉ | H | Rₙ₂₃ | H | H | H | H | H | H | CN | D | O |
| Lₐ₃₀₀ | H | H | Rₙ₁ | H | H | H | H | H | CN | D | O |
| Lₐ₃₀₁ | H | H | Rₙ₂ | H | H | H | H | H | CN | D | O |
| Lₐ₃₀₂ | H | H | Rₙ₃ | H | H | H | H | H | CN | D | O |
| Lₐ₃₀₃ | H | H | Rₙ₄ | H | H | H | H | H | CN | D | O |
| Lₐ₃₀₄ | H | H | Rₙ₅ | H | H | H | H | H | CN | D | O |
| Lₐ₃₀₅ | H | H | Rₙ₆ | H | H | H | H | H | CN | D | O |
| Lₐ₃₀₆ | H | H | Rₙ₇ | H | H | H | H | H | CN | D | O |
| Lₐ₃₀₇ | H | H | Rₙ₈ | H | H | H | H | H | CN | D | O |
| Lₐ₃₀₈ | H | H | Rₙ₉ | H | H | H | H | H | CN | D | O |
| Lₐ₃₀₉ | H | H | Rₙ₁₀ | H | H | H | H | H | CN | D | O |
| Lₐ₃₁₀ | H | H | Rₙ₁₁ | H | H | H | H | H | CN | D | O |
| Lₐ₃₁₁ | H | H | Rₙ₁₂ | H | H | H | H | H | CN | D | O |
| Lₐ₃₁₂ | H | H | Rₙ₁₄ | H | H | H | H | H | CN | D | O |
| Lₐ₃₁₃ | H | H | Rₙ₁₆ | H | H | H | H | H | CN | D | O |
| Lₐ₃₁₄ | H | H | Rₙ₂₃ | H | H | H | H | H | CN | D | O |
| Lₐ₃₁₅ | H | Rₙ₁₂ | Rₙ₂ | H | H | H | H | H | CN | D | O |
| Lₐ₃₁₆ | H | Rₙ₁₆ | Rₙ₂ | H | H | H | H | H | CN | D | O |
| Lₐ₃₁₇ | H | Rₙ₂ | Rₙ₂ | H | H | H | H | H | CN | D | O |
| Lₐ₃₁₈ | D | Rₙ₂ | Rₙ₂ | D | H | H | H | H | CN | D | O |
| Lₐ₃₁₉ | H | D | H | H | H | Rₙ₄ | H | H | CN | D | O |
| Lₐ₃₂₀ | H | D | H | H | H | Rₙ₅ | H | H | CN | D | O |
| Lₐ₃₂₁ | H | D | H | H | H | Rₙ₇ | H | H | CN | D | O |
| Lₐ₃₂₂ | H | D | H | H | H | Rₙ₉ | H | H | CN | D | O |
| Lₐ₃₂₃ | H | Rₙ₂ | H | H | H | Rₙ₄ | H | H | CN | D | O |
| Lₐ₃₂₄ | H | Rₙ₂ | H | H | H | Rₙ₅ | H | H | CN | D | O |
| Lₐ₃₂₅ | H | Rₙ₂ | H | H | H | Rₙ₇ | H | H | CN | D | O |
| Lₐ₃₂₆ | H | Rₙ₂ | H | H | H | Rₙ₉ | H | H | CN | D | O |
| Lₐ₃₂₇ | H | Rₙ₄ | H | H | H | Rₙ₄ | H | H | CN | D | O |
| Lₐ₃₂₈ | H | Rₙ₄ | H | H | H | Rₙ₅ | H | H | CN | D | O |
| Lₐ₃₂₉ | H | Rₙ₄ | H | H | H | Rₙ₇ | H | H | CN | D | O |
| Lₐ₃₃₀ | H | Rₙ₄ | H | H | H | Rₙ₉ | H | H | CN | D | O |
| Lₐ₃₃₁ | H | Rₙ₅ | H | H | H | Rₙ₄ | H | H | CN | D | O |
| Lₐ₃₃₂ | H | Rₙ₅ | H | H | H | Rₙ₅ | H | H | CN | D | O |
| Lₐ₃₃₃ | H | Rₙ₅ | H | H | H | Rₙ₇ | H | H | CN | D | O |
| Lₐ₃₃₄ | H | Rₙ₅ | H | H | H | Rₙ₉ | H | H | CN | D | O |
| Lₐ₃₃₅ | H | Rₙ₉ | H | H | H | Rₙ₄ | H | H | CN | D | O |
| Lₐ₃₃₆ | H | Rₙ₉ | H | H | H | Rₙ₅ | H | H | CN | D | O |
| Lₐ₃₃₇ | H | Rₙ₉ | H | H | H | Rₙ₇ | H | H | CN | D | O |
| Lₐ₃₃₈ | H | Rₙ₉ | H | H | H | Rₙ₉ | H | H | CN | D | O |
| Lₐ₃₃₉ | H | Rₙ₁₂ | H | H | H | Rₙ₄ | H | H | CN | D | O |
| Lₐ₃₄₀ | H | Rₙ₁₂ | H | H | H | Rₙ₅ | H | H | CN | D | O |
| Lₐ₃₄₁ | H | Rₙ₁₂ | H | H | H | Rₙ₇ | H | H | CN | D | O |
| Lₐ₃₄₂ | H | Rₙ₁₂ | H | H | H | Rₙ₉ | H | H | CN | D | O |
| Lₐ₃₄₃ | H | Rₙ₁₄ | H | H | H | Rₙ₄ | H | H | CN | D | O |
| Lₐ₃₄₄ | H | Rₙ₁₄ | H | H | H | Rₙ₅ | H | H | CN | D | O |
| Lₐ₃₄₅ | H | Rₙ₁₄ | H | H | H | Rₙ₇ | H | H | CN | D | O |
| Lₐ₃₄₆ | H | Rₙ₁₄ | H | H | H | Rₙ₉ | H | H | CN | D | O |
| Lₐ₃₄₇ | H | Rₙ₁₆ | H | H | H | Rₙ₄ | H | H | CN | D | O |
| Lₐ₃₄₈ | H | Rₙ₁₆ | H | H | H | Rₙ₅ | H | H | CN | D | O |
| Lₐ₃₄₉ | H | Rₙ₁₆ | H | H | H | Rₙ₇ | H | H | CN | D | O |
| Lₐ₃₅₀ | H | Rₙ₁₆ | H | H | H | Rₙ₉ | H | H | CN | D | O |
| Lₐ₃₅₁ | H | Rₙ₂₃ | H | H | H | Rₙ₄ | H | H | CN | D | O |
| Lₐ₃₅₂ | H | Rₙ₂₃ | H | H | H | Rₙ₅ | H | H | CN | D | O |
| Lₐ₃₅₃ | H | Rₙ₂₃ | H | H | H | Rₙ₇ | H | H | CN | D | O |
| Lₐ₃₅₄ | H | Rₙ₂₃ | H | H | H | Rₙ₉ | H | H | CN | D | O |
| Lₐ₃₅₅ | H | H | Rₙ₂ | H | H | Rₙ₄ | H | H | CN | D | O |
| Lₐ₃₅₆ | H | H | Rₙ₂ | H | H | Rₙ₅ | H | H | CN | D | O |
| Lₐ₃₅₇ | H | H | Rₙ₂ | H | H | Rₙ₇ | H | H | CN | D | O |
| Lₐ₃₅₈ | H | H | Rₙ₂ | H | H | Rₙ₉ | H | H | CN | D | O |
| Lₐ₃₅₉ | H | H | Rₙ₅ | H | H | Rₙ₄ | H | H | CN | D | O |
| Lₐ₃₆₀ | H | H | Rₙ₅ | H | H | Rₙ₅ | H | H | CN | D | O |
| Lₐ₃₆₁ | H | H | Rₙ₅ | H | H | Rₙ₇ | H | H | CN | D | O |
| Lₐ₃₆₂ | H | H | Rₙ₅ | H | H | Rₙ₉ | H | H | CN | D | O |
| Lₐ₃₆₃ | H | H | Rₙ₉ | H | H | Rₙ₄ | H | H | CN | D | O |
| Lₐ₃₆₄ | H | H | Rₙ₉ | H | H | Rₙ₅ | H | H | CN | D | O |
| Lₐ₃₆₅ | H | H | Rₙ₉ | H | H | Rₙ₇ | H | H | CN | D | O |
| Lₐ₃₆₆ | H | H | Rₙ₉ | H | H | Rₙ₉ | H | H | CN | D | O |
| Lₐ₃₆₇ | H | H | Rₙ₁₂ | H | H | Rₙ₄ | H | H | CN | D | O |
| Lₐ₃₆₈ | H | H | Rₙ₁₂ | H | H | Rₙ₅ | H | H | CN | D | O |
| Lₐ₃₆₉ | H | H | Rₙ₁₂ | H | H | Rₙ₇ | H | H | CN | D | O |
| Lₐ₃₇₀ | H | H | Rₙ₁₂ | H | H | Rₙ₉ | H | H | CN | D | O |
| Lₐ₃₇₁ | H | Rₙ₂ | Rₙ₂ | H | H | Rₙ₄ | H | H | CN | D | O |
| Lₐ₃₇₂ | H | Rₙ₁₂ | Rₙ₂ | H | H | Rₙ₄ | H | H | CN | D | O |
| Lₐ₃₇₃ | H | Rₙ₁₆ | Rₙ₂ | H | H | Rₙ₄ | H | H | CN | D | O |
| Lₐ₃₇₄ | H | Rₙ₂ | Rₙ₂ | H | H | Rₙ₅ | H | H | CN | D | O |
| Lₐ₃₇₅ | H | Rₙ₁₂ | Rₙ₂ | H | H | Rₙ₅ | H | H | CN | D | O |
| Lₐ₃₇₆ | H | Rₙ₁₆ | Rₙ₂ | H | H | Rₙ₅ | H | H | CN | D | O |
| Lₐ₃₇₇ | H | Rₙ₂ | Rₙ₂ | H | H | Rₙ₇ | H | H | CN | D | O |
| Lₐ₃₇₈ | H | Rₙ₁₂ | Rₙ₂ | H | H | Rₙ₇ | H | H | CN | D | O |
| Lₐ₃₇₉ | H | Rₙ₁₆ | Rₙ₂ | H | H | Rₙ₇ | H | H | CN | D | O |
| Lₐ₃₈₀ | H | Rₙ₂ | Rₙ₂ | H | H | Rₙ₉ | H | H | CN | D | O |
| Lₐ₃₈₁ | H | Rₙ₁₂ | Rₙ₂ | H | H | Rₙ₉ | H | H | CN | D | O |
| Lₐ₃₈₂ | H | Rₙ₁₆ | Rₙ₂ | H | H | Rₙ₉ | H | H | CN | D | O |
| Lₐ₃₈₃ | H | D | H | H | H | H | H | H | H | Rₙ₁₂ | O |
| Lₐ₃₈₄ | H | Rₙ₂ | H | H | H | H | H | H | H | Rₙ₁₂ | O |
| Lₐ₃₈₅ | H | Rₙ₄ | H | H | H | H | H | H | H | Rₙ₁₂ | O |
| Lₐ₃₈₆ | H | Rₙ₅ | H | H | H | H | H | H | H | Rₙ₁₂ | O |
| Lₐ₃₈₇ | H | Rₙ₇ | H | H | H | H | H | H | H | Rₙ₁₂ | O |
| Lₐ₃₈₈ | H | Rₙ₉ | H | H | H | H | H | H | H | Rₙ₁₂ | O |
| Lₐ₃₈₉ | H | Rₙ₁₂ | H | H | H | H | H | H | H | Rₙ₁₂ | O |
| Lₐ₃₉₀ | H | Rₙ₁₄ | H | H | H | H | H | H | H | Rₙ₁₂ | O |
| Lₐ₃₉₁ | H | Rₙ₁₆ | H | H | H | H | H | H | H | Rₙ₁₂ | O |
| Lₐ₃₉₂ | H | D | H | H | H | Rₙ₅ | H | H | H | Rₙ₁₂ | O |
| Lₐ₃₉₃ | H | Rₙ₂ | H | H | H | Rₙ₅ | H | H | H | Rₙ₁₂ | O |
| Lₐ₃₉₄ | H | Rₙ₄ | H | H | H | Rₙ₅ | H | H | H | Rₙ₁₂ | O |
| Lₐ₃₉₅ | H | Rₙ₅ | H | H | H | Rₙ₅ | H | H | H | Rₙ₁₂ | O |
| Lₐ₃₉₆ | H | Rₙ₇ | H | H | H | Rₙ₅ | H | H | H | Rₙ₁₂ | O |
| Lₐ₃₉₇ | H | Rₙ₉ | H | H | H | Rₙ₅ | H | H | H | Rₙ₁₂ | O |
| Lₐ₃₉₈ | H | Rₙ₁₂ | H | H | H | Rₙ₅ | H | H | H | Rₙ₁₂ | O |
| Lₐ₃₉₉ | H | Rₙ₁₄ | H | H | H | Rₙ₅ | H | H | H | Rₙ₁₂ | O |
| Lₐ₄₀₀ | H | Rₙ₁₆ | H | H | H | Rₙ₅ | H | H | H | Rₙ₁₂ | O |
| Lₐ₄₀₁ | H | D | H | H | H | Rₙ₉ | H | H | H | Rₙ₁₂ | O |
| Lₐ₄₀₂ | H | Rₙ₂ | H | H | H | Rₙ₉ | H | H | H | Rₙ₁₂ | O |
| Lₐ₄₀₃ | H | Rₙ₄ | H | H | H | Rₙ₉ | H | H | H | Rₙ₁₂ | O |
| Lₐ₄₀₄ | H | Rₙ₅ | H | H | H | Rₙ₉ | H | H | H | Rₙ₁₂ | O |
| Lₐ₄₀₅ | H | Rₙ₇ | H | H | H | Rₙ₉ | H | H | H | Rₙ₁₂ | O |
| Lₐ₄₀₆ | H | Rₙ₉ | H | H | H | Rₙ₉ | H | H | H | Rₙ₁₂ | O |
| Lₐ₄₀₇ | H | Rₙ₁₂ | H | H | H | Rₙ₉ | H | H | H | Rₙ₁₂ | O |
| Lₐ₄₀₈ | H | Rₙ₁₄ | H | H | H | Rₙ₉ | H | H | H | Rₙ₁₂ | O |
| Lₐ₄₀₉ | H | Rₙ₁₆ | H | H | H | Rₙ₉ | H | H | H | Rₙ₁₂ | O |
| Lₐ₄₁₀ | H | H | D | H | H | H | H | H | H | Rₙ₁₂ | O |
| Lₐ₄₁₁ | H | H | Rₙ₂ | H | H | H | H | H | H | Rₙ₁₂ | O |
| Lₐ₄₁₂ | H | H | Rₙ₄ | H | H | H | H | H | H | Rₙ₁₂ | O |
| Lₐ₄₁₃ | H | H | Rₙ₅ | H | H | H | H | H | H | Rₙ₁₂ | O |
| Lₐ₄₁₄ | H | H | Rₙ₇ | H | H | H | H | H | H | Rₙ₁₂ | O |
| Lₐ₄₁₅ | H | H | Rₙ₉ | H | H | H | H | H | H | Rₙ₁₂ | O |
| Lₐ₄₁₆ | H | H | Rₙ₁₂ | H | H | H | H | H | H | Rₙ₁₂ | O |
| Lₐ₄₁₇ | H | H | Rₙ₁₄ | H | H | H | H | H | H | Rₙ₁₂ | O |
| Lₐ₄₁₈ | H | H | Rₙ₁₆ | H | H | H | H | H | H | Rₙ₁₂ | O |
| Lₐ₄₁₉ | H | H | D | H | H | Rₙ₅ | H | H | H | Rₙ₁₂ | O |
| Lₐ₄₂₀ | H | H | Rₙ₂ | H | H | Rₙ₅ | H | H | H | Rₙ₁₂ | O |
| Lₐ₄₂₁ | H | H | Rₙ₄ | H | H | Rₙ₅ | H | H | H | Rₙ₁₂ | O |
| Lₐ₄₂₂ | H | H | Rₙ₅ | H | H | Rₙ₅ | H | H | H | Rₙ₁₂ | O |
| Lₐ₄₂₃ | H | H | Rₙ₇ | H | H | Rₙ₅ | H | H | H | Rₙ₁₂ | O |
| Lₐ₄₂₄ | H | H | Rₙ₉ | H | H | Rₙ₅ | H | H | H | Rₙ₁₂ | O |
| Lₐ₄₂₅ | H | H | Rₙ₁₂ | H | H | Rₙ₅ | H | H | H | Rₙ₁₂ | O |
| Lₐ₄₂₆ | H | H | Rₙ₁₄ | H | H | Rₙ₅ | H | H | H | Rₙ₁₂ | O |
| Lₐ₄₂₇ | H | H | Rₙ₁₆ | H | H | Rₙ₅ | H | H | H | Rₙ₁₂ | O |
| Lₐ₄₂₈ | H | H | D | H | H | Rₙ₉ | H | H | H | Rₙ₁₂ | O |
| Lₐ₄₂₉ | H | H | Rₙ₂ | H | H | Rₙ₉ | H | H | H | Rₙ₁₂ | O |
| Lₐ₄₃₀ | H | H | Rₙ₄ | H | H | Rₙ₉ | H | H | H | Rₙ₁₂ | O |
| Lₐ₄₃₁ | H | H | Rₙ₅ | H | H | Rₙ₉ | H | H | H | Rₙ₁₂ | O |
| Lₐ₄₃₂ | H | H | Rₙ₇ | H | H | Rₙ₉ | H | H | H | Rₙ₁₂ | O |
| Lₐ₄₃₃ | H | H | Rₙ₉ | H | H | Rₙ₉ | H | H | H | Rₙ₁₂ | O |
| Lₐ₄₃₄ | H | H | Rₙ₁₂ | H | H | Rₙ₉ | H | H | H | Rₙ₁₂ | O |
| Lₐ₄₃₅ | H | H | Rₙ₁₄ | H | H | Rₙ₉ | H | H | H | Rₙ₁₂ | O |
| Lₐ₄₃₆ | H | H | Rₙ₁₆ | H | H | Rₙ₉ | H | H | H | Rₙ₁₂ | O |
| Lₐ₄₃₇ | D | Rₙ₂ | Rₙ₂ | D | H | H | H | H | H | Rₙ₁₂ | O |
| Lₐ₄₃₈ | H | Rₙ₁₂ | Rₙ₂ | H | H | H | H | H | H | Rₙ₁₂ | O |
| Lₐ₄₃₉ | H | Rₙ₁₆ | Rₙ₂ | H | H | H | H | H | H | Rₙ₁₂ | O |
| Lₐ₄₄₀ | D | Rₙ₂ | Rₙ₂ | D | H | Rₙ₅ | H | H | H | Rₙ₁₂ | O |
| Lₐ₄₄₁ | H | Rₙ₁₂ | Rₙ₂ | H | H | Rₙ₅ | H | H | H | Rₙ₁₂ | O |
| Lₐ₄₄₂ | H | Rₙ₁₆ | Rₙ₂ | H | H | Rₙ₅ | H | H | H | Rₙ₁₂ | O |
| Lₐ₄₄₃ | D | Rₙ₂ | Rₙ₂ | D | H | Rₙ₉ | H | H | H | Rₙ₁₂ | O |
| Lₐ₄₄₄ | H | Rₙ₁₂ | Rₙ₂ | H | H | Rₙ₉ | H | H | H | Rₙ₁₂ | O |
| Lₐ₄₄₅ | H | Rₙ₁₆ | Rₙ₂ | H | H | Rₙ₉ | H | H | H | Rₙ₁₂ | O |
| Lₐ₄₄₆ | H | D | H | H | H | H | H | H | H | Rₙ₁₇ | O |
| Lₐ₄₄₇ | H | Rₙ₂ | H | H | H | H | H | H | H | Rₙ₁₇ | O |
| Lₐ₄₄₈ | H | Rₙ₄ | H | H | H | H | H | H | H | Rₙ₁₇ | O |
| Lₐ₄₄₉ | H | Rₙ₅ | H | H | H | H | H | H | H | Rₙ₁₇ | O |
| Lₐ₄₅₀ | H | Rₙ₇ | H | H | H | H | H | H | H | Rₙ₁₇ | O |
| Lₐ₄₅₁ | H | Rₙ₉ | H | H | H | H | H | H | H | Rₙ₁₇ | O |
| Lₐ₄₅₂ | H | D | H | H | H | H | H | H | H | Rₙ₁₇ | O |
| Lₐ₄₅₃ | H | Rₙ₂ | H | H | H | Rₙ₅ | H | H | H | Rₙ₁₇ | O |
| Lₐ₄₅₄ | H | Rₙ₄ | H | H | H | Rₙ₅ | H | H | H | Rₙ₁₇ | O |
| Lₐ₄₅₅ | H | Rₙ₅ | H | H | H | Rₙ₅ | H | H | H | Rₙ₁₇ | O |
| Lₐ₄₅₆ | H | Rₙ₇ | H | H | H | Rₙ₅ | H | H | H | Rₙ₁₇ | O |
| Lₐ₄₅₇ | H | Rₙ₉ | H | H | H | Rₙ₅ | H | H | H | Rₙ₁₇ | O |
| Lₐ₄₅₈ | H | D | H | H | H | Rₙ₉ | H | H | H | Rₙ₁₇ | O |
| Lₐ₄₅₉ | H | Rₙ₂ | H | H | H | Rₙ₉ | H | H | H | Rₙ₁₇ | O |
| Lₐ₄₆₀ | H | Rₙ₄ | H | H | H | Rₙ₉ | H | H | H | Rₙ₁₇ | O |
| Lₐ₄₆₁ | H | Rₙ₅ | H | H | H | Rₙ₉ | H | H | H | Rₙ₁₇ | O |
| Lₐ₄₆₂ | H | Rₙ₇ | H | H | H | Rₙ₉ | H | H | H | Rₙ₁₇ | O |
| Lₐ₄₆₃ | H | Rₙ₉ | H | H | H | Rₙ₉ | H | H | H | Rₙ₁₇ | O |
| Lₐ₄₆₄ | H | H | D | H | H | H | H | H | H | Rₙ₁₇ | O |
| Lₐ₄₆₅ | H | H | Rₙ₂ | H | H | H | H | H | H | Rₙ₁₇ | O |
| Lₐ₄₆₆ | H | H | Rₙ₄ | H | H | H | H | H | H | Rₙ₁₇ | O |
| Lₐ₄₆₇ | H | H | Rₙ₅ | H | H | H | H | H | H | Rₙ₁₇ | O |
| Lₐ₄₆₈ | H | H | Rₙ₇ | H | H | H | H | H | H | Rₙ₁₇ | O |
| Lₐ₄₆₉ | H | H | Rₙ₉ | H | H | H | H | H | H | Rₙ₁₇ | O |
| Lₐ₄₇₀ | H | H | D | H | H | Rₙ₅ | H | H | H | Rₙ₁₇ | O |
| Lₐ₄₇₁ | H | H | Rₙ₂ | H | H | Rₙ₅ | H | H | H | Rₙ₁₇ | O |
| Lₐ₄₇₂ | H | H | Rₙ₄ | H | H | Rₙ₅ | H | H | H | Rₙ₁₇ | O |
| Lₐ₄₇₃ | H | H | Rₙ₅ | H | H | Rₙ₅ | H | H | H | Rₙ₁₇ | O |
| Lₐ₄₇₄ | H | H | Rₙ₇ | H | H | Rₙ₅ | H | H | H | Rₙ₁₇ | O |
| Lₐ₄₇₅ | H | H | Rₙ₉ | H | H | Rₙ₅ | H | H | H | Rₙ₁₇ | O |
| Lₐ₄₇₆ | H | H | D | H | H | Rₙ₉ | H | H | H | Rₙ₁₇ | O |
| Lₐ₄₇₇ | H | H | Rₙ₂ | H | H | Rₙ₉ | H | H | H | Rₙ₁₇ | O |
| Lₐ₄₇₈ | H | H | Rₙ₄ | H | H | Rₙ₉ | H | H | H | Rₙ₁₇ | O |
| Lₐ₄₇₉ | H | H | Rₙ₅ | H | H | Rₙ₉ | H | H | H | Rₙ₁₇ | O |
| Lₐ₄₈₀ | H | H | Rₙ₇ | H | H | Rₙ₉ | H | H | H | Rₙ₁₇ | O |
| Lₐ₄₈₁ | H | H | Rₙ₉ | H | H | Rₙ₉ | H | H | H | Rₙ₁₇ | O |
| Lₐ₄₈₂ | D | Rₙ₂ | Rₙ₂ | D | H | H | H | H | H | Rₙ₁₇ | O |
| Lₐ₄₈₃ | D | Rₙ₂ | Rₙ₂ | D | H | Rₙ₅ | H | H | H | Rₙ₁₇ | O |
| Lₐ₄₈₄ | D | Rₙ₂ | Rₙ₂ | D | H | Rₙ₉ | H | H | H | Rₙ₁₇ | O |
| Lₐ₄₈₅ | H | D | H | H | H | H | H | H | H | Rₙ₂₃ | O |
| Lₐ₄₈₆ | H | Rₙ₂ | H | H | H | H | H | H | H | Rₙ₂₃ | O |
| Lₐ₄₈₇ | H | Rₙ₄ | H | H | H | H | H | H | H | Rₙ₂₃ | O |
| Lₐ₄₈₈ | H | Rₙ₅ | H | H | H | H | H | H | H | Rₙ₂₃ | O |
| Lₐ₄₈₉ | H | Rₙ₇ | H | H | H | H | H | H | H | Rₙ₂₃ | O |
| Lₐ₄₉₀ | H | Rₙ₉ | H | H | H | H | H | H | H | Rₙ₂₃ | O |
| Lₐ₄₉₁ | H | D | H | H | H | Rₙ₅ | H | H | H | Rₙ₂₃ | O |
| Lₐ₄₉₂ | H | Rₙ₂ | H | H | H | Rₙ₅ | H | H | H | Rₙ₂₃ | O |
| Lₐ₄₉₃ | H | Rₙ₄ | H | H | H | Rₙ₅ | H | H | H | Rₙ₂₃ | O |
| Lₐ₄₉₄ | H | Rₙ₅ | H | H | H | Rₙ₅ | H | H | H | Rₙ₂₃ | O |
| Lₐ₄₉₅ | H | Rₙ₇ | H | H | H | Rₙ₅ | H | H | H | Rₙ₂₃ | O |
| Lₐ₄₉₆ | H | Rₙ₉ | H | H | H | Rₙ₅ | H | H | H | Rₙ₂₃ | O |
| Lₐ₄₉₇ | H | D | H | H | H | Rₙ₉ | H | H | H | Rₙ₂₃ | O |
| Lₐ₄₉₈ | H | Rₙ₂ | H | H | H | Rₙ₉ | H | H | H | Rₙ₂₃ | O |
| Lₐ₄₉₉ | H | Rₙ₄ | H | H | H | Rₙ₉ | H | H | H | Rₙ₂₃ | O |
| Lₐ₅₀₀ | H | Rₙ₅ | H | H | H | Rₙ₉ | H | H | H | Rₙ₂₃ | O |
| Lₐ₅₀₁ | H | Rₙ₇ | H | H | H | Rₙ₉ | H | H | H | Rₙ₂₃ | O |
| Lₐ₅₀₂ | H | Rₙ₉ | H | H | H | Rₙ₉ | H | H | H | Rₙ₂₃ | O |
| Lₐ₅₀₃ | H | H | D | H | H | H | H | H | H | Rₙ₂₃ | O |
| Lₐ₅₀₄ | H | H | Rₙ₂ | H | H | H | H | H | H | Rₙ₂₃ | O |
| Lₐ₅₀₅ | H | H | Rₙ₄ | H | H | H | H | H | H | Rₙ₂₃ | O |
| Lₐ₅₀₆ | H | H | Rₙ₅ | H | H | H | H | H | H | Rₙ₂₃ | O |
| Lₐ₅₀₇ | H | H | Rₙ₇ | H | H | H | H | H | H | Rₙ₂₃ | O |
| Lₐ₅₀₈ | H | H | Rₙ₉ | H | H | H | H | H | H | Rₙ₂₃ | O |
| Lₐ₅₀₉ | H | H | D | H | H | Rₙ₅ | H | H | H | Rₙ₂₃ | O |
| Lₐ₅₁₀ | H | H | Rₙ₂ | H | H | Rₙ₅ | H | H | H | Rₙ₂₃ | O |
| Lₐ₅₁₁ | H | H | Rₙ₄ | H | H | Rₙ₅ | H | H | H | Rₙ₂₃ | O |
| Lₐ₅₁₂ | H | H | Rₙ₅ | H | H | Rₙ₅ | H | H | H | Rₙ₂₃ | O |
| Lₐ₅₁₃ | H | H | Rₙ₇ | H | H | Rₙ₅ | H | H | H | Rₙ₂₃ | O |
| Lₐ₅₁₄ | H | H | Rₙ₉ | H | H | Rₙ₅ | H | H | H | Rₙ₂₃ | O |
| Lₐ₅₁₅ | H | H | D | H | H | Rₙ₉ | H | H | H | Rₙ₂₃ | O |
| Lₐ₅₁₆ | H | H | Rₙ₂ | H | H | Rₙ₉ | H | H | H | Rₙ₂₃ | O |
| Lₐ₅₁₇ | H | H | Rₙ₄ | H | H | Rₙ₉ | H | H | H | Rₙ₂₃ | O |
| Lₐ₅₁₈ | H | H | Rₙ₅ | H | H | Rₙ₉ | H | H | H | Rₙ₂₃ | O |
| Lₐ₅₁₉ | H | H | Rₙ₇ | H | H | Rₙ₉ | H | H | H | Rₙ₂₃ | O |
| Lₐ₅₂₀ | H | H | Rₙ₉ | H | H | Rₙ₉ | H | H | H | Rₙ₂₃ | O |
| Lₐ₅₂₁ | D | Rₙ₂ | Rₙ₂ | D | H | H | H | H | H | Rₙ₂₃ | O |
| Lₐ₅₂₂ | D | Rₙ₂ | Rₙ₂ | D | H | Rₙ₅ | H | H | H | Rₙ₂₃ | O |
| Lₐ₅₂₃ | D | Rₙ₂ | Rₙ₂ | D | H | Rₙ₉ | H | H | H | Rₙ₂₃ | O |
| Lₐ₅₂₄ | H | D | H | H | H | H | H | H | CN | Rₙ₁₃ | O |
| Lₐ₅₂₅ | H | Rₙ₂ | H | H | H | H | H | H | CN | Rₙ₁₃ | O |
| Lₐ₅₂₆ | H | Rₙ₄ | H | H | H | H | H | H | CN | Rₙ₁₃ | O |
| Lₐ₅₂₇ | H | Rₙ₅ | H | H | H | H | H | H | CN | Rₙ₁₃ | O |
| Lₐ₅₂₈ | H | Rₙ₇ | H | H | H | H | H | H | CN | Rₙ₁₃ | O |
| Lₐ₅₂₉ | H | Rₙ₉ | H | H | H | H | H | H | CN | Rₙ₁₃ | O |
| Lₐ₅₃₀ | H | Rₙ₁₂ | H | H | H | H | H | H | CN | Rₙ₁₃ | O |
| Lₐ₅₃₁ | H | Rₙ₁₄ | H | H | H | H | H | H | CN | Rₙ₁₃ | O |
| Lₐ₅₃₂ | H | Rₙ₁₆ | H | H | H | H | H | H | CN | Rₙ₁₃ | O |
| Lₐ₅₃₃ | H | D | H | H | H | Rₙ₅ | H | H | CN | Rₙ₁₂ | O |
| Lₐ₅₃₄ | H | Rₙ₂ | H | H | H | Rₙ₅ | H | H | CN | Rₙ₁₂ | O |
| Lₐ₅₃₅ | H | Rₙ₄ | H | H | H | Rₙ₅ | H | H | CN | Rₙ₁₂ | O |
| Lₐ₅₃₆ | H | Rₙ₅ | H | H | H | Rₙ₅ | H | H | CN | Rₙ₁₂ | O |
| Lₐ₅₃₇ | H | Rₙ₇ | H | H | H | Rₙ₅ | H | H | CN | Rₙ₁₂ | O |
| Lₐ₅₃₈ | H | Rₙ₉ | H | H | H | Rₙ₅ | H | H | CN | Rₙ₁₂ | O |
| Lₐ₅₃₉ | H | Rₙ₁₂ | H | H | H | Rₙ₅ | H | H | CN | Rₙ₁₂ | O |
| Lₐ₅₄₀ | H | Rₙ₁₄ | H | H | H | Rₙ₅ | H | H | CN | Rₙ₁₂ | O |
| Lₐ₅₄₁ | H | Rₙ₁₆ | H | H | H | Rₙ₅ | H | H | CN | Rₙ₁₂ | O |
| Lₐ₅₄₂ | H | D | H | H | H | Rₙ₉ | H | H | CN | Rₙ₁₂ | O |
| Lₐ₅₄₃ | H | Rₙ₂ | H | H | H | Rₙ₉ | H | H | CN | Rₙ₁₂ | O |
| Lₐ₅₄₄ | H | Rₙ₄ | H | H | H | Rₙ₉ | H | H | CN | Rₙ₁₂ | O |
| Lₐ₅₄₅ | H | Rₙ₅ | H | H | H | Rₙ₉ | H | H | CN | Rₙ₁₂ | O |
| Lₐ₅₄₆ | H | Rₙ₇ | H | H | H | Rₙ₉ | H | H | CN | Rₙ₁₂ | O |
| Lₐ₅₄₇ | H | Rₙ₉ | H | H | H | Rₙ₉ | H | H | CN | Rₙ₁₂ | O |
| Lₐ₅₄₈ | H | Rₙ₁₂ | H | H | H | Rₙ₉ | H | H | CN | Rₙ₁₂ | O |
| Lₐ₅₄₉ | H | Rₙ₁₄ | H | H | H | Rₙ₉ | H | H | CN | Rₙ₁₂ | O |
| Lₐ₅₅₀ | H | Rₙ₁₆ | H | H | H | Rₙ₉ | H | H | CN | Rₙ₁₂ | O |
| Lₐ₅₅₁ | H | H | D | H | H | H | H | H | CN | Rₙ₁₂ | O |
| Lₐ₅₅₂ | H | H | Rₙ₂ | H | H | H | H | H | CN | Rₙ₁₂ | O |
| Lₐ₅₅₃ | H | H | Rₙ₄ | H | H | H | H | H | CN | Rₙ₁₂ | O |
| Lₐ₅₅₄ | H | H | Rₙ₅ | H | H | H | H | H | CN | Rₙ₁₂ | O |
| Lₐ₅₅₅ | H | H | Rₙ₇ | H | H | H | H | H | CN | Rₙ₁₂ | O |
| Lₐ₅₅₆ | H | H | Rₙ₉ | H | H | H | H | H | CN | Rₙ₁₂ | O |
| Lₐ₅₅₇ | H | H | Rₙ₁₂ | H | H | H | H | H | CN | Rₙ₁₂ | O |
| Lₐ₅₅₈ | H | H | Rₙ₁₄ | H | H | H | H | H | CN | Rₙ₁₂ | O |
| Lₐ₅₅₉ | H | H | Rₙ₁₆ | H | H | H | H | H | CN | Rₙ₁₂ | O |
| Lₐ₅₆₀ | H | H | D | H | H | Rₙ₅ | H | H | CN | Rₙ₁₂ | O |
| Lₐ₅₆₁ | H | H | Rₙ₂ | H | H | Rₙ₅ | H | H | CN | Rₙ₁₂ | O |
| Lₐ₅₆₂ | H | H | Rₙ₄ | H | H | Rₙ₅ | H | H | CN | Rₙ₁₂ | O |
| Lₐ₅₆₃ | H | H | Rₙ₅ | H | H | Rₙ₅ | H | H | CN | Rₙ₁₂ | O |
| Lₐ₅₆₄ | H | H | Rₙ₇ | H | H | Rₙ₅ | H | H | CN | Rₙ₁₂ | O |
| Lₐ₅₆₅ | H | H | Rₙ₉ | H | H | Rₙ₅ | H | H | CN | Rₙ₁₂ | O |
| Lₐ₅₆₆ | H | H | Rₙ₁₂ | H | H | Rₙ₅ | H | H | CN | Rₙ₁₂ | O |
| Lₐ₅₆₇ | H | H | Rₙ₁₄ | H | H | Rₙ₅ | H | H | CN | Rₙ₁₂ | O |
| Lₐ₅₆₈ | H | H | Rₙ₁₆ | H | H | Rₙ₅ | H | H | CN | Rₙ₁₂ | O |
| Lₐ₅₆₉ | H | H | D | H | H | Rₙ₉ | H | H | CN | Rₙ₁₂ | O |
| Lₐ₅₇₀ | H | H | Rₙ₂ | H | H | Rₙ₉ | H | H | CN | Rₙ₁₂ | O |
| Lₐ₅₇₁ | H | H | Rₙ₄ | H | H | Rₙ₉ | H | H | CN | Rₙ₁₂ | O |
| Lₐ₅₇₂ | H | H | Rₙ₅ | H | H | Rₙ₉ | H | H | CN | Rₙ₁₂ | O |
| Lₐ₅₇₃ | H | H | Rₙ₇ | H | H | Rₙ₉ | H | H | CN | Rₙ₁₂ | O |
| Lₐ₅₇₄ | H | H | Rₙ₉ | H | H | Rₙ₉ | H | H | CN | Rₙ₁₂ | O |
| Lₐ₅₇₅ | H | H | Rₙ₁₂ | H | H | Rₙ₉ | H | H | CN | Rₙ₁₂ | O |
| Lₐ₅₇₆ | H | H | Rₙ₁₄ | H | H | Rₙ₉ | H | H | CN | Rₙ₁₂ | O |
| Lₐ₅₇₇ | H | H | Rₙ₁₆ | H | H | Rₙ₉ | H | H | CN | Rₙ₁₂ | O |
| Lₐ₅₇₈ | D | Rₙ₂ | Rₙ₂ | D | H | H | H | H | CN | Rₙ₁₂ | O |
| Lₐ₅₇₉ | H | Rₙ₁₂ | Rₙ₂ | H | H | H | H | H | CN | Rₙ₁₂ | O |
| Lₐ₅₈₀ | H | Rₙ₁₆ | Rₙ₂ | H | H | H | H | H | CN | Rₙ₁₂ | O |
| Lₐ₅₈₁ | D | Rₙ₂ | Rₙ₂ | D | H | Rₙ₅ | H | H | CN | Rₙ₁₂ | O |
| Lₐ₅₈₂ | H | Rₙ₁₂ | Rₙ₂ | H | H | Rₙ₅ | H | H | CN | Rₙ₁₂ | O |
| Lₐ₅₈₃ | H | Rₙ₁₆ | Rₙ₂ | H | H | Rₙ₅ | H | H | CN | Rₙ₁₂ | O |
| Lₐ₅₈₄ | D | Rₙ₂ | Rₙ₂ | D | H | Rₙ₉ | H | H | CN | Rₙ₁₂ | O |
| Lₐ₅₈₅ | H | Rₙ₁₂ | Rₙ₂ | H | H | Rₙ₉ | H | H | CN | Rₙ₁₂ | O |
| Lₐ₅₈₆ | H | Rₙ₁₆ | Rₙ₂ | H | H | Rₙ₉ | H | H | CN | Rₙ₁₂ | O |
| Lₐ₅₈₇ | H | D | H | H | H | H | H | H | F | Rₙ₁₂ | O |
| Lₐ₅₈₈ | H | Rₙ₂ | H | H | H | H | H | H | F | Rₙ₁₂ | O |
| Lₐ₅₈₉ | H | Rₙ₄ | H | H | H | H | H | H | F | Rₙ₁₂ | O |
| Lₐ₅₉₀ | H | Rₙ₅ | H | H | H | H | H | H | F | Rₙ₁₂ | O |
| Lₐ₅₉₁ | H | Rₙ₇ | H | H | H | H | H | H | F | Rₙ₁₂ | O |
| Lₐ₅₉₂ | H | Rₙ₉ | H | H | H | H | H | H | F | Rₙ₁₂ | O |
| Lₐ₅₉₃ | H | Rₙ₁₂ | H | H | H | H | H | H | F | Rₙ₁₂ | O |
| Lₐ₅₉₄ | H | Rₙ₁₄ | H | H | H | H | H | H | F | Rₙ₁₂ | O |
| Lₐ₅₉₅ | H | Rₙ₁₆ | H | H | H | H | H | H | F | Rₙ₁₂ | O |
| Lₐ₅₉₆ | H | D | H | H | H | Rₙ₅ | H | H | F | Rₙ₁₂ | O |
| Lₐ₅₉₇ | H | Rₙ₂ | H | H | H | Rₙ₅ | H | H | F | Rₙ₁₂ | O |
| Lₐ₅₉₈ | H | Rₙ₄ | H | H | H | Rₙ₅ | H | H | F | Rₙ₁₂ | O |
| Lₐ₅₉₉ | H | Rₙ₅ | H | H | H | Rₙ₅ | H | H | F | Rₙ₁₂ | O |
| Lₐ₆₀₀ | H | Rₙ₇ | H | H | H | Rₙ₅ | H | H | F | Rₙ₁₂ | O |
| Lₐ₆₀₁ | H | Rₙ₉ | H | H | H | Rₙ₅ | H | H | F | Rₙ₁₂ | O |
| Lₐ₆₀₂ | H | Rₙ₁₂ | H | H | H | Rₙ₅ | H | H | F | Rₙ₁₂ | O |
| Lₐ₆₀₃ | H | Rₙ₁₄ | H | H | H | Rₙ₅ | H | H | F | Rₙ₁₂ | O |
| Lₐ₆₀₄ | H | Rₙ₁₆ | H | H | H | Rₙ₅ | H | H | F | Rₙ₁₂ | O |
| Lₐ₆₀₅ | H | D | H | H | H | Rₙ₉ | H | H | F | Rₙ₁₂ | O |
| Lₐ₆₀₆ | H | Rₙ₂ | H | H | H | Rₙ₉ | H | H | F | Rₙ₁₂ | O |
| Lₐ₆₀₇ | H | Rₙ₄ | H | H | H | Rₙ₉ | H | H | F | Rₙ₁₂ | O |
| Lₐ₆₀₈ | H | Rₙ₅ | H | H | H | Rₙ₉ | H | H | F | Rₙ₁₂ | O |
| Lₐ₆₀₉ | H | Rₙ₇ | H | H | H | Rₙ₉ | H | H | F | Rₙ₁₂ | O |
| Lₐ₆₁₀ | H | Rₙ₉ | H | H | H | Rₙ₉ | H | H | F | Rₙ₁₂ | O |
| Lₐ₆₁₁ | H | Rₙ₁₂ | H | H | H | Rₙ₉ | H | H | F | Rₙ₁₂ | O |
| Lₐ₆₁₂ | H | Rₙ₁₄ | H | H | H | Rₙ₉ | H | H | F | Rₙ₁₂ | O |
| Lₐ₆₁₃ | H | Rₙ₁₆ | H | H | H | Rₙ₉ | H | H | F | Rₙ₁₂ | O |
| Lₐ₆₁₄ | H | H | D | H | H | H | H | H | F | Rₙ₁₂ | O |
| Lₐ₆₁₅ | H | H | Rₙ₂ | H | H | H | H | H | F | Rₙ₁₂ | O |
| Lₐ₆₁₆ | H | H | Rₙ₄ | H | H | H | H | H | F | Rₙ₁₂ | O |
| Lₐ₆₁₇ | H | H | Rₙ₅ | H | H | H | H | H | F | Rₙ₁₂ | O |
| Lₐ₆₁₈ | H | H | Rₙ₇ | H | H | H | H | H | F | Rₙ₁₂ | O |
| Lₐ₆₁₉ | H | H | Rₙ₉ | H | H | H | H | H | F | Rₙ₁₂ | O |
| Lₐ₆₂₀ | H | H | Rₙ₁₂ | H | H | H | H | H | F | Rₙ₁₂ | O |
| Lₐ₆₂₁ | H | H | Rₙ₁₄ | H | H | H | H | H | F | Rₙ₁₂ | O |
| Lₐ₆₂₂ | H | H | Rₙ₁₆ | H | H | H | H | H | F | Rₙ₁₂ | O |
| Lₐ₆₂₃ | H | H | D | H | H | Rₙ₅ | H | H | F | Rₙ₁₂ | O |
| Lₐ₆₂₄ | H | H | Rₙ₂ | H | H | Rₙ₅ | H | H | F | Rₙ₁₂ | O |
| Lₐ₆₂₅ | H | H | Rₙ₄ | H | H | Rₙ₅ | H | H | F | Rₙ₁₂ | O |
| Lₐ₆₂₆ | H | H | Rₙ₅ | H | H | Rₙ₅ | H | H | F | Rₙ₁₂ | O |
| Lₐ₆₂₇ | H | H | Rₙ₇ | H | H | Rₙ₅ | H | H | F | Rₙ₁₂ | O |
| Lₐ₆₂₈ | H | H | Rₙ₉ | H | H | Rₙ₅ | H | H | F | Rₙ₁₂ | O |
| Lₐ₆₂₉ | H | H | Rₙ₁₂ | H | H | Rₙ₅ | H | H | F | Rₙ₁₂ | O |
| Lₐ₆₃₀ | H | H | Rₙ₁₄ | H | H | Rₙ₅ | H | H | F | Rₙ₁₂ | O |
| Lₐ₆₃₁ | H | H | Rₙ₁₆ | H | H | Rₙ₅ | H | H | F | Rₙ₁₂ | O |
| Lₐ₆₃₂ | H | H | D | H | H | Rₙ₉ | H | H | F | Rₙ₁₂ | O |
| Lₐ₆₃₃ | H | H | Rₙ₂ | H | H | Rₙ₉ | H | H | F | Rₙ₁₂ | O |
| Lₐ₆₃₄ | H | H | Rₙ₄ | H | H | Rₙ₉ | H | H | F | Rₙ₁₂ | O |
| Lₐ₆₃₅ | H | H | Rₙ₅ | H | H | Rₙ₉ | H | H | F | Rₙ₁₂ | O |
| Lₐ₆₃₆ | H | H | Rₙ₇ | H | H | Rₙ₉ | H | H | F | Rₙ₁₂ | O |
| Lₐ₆₃₇ | H | H | Rₙ₉ | H | H | Rₙ₉ | H | H | F | Rₙ₁₂ | O |
| Lₐ₆₃₈ | H | H | Rₙ₁₂ | H | H | Rₙ₉ | H | H | F | Rₙ₁₂ | O |
| Lₐ₆₃₉ | H | H | Rₙ₁₄ | H | H | Rₙ₉ | H | H | F | Rₙ₁₂ | O |
| Lₐ₆₄₀ | H | H | Rₙ₁₆ | H | H | Rₙ₉ | H | H | F | Rₙ₁₂ | O |
| Lₐ₆₄₁ | D | Rₙ₂ | Rₙ₂ | D | H | H | H | H | F | Rₙ₁₂ | O |
| Lₐ₆₄₂ | H | Rₙ₁₂ | Rₙ₂ | H | H | H | H | H | F | Rₙ₁₂ | O |
| Lₐ₆₄₃ | H | Rₙ₁₆ | Rₙ₂ | H | H | H | H | H | F | Rₙ₁₂ | O |
| Lₐ₆₄₄ | D | Rₙ₂ | Rₙ₂ | D | H | Rₙ₅ | H | H | F | Rₙ₁₂ | O |
| Lₐ₆₄₅ | H | Rₙ₁₂ | Rₙ₂ | H | H | Rₙ₅ | H | H | F | Rₙ₁₂ | O |
| Lₐ₆₄₆ | H | Rₙ₁₆ | Rₙ₂ | H | H | Rₙ₅ | H | H | F | Rₙ₁₂ | O |
| Lₐ₆₄₇ | D | Rₙ₂ | Rₙ₂ | D | H | Rₙ₉ | H | H | F | Rₙ₁₂ | O |
| Lₐ₆₄₈ | H | Rₙ₁₂ | Rₙ₂ | H | H | Rₙ₉ | H | H | F | Rₙ₁₂ | O |
| Lₐ₆₄₉ | H | Rₙ₁₆ | Rₙ₂ | H | H | Rₙ₉ | H | H | F | Rₙ₁₂ | O |
| Lₐ₆₅₀ | H | D | H | H | H | H | H | H | CN | Rₙ₁₇ | O |
| Lₐ₆₅₁ | H | Rₙ₂ | H | H | H | H | H | H | CN | Rₙ₁₇ | O |
| Lₐ₆₅₂ | H | Rₙ₄ | H | H | H | H | H | H | CN | Rₙ₁₇ | O |
| Lₐ₆₅₃ | H | Rₙ₅ | H | H | H | H | H | H | CN | Rₙ₁₇ | O |
| Lₐ₆₅₄ | H | Rₙ₇ | H | H | H | H | H | H | CN | Rₙ₁₇ | O |
| Lₐ₆₅₅ | H | Rₙ₉ | H | H | H | H | H | H | CN | Rₙ₁₇ | O |
| Lₐ₆₅₆ | H | D | H | H | H | Rₙ₅ | H | H | CN | Rₙ₁₇ | O |
| Lₐ₆₅₇ | H | Rₙ₂ | H | H | H | Rₙ₅ | H | H | CN | Rₙ₁₇ | O |
| Lₐ₆₅₈ | H | Rₙ₄ | H | H | H | Rₙ₅ | H | H | CN | Rₙ₁₇ | O |
| Lₐ₆₅₉ | H | Rₙ₅ | H | H | H | Rₙ₅ | H | H | CN | Rₙ₁₇ | O |
| Lₐ₆₆₀ | H | Rₙ₇ | H | H | H | Rₙ₅ | H | H | CN | Rₙ₁₇ | O |
| Lₐ₆₆₁ | H | Rₙ₉ | H | H | H | Rₙ₅ | H | H | CN | Rₙ₁₇ | O |
| Lₐ₆₆₂ | H | D | H | H | H | Rₙ₉ | H | H | CN | Rₙ₁₇ | O |
| Lₐ₆₆₃ | H | Rₙ₂ | H | H | H | Rₙ₉ | H | H | CN | Rₙ₁₇ | O |
| Lₐ₆₆₄ | H | Rₙ₄ | H | H | H | Rₙ₉ | H | H | CN | Rₙ₁₇ | O |
| Lₐ₆₆₅ | H | Rₙ₅ | H | H | H | Rₙ₉ | H | H | CN | R₁₇ | O |
| Lₐ₆₆₆ | H | Rₙ₇ | H | H | H | Rₙ₉ | H | H | CN | Rₙ₁₇ | O |
| Lₐ₆₆₇ | H | Rₙ₉ | H | H | H | Rₙ₉ | H | H | CN | Rₙ₁₇ | O |
| Lₐ₆₆₈ | H | H | D | H | H | H | H | H | CN | Rₙ₁₇ | O |
| Lₐ₆₆₉ | H | H | Rₙ₂ | H | H | H | H | H | CN | Rₙ₁₇ | O |
| Lₐ₆₇₀ | H | H | Rₙ₄ | H | H | H | H | H | CN | Rₙ₁₇ | O |
| L₂₆₇₁ | H | H | Rₙ₅ | H | H | H | H | H | CN | Rₙ₁₇ | O |
| Lₐ₆₇₂ | H | H | Rₙ₇ | H | H | H | H | H | CN | Rₙ₁₇ | O |
| Lₐ₆₇₃ | H | H | Rₙ₉ | H | H | H | H | H | CN | Rₙ₁₇ | O |
| Lₐ₆₇₄ | H | H | D | H | H | Rₙ₅ | H | H | CN | Rₙ₁₇ | O |
| Lₐ₆₇₅ | H | H | Rₙ₂ | H | H | Rₙ₅ | H | H | CN | Rₙ₁₇ | O |
| Lₐ₆₇₆ | H | H | Rₙ₄ | H | H | Rₙ₅ | H | H | CN | Rₙ₁₇ | O |
| Lₐ₆₇₇ | H | H | Rₙ₅ | H | H | Rₙ₅ | H | H | CN | Rₙ₁₇ | O |
| Lₐ₆₇₈ | H | H | Rₙ₇ | H | H | Rₙ₅ | H | H | CN | Rₙ₁₇ | O |
| Lₐ₆₇₉ | H | H | Rₙ₉ | H | H | Rₙ₅ | H | H | CN | Rₙ₁₇ | O |
| Lₐ₆₈₀ | H | H | D | H | H | Rₙ₉ | H | H | CN | Rₙ₁₇ | O |
| Lₐ₆₈₁ | H | H | Rₙ₂ | H | H | Rₙ₉ | H | H | CN | Rₙ₁₇ | O |
| Lₐ₆₈₂ | H | H | Rₙ₄ | H | H | Rₙ₉ | H | H | CN | Rₙ₁₇ | O |
| Lₐ₆₈₃ | H | H | Rₙ₅ | H | H | Rₙ₉ | H | H | CN | Rₙ₁₇ | O |
| Lₐ₆₈₄ | H | H | Rₙ₇ | H | H | Rₙ₉ | H | H | CN | Rₙ₁₇ | O |
| Lₐ₆₈₅ | H | H | Rₙ₉ | H | H | Rₙ₉ | H | H | CN | Rₙ₁₇ | O |
| Lₐ₆₈₆ | D | Rₙ₂ | Rₙ₂ | D | H | H | H | H | CN | Rₙ₁₇ | O |
| Lₐ₆₈₇ | D | Rₙ₂ | Rₙ₂ | D | H | Rₙ₅ | H | H | CN | Rₙ₁₇ | O |
| Lₐ₆₈₈ | D | Rₙ₂ | Rₙ₂ | D | H | Rₙ₉ | H | H | CN | Rₙ₁₇ | O |
| Lₐ₆₈₉ | H | D | H | H | H | H | H | H | F | Rₙ₁₇ | O |
| Lₐ₆₉₀ | H | Rₙ₂ | H | H | H | H | H | H | F | Rₙ₁₇ | O |
| Lₐ₆₉₁ | H | Rₙ₄ | H | H | H | H | H | H | F | Rₙ₁₇ | O |
| Lₐ₆₉₂ | H | Rₙ₅ | H | H | H | H | H | H | F | Rₙ₁₇ | O |
| Lₐ₆₉₃ | H | Rₙ₇ | H | H | H | H | H | H | F | Rₙ₁₇ | O |
| Lₐ₆₉₄ | H | Rₙ₉ | H | H | H | H | H | H | F | Rₙ₁₇ | O |
| Lₐ₆₉₅ | H | D | H | H | H | Rₙ₅ | H | H | F | Rₙ₁₇ | O |
| Lₐ₆₉₆ | H | Rₙ₂ | H | H | H | Rₙ₅ | H | H | F | Rₙ₁₇ | O |
| Lₐ₆₉₇ | H | Rₙ₄ | H | H | H | Rₙ₅ | H | H | F | Rₙ₁₇ | O |
| Lₐ₆₉₈ | H | Rₙ₅ | H | H | H | Rₙ₅ | H | H | F | Rₙ₁₇ | O |
| Lₐ₆₉₉ | H | Rₙ₇ | H | H | H | Rₙ₅ | H | H | F | Rₙ₁₇ | O |
| Lₐ₇₀₀ | H | Rₙ₉ | H | H | H | Rₙ₅ | H | H | F | Rₙ₁₇ | O |
| Lₐ₇₀₁ | H | D | H | H | H | Rₙ₉ | H | H | F | Rₙ₁₇ | O |
| Lₐ₇₀₂ | H | Rₙ₂ | H | H | H | Rₙ₉ | H | H | F | Rₙ₁₇ | O |
| Lₐ₇₀₃ | H | Rₙ₄ | H | H | H | Rₙ₉ | H | H | F | Rₙ₁₇ | O |
| Lₐ₇₀₄ | H | Rₙ₅ | H | H | H | Rₙ₉ | H | H | F | Rₙ₁₇ | O |
| Lₐ₇₀₅ | H | Rₙ₇ | H | H | H | Rₙ₉ | H | H | F | Rₙ₁₇ | O |
| Lₐ₇₀₆ | H | Rₙ₉ | H | H | H | Rₙ₉ | H | H | F | Rₙ₁₇ | O |
| Lₐ₇₀₇ | H | H | D | H | H | H | H | H | F | Rₙ₁₇ | O |
| Lₐ₇₀₈ | H | H | Rₙ₂ | H | H | H | H | H | F | Rₙ₁₇ | O |
| Lₐ₇₀₉ | H | H | Rₙ₄ | H | H | H | H | H | F | Rₙ₁₇ | O |
| Lₐ₇₁₀ | H | H | Rₙ₅ | H | H | H | H | H | F | Rₙ₁₇ | O |
| Lₐ₇₁₁ | H | H | Rₙ₇ | H | H | H | H | H | F | Rₙ₁₇ | O |
| Lₐ₇₁₂ | H | H | Rₙ₉ | H | H | H | H | H | F | Rₙ₁₇ | O |
| Lₐ₇₁₃ | H | H | D | H | H | Rₙ₅ | H | H | F | Rₙ₁₇ | O |
| Lₐ₇₁₄ | H | H | Rₙ₂ | H | H | Rₙ₅ | H | H | F | Rₙ₁₇ | O |
| Lₐ₇₁₅ | H | H | Rₙ₄ | H | H | Rₙ₅ | H | H | F | Rₙ₁₇ | O |
| Lₐ₇₁₆ | H | H | Rₙ₅ | H | H | Rₙ₅ | H | H | F | Rₙ₁₇ | O |
| Lₐ₇₁₇ | H | H | Rₙ₇ | H | H | Rₙ₅ | H | H | F | Rₙ₁₇ | O |
| Lₐ₇₁₈ | H | H | Rₙ₉ | H | H | Rₙ₅ | H | H | F | Rₙ₁₇ | O |
| Lₐ₇₁₉ | H | H | D | H | H | Rₙ₉ | H | H | F | Rₙ₁₇ | O |
| Lₐ₇₂₀ | H | H | Rₙ₂ | H | H | Rₙ₉ | H | H | F | Rₙ₁₇ | O |
| Lₐ₇₂₁ | H | H | Rₙ₄ | H | H | Rₙ₉ | H | H | F | Rₙ₁₇ | O |
| Lₐ₇₂₂ | H | H | Rₙ₅ | H | H | Rₙ₉ | H | H | F | Rₙ₁₇ | O |
| Lₐ₇₂₃ | H | H | Rₙ₇ | H | H | Rₙ₉ | H | H | F | Rₙ₁₇ | O |
| Lₐ₇₂₄ | H | H | Rₙ₉ | H | H | Rₙ₉ | H | H | F | Rₙ₁₇ | O |
| Lₐ₇₂₅ | D | Rₙ₂ | Rₙ₂ | D | H | H | H | H | F | Rₙ₁₇ | O |
| Lₐ₇₂₆ | D | Rₙ₂ | Rₙ₂ | D | H | Rₙ₅ | H | H | F | Rₙ₁₇ | O |
| Lₐ₇₂₇ | D | Rₙ₂ | Rₙ₂ | D | H | Rₙ₉ | H | H | F | Rₙ₁₇ | O |
| Lₐ₇₂₈ | H | D | H | H | H | H | H | H | CN | Rₙ₂₃ | O |
| Lₐ₇₂₉ | H | Rₙ₂ | H | H | H | H | H | H | CN | Rₙ₂₃ | O |
| Lₐ₇₃₀ | H | Rₙ₄ | H | H | H | H | H | H | CN | Rₙ₂₃ | O |
| Lₐ₇₃₁ | H | Rₙ₅ | H | H | H | H | H | H | CN | Rₙ₂₃ | O |
| Lₐ₇₃₂ | H | Rₙ₇ | H | H | H | H | H | H | CN | Rₙ₂₃ | O |
| Lₐ₇₃₃ | H | Rₙ₉ | H | H | H | H | H | H | CN | Rₙ₂₃ | O |
| Lₐ₇₃₄ | H | D | H | H | H | Rₙ₅ | H | H | CN | Rₙ₂₃ | O |
| Lₐ₇₃₅ | H | Rₙ₂ | H | H | H | Rₙ₅ | H | H | CN | Rₙ₂₃ | O |
| Lₐ₇₃₆ | H | Rₙ₄ | H | H | H | Rₙ₅ | H | H | CN | Rₙ₂₃ | O |
| Lₐ₇₃₇ | H | Rₙ₅ | H | H | H | Rₙ₅ | H | H | CN | Rₙ₂₃ | O |
| Lₐ₇₃₈ | H | Rₙ₇ | H | H | H | Rₙ₅ | H | H | CN | Rₙ₂₃ | O |
| Lₐ₇₃₉ | H | Rₙ₉ | H | H | H | Rₙ₅ | H | H | CN | Rₙ₂₃ | O |
| Lₐ₇₄₀ | H | D | H | H | H | Rₙ₉ | H | H | CN | Rₙ₂₃ | O |
| Lₐ₇₄₁ | H | Rₙ₂ | H | H | H | Rₙ₉ | H | H | CN | Rₙ₂₃ | O |
| Lₐ₇₄₂ | H | Rₙ₄ | H | H | H | Rₙ₉ | H | H | CN | Rₙ₂₃ | O |
| Lₐ₇₄₃ | H | Rₙ₅ | H | H | H | Rₙ₉ | H | H | CN | Rₙ₂₃ | O |
| Lₐ₇₄₄ | H | Rₙ₇ | H | H | H | Rₙ₉ | H | H | CN | Rₙ₂₃ | O |
| Lₐ₇₄₅ | H | Rₙ₉ | H | H | H | Rₙ₉ | H | H | CN | Rₙ₂₃ | O |
| Lₐ₇₄₆ | H | H | D | H | H | H | H | H | CN | Rₙ₂₃ | O |
| Lₐ₇₄₇ | H | H | Rₙ₂ | H | H | H | H | H | CN | Rₙ₂₃ | O |
| Lₐ₇₄₈ | H | H | Rₙ₄ | H | H | H | H | H | CN | Rₙ₂₃ | O |
| Lₐ₇₄₉ | H | H | Rₙ₅ | H | H | H | H | H | CN | Rₙ₂₃ | O |
| Lₐ₇₅₀ | H | H | Rₙ₇ | H | H | H | H | H | CN | Rₙ₂₃ | O |
| Lₐ₇₅₁ | H | H | Rₙ₉ | H | H | H | H | H | CN | Rₙ₂₃ | O |
| Lₐ₇₅₂ | H | H | D | H | H | Rₙ₅ | H | H | CN | Rₙ₂₃ | O |
| Lₐ₇₅₃ | H | H | Rₙ₂ | H | H | Rₙ₅ | H | H | CN | Rₙ₂₃ | O |
| Lₐ₇₅₄ | H | H | Rₙ₄ | H | H | Rₙ₅ | H | H | CN | Rₙ₂₃ | O |
| Lₐ₇₅₅ | H | H | Rₙ₅ | H | H | Rₙ₅ | H | H | CN | Rₙ₂₃ | O |
| Lₐ₇₅₆ | H | H | Rₙ₇ | H | H | Rₙ₅ | H | H | CN | Rₙ₂₃ | O |
| Lₐ₇₅₇ | H | H | Rₙ₉ | H | H | Rₙ₅ | H | H | CN | Rₙ₂₃ | O |
| Lₐ₇₅₈ | H | H | D | H | H | Rₙ₉ | H | H | CN | Rₙ₂₃ | O |
| Lₐ₇₅₉ | H | H | Rₙ₂ | H | H | Rₙ₉ | H | H | CN | Rₙ₂₃ | O |
| Lₐ₇₆₀ | H | H | Rₙ₄ | H | H | Rₙ₉ | H | H | CN | Rₙ₂₃ | O |
| Lₐ₇₆₁ | H | H | Rₙ₅ | H | H | Rₙ₉ | H | H | CN | Rₙ₂₃ | O |
| Lₐ₇₆₂ | H | H | Rₙ₇ | H | H | Rₙ₉ | H | H | CN | Rₙ₂₃ | O |
| Lₐ₇₆₃ | H | H | Rₙ₉ | H | H | Rₙ₉ | H | H | CN | Rₙ₂₃ | O |
| Lₐ₇₆₄ | D | Rₙ₂ | Rₙ₂ | D | H | H | H | H | CN | Rₙ₂₃ | O |
| Lₐ₇₆₅ | D | Rₙ₂ | Rₙ₂ | D | H | Rₙ₅ | H | H | CN | Rₙ₂₃ | O |
| Lₐ₇₆₆ | D | Rₙ₂ | Rₙ₂ | D | H | Rₙ₉ | H | H | CN | Rₙ₂₃ | O |
| Lₐ₇₆₇ | H | D | H | H | H | H | H | H | F | Rₙ₂₃ | O |
| Lₐ₇₆₈ | H | Rₙ₂ | H | H | H | H | H | H | F | Rₙ₂₃ | O |
| Lₐ₇₆₉ | H | Rₙ₄ | H | H | H | H | H | H | F | Rₙ₂₃ | O |
| Lₐ₇₇₀ | H | Rₙ₅ | H | H | H | H | H | H | F | Rₙ₂₃ | O |
| Lₐ₇₇₁ | H | Rₙ₇ | H | H | H | H | H | H | F | Rₙ₂₃ | O |
| Lₐ₇₇₂ | H | Rₙ₉ | H | H | H | H | H | H | F | Rₙ₂₃ | O |
| Lₐ₇₇₃ | H | D | H | H | H | Rₙ₅ | H | H | F | Rₙ₂₃ | O |
| Lₐ₇₇₄ | H | Rₙ₂ | H | H | H | Rₙ₅ | H | H | F | Rₙ₂₃ | O |
| Lₐ₇₇₅ | H | Rₙ₄ | H | H | H | Rₙ₅ | H | H | F | Rₙ₂₃ | O |
| Lₐ₇₇₆ | H | Rₙ₅ | H | H | H | Rₙ₅ | H | H | F | Rₙ₂₃ | O |
| Lₐ₇₇₇ | H | Rₙ₇ | H | H | H | Rₙ₅ | H | H | F | Rₙ₂₃ | O |
| Lₐ₇₇₈ | H | Rₙ₉ | H | H | H | Rₙ₅ | H | H | F | Rₙ₂₃ | O |
| Lₐ₇₇₉ | H | D | H | H | H | Rₙ₉ | H | H | F | Rₙ₂₃ | O |
| Lₐ₇₈₀ | H | Rₙ₂ | H | H | H | Rₙ₉ | H | H | F | Rₙ₂₃ | O |
| Lₐ₇₈₁ | H | Rₙ₄ | H | H | H | Rₙ₉ | H | H | F | Rₙ₂₃ | O |
| Lₐ₇₈₂ | H | Rₙ₅ | H | H | H | Rₙ₉ | H | H | F | Rₙ₂₃ | O |
| Lₐ₇₈₃ | H | Rₙ₇ | H | H | H | Rₙ₉ | H | H | F | Rₙ₂₃ | O |
| Lₐ₇₈₄ | H | Rₙ₉ | H | H | H | Rₙ₉ | H | H | F | Rₙ₂₃ | O |
| Lₐ₇₈₅ | H | H | D | H | H | H | H | H | F | Rₙ₂₃ | O |
| Lₐ₇₈₆ | H | H | Rₙ₂ | H | H | H | H | H | F | Rₙ₂₃ | O |
| Lₐ₇₈₇ | H | H | Rₙ₄ | H | H | H | H | H | F | Rₙ₂₃ | O |
| Lₐ₇₈₈ | H | H | Rₙ₅ | H | H | H | H | H | F | Rₙ₂₃ | O |
| Lₐ₇₈₉ | H | H | Rₙ₇ | H | H | H | H | H | F | Rₙ₂₃ | O |
| Lₐ₇₉₀ | H | H | Rₙ₉ | H | H | H | H | H | F | Rₙ₂₃ | O |
| Lₐ₇₉₁ | H | H | D | H | H | Rₙ₅ | H | H | F | Rₙ₂₃ | O |
| Lₐ₇₉₂ | H | H | Rₙ₂ | H | H | Rₙ₅ | H | H | F | Rₙ₂₃ | O |
| Lₐ₇₉₃ | H | H | Rₙ₄ | H | H | Rₙ₅ | H | H | F | Rₙ₂₃ | O |
| Lₐ₇₉₄ | H | H | Rₙ₅ | H | H | Rₙ₅ | H | H | F | Rₙ₂₃ | O |
| Lₐ₇₉₅ | H | H | Rₙ₇ | H | H | Rₙ₅ | H | H | F | Rₙ₂₃ | O |
| Lₐ₇₉₆ | H | H | Rₙ₉ | H | H | Rₙ₅ | H | H | F | Rₙ₂₃ | O |
| Lₐ₇₉₇ | H | H | D | H | H | Rₙ₉ | H | H | F | Rₙ₂₃ | O |
| Lₐ₇₉₈ | H | H | Rₙ₂ | H | H | Rₙ₉ | H | H | F | Rₙ₂₃ | O |
| Lₐ₇₉₉ | H | H | Rₙ₄ | H | H | Rₙ₉ | H | H | F | Rₙ₂₃ | O |
| Lₐ₈₀₀ | H | H | Rₙ₅ | H | H | Rₙ₉ | H | H | F | Rₙ₂₃ | O |
| Lₐ₈₀₁ | H | H | Rₙ₇ | H | H | Rₙ₉ | H | H | F | Rₙ₂₃ | O |
| Lₐ₈₀₂ | H | H | Rₙ₉ | H | H | Rₙ₉ | H | H | F | Rₙ₂₃ | O |
| Lₐ₈₀₃ | D | Rₙ₂ | Rₙ₂ | D | H | H | H | H | F | Rₙ₂₃ | O |
| Lₐ₈₀₄ | D | Rₙ₂ | Rₙ₂ | D | H | Rₙ₅ | H | H | F | Rₙ₂₃ | O |
| Lₐ₈₀₅ | D | Rₙ₂ | Rₙ₂ | D | H | Rₙ₉ | H | H | F | Rₙ₂₃ | O |
| Lₐ₈₀₆ | H | D | H | H | H | H | H | H | CN | Rₙ₁₃ | O |
| Lₐ₈₀₇ | H | Rₙ₂ | H | H | H | H | H | H | CN | Rₙ₁₃ | O |
| Lₐ₈₀₈ | H | Rₙ₄ | H | H | H | H | H | H | CN | Rₙ₁₃ | O |
| Lₐ₈₀₉ | H | Rₙ₅ | H | H | H | H | H | H | CN | Rₙ₁₃ | O |
| Lₐ₈₁₀ | H | Rₙ₇ | H | H | H | H | H | H | CN | Rₙ₁₃ | O |
| Lₐ₈₁₁ | H | Rₙ₉ | H | H | H | H | H | H | CN | Rₙ₁₃ | O |
| Lₐ₈₁₂ | H | D | H | H | H | Rₙ₅ | H | H | CN | Rₙ₁₃ | O |
| Lₐ₈₁₃ | H | Rₙ₂ | H | H | H | Rₙ₅ | H | H | CN | Rₙ₁₃ | O |
| Lₐ₈₁₄ | H | Rₙ₄ | H | H | H | Rₙ₅ | H | H | CN | Rₙ₁₃ | O |
| Lₐ₈₁₅ | H | Rₙ₅ | H | H | H | Rₙ₅ | H | H | CN | Rₙ₁₃ | O |
| Lₐ₈₁₆ | H | Rₙ₇ | H | H | H | Rₙ₅ | H | H | CN | Rₙ₁₃ | O |
| Lₐ₈₁₇ | H | Rₙ₉ | H | H | H | Rₙ₅ | H | H | CN | Rₙ₁₃ | O |
| Lₐ₈₁₈ | H | D | H | H | H | Rₙ₉ | H | H | CN | Rₙ₁₃ | O |
| Lₐ₈₁₉ | H | Rₙ₂ | H | H | H | Rₙ₉ | H | H | CN | Rₙ₁₃ | O |
| Lₐ₈₂₀ | H | Rₙ₄ | H | H | H | Rₙ₉ | H | H | CN | Rₙ₁₃ | O |
| Lₐ₈₂₁ | H | Rₙ₅ | H | H | H | Rₙ₉ | H | H | CN | Rₙ₁₃ | O |
| Lₐ₈₂₂ | H | Rₙ₇ | H | H | H | Rₙ₉ | H | H | CN | Rₙ₁₃ | O |
| Lₐ₈₂₃ | H | Rₙ₉ | H | H | H | Rₙ₉ | H | H | CN | Rₙ₁₃ | O |
| Lₐ₈₂₄ | H | H | D | H | H | H | H | H | CN | Rₙ₁₃ | O |
| Lₐ₈₂₅ | H | H | Rₙ₂ | H | H | H | H | H | CN | Rₙ₁₃ | O |
| Lₐ₈₂₆ | H | H | Rₙ₄ | H | H | H | H | H | CN | Rₙ₁₃ | O |
| Lₐ₈₂₇ | H | H | Rₙ₅ | H | H | H | H | H | CN | Rₙ₁₃ | O |
| Lₐ₈₂₈ | H | H | Rₙ₇ | H | H | H | H | H | CN | Rₙ₁₃ | O |
| Lₐ₈₂₉ | H | H | Rₙ₉ | H | H | H | H | H | CN | Rₙ₁₃ | O |
| Lₐ₈₃₀ | H | H | D | H | H | Rₙ₅ | H | H | CN | Rₙ₁₃ | O |
| Lₐ₈₃₁ | H | H | Rₙ₂ | H | H | Rₙ₅ | H | H | CN | Rₙ₁₃ | O |
| Lₐ₈₃₂ | H | H | Rₙ₄ | H | H | Rₙ₅ | H | H | CN | Rₙ₁₃ | O |
| Lₐ₈₃₃ | H | H | Rₙ₅ | H | H | Rₙ₅ | H | H | CN | Rₙ₁₃ | O |
| Lₐ₈₃₄ | H | H | Rₙ₇ | H | H | Rₙ₅ | H | H | CN | Rₙ₁₃ | O |
| Lₐ₈₃₅ | H | H | Rₙ₉ | H | H | Rₙ₅ | H | H | CN | Rₙ₁₃ | O |
| Lₐ₈₃₆ | H | H | D | H | H | Rₙ₉ | H | H | CN | Rₙ₁₃ | O |
| Lₐ₈₃₇ | H | H | Rₙ₂ | H | H | Rₙ₉ | H | H | CN | Rₙ₁₃ | O |
| Lₐ₈₃₈ | H | H | Rₙ₄ | H | H | Rₙ₉ | H | H | CN | Rₙ₁₃ | O |
| Lₐ₈₃₉ | H | H | Rₙ₅ | H | H | Rₙ₉ | H | H | CN | Rₙ₁₃ | O |
| Lₐ₈₄₀ | H | H | Rₙ₇ | H | H | Rₙ₉ | H | H | CN | Rₙ₁₃ | O |
| Lₐ₈₄₁ | H | H | Rₙ₉ | H | H | Rₙ₉ | H | H | CN | Rₙ₁₃ | O |
| Lₐ₈₄₂ | D | Rₙ₂ | Rₙ₂ | D | H | H | H | H | CN | Rₙ₁₃ | O |
| Lₐ₈₄₃ | D | Rₙ₂ | Rₙ₂ | D | H | Rₙ₅ | H | H | CN | Rₙ₁₃ | O |
| Lₐ₈₄₄ | D | Rₙ₂ | Rₙ₂ | D | H | Rₙ₉ | H | H | CN | Rₙ₁₃ | O |
| Lₐ₈₄₅ | H | D | H | H | H | H | H | H | F | Rₙ₁₃ | O |
| Lₐ₈₄₆ | H | Rₙ₂ | H | H | H | H | H | H | F | Rₙ₁₃ | O |
| Lₐ₈₄₇ | H | Rₙ₄ | H | H | H | H | H | H | F | Rₙ₁₃ | O |
| Lₐ₈₄₈ | H | Rₙ₅ | H | H | H | H | H | H | F | Rₙ₁₃ | O |
| Lₐ₈₄₉ | H | Rₙ₇ | H | H | H | H | H | H | F | Rₙ₁₃ | O |
| Lₐ₈₅₀ | H | Rₙ₉ | H | H | H | H | H | H | F | Rₙ₁₃ | O |
| Lₐ₈₅₁ | H | D | H | H | H | Rₙ₅ | H | H | F | Rₙ₁₃ | O |
| Lₐ₈₅₂ | H | Rₙ₂ | H | H | H | Rₙ₅ | H | H | F | Rₙ₁₃ | O |
| Lₐ₈₅₃ | H | Rₙ₄ | H | H | H | Rₙ₅ | H | H | F | Rₙ₁₃ | O |
| Lₐ₈₅₄ | H | Rₙ₅ | H | H | H | Rₙ₅ | H | H | F | Rₙ₁₃ | O |
| Lₐ₈₅₅ | H | Rₙ₇ | H | H | H | Rₙ₅ | H | H | F | Rₙ₁₃ | O |
| Lₐ₈₅₆ | H | Rₙ₉ | H | H | H | Rₙ₅ | H | H | F | Rₙ₁₃ | O |
| Lₐ₈₅₇ | H | D | H | H | H | Rₙ₉ | H | H | F | Rₙ₁₃ | O |
| Lₐ₈₅₈ | H | Rₙ₂ | H | H | H | Rₙ₉ | H | H | F | Rₙ₁₃ | O |
| Lₐ₈₅₉ | H | Rₙ₄ | H | H | H | Rₙ₉ | H | H | F | Rₙ₁₃ | O |
| Lₐ₈₆₀ | H | Rₙ₅ | H | H | H | Rₙ₉ | H | H | F | Rₙ₁₃ | O |
| Lₐ₈₆₁ | H | Rₙ₇ | H | H | H | Rₙ₉ | H | H | F | Rₙ₁₃ | O |
| Lₐ₈₆₂ | H | Rₙ₉ | H | H | H | Rₙ₉ | H | H | F | Rₙ₁₃ | O |
| Lₐ₈₆₃ | H | H | D | H | H | H | H | H | F | Rₙ₁₃ | O |
| Lₐ₈₆₄ | H | H | Rₙ₂ | H | H | H | H | H | F | Rₙ₁₃ | O |
| Lₐ₈₆₅ | H | H | Rₙ₄ | H | H | H | H | H | F | Rₙ₁₃ | O |
| Lₐ₈₆₆ | H | H | Rₙ₅ | H | H | H | H | H | F | Rₙ₁₃ | O |
| Lₐ₈₆₇ | H | H | Rₙ₇ | H | H | H | H | H | F | Rₙ₁₃ | O |
| Lₐ₈₆₈ | H | H | Rₙ₉ | H | H | H | H | H | F | Rₙ₁₃ | O |
| Lₐ₈₆₉ | H | H | D | H | H | Rₙ₅ | H | H | F | Rₙ₁₃ | O |
| Lₐ₈₇₀ | H | H | Rₙ₂ | H | H | Rₙ₅ | H | H | F | Rₙ₁₃ | O |
| Lₐ₈₇₁ | H | H | Rₙ₄ | H | H | Rₙ₅ | H | H | F | Rₙ₁₃ | O |
| Lₐ₈₇₂ | H | H | Rₙ₅ | H | H | Rₙ₅ | H | H | F | Rₙ₁₃ | O |
| Lₐ₈₇₃ | H | H | Rₙ₇ | H | H | Rₙ₅ | H | H | F | Rₙ₁₃ | O |
| Lₐ₈₇₄ | H | H | Rₙ₉ | H | H | Rₙ₅ | H | H | F | Rₙ₁₃ | O |
| Lₐ₈₇₅ | H | H | D | H | H | Rₙ₉ | H | H | F | Rₙ₁₃ | O |
| Lₐ₈₇₆ | H | H | Rₙ₂ | H | H | Rₙ₉ | H | H | F | Rₙ₁₃ | O |
| Lₐ₈₇₇ | H | H | Rₙ₄ | H | H | Rₙ₉ | H | H | F | Rₙ₁₃ | O |
| Lₐ₈₇₈ | H | H | Rₙ₅ | H | H | Rₙ₉ | H | H | F | Rₙ₁₃ | O |
| Lₐ₈₇₉ | H | H | Rₙ₇ | H | H | Rₙ₉ | H | H | F | Rₙ₁₃ | O |
| Lₐ₈₈₀ | H | H | Rₙ₉ | H | H | Rₙ₉ | H | H | F | Rₙ₁₃ | O |
| Lₐ₈₈₁ | D | Rₙ₂ | Rₙ₂ | D | H | H | H | H | F | Rₙ₁₃ | O |
| Lₐ₈₈₂ | D | Rₙ₂ | Rₙ₂ | D | H | Rₙ₅ | H | H | F | Rₙ₁₃ | O |
| Lₐ₈₈₃ | D | Rₙ₂ | Rₙ₂ | D | H | Rₙ₉ | H | H | F | Rₙ₁₃ | O |
| Lₐ₈₈₄ | H | D | H | H | H | H | H | H | CN | Rₙ₂₅ | O |
| Lₐ₈₈₅ | H | Rₙ₂ | H | H | H | H | H | H | CN | Rₙ₂₅ | O |
| Lₐ₈₈₆ | H | Rₙ₄ | H | H | H | H | H | H | CN | Rₙ₂₅ | O |
| Lₐ₈₈₇ | H | Rₙ₅ | H | H | H | H | H | H | CN | Rₙ₂₅ | O |
| Lₐ₈₈₈ | H | Rₙ₇ | H | H | H | H | H | H | CN | Rₙ₂₅ | O |
| Lₐ₈₈₉ | H | Rₙ₉ | H | H | H | H | H | H | CN | Rₙ₂₅ | O |
| Lₐ₈₉₀ | H | D | H | H | H | Rₙ₅ | H | H | CN | Rₙ₂₅ | O |
| Lₐ₈₉₁ | H | Rₙ₂ | H | H | H | Rₙ₅ | H | H | CN | Rₙ₂₅ | O |
| Lₐ₈₉₂ | H | Rₙ₄ | H | H | H | Rₙ₅ | H | H | CN | Rₙ₂₅ | O |
| Lₐ₈₉₃ | H | Rₙ₅ | H | H | H | Rₙ₅ | H | H | CN | Rₙ₂₅ | O |
| Lₐ₈₉₄ | H | Rₙ₇ | H | H | H | Rₙ₅ | H | H | CN | Rₙ₂₅ | O |
| Lₐ₈₉₅ | H | Rₙ₉ | H | H | H | Rₙ₅ | H | H | CN | Rₙ₂₅ | O |
| Lₐ₈₉₆ | H | D | H | H | H | Rₙ₉ | H | H | CN | Rₙ₂₅ | O |
| Lₐ₈₉₇ | H | Rₙ₂ | H | H | H | Rₙ₉ | H | H | CN | Rₙ₂₅ | O |
| Lₐ₈₉₈ | H | Rₙ₄ | H | H | H | Rₙ₉ | H | H | CN | Rₙ₂₅ | O |
| Lₐ₈₉₉ | H | Rₙ₅ | H | H | H | Rₙ₉ | H | H | CN | Rₙ₂₅ | O |
| Lₐ₉₀₀ | H | Rₙ₇ | H | H | H | Rₙ₉ | H | H | CN | Rₙ₂₅ | O |
| Lₐ₉₀₁ | H | Rₙ₉ | H | H | H | Rₙ₉ | H | H | CN | Rₙ₂₅ | O |
| Lₐ₉₀₂ | H | H | D | H | H | H | H | H | CN | Rₙ₂₅ | O |
| Lₐ₉₀₃ | H | H | Rₙ₂ | H | H | H | H | H | CN | Rₙ₂₅ | O |
| Lₐ₉₀₄ | H | H | Rₙ₄ | H | H | H | H | H | CN | Rₙ₂₅ | O |
| Lₐ₉₀₅ | H | H | Rₙ₅ | H | H | H | H | H | CN | Rₙ₂₅ | O |
| Lₐ₉₀₆ | H | H | Rₙ₇ | H | H | H | H | H | CN | Rₙ₂₅ | O |
| Lₐ₉₀₇ | H | H | Rₙ₉ | H | H | H | H | H | CN | Rₙ₂₅ | O |
| Lₐ₉₀₈ | H | H | D | H | H | Rₙ₅ | H | H | CN | Rₙ₂₅ | O |
| Lₐ₉₀₉ | H | H | Rₙ₂ | H | H | Rₙ₅ | H | H | CN | Rₙ₂₅ | O |
| Lₐ₉₁₀ | H | H | Rₙ₄ | H | H | Rₙ₅ | H | H | CN | Rₙ₂₅ | O |
| Lₐ₉₁₁ | H | H | Rₙ₅ | H | H | Rₙ₅ | H | H | CN | Rₙ₂₅ | O |
| Lₐ₉₁₂ | H | H | Rₙ₇ | H | H | Rₙ₅ | H | H | CN | Rₙ₂₅ | O |
| Lₐ₉₁₃ | H | H | Rₙ₉ | H | H | Rₙ₅ | H | H | CN | Rₙ₂₅ | O |
| Lₐ₉₁₄ | H | H | D | H | H | Rₙ₉ | H | H | CN | Rₙ₂₅ | O |
| Lₐ₉₁₅ | H | H | Rₙ₂ | H | H | Rₙ₉ | H | H | CN | Rₙ₂₅ | O |
| Lₐ₉₁₆ | H | H | Rₙ₄ | H | H | Rₙ₉ | H | H | CN | Rₙ₂₅ | O |
| Lₐ₉₁₇ | H | H | Rₙ₅ | H | H | Rₙ₉ | H | H | CN | Rₙ₂₅ | O |
| Lₐ₉₁₈ | H | H | Rₙ₇ | H | H | Rₙ₉ | H | H | CN | Rₙ₂₅ | O |
| Lₐ₉₁₉ | H | H | Rₙ₉ | H | H | Rₙ₉ | H | H | CN | Rₙ₂₅ | O |
| Lₐ₉₂₀ | D | Rₙ₂ | Rₙ₂ | D | H | H | H | H | CN | Rₙ₂₅ | O |
| Lₐ₉₂₁ | D | Rₙ₂ | Rₙ₂ | D | H | Rₙ₅ | H | H | CN | Rₙ₂₅ | O |
| Lₐ₉₂₂ | D | Rₙ₂ | Rₙ₂ | D | H | Rₙ₉ | H | H | CN | Rₙ₂₅ | O |
| Lₐ₉₂₃ | H | D | H | H | H | H | H | H | F | Rₙ₂₅ | O |
| Lₐ₉₂₄ | H | Rₙ₂ | H | H | H | H | H | H | F | Rₙ₂₅ | O |
| Lₐ₉₂₅ | H | Rₙ₄ | H | H | H | H | H | H | F | Rₙ₂₅ | O |
| Lₐ₉₂₆ | H | Rₙ₅ | H | H | H | H | H | H | F | Rₙ₂₅ | O |
| Lₐ₉₂₇ | H | Rₙ₇ | H | H | H | H | H | H | F | Rₙ₂₅ | O |
| Lₐ₉₂₈ | H | Rₙ₉ | H | H | H | H | H | H | F | Rₙ₂₅ | O |
| Lₐ₉₂₉ | H | D | H | H | H | Rₙ₅ | H | H | F | Rₙ₂₅ | O |
| Lₐ₉₃₀ | H | Rₙ₂ | H | H | H | Rₙ₅ | H | H | F | Rₙ₂₅ | O |
| Lₐ₉₃₁ | H | Rₙ₄ | H | H | H | Rₙ₅ | H | H | F | Rₙ₂₅ | O |
| Lₐ₉₃₂ | H | Rₙ₅ | H | H | H | Rₙ₅ | H | H | F | Rₙ₂₅ | O |
| Lₐ₉₃₃ | H | Rₙ₇ | H | H | H | Rₙ₅ | H | H | F | Rₙ₂₅ | O |
| Lₐ₉₃₄ | H | Rₙ₉ | H | H | H | Rₙ₅ | H | H | F | Rₙ₂₅ | O |
| Lₐ₉₃₅ | H | D | H | H | H | Rₙ₉ | H | H | F | Rₙ₂₅ | O |
| Lₐ₉₃₆ | H | Rₙ₂ | H | H | H | Rₙ₉ | H | H | F | Rₙ₂₅ | O |
| Lₐ₉₃₇ | H | Rₙ₄ | H | H | H | Rₙ₉ | H | H | F | Rₙ₂₅ | O |
| Lₐ₉₃₈ | H | Rₙ₅ | H | H | H | Rₙ₉ | H | H | F | Rₙ₂₅ | O |
| Lₐ₉₃₉ | H | Rₙ₇ | H | H | H | Rₙ₉ | H | H | F | Rₙ₂₅ | O |
| Lₐ₉₄₀ | H | Rₙ₉ | H | H | H | Rₙ₉ | H | H | F | Rₙ₂₅ | O |
| Lₐ₉₄₁ | H | H | D | H | H | H | H | H | F | Rₙ₂₅ | O |
| Lₐ₉₄₂ | H | H | Rₙ₂ | H | H | H | H | H | F | Rₙ₂₅ | O |
| Lₐ₉₄₃ | H | H | Rₙ₄ | H | H | H | H | H | F | Rₙ₂₅ | O |
| Lₐ₉₄₄ | H | H | Rₙ₅ | H | H | H | H | H | F | Rₙ₂₅ | O |
| Lₐ₉₄₅ | H | H | Rₙ₇ | H | H | H | H | H | F | Rₙ₂₅ | O |
| Lₐ₉₄₆ | H | H | Rₙ₉ | H | H | H | H | H | F | Rₙ₂₅ | O |
| Lₐ₉₄₇ | H | H | D | H | H | Rₙ₅ | H | H | F | Rₙ₂₅ | O |
| Lₐ₉₄₈ | H | H | Rₙ₂ | H | H | Rₙ₅ | H | H | F | Rₙ₂₅ | O |
| Lₐ₉₄₉ | H | H | Rₙ₄ | H | H | Rₙ₅ | H | H | F | Rₙ₂₅ | O |
| Lₐ₉₅₀ | H | H | Rₙ₅ | H | H | Rₙ₅ | H | H | F | Rₙ₂₅ | O |
| Lₐ₉₅₁ | H | H | Rₙ₇ | H | H | Rₙ₅ | H | H | F | Rₙ₂₅ | O |
| Lₐ₉₅₂ | H | H | Rₙ₉ | H | H | Rₙ₅ | H | H | F | Rₙ₂₅ | O |
| Lₐ₉₅₃ | H | H | D | H | H | Rₙ₉ | H | H | F | Rₙ₂₅ | O |
| Lₐ₉₅₄ | H | H | Rₙ₂ | H | H | Rₙ₉ | H | H | F | Rₙ₂₅ | O |
| Lₐ₉₅₅ | H | H | Rₙ₄ | H | H | Rₙ₉ | H | H | F | Rₙ₂₅ | O |
| Lₐ₉₅₆ | H | H | Rₙ₅ | H | H | Rₙ₉ | H | H | F | Rₙ₂₅ | O |
| Lₐ₉₅₇ | H | H | Rₙ₇ | H | H | Rₙ₉ | H | H | F | Rₙ₂₅ | O |
| Lₐ₉₅₈ | H | H | Rₙ₉ | H | H | Rₙ₉ | H | H | F | Rₙ₂₅ | O |
| Lₐ₉₅₉ | D | Rₙ₂ | Rₙ₂ | D | H | H | H | H | F | Rₙ₂₅ | O |
| Lₐ₉₆₀ | D | Rₙ₂ | Rₙ₂ | D | H | Rₙ₅ | H | H | F | Rₙ₂₅ | O |
| Lₐ₉₆₁ | D | Rₙ₂ | Rₙ₂ | D | H | Rₙ₉ | H | H | F | Rₙ₂₅ | O |
| Lₐ₉₆₂ | H | D | H | H | H | H | H | H | CN | Rₙ₂₆ | O |
| Lₐ₉₆₃ | H | Rₙ₂ | H | H | H | H | H | H | CN | Rₙ₂₆ | O |
| Lₐ₉₆₄ | H | Rₙ₄ | H | H | H | H | H | H | CN | Rₙ₂₆ | O |
| Lₐ₉₆₅ | H | Rₙ₅ | H | H | H | H | H | H | CN | Rₙ₂₆ | O |
| Lₐ₉₆₆ | H | Rₙ₇ | H | H | H | H | H | H | CN | Rₙ₂₆ | O |
| Lₐ₉₆₇ | H | Rₙ₉ | H | H | H | H | H | H | CN | Rₙ₂₆ | O |
| Lₐ₉₆₈ | H | D | H | H | H | Rₙ₅ | H | H | CN | Rₙ₂₆ | O |
| Lₐ₉₆₉ | H | Rₙ₂ | H | H | H | Rₙ₅ | H | H | CN | Rₙ₂₆ | O |
| Lₐ₉₇₀ | H | Rₙ₄ | H | H | H | Rₙ₅ | H | H | CN | Rₙ₂₆ | O |
| Lₐ₉₇₁ | H | Rₙ₅ | H | H | H | Rₙ₅ | H | H | CN | Rₙ₂₆ | O |
| Lₐ₉₇₂ | H | Rₙ₇ | H | H | H | Rₙ₅ | H | H | CN | Rₙ₂₆ | O |
| Lₐ₉₇₃ | H | Rₙ₉ | H | H | H | Rₙ₅ | H | H | CN | Rₙ₂₆ | O |
| Lₐ₉₇₄ | H | D | H | H | H | Rₙ₉ | H | H | CN | Rₙ₂₆ | O |
| Lₐ₉₇₅ | H | Rₙ₂ | H | H | H | Rₙ₉ | H | H | CN | Rₙ₂₆ | O |
| Lₐ₉₇₆ | H | Rₙ₄ | H | H | H | Rₙ₉ | H | H | CN | Rₙ₂₆ | O |
| Lₐ₉₇₇ | H | Rₙ₅ | H | H | H | Rₙ₉ | H | H | CN | Rₙ₂₆ | O |
| Lₐ₉₇₈ | H | Rₙ₇ | H | H | H | Rₙ₉ | H | H | CN | Rₙ₂₆ | O |
| Lₐ₉₇₉ | H | Rₙ₉ | H | H | H | Rₙ₉ | H | H | CN | Rₙ₂₆ | O |
| Lₐ₉₈₀ | H | H | D | H | H | H | H | H | CN | Rₙ₂₆ | O |
| Lₐ₉₈₁ | H | H | Rₙ₂ | H | H | H | H | H | CN | Rₙ₂₆ | O |
| Lₐ₉₈₂ | H | H | Rₙ₄ | H | H | H | H | H | CN | Rₙ₂₆ | O |
| Lₐ₉₈₃ | H | H | Rₙ₅ | H | H | H | H | H | CN | Rₙ₂₆ | O |
| Lₐ₉₈₄ | H | H | Rₙ₇ | H | H | H | H | H | CN | Rₙ₂₆ | O |
| Lₐ₉₈₅ | H | H | Rₙ₉ | H | H | H | H | H | CN | Rₙ₂₆ | O |
| Lₐ₉₈₆ | H | H | D | H | H | Rₙ₅ | H | H | CN | Rₙ₂₆ | O |
| Lₐ₉₈₇ | H | H | Rₙ₂ | H | H | Rₙ₅ | H | H | CN | Rₙ₂₆ | O |
| Lₐ₉₈₈ | H | H | Rₙ₄ | H | H | Rₙ₅ | H | H | CN | Rₙ₂₆ | O |
| Lₐ₉₈₉ | H | H | Rₙ₅ | H | H | Rₙ₅ | H | H | CN | Rₙ₂₆ | O |
| Lₐ₉₉₀ | H | H | Rₙ₇ | H | H | Rₙ₅ | H | H | CN | Rₙ₂₆ | O |
| Lₐ₉₉₁ | H | H | Rₙ₉ | H | H | Rₙ₅ | H | H | CN | Rₙ₂₆ | O |
| Lₐ₉₉₂ | H | H | D | H | H | Rₙ₉ | H | H | CN | Rₙ₂₆ | O |
| Lₐ₉₉₃ | H | H | Rₙ₂ | H | H | Rₙ₉ | H | H | CN | Rₙ₂₆ | O |
| Lₐ₉₉₄ | H | H | Rₙ₄ | H | H | Rₙ₉ | H | H | CN | Rₙ₂₆ | O |
| Lₐ₉₉₅ | H | H | Rₙ₅ | H | H | Rₙ₉ | H | H | CN | Rₙ₂₆ | O |
| Lₐ₉₉₆ | H | H | Rₙ₇ | H | H | Rₙ₉ | H | H | CN | Rₙ₂₆ | O |
| Lₐ₉₉₇ | H | H | Rₙ₉ | H | H | Rₙ₉ | H | H | CN | Rₙ₂₆ | O |
| Lₐ₉₉₈ | D | Rₙ₂ | Rₙ₂ | D | H | H | H | H | CN | Rₙ₂₆ | O |
| Lₐ₉₉₉ | D | Rₙ₂ | Rₙ₂ | D | H | Rₙ₅ | H | H | CN | Rₙ₂₆ | O |
| Lₐ₁₀₀₀ | D | Rₙ₂ | Rₙ₂ | D | H | Rₙ₉ | H | H | CN | Rₙ₂₆ | O |
| Lₐ₁₀₀₁ | H | D | H | H | H | H | H | H | F | Rₙ₂₆ | O |
| Lₐ₁₀₀₂ | H | Rₙ₂ | H | H | H | H | H | H | F | Rₙ₂₆ | O |
| Lₐ₁₀₀₃ | H | Rₙ₄ | H | H | H | H | H | H | F | Rₙ₂₆ | O |
| Lₐ₁₀₀₄ | H | Rₙ₅ | H | H | H | H | H | H | F | Rₙ₂₆ | O |
| Lₐ₁₀₀₅ | H | Rₙ₇ | H | H | H | H | H | H | F | Rₙ₂₆ | O |
| Lₐ₁₀₀₆ | H | Rₙ₉ | H | H | H | H | H | H | F | Rₙ₂₆ | O |
| Lₐ₁₀₀₇ | H | D | H | H | H | Rₙ₅ | H | H | F | Rₙ₂₆ | O |
| Lₐ₁₀₀₈ | H | Rₙ₂ | H | H | H | Rₙ₅ | H | H | F | Rₙ₂₆ | O |
| Lₐ₁₀₀₉ | H | Rₙ₄ | H | H | H | Rₙ₅ | H | H | F | Rₙ₂₆ | O |
| Lₐ₁₀₁₀ | H | Rₙ₅ | H | H | H | R₅ | H | H | F | Rₙ₂₆ | O |
| Lₐ₁₀₁₁ | H | Rₙ₇ | H | H | H | Rₙ₅ | H | H | F | Rₙ₂₆ | O |
| Lₐ₁₀₁₂ | H | Rₙ₉ | H | H | H | Rₙ₅ | H | H | F | Rₙ₂₆ | O |
| Lₐ₁₀₁₃ | H | D | H | H | H | Rₙ₉ | H | H | F | Rₙ₂₆ | O |
| Lₐ₁₀₁₄ | H | Rₙ₂ | H | H | H | Rₙ₉ | H | H | F | Rₙ₂₆ | O |
| Lₐ₁₀₁₅ | H | Rₙ₄ | H | H | H | Rₙ₉ | H | H | F | Rₙ₂₆ | O |
| Lₐ₁₀₁₆ | H | Rₙ₅ | H | H | H | Rₙ₉ | H | H | F | Rₙ₂₆ | O |
| Lₐ₁₀₁₇ | H | Rₙ₇ | H | H | H | Rₙ₉ | H | H | F | Rₙ₂₆ | O |
| Lₐ₁₀₁₈ | H | Rₙ₉ | H | H | H | Rₙ₉ | H | H | F | Rₙ₂₆ | O |
| Lₐ₁₀₁₉ | H | H | D | H | H | H | H | H | F | Rₙ₂₆ | O |
| Lₐ₁₀₂₀ | H | H | Rₙ₂ | H | H | H | H | H | F | Rₙ₂₆ | O |
| Lₐ₁₀₂₁ | H | H | Rₙ₄ | H | H | H | H | H | F | Rₙ₂₆ | O |
| Lₐ₁₀₂₂ | H | H | Rₙ₅ | H | H | H | H | H | F | Rₙ₂₆ | O |
| Lₐ₁₀₂₃ | H | H | Rₙ₇ | H | H | H | H | H | F | Rₙ₂₆ | O |
| Lₐ₁₀₂₄ | H | H | Rₙ₉ | H | H | H | H | H | F | Rₙ₂₆ | O |
| Lₐ₁₀₂₅ | H | H | D | H | H | Rₙ₅ | H | H | F | Rₙ₂₆ | O |
| Lₐ₁₀₂₆ | H | H | Rₙ₂ | H | H | Rₙ₅ | H | H | F | Rₙ₂₆ | O |
| Lₐ₁₀₂₇ | H | H | Rₙ₄ | H | H | Rₙ₅ | H | H | F | Rₙ₂₆ | O |
| Lₐ₁₀₂₈ | H | H | Rₙ₅ | H | H | Rₙ₅ | H | H | F | Rₙ₂₆ | O |
| Lₐ₁₀₂₉ | H | H | Rₙ₇ | H | H | Rₙ₅ | H | H | F | Rₙ₂₆ | O |
| Lₐ₁₀₃₀ | H | H | Rₙ₉ | H | H | Rₙ₅ | H | H | F | Rₙ₂₆ | O |
| Lₐ₁₀₃₁ | H | H | D | H | H | Rₙ₉ | H | H | F | Rₙ₂₆ | O |
| Lₐ₁₀₃₂ | H | H | Rₙ₂ | H | H | Rₙ₉ | H | H | F | Rₙ₂₆ | O |
| Lₐ₁₀₃₃ | H | H | Rₙ₄ | H | H | Rₙ₉ | H | H | F | Rₙ₂₆ | O |
| Lₐ₁₀₃₄ | H | H | Rₙ₅ | H | H | Rₙ₉ | H | H | F | Rₙ₂₆ | O |
| Lₐ₁₀₃₅ | H | H | Rₙ₇ | H | H | Rₙ₉ | H | H | F | Rₙ₂₆ | O |
| Lₐ₁₀₃₆ | H | H | Rₙ₉ | H | H | Rₙ₉ | H | H | F | Rₙ₂₆ | O |
| Lₐ₁₀₃₇ | D | Rₙ₂ | Rₙ₂ | D | H | H | H | H | F | Rₙ₂₆ | O |
| Lₐ₁₀₃₈ | D | Rₙ₂ | Rₙ₂ | D | H | Rₙ₅ | H | H | F | Rₙ₂₆ | O |
| Lₐ₁₀₃₉ | D | Rₙ | Rₙ₂ | D | H | Rₙ₉ | H | H | F | Rₙ₂₆ | O |
| Lₐ₁₀₄₀ | H | D | H | H | H | H | H | H | CN | Rₙ₁₄ | O |
| Lₐ₁₀₄₁ | H | Rₙ₂ | H | H | H | H | H | H | CN | Rₙ₁₄ | O |
| Lₐ₁₀₄₂ | H | Rₙ₄ | H | H | H | H | H | H | CN | Rₙ₁₄ | O |
| Lₐ₁₀₄₃ | H | Rₙ₅ | H | H | H | H | H | H | CN | Rₙ₁₄ | O |
| Lₐ₁₀₄₄ | H | Rₙ₇ | H | H | H | H | H | H | CN | Rₙ₁₄ | O |
| Lₐ₁₀₄₅ | H | Rₙ₉ | H | H | H | H | H | H | CN | Rₙ₁₄ | O |
| Lₐ₁₀₄₆ | H | D | H | H | H | Rₙ₅ | H | H | CN | Rₙ₁₄ | O |
| Lₐ₁₀₄₇ | H | Rₙ₂ | H | H | H | Rₙ₅ | H | H | CN | Rₙ₁₄ | O |
| Lₐ₁₀₄₈ | H | Rₙ₄ | H | H | H | Rₙ₅ | H | H | CN | Rₙ₁₄ | O |
| Lₐ₁₀₄₉ | H | Rₙ₅ | H | H | H | Rₙ₅ | H | H | CN | Rₙ₁₄ | O |
| Lₐ₁₀₅₀ | H | Rₙ₇ | H | H | H | Rₙ₅ | H | H | CN | Rₙ₁₄ | O |
| Lₐ₁₀₅₁ | H | Rₙ₉ | H | H | H | Rₙ₅ | H | H | CN | Rₙ₁₄ | O |
| Lₐ₁₀₅₂ | H | D | H | H | H | Rₙ₉ | H | H | CN | Rₙ₁₄ | O |
| Lₐ₁₀₅₃ | H | Rₙ₂ | H | H | H | Rₙ₉ | H | H | CN | Rₙ₁₄ | O |
| Lₐ₁₀₅₄ | H | Rₙ₄ | H | H | H | Rₙ₉ | H | H | CN | Rₙ₁₄ | O |
| Lₐ₁₀₅₅ | H | Rₙ₅ | H | H | H | Rₙ₉ | H | H | CN | Rₙ₁₄ | O |
| Lₐ₁₀₅₆ | H | Rₙ₇ | H | H | H | Rₙ₉ | H | H | CN | Rₙ₁₄ | O |
| Lₐ₁₀₅₇ | H | Rₙ₉ | H | H | H | Rₙ₉ | H | H | CN | Rₙ₁₄ | O |
| Lₐ₁₀₅₈ | H | H | D | H | H | H | H | H | CN | Rₙ₁₄ | O |
| Lₐ₁₀₅₉ | H | H | Rₙ₂ | H | H | H | H | H | CN | Rₙ₁₄ | O |
| Lₐ₁₀₆₀ | H | H | Rₙ₄ | H | H | H | H | H | CN | Rₙ₁₄ | O |
| Lₐ₁₀₆₁ | H | H | Rₙ₅ | H | H | H | H | H | CN | Rₙ₁₄ | O |
| Lₐ₁₀₆₂ | H | H | Rₙ₇ | H | H | H | H | H | CN | Rₙ₁₄ | O |
| Lₐ₁₀₆₃ | H | H | Rₙ₉ | H | H | H | H | H | CN | Rₙ₁₄ | O |
| Lₐ₁₀₆₄ | H | H | D | H | H | Rₙ₅ | H | H | CN | Rₙ₁₄ | O |
| Lₐ₁₀₆₅ | H | H | Rₙ₂ | H | H | Rₙ₅ | H | H | CN | Rₙ₁₄ | O |
| Lₐ₁₀₆₆ | H | H | Rₙ₄ | H | H | Rₙ₅ | H | H | CN | Rₙ₁₄ | O |
| Lₐ₁₀₆₇ | H | H | Rₙ₅ | H | H | Rₙ₅ | H | H | CN | Rₙ₁₄ | O |
| Lₐ₁₀₆₈ | H | H | Rₙ₇ | H | H | Rₙ₅ | H | H | CN | Rₙ₁₄ | O |
| Lₐ₁₀₆₉ | H | H | Rₙ₉ | H | H | Rₙ₅ | H | H | CN | Rₙ₁₄ | O |
| Lₐ₁₀₇₀ | H | H | D | H | H | Rₙ₉ | H | H | CN | Rₙ₁₄ | O |
| Lₐ₁₀₇₁ | H | H | Rₙ₂ | H | H | Rₙ₉ | H | H | CN | Rₙ₁₄ | O |
| Lₐ₁₀₇₂ | H | H | Rₙ₄ | H | H | Rₙ₉ | H | H | CN | Rₙ₁₄ | O |
| Lₐ₁₀₇₃ | H | H | Rₙ₅ | H | H | Rₙ₉ | H | H | CN | Rₙ₁₄ | O |
| Lₐ₁₀₇₄ | H | H | Rₙ₇ | H | H | Rₙ₉ | H | H | CN | Rₙ₁₄ | O |
| Lₐ₁₀₇₅ | H | H | Rₙ₉ | H | H | Rₙ₉ | H | H | CN | Rₙ₁₄ | O |
| Lₐ₁₀₇₆ | D | Rₙ₂ | Rₙ₂ | D | H | H | H | H | CN | Rₙ₁₄ | O |
| Lₐ₁₀₇₇ | D | Rₙ₂ | Rₙ₂ | D | H | Rₙ₅ | H | H | CN | Rₙ₁₄ | O |
| Lₐ₁₀₇₈ | D | Rₙ₂ | Rₙ₂ | D | H | Rₙ₉ | H | H | CN | Rₙ₁₄ | O |
| Lₐ₁₀₇₉ | H | D | H | H | H | H | H | H | F | Rₙ₁₄ | O |
| Lₐ₁₀₈₀ | H | Rₙ₂ | H | H | H | H | H | H | F | Rₙ₁₄ | O |
| Lₐ₁₀₈₁ | H | Rₙ₄ | H | H | H | H | H | H | F | Rₙ₁₄ | O |
| Lₐ₁₀₈₂ | H | Rₙ₅ | H | H | H | H | H | H | F | Rₙ₁₄ | O |
| Lₐ₁₀₈₃ | H | Rₙ₇ | H | H | H | H | H | H | F | Rₙ₁₄ | O |
| Lₐ₁₀₈₄ | H | Rₙ₉ | H | H | H | H | H | H | F | Rₙ₁₄ | O |
| Lₐ₁₀₈₅ | H | D | H | H | H | Rₙ₅ | H | H | F | Rₙ₁₄ | O |
| Lₐ₁₀₈₆ | H | Rₙ₂ | H | H | H | Rₙ₅ | H | H | F | Rₙ₁₄ | O |
| Lₐ₁₀₈₇ | H | Rₙ₄ | H | H | H | Rₙ₅ | H | H | F | Rₙ₁₄ | O |
| Lₐ₁₀₈₈ | H | Rₙ₅ | H | H | H | Rₙ₅ | H | H | F | Rₙ₁₄ | O |
| Lₐ₁₀₈₉ | H | Rₙ₇ | H | H | H | Rₙ₅ | H | H | F | Rₙ₁₄ | O |
| Lₐ₁₀₉₀ | H | Rₙ₉ | H | H | H | Rₙ₅ | H | H | F | Rₙ₁₄ | O |
| Lₐ₁₀₉₁ | H | D | H | H | H | Rₙ₉ | H | H | F | Rₙ₁₄ | O |
| Lₐ₁₀₉₂ | H | Rₙ₂ | H | H | H | Rₙ₉ | H | H | F | Rₙ₁₄ | O |
| Lₐ₁₀₉₃ | H | Rₙ₄ | H | H | H | Rₙ₉ | H | H | F | Rₙ₁₄ | O |
| Lₐ₁₀₉₄ | H | Rₙ₅ | H | H | H | Rₙ₉ | H | H | F | Rₙ₁₄ | O |
| Lₐ₁₀₉₅ | H | Rₙ₇ | H | H | H | Rₙ₉ | H | H | F | Rₙ₁₄ | O |
| Lₐ₁₀₉₆ | H | Rₙ₉ | H | H | H | Rₙ₉ | H | H | F | Rₙ₁₄ | O |
| Lₐ₁₀₉₇ | H | H | D | H | H | H | H | H | F | Rₙ₁₄ | O |
| Lₐ₁₀₉₈ | H | H | Rₙ₂ | H | H | H | H | H | F | Rₙ₁₄ | O |
| Lₐ₁₀₉₉ | H | H | Rₙ₄ | H | H | H | H | H | F | Rₙ₁₄ | O |
| Lₐ₁₁₀₀ | H | H | Rₙ₅ | H | H | H | H | H | F | Rₙ₁₄ | O |
| Lₐ₁₁₀₁ | H | H | Rₙ₇ | H | H | H | H | H | F | Rₙ₁₄ | O |
| Lₐ₁₁₀₂ | H | H | Rₙ₉ | H | H | H | H | H | F | Rₙ₁₄ | O |
| Lₐ₁₁₀₃ | H | H | D | H | H | Rₙ₅ | H | H | F | Rₙ₁₄ | O |
| Lₐ₁₁₀₄ | H | H | Rₙ₂ | H | H | Rₙ₅ | H | H | F | Rₙ₁₄ | O |
| Lₐ₁₁₀₅ | H | H | Rₙ₄ | H | H | Rₙ₅ | H | H | F | Rₙ₁₄ | O |
| Lₐ₁₁₀₆ | H | H | Rₙ₅ | H | H | Rₙ₅ | H | H | F | Rₙ₁₄ | O |
| Lₐ₁₁₀₇ | H | H | Rₙ₇ | H | H | Rₙ₅ | H | H | F | Rₙ₁₄ | O |
| Lₐ₁₁₀₈ | H | H | Rₙ₉ | H | H | Rₙ₅ | H | H | F | Rₙ₁₄ | O |
| Lₐ₁₁₀₉ | H | H | D | H | H | Rₙ₉ | H | H | F | Rₙ₁₄ | O |
| Lₐ₁₁₁₀ | H | H | Rₙ₂ | H | H | Rₙ₉ | H | H | F | Rₙ₁₄ | O |
| Lₐ₁₁₁₁ | H | H | Rₙ₄ | H | H | Rₙ₉ | H | H | F | Rₙ₁₄ | O |
| Lₐ₁₁₁₂ | H | H | Rₙ₅ | H | H | Rₙ₉ | H | H | F | Rₙ₁₄ | O |
| Lₐ₁₁₁₃ | H | H | Rₙ₇ | H | H | Rₙ₉ | H | H | F | Rₙ₁₄ | O |
| Lₐ₁₁₁₄ | H | H | Rₙ₉ | H | H | Rₙ₉ | H | H | F | Rₙ₁₄ | O |
| Lₐ₁₁₁₅ | D | Rₙ₂ | Rₙ₂ | D | H | H | H | H | F | Rₙ₁₄ | O |
| Lₐ₁₁₁₆ | D | Rₙ₂ | Rₙ₂ | D | H | Rₙ₅ | H | H | F | Rₙ₁₄ | O |
| Lₐ₁₁₁₇ | D | Rₙ₂ | Rₙ₂ | D | H | Rₙ₉ | H | H | F | Rₙ₁₄ | O |
| Lₐ₁₁₁₈ | H | Rₙ₅ | H | H | H | H | H | H | H | Rₙ₁₅ | O |
| Lₐ₁₁₁₉ | H | Rₙ₅ | H | H | H | H | H | H | H | Rₙ₁₈ | O |
| Lₐ₁₁₂₀ | H | Rₙ₅ | H | H | H | H | H | H | H | Rₙ₁₉ | O |
| Lₐ₁₁₂₁ | H | Rₙ₅ | H | H | H | H | H | H | H | Rₙ₂₀ | O |
| Lₐ₁₁₂₂ | H | Rₙ₅ | H | H | H | H | H | H | H | Rₙ₂₁ | O |
| Lₐ₁₁₂₃ | H | Rₙ₅ | H | H | H | H | H | H | H | Rₙ₂₂ | O |
| Lₐ₁₁₂₄ | H | Rₙ₅ | H | H | H | H | H | H | H | Rₙ₂₇ | O |
| Lₐ₁₁₂₅ | H | H | Rₙ₅ | H | H | H | H | H | H | Rₙ₁₅ | O |
| Lₐ₁₁₂₆ | H | H | Rₙ₅ | H | H | H | H | H | H | Rₙ₁₈ | O |
| Lₐ₁₁₂₇ | H | H | Rₙ₅ | H | H | H | H | H | H | Rₙ₁₉ | O |
| Lₐ₁₁₂₈ | H | H | Rₙ₅ | H | H | H | H | H | H | Rₙ₂₀ | O |
| Lₐ₁₁₂₉ | H | H | Rₙ₅ | H | H | H | H | H | H | Rₙ₂₁ | O |
| Lₐ₁₁₃₀ | H | H | Rₙ₅ | H | H | H | H | H | H | Rₙ₂₂ | O |
| Lₐ₁₁₃₁ | H | H | Rₙ₅ | H | H | H | H | H | H | Rₙ₂₇ | O |
| Lₐ₁₁₃₂ | H | Rₙ₉ | H | H | H | H | H | H | H | Rₙ₁₅ | O |
| Lₐ₁₁₃₃ | H | Rₙ₉ | H | H | H | H | H | H | H | Rₙ₁₈ | O |
| Lₐ₁₁₃₄ | H | Rₙ₉ | H | H | H | H | H | H | H | Rₙ₁₉ | O |
| Lₐ₁₁₃₅ | H | Rₙ₉ | H | H | H | H | H | H | H | Rₙ₂₀ | O |
| Lₐ₁₁₃₆ | H | Rₙ₉ | H | H | H | H | H | H | H | Rₙ₂₁ | O |
| Lₐ₁₁₃₇ | H | Rₙ₉ | H | H | H | H | H | H | H | Rₙ₂₂ | O |
| Lₐ₁₁₃₈ | H | Rₙ₉ | H | H | H | H | H | H | H | Rₙ₂₇ | O |
| Lₐ₁₁₃₉ | H | H | Rₙ₉ | H | H | H | H | H | H | Rₙ₁₅ | O |
| Lₐ₁₁₄₀ | H | H | Rₙ₉ | H | H | H | H | H | H | Rₙ₁₈ | O |
| Lₐ₁₁₄₁ | H | H | Rₙ₉ | H | H | H | H | H | H | Rₙ₁₉ | O |
| Lₐ₁₁₄₂ | H | H | Rₙ₉ | H | H | H | H | H | H | Rₙ₂₀ | O |
| Lₐ₁₁₄₃ | H | H | Rₙ₉ | H | H | H | H | H | H | Rₙ₂₁ | O |
| Lₐ₁₁₄₄ | H | H | Rₙ₉ | H | H | H | H | H | H | Rₙ₂₂ | O |
| Lₐ₁₁₄₅ | H | H | Rₙ₉ | H | H | H | H | H | H | Rₙ₂₇ | O |
| Lₐ₁₁₄₆ | H | Rₙ₅ | H | H | H | Rₙ₅ | H | H | H | Rₙ₁₅ | O |
| Lₐ₁₁₄₇ | H | Rₙ₅ | H | H | H | Rₙ₅ | H | H | H | Rₙ₁₈ | O |
| Lₐ₁₁₄₈ | H | Rₙ₅ | H | H | H | Rₙ₅ | H | H | H | Rₙ₁₉ | O |
| Lₐ₁₁₄₉ | H | Rₙ₅ | H | H | H | Rₙ₅ | H | H | H | Rₙ₂₀ | O |
| Lₐ₁₁₅₀ | H | Rₙ₅ | H | H | H | Rₙ₅ | H | H | H | Rₙ₂₁ | O |
| Lₐ₁₁₅₁ | H | Rₙ₅ | H | H | H | Rₙ₅ | H | H | H | Rₙ₂₂ | O |
| Lₐ₁₁₅₂ | H | Rₙ₅ | H | H | H | Rₙ₅ | H | H | H | Rₙ₂₇ | O |
| Lₐ₁₁₅₃ | H | H | Rₙ₅ | H | H | Rₙ₅ | H | H | H | Rₙ₁₅ | O |
| Lₐ₁₁₅₄ | H | H | Rₙ₅ | H | H | Rₙ₅ | H | H | H | Rₙ₁₈ | O |
| Lₐ₁₁₅₅ | H | H | Rₙ₅ | H | H | Rₙ₅ | H | H | H | Rₙ₁₉ | O |
| Lₐ₁₁₅₆ | H | H | Rₙ₅ | H | H | Rₙ₅ | H | H | H | Rₙ₂₀ | O |
| Lₐ₁₁₅₇ | H | H | Rₙ₅ | H | H | Rₙ₅ | H | H | H | Rₙ₂₁ | O |
| Lₐ₁₁₅₈ | H | H | Rₙ₅ | H | H | Rₙ₅ | H | H | H | Rₙ₂₂ | O |
| Lₐ₁₁₅₉ | H | H | Rₙ₅ | H | H | Rₙ₅ | H | H | H | Rₙ₂₇ | O |
| Lₐ₁₁₆₀ | H | Rₙ₉ | H | H | H | Rₙ₅ | H | H | H | Rₙ₁₅ | O |
| Lₐ₁₁₆₁ | H | Rₙ₉ | H | H | H | Rₙ₅ | H | H | H | Rₙ₁₈ | O |
| Lₐ₁₁₆₂ | H | Rₙ₉ | H | H | H | Rₙ₅ | H | H | H | Rₙ₁₉ | O |
| Lₐ₁₁₆₃ | H | Rₙ₉ | H | H | H | Rₙ₅ | H | H | H | Rₙ₂₀ | O |
| Lₐ₁₁₆₄ | H | Rₙ₉ | H | H | H | Rₙ₅ | H | H | H | Rₙ₂₁ | O |
| Lₐ₁₁₆₅ | H | Rₙ₉ | H | H | H | Rₙ₅ | H | H | H | Rₙ₂₂ | O |
| Lₐ₁₁₆₆ | H | Rₙ₉ | H | H | H | Rₙ₅ | H | H | H | Rₙ₂₇ | O |
| Lₐ₁₁₆₇ | H | H | Rₙ₉ | H | H | Rₙ₅ | H | H | H | Rₙ₁₅ | O |
| Lₐ₁₁₆₈ | H | H | Rₙ₉ | H | H | Rₙ₅ | H | H | H | Rₙ₁₈ | O |
| Lₐ₁₁₆₉ | H | H | Rₙ₉ | H | H | Rₙ₅ | H | H | H | Rₙ₁₉ | O |
| Lₐ₁₁₇₀ | H | H | Rₙ₉ | H | H | Rₙ₅ | H | H | H | Rₙ₂₀ | O |
| Lₐ₁₁₇₁ | H | H | Rₙ₉ | H | H | Rₙ₅ | H | H | H | Rₙ₂₁ | O |
| Lₐ₁₁₇₂ | H | H | Rₙ₉ | H | H | Rₙ₅ | H | H | H | Rₙ₂₂ | O |
| Lₐ₁₁₇₃ | H | H | Rₙ₉ | H | H | Rₙ₅ | H | H | H | Rₙ₂₇ | O |
| Lₐ₁₁₇₄ | H | Rₙ₅ | H | H | H | H | H | H | CN | Rₙ₁₅ | O |
| Lₐ₁₁₇₅ | H | Rₙ₅ | H | H | H | H | H | H | CN | Rₙ₁₈ | O |
| Lₐ₁₁₇₆ | H | Rₙ₅ | H | H | H | H | H | H | CN | Rₙ₁₉ | O |
| Lₐ₁₁₇₇ | H | Rₙ₅ | H | H | H | H | H | H | CN | Rₙ₂₀ | O |
| Lₐ₁₁₇₈ | H | Rₙ₅ | H | H | H | H | H | H | CN | Rₙ₂₁ | O |
| Lₐ₁₁₇₉ | H | Rₙ₅ | H | H | H | H | H | H | CN | Rₙ₂₂ | O |
| Lₐ₁₁₈₀ | H | Rₙ₅ | H | H | H | H | H | H | CN | Rₙ₂₇ | O |
| Lₐ₁₁₈₁ | H | H | Rₙ₅ | H | H | H | H | H | CN | Rₙ₁₅ | O |
| Lₐ₁₁₈₂ | H | H | Rₙ₅ | H | H | H | H | H | CN | Rₙ₁₈ | O |
| Lₐ₁₁₈₃ | H | H | Rₙ₅ | H | H | H | H | H | CN | Rₙ₁₉ | O |
| Lₐ₁₁₈₄ | H | H | Rₙ₅ | H | H | H | H | H | CN | Rₙ₂₀ | O |
| Lₐ₁₁₈₅ | H | H | Rₙ₅ | H | H | H | H | H | CN | Rₙ₂₁ | O |
| Lₐ₁₁₈₆ | H | H | Rₙ₅ | H | H | H | H | H | CN | Rₙ₂₂ | O |
| Lₐ₁₁₈₇ | H | H | Rₙ₅ | H | H | H | H | H | CN | Rₙ₂₇ | O |
| Lₐ₁₁₈₈ | H | Rₙ₉ | H | H | H | H | H | H | CN | Rₙ₁₅ | O |
| Lₐ₁₁₈₉ | H | Rₙ₉ | H | H | H | H | H | H | CN | Rₙ₁₈ | O |
| Lₐ₁₁₉₀ | H | Rₙ₉ | H | H | H | H | H | H | CN | Rₙ₁₉ | O |
| Lₐ₁₁₉₁ | H | Rₙ₉ | H | H | H | H | H | H | CN | Rₙ₂₀ | O |
| Lₐ₁₁₉₂ | H | Rₙ₉ | H | H | H | H | H | H | CN | Rₙ₂₁ | O |
| Lₐ₁₁₉₃ | H | Rₙ₉ | H | H | H | H | H | H | CN | Rₙ₂₂ | O |
| Lₐ₁₁₉₄ | H | Rₙ₉ | H | H | H | H | H | H | CN | Rₙ₂₇ | O |
| Lₐ₁₁₉₅ | H | H | Rₙ₉ | H | H | H | H | H | CN | Rₙ₁₅ | O |
| Lₐ₁₁₉₆ | H | H | Rₙ₉ | H | H | H | H | H | CN | Rₙ₁₈ | O |
| Lₐ₁₁₉₇ | H | H | Rₙ₉ | H | H | H | H | H | CN | Rₙ₁₉ | O |
| Lₐ₁₁₉₈ | H | H | Rₙ₉ | H | H | H | H | H | CN | Rₙ₂₀ | O |
| Lₐ₁₁₉₉ | H | H | Rₙ₉ | H | H | H | H | H | CN | Rₙ₂₁ | O |
| Lₐ₁₂₀₀ | H | H | Rₙ₉ | H | H | H | H | H | CN | Rₙ₂₂ | O |
| Lₐ₁₂₀₁ | H | H | Rₙ₉ | H | H | H | H | H | CN | Rₙ₂₇ | O |
| Lₐ₁₂₀₂ | H | Rₙ₅ | H | H | H | Rₙ₅ | H | H | CN | Rₙ₁₅ | O |
| Lₐ₁₂₀₃ | H | Rₙ₅ | H | H | H | Rₙ₅ | H | H | CN | Rₙ₁₈ | O |
| Lₐ₁₂₀₄ | H | Rₙ₅ | H | H | H | Rₙ₅ | H | H | CN | Rₙ₁₉ | O |
| Lₐ₁₂₀₅ | H | Rₙ₅ | H | H | H | Rₙ₅ | H | H | CN | Rₙ₂₀ | O |
| Lₐ₁₂₀₆ | H | Rₙ₅ | H | H | H | Rₙ₅ | H | H | CN | Rₙ₂₁ | O |
| Lₐ₁₂₀₇ | H | Rₙ₅ | H | H | H | Rₙ₅ | H | H | CN | Rₙ₂₂ | O |
| Lₐ₁₂₀₈ | H | Rₙ₅ | H | H | H | Rₙ₅ | H | H | CN | Rₙ₂₇ | O |
| Lₐ₁₂₀₉ | H | H | Rₙ₅ | H | H | Rₙ₅ | H | H | CN | Rₙ₁₅ | O |
| Lₐ₁₂₁₀ | H | H | Rₙ₅ | H | H | Rₙ₅ | H | H | CN | Rₙ₁₈ | O |
| Lₐ₁₂₁₁ | H | H | Rₙ₅ | H | H | Rₙ₅ | H | H | CN | Rₙ₁₉ | O |
| Lₐ₁₂₁₂ | H | H | Rₙ₅ | H | H | Rₙ₅ | H | H | CN | Rₙ₂₀ | O |
| Lₐ₁₂₁₃ | H | H | Rₙ₅ | H | H | Rₙ₅ | H | H | CN | Rₙ₂₁ | O |
| Lₐ₁₂₁₄ | H | H | Rₙ₅ | H | H | Rₙ₅ | H | H | CN | Rₙ₂₂ | O |
| Lₐ₁₂₁₅ | H | H | Rₙ₅ | H | H | Rₙ₅ | H | H | CN | Rₙ₂₇ | O |
| Lₐ₁₂₁₆ | H | Rₙ₉ | H | H | H | Rₙ₅ | H | H | CN | Rₙ₁₅ | O |
| Lₐ₁₂₁₇ | H | Rₙ₉ | H | H | H | Rₙ₅ | H | H | CN | Rₙ₁₈ | O |
| Lₐ₁₂₁₈ | H | Rₙ₉ | H | H | H | Rₙ₅ | H | H | CN | Rₙ₁₉ | O |
| Lₐ₁₂₁₉ | H | Rₙ₉ | H | H | H | Rₙ₅ | H | H | CN | Rₙ₂₀ | O |
| Lₐ₁₂₂₀ | H | Rₙ₉ | H | H | H | Rₙ₅ | H | H | CN | Rₙ₂₁ | O |
| Lₐ₁₂₂₁ | H | Rₙ₉ | H | H | H | Rₙ₅ | H | H | CN | Rₙ₂₂ | O |
| Lₐ₁₂₂₂ | H | Rₙ₉ | H | H | H | Rₙ₅ | H | H | CN | Rₙ₂₇ | O |
| Lₐ₁₂₂₃ | H | H | Rₙ₉ | H | H | Rₙ₅ | H | H | CN | Rₙ₁₅ | O |
| Lₐ₁₂₂₄ | H | H | Rₙ₉ | H | H | Rₙ₅ | H | H | CN | Rₙ₁₈ | O |
| Lₐ₁₂₂₅ | H | H | Rₙ₉ | H | H | Rₙ₅ | H | H | CN | Rₙ₁₉ | O |
| Lₐ₁₂₂₆ | H | H | Rₙ₉ | H | H | Rₙ₅ | H | H | CN | Rₙ₂₀ | O |
| Lₐ₁₂₂₇ | H | H | Rₙ₉ | H | H | Rₙ₅ | H | H | CN | Rₙ₂₁ | O |
| Lₐ₁₂₂₈ | H | H | Rₙ₉ | H | H | Rₙ₅ | H | H | CN | Rₙ₂₂ | O |
| Lₐ₁₂₂₉ | H | H | Rₙ₉ | H | H | Rₙ₅ | H | H | CN | Rₙ₂₇ | O |
| Lₐ₁₂₃₀ | H | Rₙ₅ | H | H | H | H | H | H | F | Rₙ₁₅ | O |
| Lₐ₁₂₃₁ | H | Rₙ₅ | H | H | H | H | H | H | F | Rₙ₁₈ | O |
| Lₐ₁₂₃₂ | H | Rₙ₅ | H | H | H | H | H | H | F | Rₙ₁₉ | O |
| Lₐ₁₂₃₃ | H | Rₙ₅ | H | H | H | H | H | H | F | Rₙ₂₀ | O |
| Lₐ₁₂₃₄ | H | Rₙ₅ | H | H | H | H | H | H | F | Rₙ₂₁ | O |
| Lₐ₁₂₃₅ | H | Rₙ₅ | H | H | H | H | H | H | F | Rₙ₂₂ | O |
| Lₐ₁₂₃₆ | H | Rₙ₅ | H | H | H | H | H | H | F | Rₙ₂₇ | O |
| Lₐ₁₂₃₇ | H | H | Rₙ₅ | H | H | H | H | H | F | Rₙ₁₅ | O |
| Lₐ₁₂₃₈ | H | H | Rₙ₅ | H | H | H | H | H | F | Rₙ₁₈ | O |
| Lₐ₁₂₃₉ | H | H | Rₙ₅ | H | H | H | H | H | F | Rₙ₁₉ | O |
| Lₐ₁₂₄₀ | H | H | Rₙ₅ | H | H | H | H | H | F | Rₙ₂₀ | O |
| Lₐ₁₂₄₁ | H | H | Rₙ₅ | H | H | H | H | H | F | Rₙ₂₁ | O |
| Lₐ₁₂₄₂ | H | H | Rₙ₅ | H | H | H | H | H | F | Rₙ₂₂ | O |
| Lₐ₁₂₄₃ | H | H | Rₙ₅ | H | H | H | H | H | F | Rₙ₂₇ | O |
| Lₐ₁₂₄₄ | H | Rₙ₉ | H | H | H | H | H | H | F | Rₙ₁₅ | O |
| Lₐ₁₂₄₅ | H | Rₙ₉ | H | H | H | H | H | H | F | Rₙ₁₈ | O |
| Lₐ₁₂₄₆ | H | Rₙ₉ | H | H | H | H | H | H | F | Rₙ₁₉ | O |
| Lₐ₁₂₄₇ | H | Rₙ₉ | H | H | H | H | H | H | F | Rₙ₂₀ | O |
| Lₐ₁₂₄₈ | H | Rₙ₉ | H | H | H | H | H | H | F | Rₙ₂₁ | O |
| Lₐ₁₂₄₉ | H | Rₙ₉ | H | H | H | H | H | H | F | Rₙ₂₂ | O |
| Lₐ₁₂₅₀ | H | Rₙ₉ | H | H | H | H | H | H | F | Rₙ₂₇ | O |
| Lₐ₁₂₅₁ | H | H | Rₙ₉ | H | H | H | H | H | F | Rₙ₁₅ | O |
| Lₐ₁₂₅₂ | H | H | Rₙ₉ | H | H | H | H | H | F | Rₙ₁₈ | O |
| Lₐ₁₂₅₃ | H | H | Rₙ₉ | H | H | H | H | H | F | Rₙ₁₉ | O |
| Lₐ₁₂₅₄ | H | H | Rₙ₉ | H | H | H | H | H | F | Rₙ₂₀ | O |
| Lₐ₁₂₅₅ | H | H | Rₙ₉ | H | H | H | H | H | F | Rₙ₂₁ | O |
| Lₐ₁₂₅₆ | H | H | Rₙ₉ | H | H | H | H | H | F | Rₙ₂₂ | O |
| Lₐ₁₂₅₇ | H | H | Rₙ₉ | H | H | H | H | H | F | Rₙ₂₇ | O |
| Lₐ₁₂₅₈ | H | Rₙ₅ | H | H | H | Rₙ₅ | H | H | F | Rₙ₁₅ | O |
| Lₐ₁₂₅₉ | H | Rₙ₅ | H | H | H | Rₙ₅ | H | H | F | Rₙ₁₈ | O |
| Lₐ₁₂₆₀ | H | Rₙ₅ | H | H | H | Rₙ₅ | H | H | F | Rₙ₁₉ | O |
| Lₐ₁₂₆₁ | H | Rₙ₅ | H | H | H | Rₙ₅ | H | H | F | Rₙ₂₀ | O |
| Lₐ₁₂₆₂ | H | Rₙ₅ | H | H | H | Rₙ₅ | H | H | F | Rₙ₂₁ | O |
| Lₐ₁₂₆₃ | H | Rₙ₅ | H | H | H | Rₙ₅ | H | H | F | Rₙ₂₂ | O |
| Lₐ₁₂₆₄ | H | Rₙ₅ | H | H | H | Rₙ₅ | H | H | F | Rₙ₂₇ | O |
| Lₐ₁₂₆₅ | H | H | Rₙ₅ | H | H | Rₙ₅ | H | H | F | Rₙ₁₅ | O |
| Lₐ₁₂₆₆ | H | H | Rₙ₅ | H | H | Rₙ₅ | H | H | F | Rₙ₁₈ | O |
| Lₐ₁₂₆₇ | H | H | Rₙ₅ | H | H | Rₙ₅ | H | H | F | Rₙ₁₉ | O |
| Lₐ₁₂₆₈ | H | H | Rₙ₅ | H | H | Rₙ₅ | H | H | F | Rₙ₂₀ | O |
| Lₐ₁₂₆₉ | H | H | Rₙ₅ | H | H | Rₙ₅ | H | H | F | Rₙ₂₁ | O |
| Lₐ₁₂₇₀ | H | H | Rₙ₅ | H | H | Rₙ₅ | H | H | F | Rₙ₂₂ | O |
| Lₐ₁₂₇₁ | H | H | Rₙ₅ | H | H | Rₙ₅ | H | H | F | Rₙ₂₇ | O |
| Lₐ₁₂₇₂ | H | Rₙ₉ | H | H | H | Rₙ₅ | H | H | F | Rₙ₁₅ | O |
| Lₐ₁₂₇₃ | H | Rₙ₉ | H | H | H | Rₙ₅ | H | H | F | Rₙ₁₈ | O |
| Lₐ₁₂₇₄ | H | Rₙ₉ | H | H | H | Rₙ₅ | H | H | F | Rₙ₁₉ | O |
| Lₐ₁₂₇₅ | H | Rₙ₉ | H | H | H | Rₙ₅ | H | H | F | Rₙ₂₀ | O |
| Lₐ₁₂₇₆ | H | Rₙ₉ | H | H | H | Rₙ₅ | H | H | F | Rₙ₂₁ | O |
| Lₐ₁₂₇₇ | H | Rₙ₉ | H | H | H | Rₙ₅ | H | H | F | Rₙ₂₂ | O |
| Lₐ₁₂₇₈ | H | Rₙ₉ | H | H | H | Rₙ₅ | H | H | F | Rₙ₂₇ | O |
| Lₐ₁₂₇₉ | H | H | Rₙ₉ | H | H | Rₙ₅ | H | H | F | Rₙ₁₅ | O |
| Lₐ₁₂₈₀ | H | H | Rₙ₉ | H | H | Rₙ₅ | H | H | F | Rₙ₁₈ | O |
| Lₐ₁₂₈₁ | H | H | Rₙ₉ | H | H | Rₙ₅ | H | H | F | Rₙ₁₉ | O |
| Lₐ₁₂₈₂ | H | H | Rₙ₉ | H | H | Rₙ₅ | H | H | F | Rₙ₂₀ | O |
| Lₐ₁₂₈₃ | H | H | Rₙ₉ | H | H | Rₙ₅ | H | H | F | Rₙ₂₁ | O |
| Lₐ₁₂₈₄ | H | H | Rₙ₉ | H | H | Rₙ₅ | H | H | F | Rₙ₂₂ | O |
| Lₐ₁₂₈₅ | H | H | Rₙ₉ | H | H | Rₙ₅ | H | H | F | Rₙ₂₇ | O |
| Lₐ₁₂₈₆ | H | Rₙ₅ | H | H | H | H | H | H | H | Rₙ₁₇ | S |
| Lₐ₁₂₈₇ | H | Rₙ₅ | H | H | H | Rₙ₅ | H | H | H | Rₙ₁₇ | S |
| Lₐ₁₂₈₈ | H | Rₙ₅ | H | H | H | Rₙ₉ | H | H | H | Rₙ₁₇ | S |
| Lₐ₁₂₈₉ | H | H | Rₙ₅ | H | H | H | H | H | H | Rₙ₁₇ | S |
| Lₐ₁₂₉₀ | H | H | Rₙ₅ | H | H | Rₙ₅ | H | H | H | Rₙ₁₇ | S |
| Lₐ₁₂₉₁ | H | H | Rₙ₅ | H | H | Rₙ₉ | H | H | H | Rₙ₁₇ | S |
| Lₐ₁₂₉₂ | H | Rₙ₅ | H | H | H | H | H | H | H | Rₙ₂₄ | S |
| Lₐ₁₂₉₃ | H | Rₙ₅ | H | H | H | Rₙ₅ | H | H | H | Rₙ₂₄ | S |
| Lₐ₁₂₉₄ | H | Rₙ₅ | H | H | H | Rₙ₉ | H | H | H | Rₙ₂₄ | S |
| Lₐ₁₂₉₅ | H | H | Rₙ₅ | H | H | H | H | H | H | Rₙ₂₄ | S |
| Lₐ₁₂₉₆ | H | H | Rₙ₅ | H | H | Rₙ₅ | H | H | H | Rₙ₂₄ | S |
| Lₐ₁₂₉₇ | H | H | Rₙ₅ | H | H | Rₙ₉ | H | H | H | Rₙ₂₄ | S |
| Lₐ₁₂₉₈ | H | Rₙ₅ | H | H | H | H | H | H | CN | D | S |
| Lₐ₁₂₉₉ | H | Rₙ₅ | H | H | H | Rₙ₅ | H | H | CN | D | S |
| Lₐ₁₃₀₀ | H | Rₙ₅ | H | H | H | Rₙ₉ | H | H | CN | D | S |
| Lₐ₁₃₀₁ | H | H | Rₙ₅ | H | H | H | H | H | CN | D | S |
| Lₐ₁₃₀₂ | H | H | Rₙ₅ | H | H | Rₙ₅ | H | H | CN | D | S |
| Lₐ₁₃₀₃ | H | H | Rₙ₅ | H | H | Rₙ₉ | H | H | CN | D | S |
| Lₐ₁₃₀₄ | H | Rₙ₅ | H | H | H | H | H | H | CN | Rₙ₁₂ | S |
| Lₐ₁₃₀₅ | H | Rₙ₅ | H | H | H | Rₙ₅ | H | H | CN | Rₙ₁₂ | S |
| Lₐ₁₃₀₆ | H | Rₙ₅ | H | H | H | Rₙ₉ | H | H | CN | Rₙ₁₂ | S |
| Lₐ₁₃₀₇ | H | H | Rₙ₅ | H | H | H | H | H | CN | Rₙ₁₂ | S |
| Lₐ₁₃₀₈ | H | H | Rₙ₅ | H | H | Rₙ₅ | H | H | CN | Rₙ₁₂ | S |
| Lₐ₁₃₀₉ | H | H | Rₙ₅ | H | H | Rₙ₉ | H | H | CN | Rₙ₁₂ | S |
| Lₐ₁₃₁₀ | H | Rₙ₅ | H | H | H | H | H | H | F | Rₙ₁₂ | S |
| Lₐ₁₃₁₁ | H | Rₙ₅ | H | H | H | Rₙ₅ | H | H | F | Rₙ₁₂ | S |
| Lₐ₁₃₁₂ | H | Rₙ₅ | H | H | H | Rₙ₉ | H | H | F | Rₙ₁₂ | S |
| Lₐ₁₃₁₃ | H | H | Rₙ₅ | H | H | H | H | H | F | Rₙ₁₂ | S |
| Lₐ₁₃₁₄ | H | H | Rₙ₅ | H | H | Rₙ₅ | H | H | F | Rₙ₁₂ | S |
| Lₐ₁₃₁₅ | H | H | Rₙ₅ | H | H | Rₙ₉ | H | H | F | Rₙ₁₂ | S |
| Lₐ₁₃₁₆ | H | Rₙ₅ | H | H | H | H | H | H | CN | Rₙ₁₄ | S |
| Lₐ₁₃₁₇ | H | Rₙ₅ | H | H | H | Rₙ₅ | H | H | CN | Rₙ₁₄ | S |
| Lₐ₁₃₁₈ | H | Rₙ₅ | H | H | H | Rₙ₉ | H | H | CN | Rₙ₁₄ | S |
| Lₐ₁₃₁₉ | H | H | Rₙ₅ | H | H | H | H | H | CN | Rₙ₁₄ | S |
| Lₐ₁₃₂₀ | H | H | Rₙ₅ | H | H | Rₙ₅ | H | H | CN | Rₙ₁₄ | S |
| Lₐ₁₃₂₁ | H | H | Rₙ₅ | H | H | Rₙ₉ | H | H | CN | Rₙ₁₄ | S |
| Lₐ₁₃₂₂ | H | Rₙ₅ | H | H | H | H | H | H | F | Rₙ₁₄ | S |
| Lₐ₁₃₂₃ | H | Rₙ₅ | H | H | H | Rₙ₅ | H | H | F | Rₙ₁₄ | S |
| Lₐ₁₃₂₄ | H | Rₙ₅ | H | H | H | Rₙ₉ | H | H | F | Rₙ₁₄ | S |
| Lₐ₁₃₂₅ | H | H | Rₙ₅ | H | H | H | H | H | F | Rₙ₁₄ | S |
| Lₐ₁₃₂₆ | H | H | Rₙ₅ | H | H | Rₙ₅ | H | H | F | Rₙ₁₄ | S |
| Lₐ₁₃₂₇ | H | H | Rₙ₅ | H | H | Rₙ₉ | H | H | F | Rₙ₁₄ | S |
| Lₐ₁₃₂₈ | H | Rₙ₅ | H | H | H | H | H | H | CN | Rₙ₁₇ | S |
| Lₐ₁₃₂₉ | H | Rₙ₅ | H | H | H | Rₙ₅ | H | H | CN | Rₙ₁₇ | S |
| Lₐ₁₃₃₀ | H | Rₙ₅ | H | H | H | Rₙ₉ | H | H | CN | Rₙ₁₇ | S |
| Lₐ₁₃₃₁ | H | H | Rₙ₅ | H | H | H | H | H | CN | Rₙ₁₇ | S |
| Lₐ₁₃₃₂ | H | H | Rₙ₅ | H | H | Rₙ₅ | H | H | CN | Rₙ₁₇ | S |
| Lₐ₁₃₃₃ | H | H | Rₙ₅ | H | H | Rₙ₉ | H | H | CN | Rₙ₁₇ | S |
| Lₐ₁₃₃₄ | H | Rₙ₅ | H | H | H | H | H | H | F | Rₙ₁₇ | S |
| Lₐ₁₃₃₅ | H | Rₙ₅ | H | H | H | Rₙ₅ | H | H | F | Rₙ₁₇ | S |
| Lₐ₁₃₃₆ | H | Rₙ₅ | H | H | H | Rₙ₉ | H | H | F | Rₙ₁₇ | S |
| Lₐ₁₃₃₇ | H | H | Rₙ₅ | H | H | H | H | H | F | Rₙ₁₇ | S |
| Lₐ₁₃₃₈ | H | H | Rₙ₅ | H | H | Rₙ₅ | H | H | F | Rₙ₁₇ | S |
| Lₐ₁₃₃₉ | H | H | Rₙ₅ | H | H | Rₙ₉ | H | H | F | Rₙ₁₇ | S |
| Lₐ₁₃₄₀ | H | Rₙ₅ | H | H | H | H | H | H | H | Rₙ₁₈ | S |
| Lₐ₁₃₄₁ | H | Rₙ₅ | H | H | H | Rₙ₅ | H | H | H | Rₙ₁₈ | S |
| Lₐ₁₃₄₂ | H | Rₙ₅ | H | H | H | Rₙ₉ | H | H | H | Rₙ₁₈ | S |
| Lₐ₁₃₄₃ | H | H | Rₙ₅ | H | H | H | H | H | H | Rₙ₁₈ | S |
| Lₐ₁₃₄₄ | H | H | Rₙ₅ | H | H | Rₙ₅ | H | H | H | Rₙ₁₈ | S |
| Lₐ₁₃₄₅ | H | H | Rₙ₅ | H | H | Rₙ₉ | H | H | H | Rₙ₁₈ | S |
| Lₐ₁₃₄₆ | H | Rₙ₅ | H | H | H | H | H | H | H | Rₙ₁₈ | S |
| Lₐ₁₃₄₇ | H | Rₙ₅ | H | H | H | Rₙ₅ | H | H | H | Rₙ₁₈ | S |
| Lₐ₁₃₄₈ | H | Rₙ₅ | H | H | H | Rₙ₉ | H | H | H | Rₙ₁₈ | S |
| Lₐ₁₃₄₉ | H | H | Rₙ₅ | H | H | H | H | H | H | Rₙ₁₈ | S |
| Lₐ₁₃₅₀ | H | H | Rₙ₅ | H | H | Rₙ₅ | H | H | H | Rₙ₁₈ | S |
| Lₐ₁₃₅₁ | H | H | Rₙ₅ | H | H | Rₙ₉ | H | H | H | Rₙ₁₈ | S |
| Lₐ₁₃₅₂ | H | Rₙ₅ | H | H | H | H | H | H | CN | Rₙ₁₉ | S |
| Lₐ₁₃₅₃ | H | Rₙ₅ | H | H | H | Rₙ₅ | H | H | CN | Rₙ₁₉ | S |
| Lₐ₁₃₅₄ | H | Rₙ₅ | H | H | H | Rₙ₉ | H | H | CN | Rₙ₁₉ | S |
| Lₐ₁₃₅₅ | H | H | Rₙ₅ | H | H | H | H | H | CN | Rₙ₁₉ | S |
| Lₐ₁₃₅₆ | H | H | Rₙ₅ | H | H | Rₙ₅ | H | H | CN | Rₙ₁₉ | S |
| Lₐ₁₃₅₇ | H | H | Rₙ₅ | H | H | Rₙ₉ | H | H | CN | Rₙ₁₉ | S |
| Lₐ₁₃₅₈ | H | Rₙ₅ | H | H | H | H | H | H | F | Rₙ₁₉ | S |
| Lₐ₁₃₅₉ | H | Rₙ₅ | H | H | H | Rₙ₅ | H | H | F | Rₙ₁₉ | S |
| Lₐ₁₃₆₀ | H | Rₙ₅ | H | H | H | Rₙ₉ | H | H | F | Rₙ₁₉ | S |
| Lₐ₁₃₆₁ | H | H | Rₙ₅ | H | H | H | H | H | F | Rₙ₁₉ | S |
| Lₐ₁₃₆₂ | H | H | Rₙ₅ | H | H | Rₙ₅ | H | H | F | Rₙ₁₉ | S |
| Lₐ₁₃₆₃ | H | H | Rₙ₅ | H | H | Rₙ₉ | H | H | F | Rₙ₁₉ | S |
| Lₐ₁₃₆₄ | H | Rₙ₅ | H | H | H | H | H | H | CN | Rₙ₂₃ | S |
| Lₐ₁₃₆₅ | H | Rₙ₅ | H | H | H | Rₙ₅ | H | H | CN | Rₙ₂₃ | S |
| Lₐ₁₃₆₆ | H | Rₙ₅ | H | H | H | Rₙ₉ | H | H | CN | Rₙ₂₃ | S |
| Lₐ₁₃₆₇ | H | H | Rₙ₅ | H | H | H | H | H | CN | Rₙ₂₃ | S |
| Lₐ₁₃₆₈ | H | H | Rₙ₅ | H | H | Rₙ₅ | H | H | CN | Rₙ₂₃ | S |
| Lₐ₁₃₆₉ | H | H | Rₙ₅ | H | H | Rₙ₉ | H | H | CN | Rₙ₂₃ | S |
| Lₐ₁₃₇₀ | H | Rₙ₅ | H | H | H | H | H | H | F | Rₙ₂₃ | S |
| Lₐ₁₃₇₁ | H | Rₙ₅ | H | H | H | Rₙ₅ | H | H | F | Rₙ₂₃ | S |
| Lₐ₁₃₇₂ | H | Rₙ₅ | H | H | H | Rₙ₉ | H | H | F | Rₙ₂₃ | S |
| Lₐ₁₃₇₃ | H | H | Rₙ₅ | H | H | H | H | H | F | Rₙ₂₃ | S |
| Lₐ₁₃₇₄ | H | H | Rₙ₅ | H | H | Rₙ₅ | H | H | F | Rₙ₂₃ | S |
| Lₐ₁₃₇₅ | H | H | Rₙ₅ | H | H | Rₙ₉ | H | H | F | Rₙ₂₃ | S |
| Lₐ₁₃₇₆ | H | Rₙ₅ | H | H | H | H | H | H | CN | Rₙ₂₄ | S |
| Lₐ₁₃₇₇ | H | Rₙ₅ | H | H | H | Rₙ₅ | H | H | CN | Rₙ₂₄ | S |
| Lₐ₁₃₇₈ | H | Rₙ₅ | H | H | H | Rₙ₉ | H | H | CN | Rₙ₂₄ | S |
| Lₐ₁₃₇₉ | H | H | Rₙ₅ | H | H | H | H | H | CN | Rₙ₂₄ | S |
| Lₐ₁₃₈₀ | H | H | Rₙ₅ | H | H | Rₙ₅ | H | H | CN | Rₙ₂₄ | S |
| Lₐ₁₃₈₁ | H | H | Rₙ₅ | H | H | Rₙ₉ | H | H | CN | Rₙ₂₄ | S |
| Lₐ₁₃₈₂ | H | Rₙ₅ | H | H | H | H | H | H | F | Rₙ₂₄ | S |
| Lₐ₁₃₈₃ | H | Rₙ₅ | H | H | H | Rₙ₅ | H | H | F | Rₙ₂₄ | S |
| Lₐ₁₃₈₄ | H | Rₙ₅ | H | H | H | Rₙ₉ | H | H | F | Rₙ₂₄ | S |
| Lₐ₁₃₈₅ | H | H | Rₙ₅ | H | H | H | H | H | F | Rₙ₂₄ | S |
| Lₐ₁₃₈₆ | H | H | Rₙ₅ | H | H | Rₙ₅ | H | H | F | Rₙ₂₄ | S |
| Lₐ₁₃₈₇ | H | H | Rₙ₅ | H | H | Rₙ₉ | H | H | F | Rₙ₂₄ | S |
| Lₐ₁₃₈₈ | H | Rₙ₅ | H | H | H | H | H | H | CN | Rₙ₂₅ | S |
| Lₐ₁₃₈₉ | H | Rₙ₅ | H | H | H | Rₙ₅ | H | H | CN | Rₙ₂₅ | S |
| Lₐ₁₃₉₀ | H | Rₙ₅ | H | H | H | Rₙ₉ | H | H | CN | Rₙ₂₅ | S |
| Lₐ₁₃₉₁ | H | H | Rₙ₅ | H | H | H | H | H | CN | Rₙ₂₅ | S |
| Lₐ₁₃₉₂ | H | H | Rₙ₅ | H | H | Rₙ₅ | H | H | CN | Rₙ₂₅ | S |
| Lₐ₁₃₉₃ | H | H | Rₙ₅ | H | H | Rₙ₉ | H | H | CN | Rₙ₂₅ | S |
| Lₐ₁₃₉₄ | H | Rₙ₅ | H | H | H | H | H | H | F | Rₙ₂₅ | S |
| Lₐ₁₃₉₅ | H | Rₙ₅ | H | H | H | Rₙ₅ | H | H | F | Rₙ₂₅ | S |
| Lₐ₁₃₉₆ | H | Rₙ₅ | H | H | H | Rₙ₉ | H | H | F | Rₙ₂₅ | S |
| Lₐ₁₃₉₇ | H | H | Rₙ₅ | H | H | H | H | H | F | Rₙ₂₅ | S |
| Lₐ₁₃₉₈ | H | H | Rₙ₅ | H | H | Rₙ₅ | H | H | F | Rₙ₂₅ | S |
| Lₐ₁₃₉₉ | H | H | Rₙ₅ | H | H | Rₙ₉ | H | H | F | Rₙ₂₅ | S |
| Lₐ₁₄₀₀ | H | Rₙ₅ | H | H | H | H | H | H | CN | Rₙ₂₆ | S |
| Lₐ₁₄₀₁ | H | Rₙ₅ | H | H | H | Rₙ₅ | H | H | CN | Rₙ₂₆ | S |
| Lₐ₁₄₀₂ | H | Rₙ₅ | H | H | H | Rₙ₉ | H | H | CN | Rₙ₂₆ | S |
| Lₐ₁₄₀₃ | H | H | Rₙ₅ | H | H | H | H | H | CN | Rₙ₂₆ | S |
| Lₐ₁₄₀₄ | H | H | Rₙ₅ | H | H | Rₙ₅ | H | H | CN | Rₙ₂₆ | S |
| Lₐ₁₄₀₅ | H | H | Rₙ₅ | H | H | Rₙ₉ | H | H | CN | Rₙ₂₆ | S |
| Lₐ₁₄₀₆ | H | Rₙ₅ | H | H | H | H | H | H | F | Rₙ₂₆ | S |
| Lₐ₁₄₀₇ | H | Rₙ₅ | H | H | H | Rₙ₅ | H | H | F | Rₙ₂₆ | S |
| Lₐ₁₄₀₈ | H | Rₙ₅ | H | H | H | Rₙ₉ | H | H | F | Rₙ₂₆ | S |
| Lₐ₁₄₀₉ | H | H | Rₙ₅ | H | H | H | H | H | F | R₁₂₆ | S |
| Lₐ₁₄₁₀ | H | H | Rₙ₅ | H | H | Rₙ₅ | H | H | F | Rₙ₂₆ | S |
| Lₐ₁₄₁₁ | H | H | Rₙ₅ | H | H | Rₙ₉ | H | H | F | Rₙ₂₆ | S |

wherein Lₐ₁₄₁₂ to Lₐ₁₄₇₄ each have the following structure: 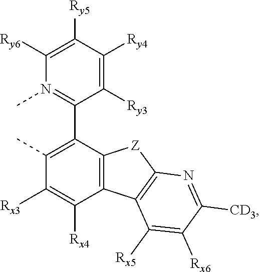
wherein R_{y3} to R_{y6}, Rₓ₃ to Rₓ₆, and Z are selected from atoms or groups in the following table:

| Lₐ | R_{y3} | R_{y4} | R_{y5} | R_{y6} | Rₓ₃ | Rₓ₄ | Rₓ₅ | Rₓ₆ | Z |
|---|---|---|---|---|---|---|---|---|---|
| Lₐ₁₄₁₂ | D | H | H | H | H | H | H | H | O |
| Lₐ₁₄₁₃ | H | D | H | H | H | H | H | H | O |
| Lₐ₁₄₁₄ | H | H | D | H | H | H | H | H | O |
| Lₐ₁₄₁₅ | H | H | H | D | H | H | H | H | O |
| Lₐ₁₄₁₆ | H | Rₙ₁ | H | H | H | H | H | H | O |
| Lₐ₁₄₁₇ | H | Rₙ₂ | H | H | H | H | H | H | O |
| Lₐ₁₄₁₈ | H | Rₙ₃ | H | H | H | H | H | H | O |
| Lₐ₁₄₁₉ | H | Rₙ₄ | H | H | H | H | H | H | O |
| Lₐ₁₄₂₀ | H | Rₙ₅ | H | H | H | H | H | H | O |
| Lₐ₁₄₂₁ | H | Rₙ₆ | H | H | H | H | H | H | O |
| Lₐ₁₄₂₂ | H | Rₙ₇ | H | H | H | H | H | H | O |
| Lₐ₁₄₂₃ | H | Rₙ₈ | H | H | H | H | H | H | O |
| Lₐ₁₄₂₄ | D | Rₙ₉ | D | D | H | H | H | H | O |
| Lₐ₁₄₂₅ | H | Rₙ₁₀ | H | H | H | H | H | H | O |
| Lₐ₁₄₂₆ | H | Rₙ₁₁ | H | H | H | H | H | H | O |
| Lₐ₁₄₂₇ | H | Rₙ₁₂ | Rₙ₂ | H | H | H | H | H | O |
| Lₐ₁₄₂₈ | H | Rₙ₁₄ | Rₙ₂ | H | H | H | H | H | O |
| Lₐ₁₄₂₉ | H | Rₙ₁₆ | Rₙ₂ | H | H | H | H | H | O |
| Lₐ₁₄₃₀ | H | Rₙ₂₃ | H | H | H | H | H | H | O |
| Lₐ₁₄₃₁ | H | H | Rₙ₁ | H | H | H | H | H | O |
| Lₐ₁₄₃₂ | H | H | Rₙ₂ | H | H | H | H | H | O |
| Lₐ₁₄₃₃ | H | H | Rₙ₃ | H | H | H | H | H | O |
| Lₐ₁₄₃₄ | H | H | Rₙ₄ | H | H | H | H | H | O |
| Lₐ₁₄₃₅ | H | H | Rₙ₅ | H | H | H | H | H | O |
| Lₐ₁₄₃₆ | H | H | Rₙ₆ | H | H | H | H | H | O |
| Lₐ₁₄₃₇ | H | H | Rₙ₇ | H | H | H | H | H | O |
| Lₐ₁₄₃₈ | H | H | Rₙ₈ | H | H | H | H | H | O |
| Lₐ₁₄₃₉ | H | H | Rₙ₉ | H | H | H | H | H | O |
| Lₐ₁₄₄₀ | H | H | Rₙ₁₀ | H | H | H | H | H | O |
| Lₐ₁₄₄₁ | H | H | Rₙ₁₁ | H | H | H | H | H | O |
| Lₐ₁₄₄₂ | H | Rₙ₂ | Rₙ₁₂ | H | H | H | H | H | O |
| Lₐ₁₄₄₃ | H | Rₙ₂ | Rₙ₁₄ | H | H | H | H | H | O |
| Lₐ₁₄₄₄ | H | Rₙ₂ | Rₙ₁₆ | H | H | H | H | H | O |
| Lₐ₁₄₄₅ | H | H | Rₙ₂₃ | H | H | H | H | H | O |
| Lₐ₁₄₄₆ | H | Rₙ₂ | Rₙ₂ | H | H | H | H | H | O |
| Lₐ₁₄₄₇ | H | D | H | H | H | Rₙ₂ | H | H | O |
| Lₐ₁₄₄₈ | H | D | H | H | H | Rₙ₄ | H | H | O |
| Lₐ₁₄₄₉ | H | D | H | H | H | Rₙ₅ | H | H | O |
| Lₐ₁₄₅₀ | H | D | H | H | H | Rₙ₇ | H | H | O |
| Lₐ₁₄₅₁ | H | D | H | H | H | Rₙ₉ | H | H | O |
| Lₐ₁₄₅₂ | H | D | H | H | H | Rₙ₁₂ | H | H | O |
| Lₐ₁₄₅₃ | H | D | H | H | H | F | H | H | O |
| Lₐ₁₄₅₄ | H | Rₙ₅ | H | H | H | Rₙ₂ | H | H | O |
| Lₐ₁₄₅₅ | H | Rₙ₅ | H | H | H | Rₙ₄ | H | H | O |
| Lₐ₁₄₅₆ | H | Rₙ₅ | H | H | H | Rₙ₅ | H | H | O |
| Lₐ₁₄₅₇ | H | Rₙ₅ | H | H | H | Rₙ₇ | H | H | O |
| Lₐ₁₄₅₈ | H | Rₙ₅ | H | H | H | Rₙ₉ | H | H | O |
| Lₐ₁₄₅₉ | H | Rₙ₅ | H | H | H | Rₙ₁₂ | H | H | O |
| Lₐ₁₄₆₀ | H | Rₙ₅ | H | H | H | F | H | H | O |
| Lₐ₁₄₆₁ | H | H | Rₙ₅ | H | H | Rₙ₂ | H | H | O |
| Lₐ₁₄₆₂ | H | H | Rₙ₅ | H | H | Rₙ₄ | H | H | O |
| Lₐ₁₄₆₃ | H | H | Rₙ₅ | H | H | Rₙ₅ | H | H | O |
| Lₐ₁₄₆₄ | H | H | Rₙ₅ | H | H | Rₙ₇ | H | H | O |
| Lₐ₁₄₆₅ | H | H | Rₙ₅ | H | H | Rₙ₉ | H | H | O |
| Lₐ₁₄₆₆ | H | H | Rₙ₅ | H | H | Rₙ₁₂ | H | H | O |
| Lₐ₁₄₆₇ | H | H | Rₙ₅ | H | H | F | H | H | O |
| Lₐ₁₄₆₈ | H | Rₙ₁₆ | Rₙ₂ | H | H | Rₙ₂ | H | H | O |
| Lₐ₁₄₆₉ | H | Rₙ₁₆ | Rₙ₂ | H | H | Rₙ₄ | H | H | O |
| Lₐ₁₄₇₀ | H | Rₙ₁₆ | Rₙ₂ | H | H | Rₙ₅ | H | H | O |
| Lₐ₁₄₇₁ | H | Rₙ₁₆ | Rₙ₂ | H | H | Rₙ₇ | H | H | O |
| Lₐ₁₄₇₂ | H | Rₙ₁₆ | Rₙ₂ | H | H | Rₙ₉ | H | H | O |
| Lₐ₁₄₇₃ | H | Rₙ₁₆ | Rₙ₂ | H | H | Rₙ₁₂ | H | H | O |
| Lₐ₁₄₇₄ | H | Rₙ₁₆ | Rₙ₂ | H | H | F | H | H | O |

wherein Rₐ₁ to Rₙ₂₇ are selected from the following structures: 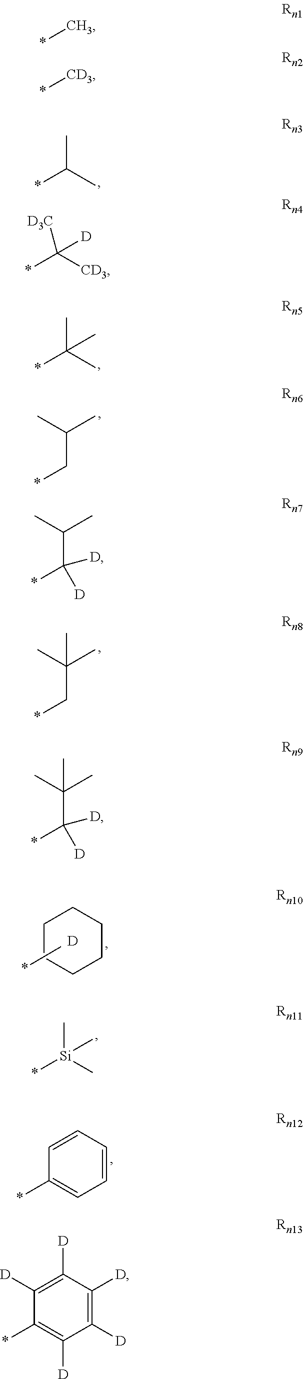 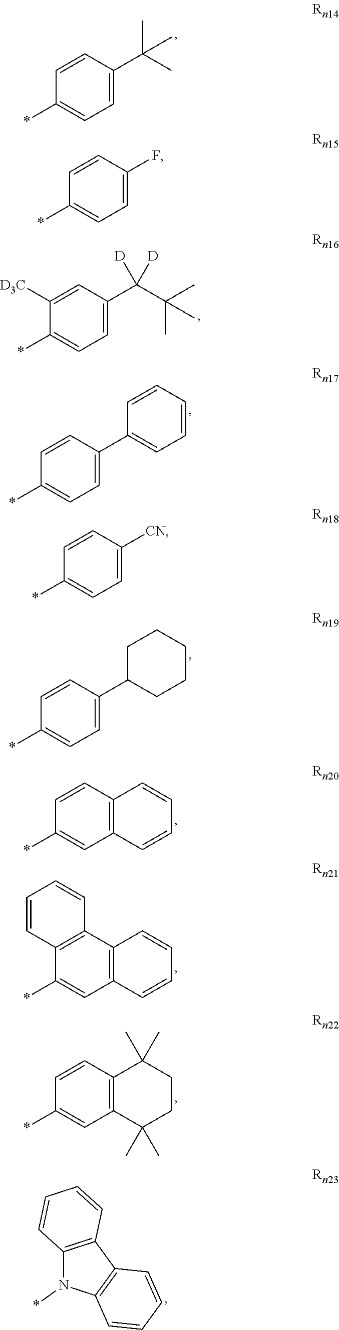 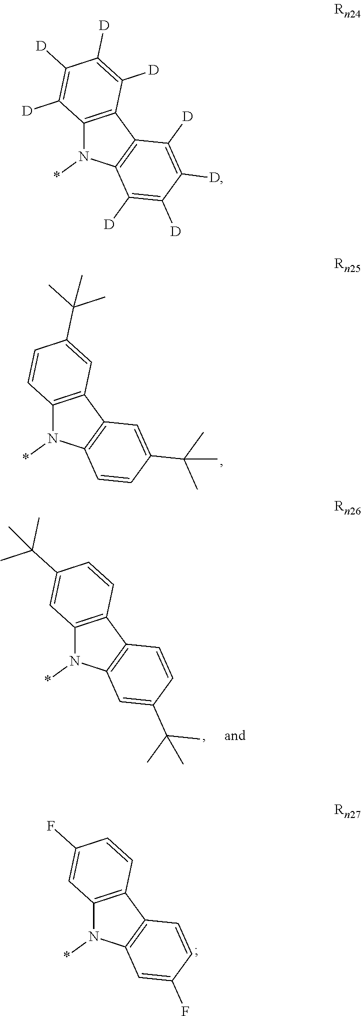
wherein optionally, hydrogens in Rₙ₁, Rₙ₃, Rₙ₅ to Rₙ₁₂, Rₙ₁₄ to Rₙ₂₃, and Rₙ₂₅ to Rₙ₂₇ can be partially or fully substituted with deuterium.

12. The organic electroluminescent device according to claim 11, wherein L_{b} is, at each occurrence identically or differently, selected from the group consisting of L_{b1}, to L_{b160}, the L_{b1} to L_{b160} having the following structures: 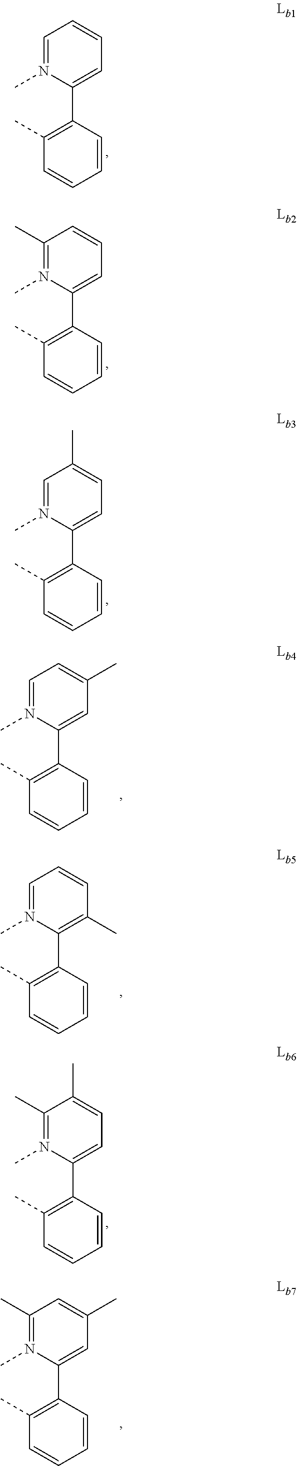 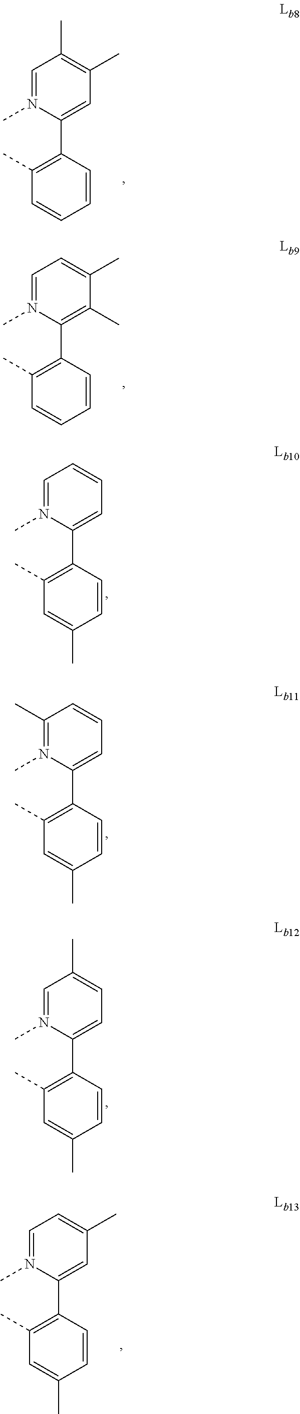 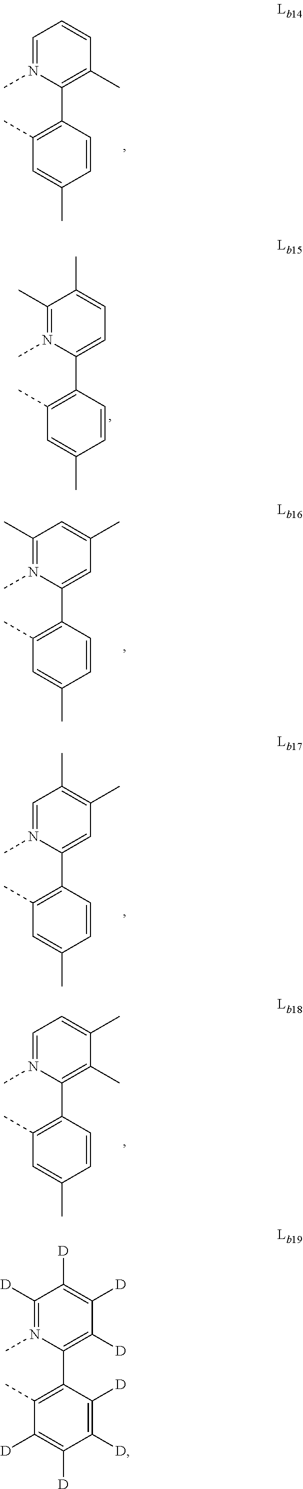 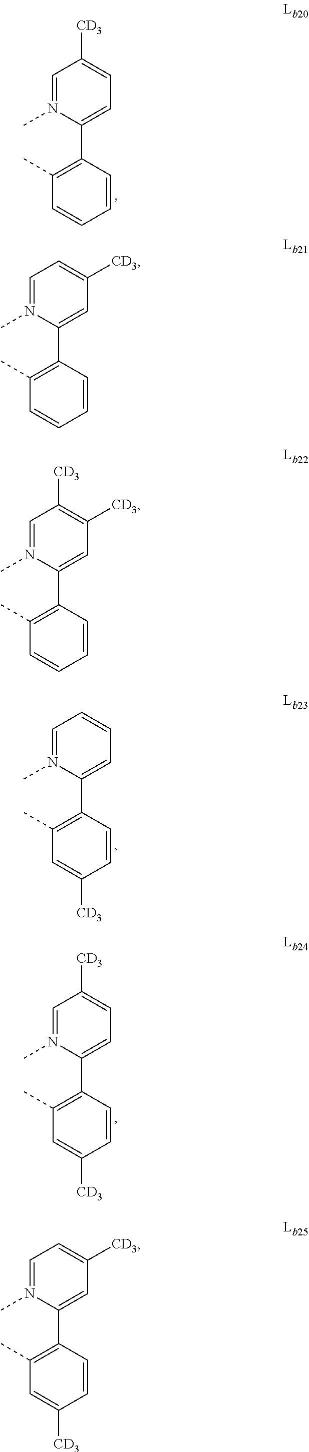 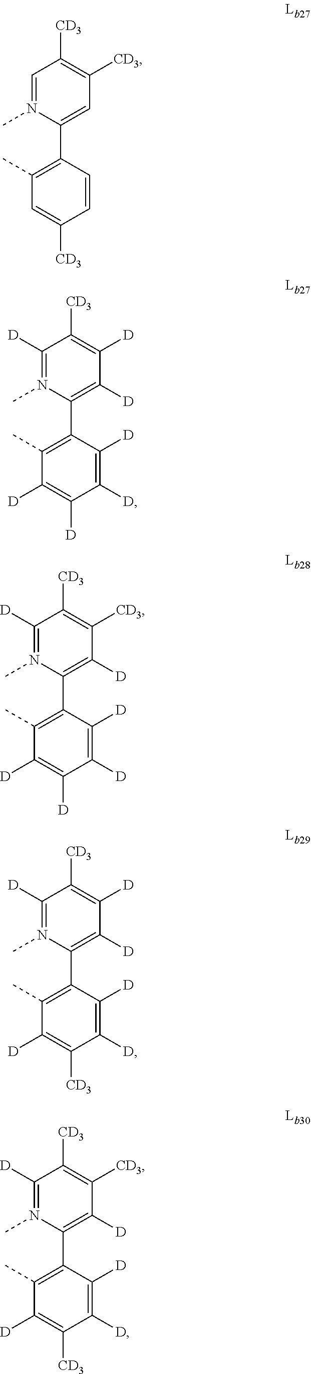 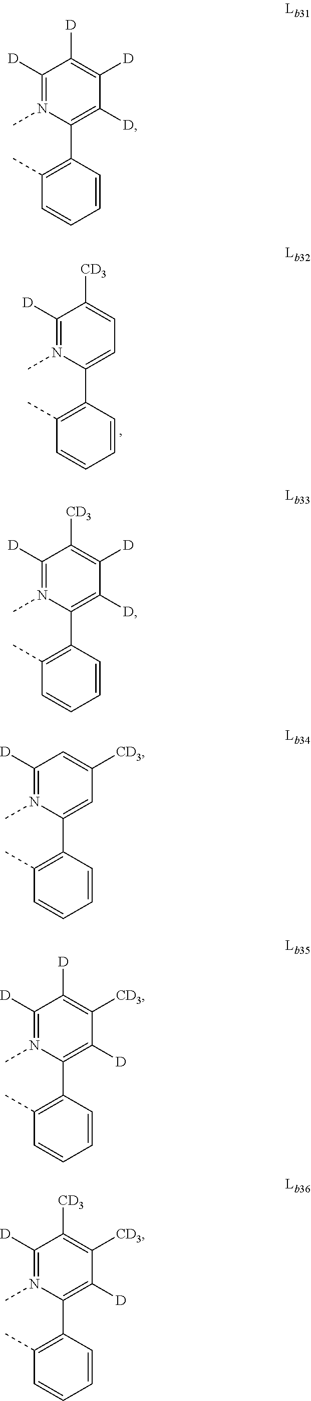 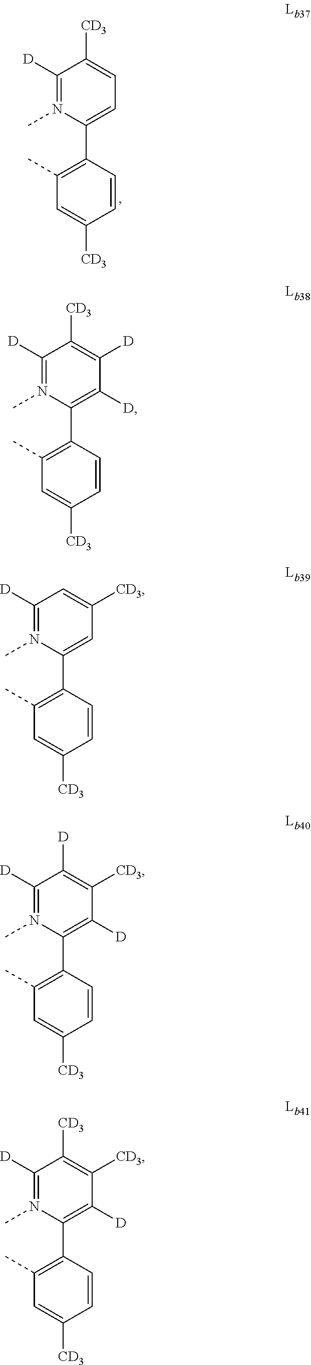 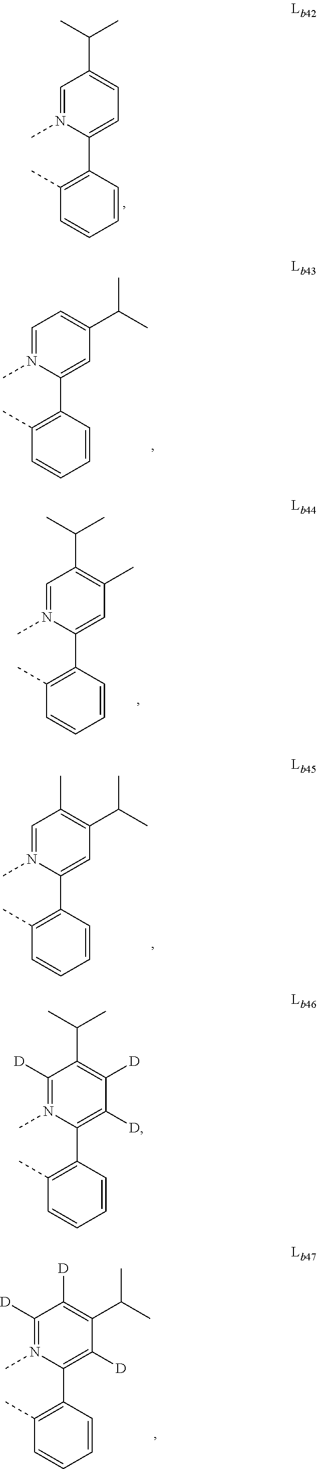 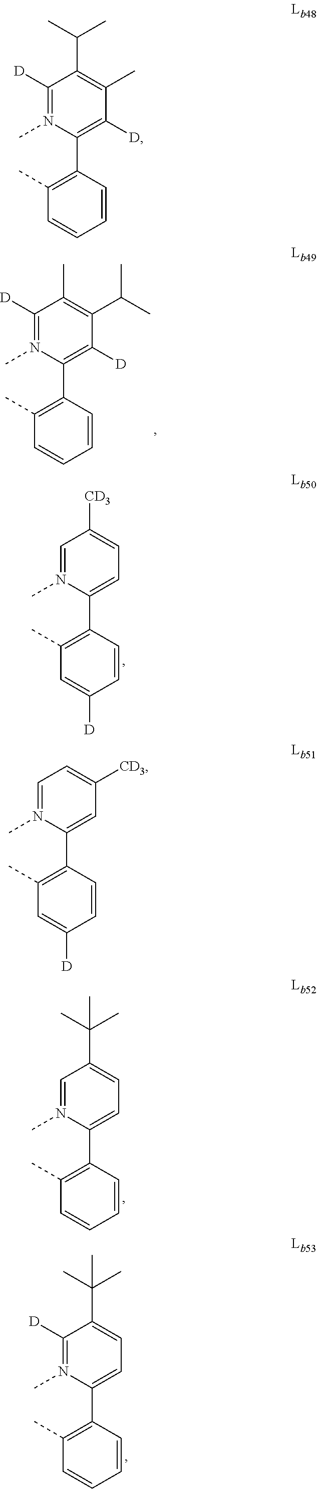 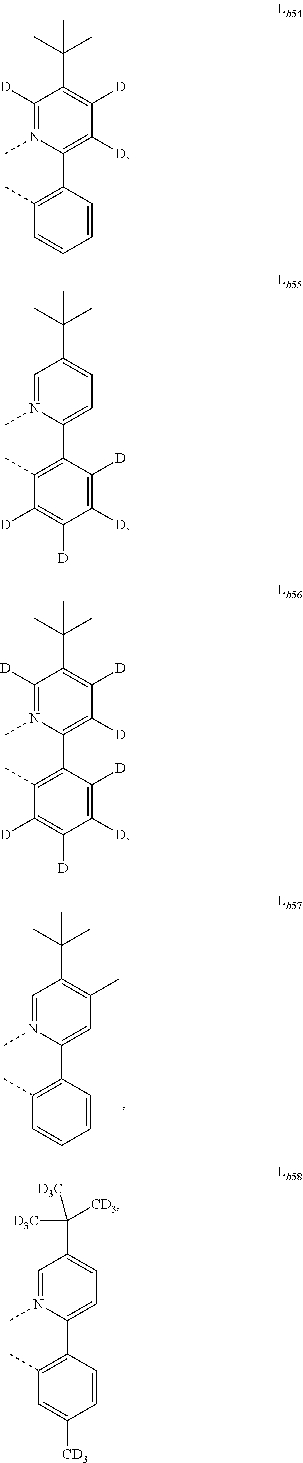 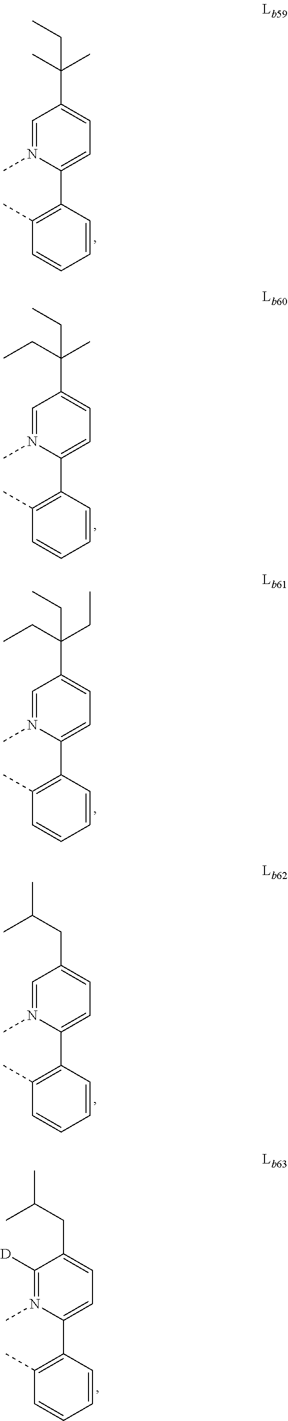 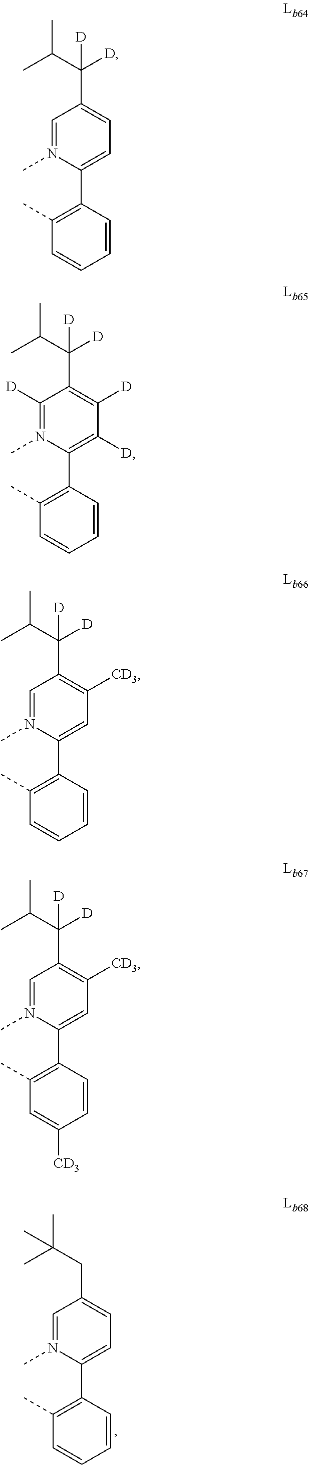 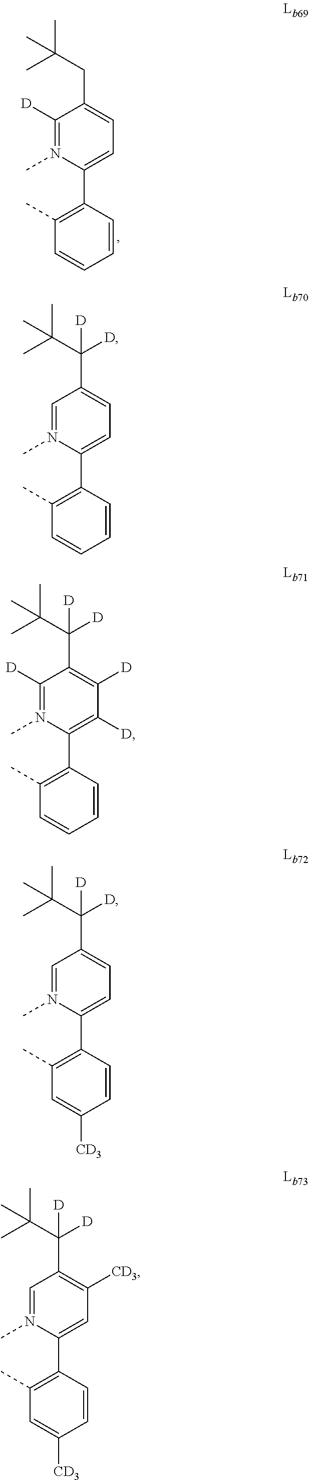 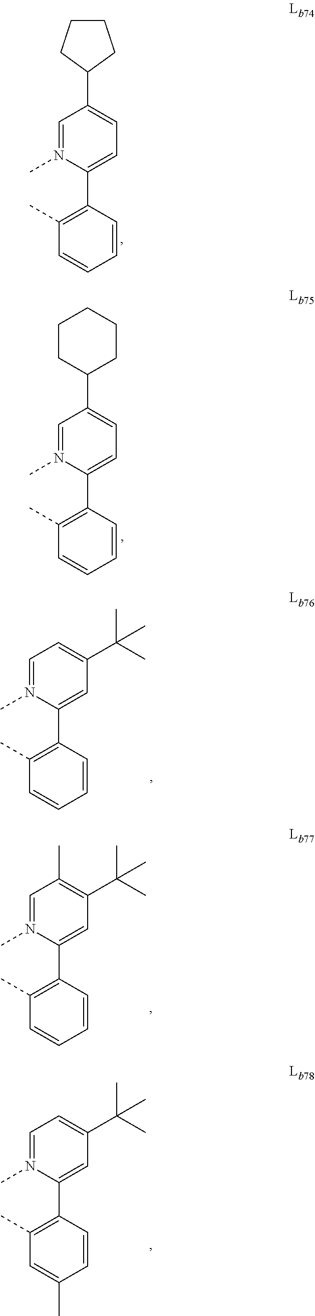 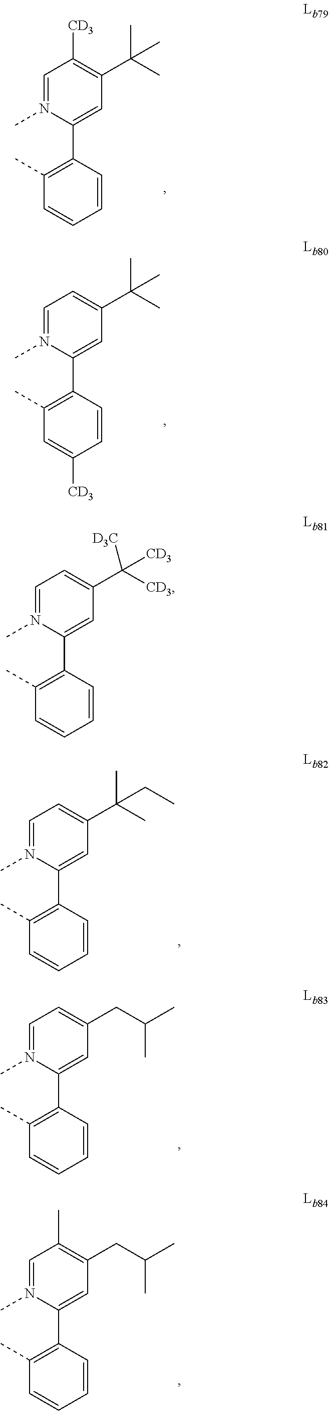 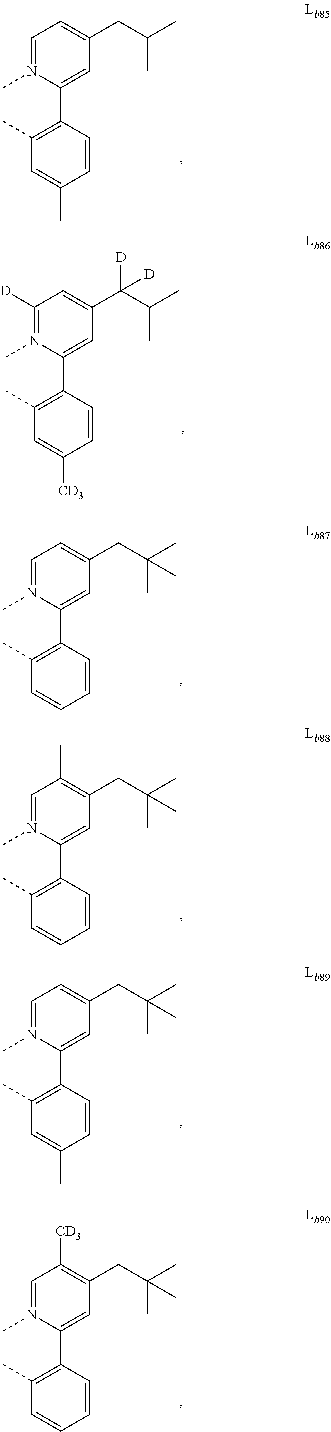 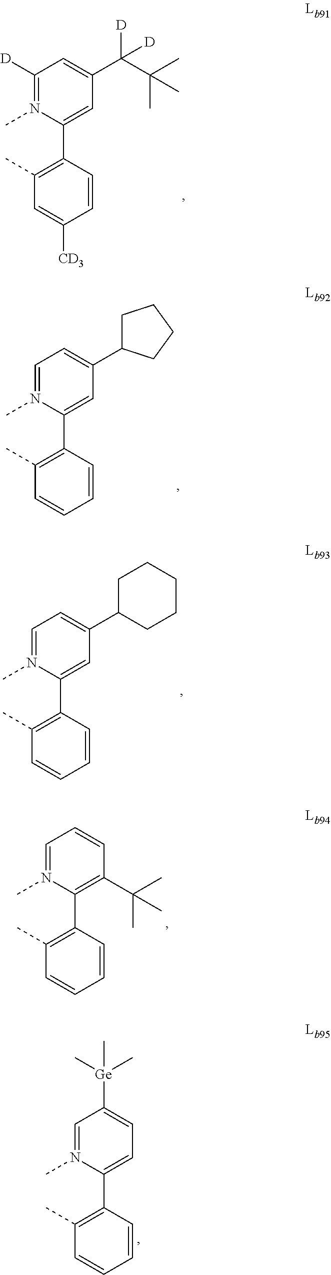 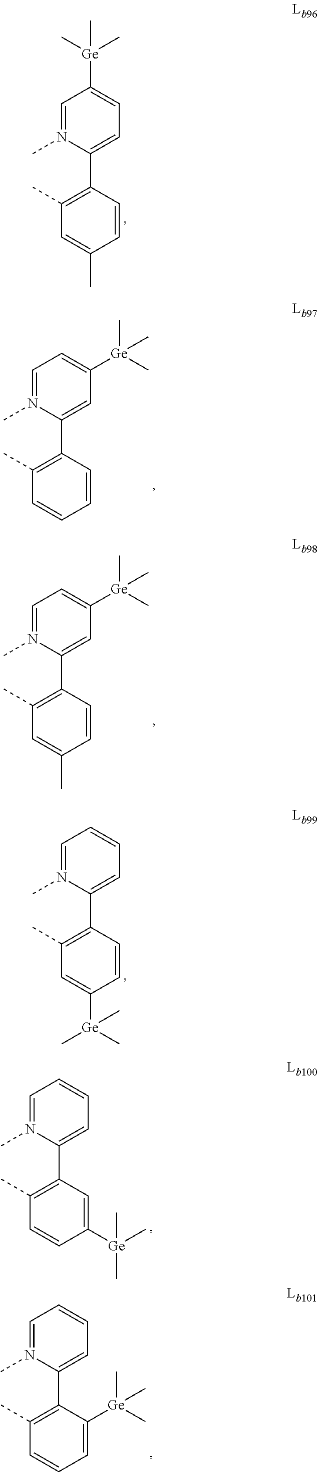 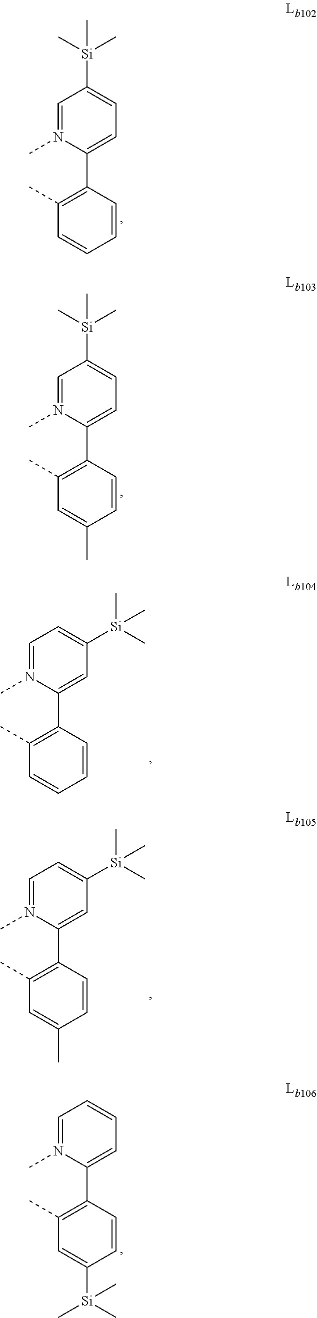 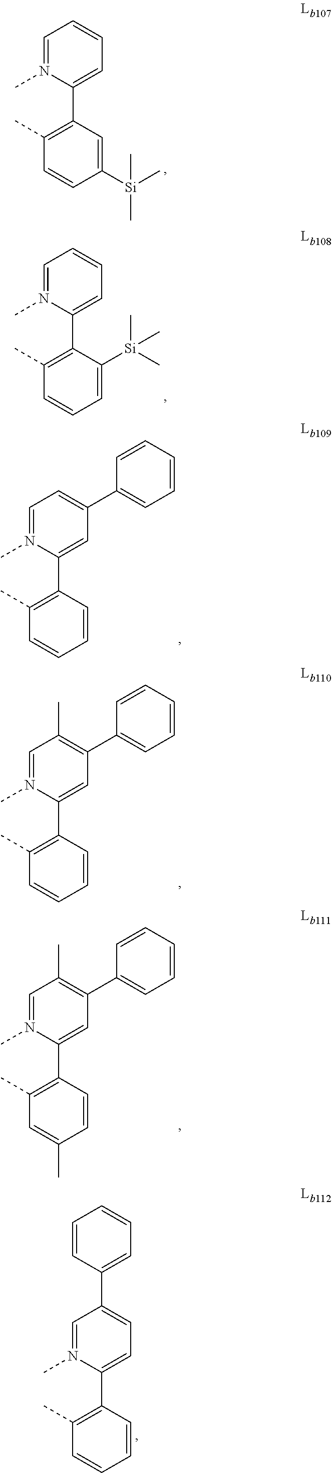 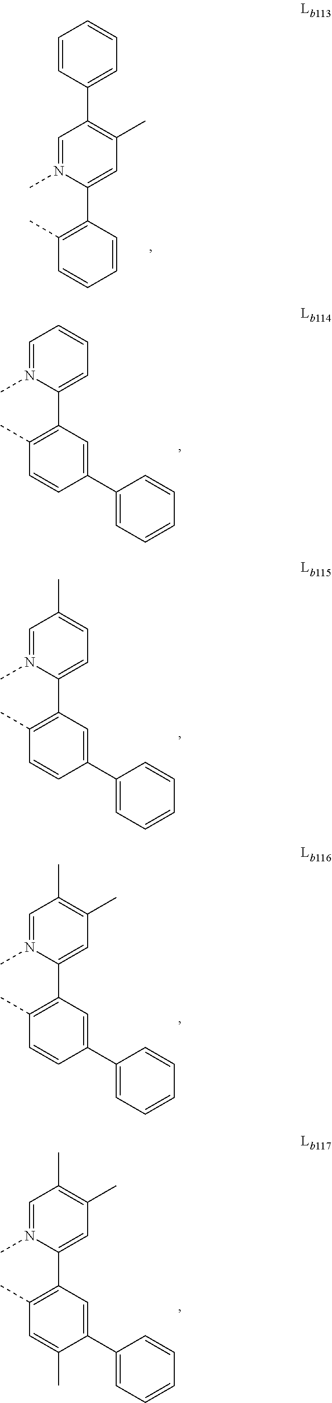 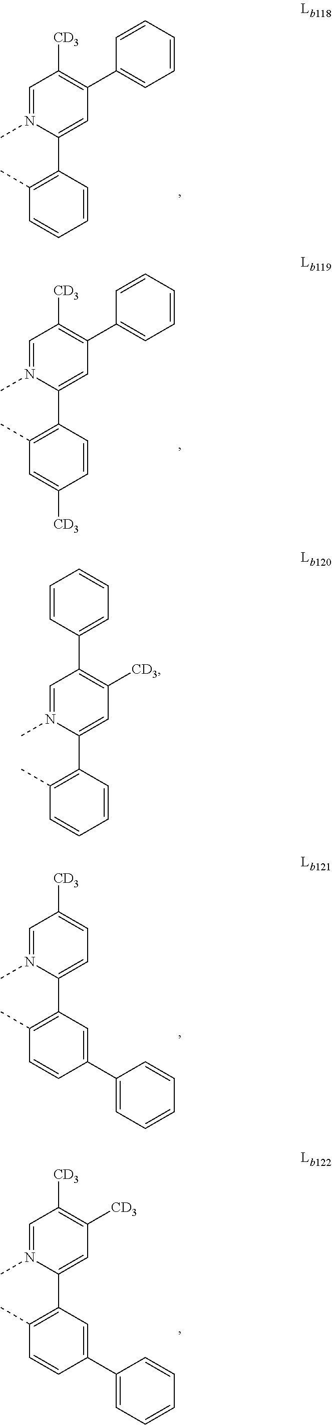 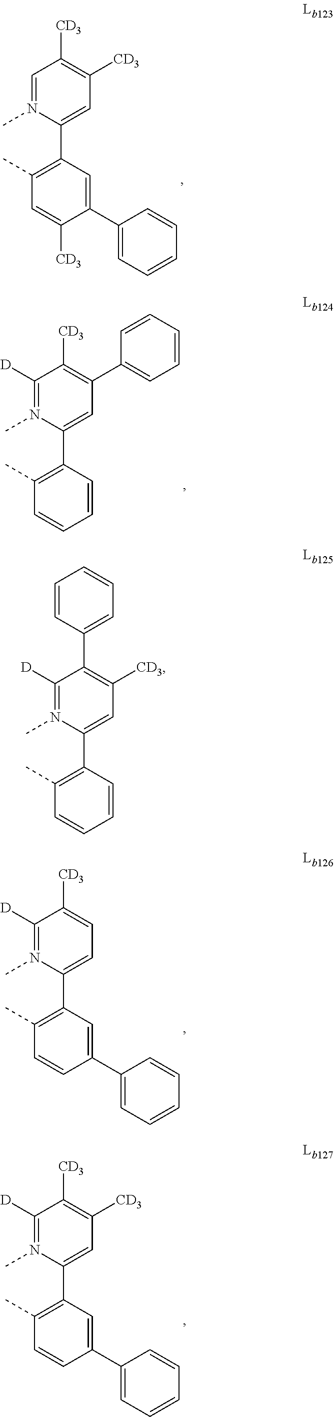 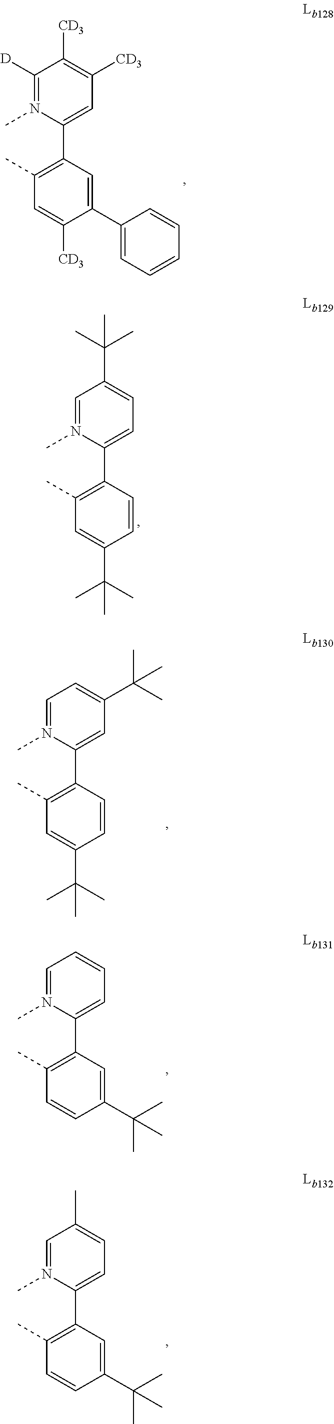 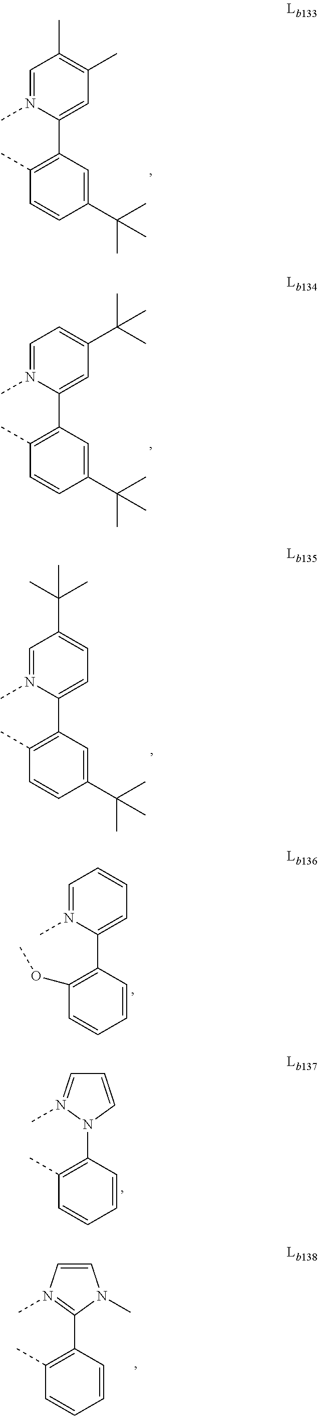 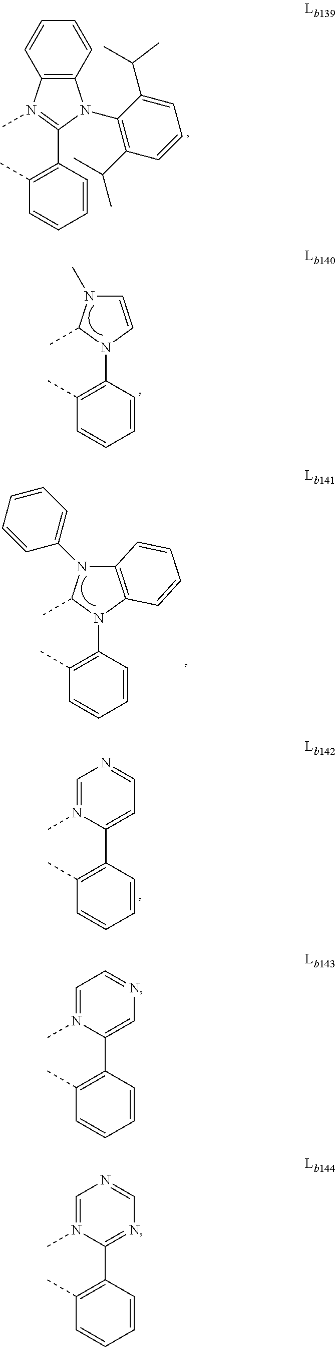 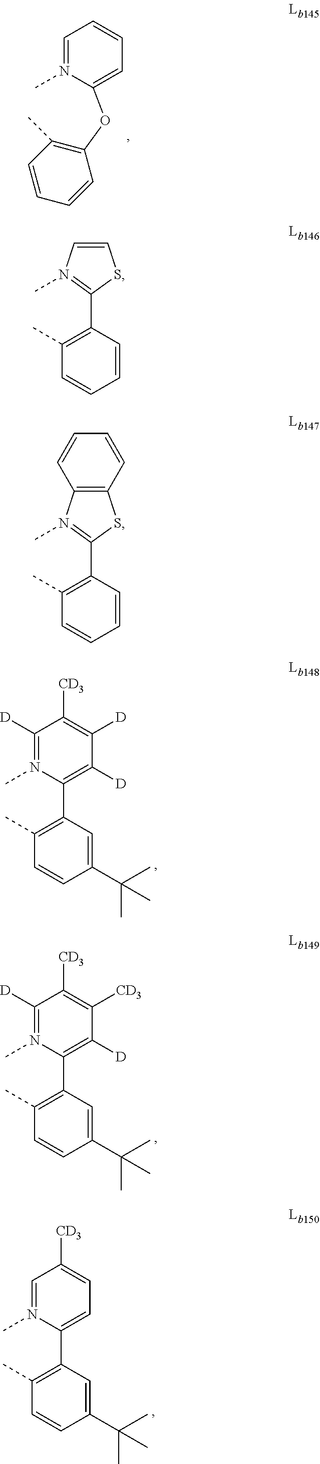 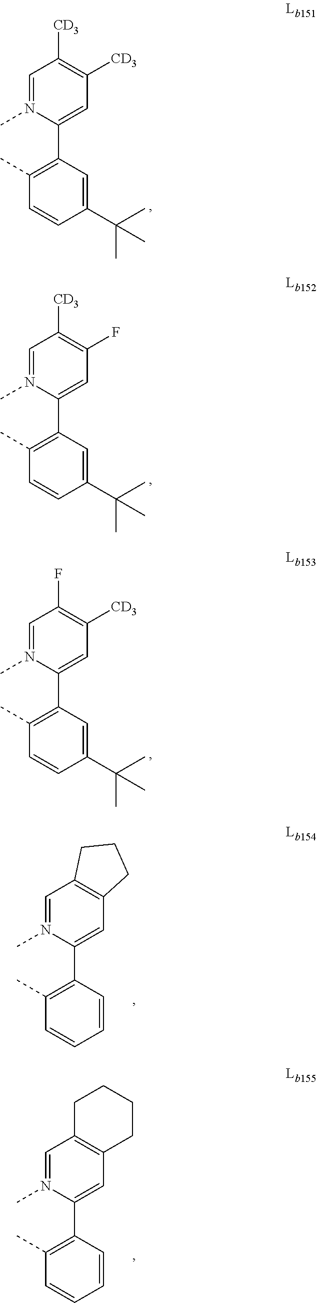 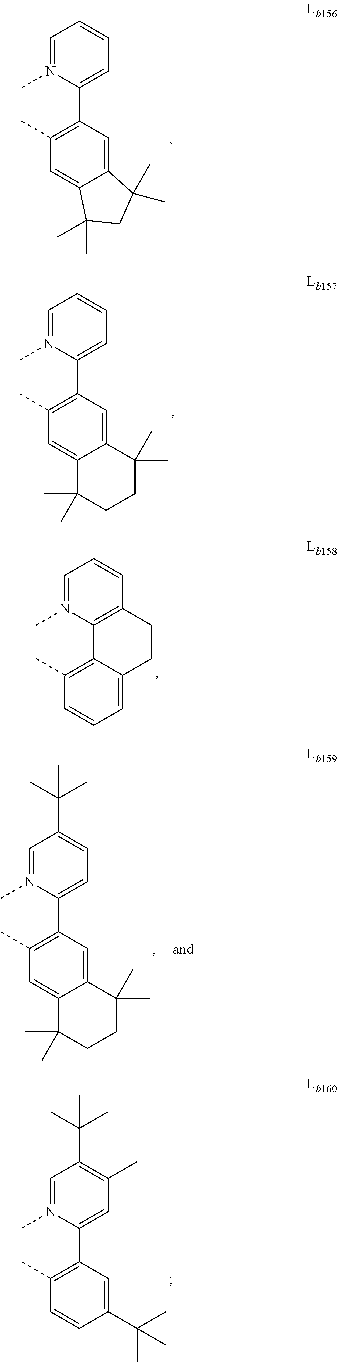
wherein optionally, hydrogens in L_{b1} to L_{b18}, L_{b20} to L_{b26}, and L_{b31} to L_{b160} can be partially or fully substituted with deutenium.

13. The organic electroluminescent device according to claim 12, wherein the metal complex has a structure of Ir(Lₐ)(L_{b})₂, wherein the two L_{b} are the same or different, Lₐ is, at each occurrence identically or differently, selected from the group consisting of Lₐ₁, to Lₐ₁₄₇₄, and L_{b} is, at each occurrence identically or differently, selected from one or two of the group consisting of L_{b1} to L_{b160};
preferably, the metal complex is selected from the group consisting of Metal Complex 1 to Metal Complex 1516, and Metal Complex 1 to Metal Complex 1516 each have a structure of Ir(Lₐ)(L_{b})₂, wherein the two L_{b} are the same, and Lₐ and L_{b} are selected from respective structures in the following table:

| Metal Complex | Lₐ | L_{b} | Metal Complex | Lₐ | L_{b} |
|---|---|---|---|---|---|
| 1 | Lₐ₂₈₉ | L_{b1} | 2 | Lₐ₂₉₆ | L_{b1} |
| 3 | Lₐ₃₀₄ | L_{b1} | 4 | Lₐ₃₁₁ | L_{b1} |
| 5 | Lₐ₃₁₆ | L_{b1} | 6 | Lₐ₃₃₂ | L_{b1} |
| 7 | Lₐ₄₄₆ | L_{b1} | 8 | Lₐ₄₄₉ | L_{b1} |
| 9 | Lₐ₄₅₂ | L_{b1} | 10 | Lₐ₄₅₅ | L_{b1} |
| 11 | Lₐ₄₆₇ | L_{b1} | 12 | Lₐ₄₇₀ | L_{b1} |
| 13 | Lₐ₄₇₃ | L_{b1} | 14 | Lₐ₄₈₂ | L_{b1} |
| 15 | Lₐ₄₈₃ | L_{b1} | 16 | Lₐ₄₈₅ | L_{b1} |
| 17 | Lₐ₄₈₈ | L_{b1} | 18 | Lₐ₄₉₁ | L_{b1} |
| 19 | Lₐ₄₉₄ | L_{b1} | 20 | Lₐ₅₀₆ | L_{b1} |
| 21 | Lₐ₅₁₂ | L_{b1} | 22 | Lₐ₅₂₄ | L_{b1} |
| 23 | Lₐ₅₂₇ | L_{b1} | 24 | Lₐ₅₃₀ | L_{b1} |
| 25 | Lₐ₅₃₃ | L_{b1} | 26 | Lₐ₅₃₆ | L_{b1} |
| 27 | Lₐ₅₄₂ | L_{b1} | 28 | Lₐ₅₄₅ | L_{b1} |
| 29 | Lₐ₅₅₄ | L_{b1} | 30 | Lₐ₅₆₃ | L_{b1} |
| 31 | Lₐ₅₇₂ | L_{b1} | 32 | Lₐ₅₇₈ | L_{b1} |
| 33 | Lₐ₅₈₀ | L_{b1} | 34 | Lₐ₅₈₃ | L_{b1} |
| 35 | Lₐ₅₈₆ | L_{b1} | 36 | Lₐ₅₉₀ | L_{b1} |
| 37 | Lₐ₅₉₉ | L_{b1} | 38 | Lₐ₆₀₈ | L_{b1} |
| 39 | Lₐ₆₁₇ | L_{b1} | 40 | Lₐ₆₄₆ | L_{b1} |
| 41 | Lₐ₆₅₀ | L_{b1} | 42 | Lₐ₆₅₃ | L_{b1} |
| 43 | Lₐ₆₅₆ | L_{b1} | 44 | Lₐ₆₅₉ | L_{b1} |
| 45 | Lₐ₆₆₅ | L_{b1} | 46 | Lₐ₆₇₁ | L_{b1} |
| 47 | Lₐ₆₇₇ | L_{b1} | 48 | Lₐ₆₈₃ | L_{b1} |
| 49 | Lₐ₆₈₉ | L_{b1} | 50 | Lₐ₆₉₂ | L_{b1} |
| 51 | Lₐ₆₉₅ | L_{b1} | 52 | Lₐ₆₉₈ | L_{b1} |
| 53 | Lₐ₇₀₄ | L_{b1} | 54 | Lₐ₇₂₈ | L_{b1} |
| 55 | Lₐ₇₃₁ | L_{b1} | 56 | Lₐ₇₃₄ | L_{b1} |
| 57 | Lₐ₇₃₇ | L_{b1} | 58 | Lₐ₇₄₀ | L_{b1} |
| 59 | Lₐ₇₄₃ | L_{b1} | 60 | Lₐ₇₄₉ | L_{b1} |
| 61 | Lₐ₇₅₅ | L_{b1} | 62 | Lₐ₇₅₇ | L_{b1} |
| 63 | Lₐ₇₆₁ | L_{b1} | 64 | Lₐ₇₆₄ | L_{b1} |
| 65 | Lₐ₇₆₅ | L_{b1} | 66 | Lₐ₈₀₆ | L_{b1} |
| 67 | Lₐ₈₀₉ | L_{b1} | 68 | Lₐ₈₁₂ | L_{b1} |
| 69 | Lₐ₈₁₈ | L_{b1} | 70 | Lₐ₈₄₈ | L_{b1} |
| 71 | Lₐ₈₅₁ | L_{b1} | 72 | Lₐ₈₈₄ | L_{b1} |
| 73 | Lₐ₈₈₇ | L_{b1} | 74 | Lₐ₈₉₀ | L_{b1} |
| 75 | Lₐ₈₉₃ | L_{b1} | 76 | Lₐ₈₉₆ | L_{b1} |
| 77 | Lₐ₈₉₉ | L_{b1} | 78 | Lₐ₉₀₃ | L_{b1} |
| 79 | Lₐ₉₀₅ | L_{b1} | 80 | Lₐ₉₀₉ | L_{b1} |
| 81 | Lₐ₉₁₁ | L_{b1} | 82 | Lₐ₉₁₄ | L_{b1} |
| 83 | Lₐ₉₁₇ | L_{b1} | 84 | Lₐ₉₂₀ | L_{b1} |
| 85 | Lₐ₉₂₁ | L_{b1} | 86 | Lₐ₉₆₂ | L_{b1} |
| 87 | Lₐ₉₆₃ | L_{b1} | 88 | Lₐ₉₆₅ | L_{b1} |
| 89 | Lₐ₉₆₉ | L_{b1} | 90 | Lₐ₉₇₁ | L_{b1} |
| 91 | Lₐ₉₇₄ | L_{b1} | 92 | Lₐ₉₇₇ | L_{b1} |
| 93 | Lₐ₉₈₀ | L_{b1} | 94 | Lₐ₉₈₁ | L_{b1} |
| 95 | Lₐ₉₈₇ | L_{b1} | 96 | Lₐ₉₈₉ | L_{b1} |
| 97 | Lₐ₉₉₃ | L_{b1} | 98 | Lₐ₉₉₅ | L_{b1} |
| 99 | Lₐ₉₉₈ | L_{b1} | 100 | Lₐ₉₉₉ | L_{b1} |
| 101 | Lₐ₁₀₀₀ | L_{b1} | 102 | Lₐ₁₀₄₀ | L_{b1} |
| 103 | Lₐ₁₀₄₃ | L_{b1} | 104 | Lₐ₁₀₄₆ | L_{b1} |
| 105 | Lₐ₁₂₈₆ | L_{b1} | 106 | Lₐ₁₂₉₂ | L_{b1} |
| 107 | Lₐ₁₂₉₃ | L_{b1} | 108 | Lₐ₁₃₀₄ | L_{b1} |
| 109 | Lₐ₁₃₁₆ | L_{b1} | 110 | Lₐ₁₃₂₈ | L_{b1} |
| 111 | Lₐ₁₃₆₄ | L_{b1} | 112 | Lₐ₁₃₆₅ | L_{b1} |
| 113 | Lₐ₁₃₈₅ | L_{b1} | 114 | Lₐ₁₃₈₆ | L_{b1} |
| 115 | Lₐ₁₄₀₀ | L_{b1} | 116 | Lₐ₁₄₀₁ | L_{b1} |
| 117 | Lₐ₂₈₉ | L_{b3} | 118 | Lₐ₂₉₆ | L_{b3} |
| 119 | Lₐ₃₀₄ | L_{b3} | 120 | Lₐ₃₁₁ | L_{b3} |
| 121 | Lₐ₃₁₆ | L_{b3} | 122 | Lₐ₃₃₂ | L_{b3} |
| 123 | Lₐ₄₄₆ | L_{b3} | 124 | Lₐ₄₄₉ | L_{b3} |
| 125 | Lₐ₄₅₂ | L_{b3} | 126 | Lₐ₄₅₅ | L_{b3} |
| 127 | Lₐ₄₆₇ | L_{b3} | 128 | Lₐ₄₇₀ | L_{b3} |
| 129 | Lₐ₄₇₃ | L_{b3} | 130 | Lₐ₄₈₂ | L_{b3} |
| 131 | Lₐ₄₈₃ | L_{b3} | 132 | Lₐ₄₈₅ | L_{b3} |
| 133 | Lₐ₄₈₈ | L_{b3} | 134 | Lₐ₄₉₁ | L_{b3} |
| 135 | Lₐ₄₉₄ | L_{b3} | 136 | Lₐ₅₀₆ | L_{b3} |
| 137 | Lₐ₅₁₂ | L_{b3} | 138 | Lₐ₅₂₄ | L_{b3} |
| 139 | Lₐ₅₂₇ | L_{b3} | 140 | Lₐ₅₃₀ | L_{b3} |
| 141 | Lₐ₅₃₃ | L_{b3} | 142 | Lₐ₅₃₆ | L_{b3} |
| 143 | Lₐ₅₄₂ | L_{b3} | 144 | Lₐ₅₄₅ | L_{b3} |
| 145 | Lₐ₅₅₄ | L_{b3} | 146 | Lₐ₅₆₃ | L_{b3} |
| 147 | Lₐ₅₇₂ | L_{b3} | 148 | Lₐ₅₇₈ | L_{b3} |
| 149 | Lₐ₅₈₀ | L_{b3} | 150 | Lₐ₅₈₃ | L_{b3} |
| 151 | Lₐ₅₈₆ | L_{b3} | 152 | Lₐ₅₉₀ | L_{b3} |
| 153 | Lₐ₅₉₉ | L_{b3} | 154 | Lₐ₆₀₈ | L_{b3} |
| 155 | Lₐ₆₁₇ | L_{b3} | 156 | Lₐ₆₄₆ | L_{b3} |
| 157 | Lₐ₆₅₀ | L_{b3} | 158 | Lₐ₆₅₃ | L_{b3} |
| 159 | Lₐ₆₅₆ | L_{b3} | 160 | Lₐ₆₅₉ | L_{b3} |
| 161 | Lₐ₆₆₅ | L_{b3} | 162 | Lₐ₆₇₁ | L_{b3} |
| 163 | Lₐ₆₇₇ | L_{b3} | 164 | Lₐ₆₈₃ | L_{b3} |
| 165 | Lₐ₆₈₉ | L_{b3} | 166 | Lₐ₆₉₂ | L_{b3} |
| 167 | Lₐ₆₉₅ | L_{b3} | 168 | Lₐ₆₉₈ | L_{b3} |
| 169 | Lₐ₇₀₄ | L_{b3} | 170 | Lₐ₇₂₈ | L_{b3} |
| 171 | Lₐ₇₃₁ | L_{b3} | 172 | Lₐ₇₃₄ | L_{b3} |
| 173 | Lₐ₇₃₇ | L_{b3} | 174 | Lₐ₇₄₀ | L_{b3} |
| 175 | Lₐ₇₄₃ | L_{b3} | 176 | Lₐ₇₄₉ | L_{b3} |
| 177 | Lₐ₇₅₅ | L_{b3} | 178 | Lₐ₇₅₇ | L_{b3} |
| 179 | Lₐ₇₆₁ | L_{b3} | 180 | Lₐ₇₆₄ | L_{b3} |
| 181 | Lₐ₇₆₅ | L_{b3} | 182 | Lₐ₈₀₆ | L_{b3} |
| 183 | Lₐ₈₀₉ | L_{b3} | 184 | Lₐ₈₁₂ | L_{b3} |
| 185 | Lₐ₈₁₈ | L_{b3} | 186 | Lₐ₈₄₈ | L_{b3} |
| 187 | Lₐ₈₅₁ | L_{b3} | 188 | Lₐ₈₈₄ | L_{b3} |
| 189 | Lₐ₈₈₇ | L_{b3} | 190 | Lₐ₈₉₀ | L_{b3} |
| 191 | Lₐ₈₉₃ | L_{b3} | 192 | Lₐ₈₉₆ | L_{b3} |
| 193 | Lₐ₈₉₉ | L_{b3} | 194 | Lₐ₉₀₃ | L_{b3} |
| 195 | Lₐ₉₀₅ | L_{b3} | 196 | Lₐ₉₀₉ | L_{b3} |
| 197 | Lₐ₉₁₁ | L_{b3} | 198 | Lₐ₉₁₄ | L_{b3} |
| 199 | Lₐ₉₁₇ | L_{b3} | 200 | Lₐ₉₂₀ | L_{b3} |
| 201 | Lₐ₉₂₁ | L_{b3} | 202 | Lₐ₉₆₂ | L_{b3} |
| 203 | Lₐ₉₆₃ | L_{b3} | 204 | Lₐ₉₆₅ | L_{b3} |
| 205 | Lₐ₉₆₉ | L_{b3} | 206 | Lₐ₉₇₁ | L_{b3} |
| 207 | Lₐ₉₇₄ | L_{b3} | 208 | Lₐ₉₇₇ | L_{b3} |
| 209 | Lₐ₉₈₀ | L_{b3} | 210 | Lₐ₉₈₁ | L_{b3} |
| 211 | Lₐ₉₈₇ | L_{b3} | 212 | Lₐ₉₈₉ | L_{b3} |
| 213 | Lₐ₉₉₃ | L_{b3} | 214 | Lₐ₉₉₅ | L_{b3} |
| 215 | Lₐ₉₉₈ | L_{b3} | 216 | Lₐ₉₉₉ | L_{b3} |
| 217 | Lₐ₁₀₀₀ | L_{b3} | 218 | Lₐ₁₀₄₀ | L_{b3} |
| 219 | Lₐ₁₀₄₃ | L_{b3} | 220 | Lₐ₁₀₄₆ | L_{b3} |
| 221 | Lₐ₁₂₈₆ | L_{b3} | 222 | Lₐ₁₂₉₂ | L_{b3} |
| 223 | Lₐ₁₂₉₃ | L_{b3} | 224 | Lₐ₁₃₀₄ | L_{b3} |
| 225 | Lₐ₁₃₁₆ | L_{b3} | 226 | Lₐ₁₃₂₈ | L_{b3} |
| 227 | Lₐ₁₃₆₄ | L_{b3} | 228 | Lₐ₁₃₆₅ | L_{b3} |
| 229 | Lₐ₁₃₈₅ | L_{b3} | 230 | Lₐ₁₃₈₆ | L_{b3} |
| 231 | Lₐ₁₄₀₀ | L_{b3} | 232 | Lₐ₁₄₀₁ | L_{b3} |
| 233 | Lₐ₂₈₉ | L_{b8} | 234 | Lₐ₂₉₆ | L_{b8} |
| 235 | Lₐ₃₀₄ | L_{b8} | 236 | Lₐ₃₁₁ | L_{b8} |
| 237 | Lₐ₃₁₆ | L_{b8} | 238 | Lₐ₃₃₂ | L_{b8} |
| 239 | Lₐ₄₄₆ | L_{b8} | 240 | Lₐ₄₄₉ | L_{b8} |
| 241 | Lₐ₄₅₂ | L_{b8} | 242 | Lₐ₄₅₅ | L_{b8} |
| 243 | Lₐ₄₆₇ | L_{b8} | 244 | Lₐ₄₇₀ | L_{b8} |
| 245 | Lₐ₄₇₃ | L_{b8} | 246 | Lₐ₄₈₂ | L_{b8} |
| 247 | Lₐ₄₈₃ | L_{b8} | 248 | Lₐ₄₈₅ | L_{b8} |
| 249 | Lₐ₄₈₈ | L_{b8} | 250 | Lₐ₄₉₁ | L_{b8} |
| 251 | Lₐ₄₉₄ | L_{b8} | 252 | Lₐ₅₀₆ | L_{b8} |
| 253 | Lₐ₅₁₂ | L_{b8} | 254 | Lₐ₅₂₄ | L_{b8} |
| 255 | Lₐ₅₂₇ | L_{b8} | 256 | Lₐ₅₃₀ | L_{b8} |
| 257 | Lₐ₅₃₃ | L_{b8} | 258 | Lₐ₅₃₆ | L_{b8} |
| 259 | Lₐ₅₄₂ | L_{b8} | 260 | Lₐ₅₄₅ | L_{b8} |
| 261 | Lₐ₅₅₄ | L_{b8} | 262 | Lₐ₅₆₃ | L_{b8} |
| 263 | Lₐ₅₇₂ | L_{b8} | 264 | Lₐ₅₇₈ | L_{b8} |
| 265 | Lₐ₅₈₀ | L_{b8} | 266 | Lₐ₅₈₃ | L_{b8} |
| 267 | Lₐ₅₈₆ | L_{b8} | 268 | Lₐ₅₉₀ | L_{b8} |
| 269 | Lₐ₅₉₉ | L_{b8} | 270 | Lₐ₆₀₈ | L_{b8} |
| 271 | Lₐ₆₁₇ | L_{b8} | 272 | Lₐ₆₄₆ | L_{b8} |
| 273 | Lₐ₆₅₀ | L_{b8} | 274 | Lₐ₆₅₃ | L_{b8} |
| 275 | Lₐ₆₅₆ | L_{b8} | 276 | Lₐ₆₅₉ | L_{b8} |
| 277 | Lₐ₆₆₅ | L_{b8} | 278 | Lₐ₆₇₁ | L_{b8} |
| 279 | Lₐ₆₇₇ | L_{b8} | 280 | Lₐ₆₈₃ | L_{b8} |
| 281 | Lₐ₆₈₉ | L_{b8} | 282 | Lₐ₆₉₂ | L_{b8} |
| 283 | Lₐ₆₉₅ | L_{b8} | 284 | Lₐ₆₉₈ | L_{b8} |
| 285 | Lₐ₇₀₄ | L_{b8} | 286 | Lₐ₇₂₈ | L_{b8} |
| 287 | Lₐ₇₃₁ | L_{b8} | 288 | Lₐ₇₃₄ | L_{b8} |
| 289 | Lₐ₇₃₇ | L_{b8} | 290 | Lₐ₇₄₀ | L_{b8} |
| 291 | Lₐ₇₄₃ | L_{b8} | 292 | Lₐ₇₄₉ | L_{b8} |
| 293 | Lₐ₇₅₅ | L_{b8} | 294 | Lₐ₇₅₇ | L_{b8} |
| 295 | Lₐ₇₆₁ | L_{b8} | 296 | Lₐ₇₆₄ | L_{b8} |
| 297 | Lₐ₇₆₅ | L_{b8} | 298 | Lₐ₈₀₆ | L_{b8} |
| 299 | Lₐ₈₀₉ | L_{b8} | 300 | Lₐ₈₁₂ | L_{b8} |
| 301 | Lₐ₈₁₈ | L_{b8} | 302 | Lₐ₈₄₈ | L_{b8} |
| 303 | Lₐ₈₅₁ | L_{b8} | 304 | Lₐ₈₈₄ | L_{b8} |
| 305 | Lₐ₈₈₇ | L_{b8} | 306 | Lₐ₈₉₀ | L_{b8} |
| 307 | Lₐ₈₉₃ | L_{b8} | 308 | Lₐ₈₉₆ | L_{b8} |
| 309 | Lₐ₈₉₉ | L_{b8} | 310 | Lₐ₉₀₃ | L_{b8} |
| 311 | Lₐ₉₀₅ | L_{b8} | 312 | Lₐ₉₀₉ | L_{b8} |
| 313 | Lₐ₉₁₁ | L_{b8} | 314 | Lₐ₉₁₄ | L_{b8} |
| 315 | Lₐ₉₁₇ | L_{b8} | 316 | Lₐ₉₂₀ | L_{b8} |
| 317 | Lₐ₉₂₁ | L_{b8} | 318 | Lₐ₉₆₂ | L_{b8} |
| 319 | Lₐ₉₆₃ | L_{b8} | 320 | Lₐ₉₆₅ | L_{b8} |
| 321 | Lₐ₉₆₉ | L_{b8} | 322 | Lₐ₉₇₁ | L_{b8} |
| 323 | Lₐ₉₇₄ | L_{b8} | 324 | Lₐ₉₇₇ | L_{b8} |
| 325 | Lₐ₉₈₀ | L_{b8} | 326 | Lₐ₉₈₁ | L_{b8} |
| 327 | Lₐ₉₈₇ | L_{b8} | 328 | Lₐ₉₈₉ | L_{b8} |
| 329 | Lₐ₉₉₃ | L_{b8} | 330 | Lₐ₉₉₅ | L_{b8} |
| 331 | Lₐ₉₉₈ | L_{b8} | 332 | Lₐ₉₉₉ | L_{b8} |
| 333 | Lₐ₁₀₀₀ | L_{b8} | 334 | Lₐ₁₀₄₀ | L_{b8} |
| 335 | Lₐ₁₀₄₃ | L_{b8} | 336 | Lₐ₁₀₄₆ | L_{b8} |
| 337 | Lₐ₁₂₈₆ | L_{b8} | 338 | Lₐ₁₂₉₂ | L_{b8} |
| 339 | Lₐ₁₂₉₃ | L_{b8} | 340 | Lₐ₁₃₀₄ | L_{b8} |
| 341 | Lₐ₁₃₁₆ | L_{b8} | 342 | Lₐ₁₃₂₈ | L_{b8} |
| 343 | Lₐ₁₃₆₄ | L_{b8} | 344 | Lₐ₁₃₆₅ | L_{b8} |
| 345 | Lₐ₁₃₈₅ | L_{b8} | 346 | Lₐ₁₃₈₆ | L_{b8} |
| 347 | Lₐ₁₄₀₀ | L_{b8} | 348 | Lₐ₁₄₀₁ | L_{b8} |
| 349 | Lₐ₂₈₉ | L_{b33} | 350 | Lₐ₂₉₆ | L_{b33} |
| 351 | Lₐ₃₀₄ | L_{b33} | 352 | Lₐ₃₁₁ | L_{b33} |
| 353 | Lₐ₃₁₆ | L_{b33} | 354 | Lₐ₃₃₂ | L_{b33} |
| 355 | Lₐ₄₄₆ | L_{b33} | 356 | Lₐ₄₄₉ | L_{b33} |
| 357 | Lₐ₄₅₂ | L_{b33} | 358 | Lₐ₄₅₅ | L_{b33} |
| 359 | Lₐ₄₆₇ | L_{b33} | 360 | Lₐ₄₇₀ | L_{b33} |
| 361 | Lₐ₄₇₃ | L_{b33} | 362 | Lₐ₄₈₂ | L_{b33} |
| 363 | Lₐ₄₈₃ | L_{b33} | 364 | Lₐ₄₈₅ | L_{b33} |
| 365 | Lₐ₄₈₈ | L_{b33} | 366 | Lₐ₄₉₁ | L_{b33} |
| 367 | Lₐ₄₉₄ | L_{b33} | 368 | Lₐ₅₀₆ | L_{b33} |
| 369 | Lₐ₅₁₂ | L_{b33} | 370 | Lₐ₅₂₄ | L_{b33} |
| 371 | Lₐ₅₂₇ | L_{b33} | 372 | Lₐ₅₃₀ | L_{b33} |
| 373 | Lₐ₅₃₃ | L_{b33} | 374 | Lₐ₅₃₆ | L_{b33} |
| 375 | Lₐ₅₄₂ | L_{b33} | 376 | Lₐ₅₄₅ | L_{b33} |
| 377 | Lₐ₅₅₄ | L_{b33} | 378 | Lₐ₅₆₃ | L_{b33} |
| 379 | Lₐ₅₇₂ | L_{b33} | 380 | Lₐ₅₇₈ | L_{b33} |
| 381 | Lₐ₅₈₀ | L_{b33} | 382 | Lₐ₅₈₃ | L_{b33} |
| 383 | Lₐ₅₈₆ | L_{b33} | 384 | Lₐ₅₉₀ | L_{b33} |
| 385 | Lₐ₅₉₉ | L_{b33} | 386 | Lₐ₆₀₈ | L_{b33} |
| 387 | Lₐ₆₁₇ | L_{b33} | 388 | Lₐ₆₄₆ | L_{b33} |
| 389 | Lₐ₆₅₀ | L_{b33} | 390 | Lₐ₆₅₃ | L_{b33} |
| 391 | Lₐ₆₅₆ | L_{b33} | 392 | Lₐ₆₅₉ | L_{b33} |
| 393 | Lₐ₆₆₅ | L_{b33} | 394 | Lₐ₆₇₁ | L_{b33} |
| 395 | Lₐ₆₇₇ | L_{b33} | 396 | Lₐ₆₈₃ | L_{b33} |
| 397 | Lₐ₆₈₉ | L_{b33} | 398 | Lₐ₆₉₂ | L_{b33} |
| 399 | Lₐ₆₉₅ | L_{b33} | 400 | Lₐ₆₉₈ | L_{b33} |
| 401 | Lₐ₇₀₄ | L_{b33} | 402 | Lₐ₇₂₈ | L_{b33} |
| 403 | Lₐ₇₃₁ | L_{b33} | 404 | Lₐ₇₃₄ | L_{b33} |
| 405 | Lₐ₇₃₇ | L_{b33} | 406 | Lₐ₇₄₀ | L_{b33} |
| 407 | Lₐ₇₄₃ | L_{b33} | 408 | Lₐ₇₄₉ | L_{b33} |
| 409 | Lₐ₇₅₅ | L_{b33} | 410 | Lₐ₇₅₇ | L_{b33} |
| 411 | Lₐ₇₆₁ | L_{b33} | 412 | Lₐ₇₆₄ | L_{b33} |
| 413 | Lₐ₇₆₅ | L_{b33} | 414 | Lₐ₈₀₆ | L_{b33} |
| 415 | Lₐ₈₀₉ | L_{b33} | 416 | Lₐ₈₁₂ | L_{b33} |
| 417 | Lₐ₈₁₈ | L_{b33} | 418 | Lₐ₈₄₈ | L_{b33} |
| 419 | Lₐ₈₅₁ | L_{b33} | 420 | Lₐ₈₈₄ | L_{b33} |
| 421 | Lₐ₈₈₇ | L_{b33} | 422 | Lₐ₈₉₀ | L_{b33} |
| 423 | Lₐ₈₉₃ | L_{b33} | 424 | Lₐ₈₉₆ | L_{b33} |
| 425 | Lₐ₈₉₉ | L_{b33} | 426 | Lₐ₉₀₃ | L_{b33} |
| 427 | Lₐ₉₀₅ | L_{b33} | 428 | Lₐ₉₀₉ | L_{b33} |
| 429 | Lₐ₉₁₁ | L_{b33} | 430 | Lₐ₉₁₄ | L_{b33} |
| 431 | Lₐ₉₁₇ | L_{b33} | 432 | Lₐ₉₂₀ | L_{b33} |
| 433 | Lₐ₉₂₁ | L_{b33} | 434 | Lₐ₉₆₂ | L_{b33} |
| 435 | Lₐ₉₆₃ | L_{b33} | 436 | Lₐ₉₆₅ | L_{b33} |
| 437 | Lₐ₉₆₉ | L_{b33} | 438 | Lₐ₉₇₁ | L_{b33} |
| 439 | Lₐ₉₇₄ | L_{b33} | 440 | Lₐ₉₇₇ | L_{b33} |
| 441 | Lₐ₉₈₀ | L_{b33} | 442 | Lₐ₉₈₁ | L_{b33} |
| 443 | Lₐ₉₈₇ | L_{b33} | 444 | Lₐ₉₈₉ | L_{b33} |
| 445 | Lₐ₉₉₃ | L_{b33} | 446 | Lₐ₉₉₅ | L_{b33} |
| 447 | Lₐ₉₉₈ | L_{b33} | 448 | Lₐ₉₉₉ | L_{b33} |
| 449 | Lₐ₁₀₀₀ | L_{b33} | 450 | Lₐ₁₀₄₀ | L_{b33} |
| 451 | Lₐ₁₀₄₃ | L_{b33} | 452 | Lₐ₁₀₄₆ | L_{b33} |
| 453 | Lₐ₁₂₈₆ | L_{b33} | 454 | Lₐ₁₂₉₂ | L_{b33} |
| 455 | Lₐ₁₂₉₃ | L_{b33} | 456 | Lₐ₁₃₀₄ | L_{b33} |
| 457 | Lₐ₁₃₁₆ | L_{b33} | 458 | Lₐ₁₃₂₈ | L_{b33} |
| 459 | Lₐ₁₃₆₄ | L_{b33} | 460 | Lₐ₁₃₆₅ | L_{b33} |
| 461 | Lₐ₁₃₈₅ | L_{b33} | 462 | Lₐ₁₃₈₆ | L_{b33} |
| 463 | Lₐ₁₄₀₀ | L_{b33} | 464 | Lₐ₁₄₀₁ | L_{b33} |
| 465 | Lₐ₂₈₉ | L_{b36} | 466 | Lₐ₂₉₆ | L_{b36} |
| 467 | Lₐ₃₀₄ | L_{b36} | 468 | Lₐ₃₁₁ | L_{b36} |
| 469 | Lₐ₃₁₆ | L_{b36} | 470 | Lₐ₃₃₂ | L_{b36} |
| 471 | Lₐ₄₄₆ | L_{b36} | 472 | Lₐ₄₄₉ | L_{b36} |
| 473 | Lₐ₄₅₂ | L_{b36} | 474 | Lₐ₄₅₅ | L_{b36} |
| 475 | Lₐ₄₆₇ | L_{b36} | 476 | Lₐ₄₇₀ | L_{b36} |
| 477 | Lₐ₄₇₃ | L_{b36} | 478 | Lₐ₄₈₂ | L_{b36} |
| 479 | Lₐ₄₈₃ | L_{b36} | 480 | Lₐ₄₈₅ | L_{b36} |
| 481 | Lₐ₄₈₈ | L_{b36} | 482 | Lₐ₄₉₁ | L_{b36} |
| 483 | Lₐ₄₉₄ | L_{b36} | 484 | Lₐ₅₀₆ | L_{b36} |
| 485 | Lₐ₅₁₂ | L_{b36} | 486 | Lₐ₅₂₄ | L_{b36} |
| 487 | Lₐ₅₂₇ | L_{b36} | 488 | Lₐ₅₃₀ | L_{b36} |
| 489 | Lₐ₅₃₃ | L_{b36} | 490 | Lₐ₅₃₆ | L_{b36} |
| 491 | Lₐ₅₄₂ | L_{b36} | 492 | Lₐ₅₄₅ | L_{b36} |
| 493 | Lₐ₅₅₄ | L_{b36} | 494 | Lₐ₅₆₃ | L_{b36} |
| 495 | Lₐ₅₇₂ | L_{b36} | 496 | Lₐ₅₇₈ | L_{b36} |
| 497 | Lₐ₅₈₀ | L_{b36} | 498 | Lₐ₅₈₃ | L_{b36} |
| 499 | Lₐ₅₈₆ | L_{b36} | 500 | Lₐ₅₉₀ | L_{b36} |
| 501 | Lₐ₅₉₉ | L_{b36} | 502 | Lₐ₆₀₈ | L_{b36} |
| 503 | Lₐ₆₁₇ | L_{b36} | 504 | Lₐ₆₄₆ | L_{b36} |
| 505 | Lₐ₆₅₀ | L_{b36} | 506 | Lₐ₆₅₃ | L_{b36} |
| 507 | Lₐ₆₅₆ | L_{b36} | 508 | Lₐ₆₅₉ | L_{b36} |
| 509 | Lₐ₆₆₅ | L_{b36} | 510 | Lₐ₆₇₁ | L_{b36} |
| 511 | Lₐ₆₇₇ | L_{b36} | 512 | Lₐ₆₈₃ | L_{b36} |
| 513 | Lₐ₆₈₉ | L_{b36} | 514 | Lₐ₆₉₂ | L_{b36} |
| 515 | Lₐ₆₉₅ | L_{b36} | 516 | Lₐ₆₉₈ | L_{b36} |
| 517 | Lₐ₇₀₄ | L_{b36} | 518 | Lₐ₇₂₈ | L_{b36} |
| 519 | Lₐ₇₃₁ | L_{b36} | 520 | Lₐ₇₃₄ | L_{b36} |
| 521 | Lₐ₇₃₇ | L_{b36} | 522 | Lₐ₇₄₀ | L_{b36} |
| 523 | Lₐ₇₄₃ | L_{b36} | 524 | Lₐ₇₄₉ | L_{b36} |
| 525 | Lₐ₇₅₅ | L_{b36} | 526 | Lₐ₇₅₇ | L_{b36} |
| 527 | Lₐ₇₆₁ | L_{b36} | 528 | Lₐ₇₆₄ | L_{b36} |
| 529 | Lₐ₇₆₅ | L_{b36} | 530 | Lₐ₈₀₆ | L_{b36} |
| 531 | Lₐ₈₀₉ | L_{b36} | 532 | Lₐ₈₁₂ | L_{b36} |
| 533 | Lₐ₈₁₈ | L_{b36} | 534 | Lₐ₈₄₈ | L_{b36} |
| 535 | Lₐ₈₅₁ | L_{b36} | 536 | Lₐ₈₈₄ | L_{b36} |
| 537 | Lₐ₈₈₇ | L_{b36} | 538 | Lₐ₈₉₀ | L_{b36} |
| 539 | Lₐ₈₉₃ | L_{b36} | 540 | Lₐ₈₉₆ | L_{b36} |
| 541 | Lₐ₈₉₉ | L_{b36} | 542 | Lₐ₉₀₃ | L_{b36} |
| 543 | Lₐ₉₀₅ | L_{b36} | 544 | Lₐ₉₀₉ | L_{b36} |
| 545 | Lₐ₉₁₁ | L_{b36} | 546 | Lₐ₉₁₄ | L_{b36} |
| 547 | Lₐ₉₁₇ | L_{b36} | 548 | Lₐ₉₂₀ | L_{b36} |
| 549 | Lₐ₉₂₁ | L_{b36} | 550 | Lₐ₉₆₂ | L_{b36} |
| 551 | Lₐ₉₆₃ | L_{b36} | 552 | Lₐ₉₆₅ | L_{b36} |
| 553 | Lₐ₉₆₉ | L_{b36} | 554 | Lₐ₉₇₁ | L_{b36} |
| 555 | Lₐ₉₇₄ | L_{b36} | 556 | Lₐ₉₇₇ | L_{b36} |
| 557 | Lₐ₉₈₀ | L_{b36} | 558 | Lₐ₉₈₁ | L_{b36} |
| 559 | Lₐ₉₈₇ | L_{b36} | 560 | Lₐ₉₈₉ | L_{b36} |
| 561 | Lₐ₉₉₃ | L_{b36} | 562 | Lₐ₉₉₅ | L_{b36} |
| 563 | Lₐ₉₉₈ | L_{b36} | 564 | Lₐ₉₉₉ | L_{b36} |
| 565 | Lₐ₁₀₀₀ | L_{b36} | 566 | Lₐ₁₀₄₀ | L_{b36} |
| 567 | Lₐ₁₀₄₃ | L_{b36} | 568 | Lₐ₁₀₄₆ | L_{b36} |
| 569 | Lₐ₁₂₈₆ | L_{b36} | 570 | Lₐ₁₂₉₂ | L_{b36} |
| 571 | Lₐ₁₂₉₃ | L_{b36} | 572 | Lₐ₁₃₀₄ | L_{b36} |
| 573 | Lₐ₁₃₁₆ | L_{b36} | 574 | Lₐ₁₃₂₈ | L_{b36} |
| 575 | Lₐ₁₃₆₄ | L_{b36} | 576 | Lₐ₁₃₆₅ | L_{b36} |
| 577 | Lₐ₁₃₈₅ | L_{b36} | 578 | Lₐ₁₃₈₆ | L_{b36} |
| 579 | Lₐ₁₄₀₀ | L_{b36} | 580 | Lₐ₁₄₀₁ | L_{b36} |
| 581 | Lₐ₂₈₉ | L_{b52} | 582 | Lₐ₂₉₆ | L_{b52} |
| 583 | Lₐ₃₀₄ | L_{b52} | 584 | Lₐ₃₁₁ | L_{b52} |
| 585 | Lₐ₃₁₆ | L_{b52} | 586 | Lₐ₃₃₂ | L_{b52} |
| 587 | Lₐ₄₄₆ | L_{b52} | 588 | Lₐ₄₄₉ | L_{b52} |
| 589 | Lₐ₄₅₂ | L_{b52} | 590 | Lₐ₄₅₅ | L_{b52} |
| 591 | Lₐ₄₆₇ | L_{b52} | 592 | Lₐ₄₇₀ | L_{b52} |
| 593 | Lₐ₄₇₃ | L_{b52} | 594 | Lₐ₄₈₂ | L_{b52} |
| 595 | Lₐ₄₈₃ | L_{b52} | 596 | Lₐ₄₈₅ | L_{b52} |
| 597 | Lₐ₄₈₈ | L_{b52} | 598 | Lₐ₄₉₁ | L_{b52} |
| 599 | Lₐ₄₉₄ | L_{b52} | 600 | Lₐ₅₀₆ | L_{b52} |
| 601 | Lₐ₅₁₂ | L_{b52} | 602 | Lₐ₅₂₄ | L_{b52} |
| 603 | Lₐ₅₂₇ | L_{b52} | 604 | Lₐ₅₃₀ | L_{b52} |
| 605 | Lₐ₅₃₃ | L_{b52} | 606 | Lₐ₅₃₆ | L_{b52} |
| 607 | Lₐ₅₄₂ | L_{b52} | 608 | Lₐ₅₄₅ | L_{b52} |
| 609 | Lₐ₅₅₄ | L_{b52} | 610 | Lₐ₅₆₃ | L_{b52} |
| 611 | Lₐ₅₇₂ | L_{b52} | 612 | Lₐ₅₇₈ | L_{b52} |
| 613 | Lₐ₅₈₀ | L_{b52} | 614 | Lₐ₅₈₃ | L_{b52} |
| 615 | Lₐ₅₈₆ | L_{b52} | 616 | Lₐ₅₉₀ | L_{b52} |
| 617 | Lₐ₅₉₉ | L_{b52} | 618 | Lₐ₆₀₈ | L_{b52} |
| 619 | Lₐ₆₁₇ | L_{b52} | 620 | Lₐ₆₄₆ | L_{b52} |
| 621 | Lₐ₆₅₀ | L_{b52} | 622 | Lₐ₆₅₃ | L_{b52} |
| 623 | Lₐ₆₅₆ | L_{b52} | 624 | Lₐ₆₅₉ | L_{b52} |
| 625 | Lₐ₆₆₅ | L_{b52} | 626 | Lₐ₆₇₁ | L_{b52} |
| 627 | Lₐ₆₇₇ | L_{b52} | 628 | Lₐ₆₈₃ | L_{b52} |
| 629 | Lₐ₆₈₉ | L_{b52} | 630 | Lₐ₆₉₂ | L_{b52} |
| 631 | Lₐ₆₉₅ | L_{b52} | 632 | Lₐ₆₉₈ | L_{b52} |
| 633 | Lₐ₇₀₄ | L_{b52} | 634 | Lₐ₇₂₈ | L_{b52} |
| 635 | Lₐ₇₃₁ | L_{b52} | 636 | Lₐ₇₃₄ | L_{b52} |
| 637 | Lₐ₇₃₇ | L_{b52} | 638 | Lₐ₇₄₀ | L_{b52} |
| 639 | Lₐ₇₄₃ | L_{b52} | 640 | Lₐ₇₄₉ | L_{b52} |
| 641 | Lₐ₇₅₅ | L_{b52} | 642 | Lₐ₇₅₇ | L_{b52} |
| 643 | Lₐ₇₆₁ | L_{b52} | 644 | Lₐ₇₆₄ | L_{b52} |
| 645 | Lₐ₇₆₅ | L_{b52} | 646 | Lₐ₈₀₆ | L_{b52} |
| 647 | Lₐ₈₀₉ | L_{b52} | 648 | Lₐ₈₁₂ | L_{b52} |
| 649 | Lₐ₈₁₈ | L_{b52} | 650 | Lₐ₈₄₈ | L_{b52} |
| 651 | Lₐ₈₅₁ | L_{b52} | 652 | Lₐ₈₈₄ | L_{b52} |
| 653 | Lₐ₈₈₇ | L_{b52} | 654 | Lₐ₈₉₀ | L_{b52} |
| 655 | Lₐ₈₉₃ | L_{b52} | 656 | Lₐ₈₉₆ | L_{b52} |
| 657 | Lₐ₈₉₉ | L_{b52} | 658 | Lₐ₉₀₃ | L_{b52} |
| 659 | Lₐ₉₀₅ | L_{b52} | 660 | Lₐ₉₀₉ | L_{b52} |
| 661 | Lₐ₉₁₁ | L_{b52} | 662 | Lₐ₉₁₄ | L_{b52} |
| 663 | Lₐ₉₁₇ | L_{b52} | 664 | Lₐ₉₂₀ | L_{b52} |
| 665 | Lₐ₉₂₁ | L_{b52} | 666 | Lₐ₉₆₂ | L_{b52} |
| 667 | Lₐ₉₆₃ | L_{b52} | 668 | Lₐ₉₆₅ | L_{b52} |
| 669 | Lₐ₉₆₉ | L_{b52} | 670 | Lₐ₉₇₁ | L_{b52} |
| 671 | Lₐ₉₇₄ | L_{b52} | 672 | Lₐ₉₇₇ | L_{b52} |
| 673 | Lₐ₉₈₀ | L_{b52} | 674 | Lₐ₉₈₁ | L_{b52} |
| 675 | Lₐ₉₈₇ | L_{b52} | 676 | Lₐ₉₈₉ | L_{b52} |
| 677 | Lₐ₉₉₃ | L_{b52} | 678 | Lₐ₉₉₅ | L_{b52} |
| 679 | Lₐ₉₉₈ | L_{b52} | 680 | Lₐ₉₉₉ | L_{b52} |
| 681 | Lₐ₁₀₀₀ | L_{b52} | 682 | Lₐ₁₀₄₀ | L_{b52} |
| 683 | Lₐ₁₀₄₃ | L_{b52} | 684 | Lₐ₁₀₄₆ | L_{b52} |
| 685 | Lₐ₁₂₈₆ | L_{b52} | 686 | Lₐ₁₂₉₂ | L_{b52} |
| 687 | Lₐ₁₂₉₃ | L_{b52} | 688 | Lₐ₁₃₀₄ | L_{b52} |
| 689 | Lₐ₁₃₁₆ | L_{b52} | 690 | Lₐ₁₃₂₈ | L_{b52} |
| 691 | Lₐ₁₃₆₄ | L_{b52} | 692 | Lₐ₁₃₆₅ | L_{b52} |
| 693 | Lₐ₁₃₈₅ | L_{b52} | 694 | Lₐ₁₃₈₆ | L_{b52} |
| 695 | Lₐ₁₄₀₀ | L_{b52} | 696 | Lₐ₁₄₀₁ | L_{b52} |
| 697 | Lₐ₂₈₉ | L_{b57} | 698 | Lₐ₂₉₆ | L_{b57} |
| 699 | Lₐ₃₀₄ | L_{b57} | 700 | Lₐ₃₁₁ | L_{b57} |
| 701 | Lₐ₃₁₆ | L_{b57} | 702 | Lₐ₃₃₂ | L_{b57} |
| 703 | Lₐ₄₄₆ | L_{b57} | 704 | Lₐ₄₄₉ | L_{b57} |
| 705 | Lₐ₄₅₂ | L_{b57} | 706 | Lₐ₄₅₅ | L_{b57} |
| 707 | Lₐ₄₆₇ | L_{b57} | 708 | Lₐ₄₇₀ | L_{b57} |
| 709 | Lₐ₄₇₃ | L_{b57} | 710 | Lₐ₄₈₂ | L_{b57} |
| 711 | Lₐ₄₈₃ | L_{b57} | 712 | Lₐ₄₈₅ | L_{b57} |
| 713 | Lₐ₄₈₈ | L_{b57} | 714 | Lₐ₄₉₁ | L_{b57} |
| 715 | Lₐ₄₉₄ | L_{b57} | 716 | Lₐ₅₀₆ | L_{b57} |
| 717 | Lₐ₅₁₂ | L_{b57} | 718 | Lₐ₅₂₄ | L_{b57} |
| 719 | Lₐ₅₂₇ | L_{b57} | 720 | Lₐ₅₃₀ | L_{b57} |
| 721 | Lₐ₅₃₃ | L_{b57} | 722 | Lₐ₅₃₆ | L_{b57} |
| 723 | Lₐ₅₄₂ | L_{b57} | 724 | Lₐ₅₄₅ | L_{b57} |
| 725 | Lₐ₅₅₄ | L_{b57} | 726 | Lₐ₅₆₃ | L_{b57} |
| 727 | Lₐ₅₇₂ | L_{b57} | 728 | Lₐ₅₇₈ | L_{b57} |
| 729 | Lₐ₅₈₀ | L_{b57} | 730 | Lₐ₅₈₃ | L_{b57} |
| 731 | Lₐ₅₈₆ | L_{b57} | 732 | Lₐ₅₉₀ | L_{b57} |
| 733 | Lₐ₅₉₉ | L_{b57} | 734 | Lₐ₆₀₈ | L_{b57} |
| 735 | Lₐ₆₁₇ | L_{b57} | 736 | Lₐ₆₄₆ | L_{b57} |
| 737 | Lₐ₆₅₀ | L_{b57} | 738 | Lₐ₆₅₃ | L_{b57} |
| 739 | Lₐ₆₅₆ | L_{b57} | 740 | Lₐ₆₅₉ | L_{b57} |
| 741 | Lₐ₆₆₅ | L_{b57} | 742 | Lₐ₆₇₁ | L_{b57} |
| 743 | Lₐ₆₇₇ | L_{b57} | 744 | Lₐ₆₈₃ | L_{b57} |
| 745 | Lₐ₆₈₉ | L_{b57} | 746 | Lₐ₆₉₂ | L_{b57} |
| 747 | Lₐ₆₉₅ | L_{b57} | 748 | Lₐ₆₉₈ | L_{b57} |
| 749 | Lₐ₇₀₄ | L_{b57} | 750 | Lₐ₇₂₈ | L_{b57} |
| 751 | Lₐ₇₃₁ | L_{b57} | 752 | Lₐ₇₃₄ | L_{b57} |
| 753 | Lₐ₇₃₇ | L_{b57} | 754 | Lₐ₇₄₀ | L_{b57} |
| 755 | Lₐ₇₄₃ | L_{b57} | 756 | Lₐ₇₄₉ | L_{b57} |
| 757 | Lₐ₇₅₅ | L_{b57} | 758 | Lₐ₇₅₇ | L_{b57} |
| 759 | Lₐ₇₆₁ | L_{b57} | 760 | Lₐ₇₆₄ | L_{b57} |
| 761 | Lₐ₇₆₅ | L_{b57} | 762 | Lₐ₈₀₆ | L_{b57} |
| 763 | Lₐ₈₀₉ | L_{b57} | 764 | Lₐ₈₁₂ | L_{b57} |
| 765 | Lₐ₈₁₈ | L_{b57} | 766 | Lₐ₈₄₈ | L_{b57} |
| 767 | Lₐ₈₅₁ | L_{b57} | 768 | Lₐ₈₈₄ | L_{b57} |
| 769 | Lₐ₈₈₇ | L_{b57} | 770 | Lₐ₈₉₀ | L_{b57} |
| 771 | Lₐ₈₉₃ | L_{b57} | 772 | Lₐ₈₉₆ | L_{b57} |
| 773 | Lₐ₈₉₉ | L_{b57} | 774 | Lₐ₉₀₃ | L_{b57} |
| 775 | Lₐ₉₀₅ | L_{b57} | 776 | Lₐ₉₀₉ | L_{b57} |
| 777 | Lₐ₉₁₁ | L_{b57} | 778 | Lₐ₉₁₄ | L_{b57} |
| 779 | Lₐ₉₁₇ | L_{b57} | 780 | Lₐ₉₂₀ | L_{b57} |
| 781 | Lₐ₉₂₁ | L_{b57} | 782 | Lₐ₉₆₂ | L_{b57} |
| 783 | Lₐ₉₆₃ | L_{b57} | 784 | Lₐ₉₆₅ | L_{b57} |
| 785 | Lₐ₉₆₉ | L_{b57} | 786 | Lₐ₉₇₁ | L_{b57} |
| 787 | Lₐ₉₇₄ | L_{b57} | 788 | Lₐ₉₇₇ | L_{b57} |
| 789 | Lₐ₉₈₀ | L_{b57} | 790 | Lₐ₉₈₁ | L_{b57} |
| 791 | Lₐ₉₈₇ | L_{b57} | 792 | Lₐ₉₈₉ | L_{b57} |
| 793 | Lₐ₉₉₃ | L_{b57} | 794 | Lₐ₉₉₅ | L_{b57} |
| 795 | Lₐ₉₉₈ | L_{b57} | 796 | Lₐ₉₉₉ | L_{b57} |
| 797 | Lₐ₁₀₀₀ | L_{b57} | 798 | Lₐ₁₀₄₀ | L_{b57} |
| 799 | Lₐ₁₀₄₃ | L_{b57} | 800 | Lₐ₁₀₄₆ | L_{b57} |
| 801 | Lₐ₁₂₈₆ | L_{b57} | 802 | Lₐ₁₂₉₂ | L_{b57} |
| 803 | Lₐ₁₂₉₃ | L_{b57} | 804 | Lₐ₁₃₀₄ | L_{b57} |
| 805 | Lₐ₁₃₁₆ | L_{b57} | 806 | Lₐ₁₃₂₈ | L_{b57} |
| 807 | Lₐ₁₃₆₄ | L_{b57} | 808 | Lₐ₁₃₆₅ | L_{b57} |
| 809 | Lₐ₁₃₈₅ | L_{b57} | 810 | Lₐ₁₃₈₆ | L_{b57} |
| 811 | Lₐ₁₄₀₀ | L_{b57} | 812 | Lₐ₁₄₀₁ | L_{b57} |
| 813 | Lₐ₂₈₉ | L_{b128} | 814 | Lₐ₂₉₆ | L_{b128} |
| 815 | Lₐ₃₀₄ | L_{b128} | 816 | Lₐ₃₁₁ | L_{b128} |
| 817 | Lₐ₃₁₆ | L_{b128} | 818 | Lₐ₃₃₂ | L_{b128} |
| 819 | Lₐ₄₄₆ | L_{b128} | 820 | Lₐ₄₄₉ | L_{b128} |
| 821 | Lₐ₄₅₂ | L_{b128} | 822 | Lₐ₄₅₅ | L_{b128} |
| 823 | Lₐ₄₆₇ | L_{b128} | 824 | Lₐ₄₇₀ | L_{b128} |
| 825 | Lₐ₄₇₃ | L_{b128} | 826 | Lₐ₄₈₂ | L_{b128} |
| 827 | Lₐ₄₈₃ | L_{b128} | 828 | Lₐ₄₈₅ | L_{b128} |
| 829 | Lₐ₄₈₈ | L_{b128} | 830 | Lₐ₄₉₁ | L_{b128} |
| 831 | Lₐ₄₉₄ | L_{b128} | 832 | Lₐ₅₀₆ | L_{b128} |
| 833 | Lₐ₅₁₂ | L_{b128} | 834 | Lₐ₅₂₄ | L_{b128} |
| 835 | Lₐ₅₂₇ | L_{b128} | 836 | Lₐ₅₃₀ | L_{b128} |
| 837 | Lₐ₅₃₃ | L_{b128} | 838 | Lₐ₅₃₆ | L_{b128} |
| 839 | Lₐ₅₄₂ | L_{b128} | 840 | Lₐ₅₄₅ | L_{b128} |
| 841 | Lₐ₅₅₄ | L_{b128} | 842 | Lₐ₅₆₃ | L_{b128} |
| 843 | Lₐ₅₇₂ | L_{b128} | 844 | Lₐ₅₇₈ | L_{b128} |
| 845 | Lₐ₅₈₀ | L_{b128} | 846 | Lₐ₅₈₃ | L_{b128} |
| 847 | Lₐ₅₈₆ | L_{b128} | 848 | Lₐ₅₉₀ | L_{b128} |
| 849 | Lₐ₅₉₉ | L_{b128} | 850 | Lₐ₆₀₈ | L_{b128} |
| 851 | Lₐ₆₁₇ | L_{b128} | 852 | Lₐ₆₄₆ | L_{b128} |
| 853 | Lₐ₆₅₀ | L_{b128} | 854 | Lₐ₆₅₃ | L_{b128} |
| 855 | Lₐ₆₅₆ | L_{b128} | 856 | Lₐ₆₅₉ | L_{b128} |
| 857 | Lₐ₆₆₅ | L_{b128} | 858 | Lₐ₆₇₁ | L_{b128} |
| 859 | Lₐ₆₇₇ | L_{b128} | 860 | Lₐ₆₈₃ | L_{b128} |
| 861 | Lₐ₆₈₉ | L_{b128} | 862 | Lₐ₆₉₂ | L_{b128} |
| 863 | Lₐ₆₉₅ | L_{b128} | 864 | Lₐ₆₉₈ | L_{b128} |
| 865 | Lₐ₇₀₄ | L_{b128} | 866 | Lₐ₇₂₈ | L_{b128} |
| 867 | Lₐ₇₃₁ | L_{b128} | 868 | Lₐ₇₃₄ | L_{b128} |
| 869 | Lₐ₇₃₇ | L_{b128} | 870 | Lₐ₇₄₀ | L_{b128} |
| 871 | Lₐ₇₄₃ | L_{b128} | 872 | Lₐ₇₄₉ | L_{b128} |
| 873 | Lₐ₇₅₅ | L_{b128} | 874 | Lₐ₇₅₇ | L_{b128} |
| 875 | Lₐ₇₆₁ | L_{b128} | 876 | Lₐ₇₆₄ | L_{b128} |
| 877 | Lₐ₇₆₅ | L_{b128} | 878 | Lₐ₈₀₆ | L_{b128} |
| 879 | Lₐ₈₀₉ | L_{b128} | 880 | Lₐ₈₁₂ | L_{b128} |
| 881 | Lₐ₈₁₈ | L_{b128} | 882 | Lₐ₈₄₈ | L_{b128} |
| 883 | Lₐ₈₅₁ | L_{b128} | 884 | Lₐ₈₈₄ | L_{b128} |
| 885 | Lₐ₈₈₇ | L_{b128} | 886 | Lₐ₈₉₀ | L_{b128} |
| 887 | Lₐ₈₉₃ | L_{b128} | 888 | Lₐ₈₉₆ | L_{b128} |
| 889 | Lₐ₈₉₉ | L_{b128} | 890 | Lₐ₉₀₃ | L_{b128} |
| 891 | Lₐ₉₀₅ | L_{b128} | 892 | Lₐ₉₀₉ | L_{b128} |
| 893 | Lₐ₉₁₁ | L_{b128} | 894 | Lₐ₉₁₄ | L_{b128} |
| 895 | Lₐ₉₁₇ | L_{b128} | 896 | Lₐ₉₂₀ | L_{b128} |
| 897 | Lₐ₉₂₁ | L_{b128} | 898 | Lₐ₉₆₂ | L_{b128} |
| 899 | Lₐ₉₆₃ | L_{b128} | 900 | Lₐ₉₆₅ | L_{b128} |
| 901 | Lₐ₉₆₉ | L_{b128} | 902 | Lₐ₉₇₁ | L_{b128} |
| 903 | Lₐ₉₇₄ | L_{b128} | 904 | Lₐ₉₇₇ | L_{b128} |
| 905 | Lₐ₉₈₀ | L_{b128} | 906 | Lₐ₉₈₁ | L_{b128} |
| 907 | Lₐ₉₈₇ | L_{b128} | 908 | Lₐ₉₈₉ | L_{b128} |
| 909 | Lₐ₉₉₃ | L_{b128} | 910 | Lₐ₉₉₅ | L_{b128} |
| 911 | Lₐ₉₉₈ | L_{b128} | 912 | Lₐ₉₉₉ | L_{b128} |
| 913 | Lₐ₁₀₀₀ | L_{b128} | 914 | Lₐ₁₀₄₀ | L_{b128} |
| 915 | Lₐ₁₀₄₃ | L_{b128} | 916 | Lₐ₁₀₄₆ | L_{b128} |
| 917 | Lₐ₁₂₈₆ | L_{b128} | 918 | Lₐ₁₂₉₂ | L_{b128} |
| 919 | Lₐ₁₂₉₃ | L_{b128} | 920 | Lₐ₁₃₀₄ | L_{b128} |
| 921 | Lₐ₁₃₁₆ | L_{b128} | 922 | Lₐ₁₃₂₈ | L_{b128} |
| 923 | Lₐ₁₃₆₄ | L_{b128} | 924 | Lₐ₁₃₆₅ | L_{b128} |
| 925 | Lₐ₁₃₈₅ | L_{b128} | 926 | Lₐ₁₃₈₆ | L_{b128} |
| 927 | Lₐ₁₄₀₀ | L_{b128} | 928 | Lₐ₁₄₀₁ | L_{b128} |
| 929 | Lₐ₂₈₉ | L_{b132} | 930 | Lₐ₂₉₆ | L_{b132} |
| 931 | Lₐ₃₀₄ | L_{b132} | 932 | Lₐ₃₁₁ | L_{b132} |
| 933 | Lₐ₃₁₆ | L_{b132} | 934 | Lₐ₃₃₂ | L_{b132} |
| 935 | Lₐ₄₄₆ | L_{b132} | 936 | Lₐ₄₄₉ | L_{b132} |
| 937 | Lₐ₄₅₂ | L_{b132} | 938 | Lₐ₄₅₅ | L_{b132} |
| 939 | Lₐ₄₆₇ | L_{b132} | 940 | Lₐ₄₇₀ | L_{b132} |
| 941 | Lₐ₄₇₃ | L_{b132} | 942 | Lₐ₄₈₂ | L_{b132} |
| 943 | Lₐ₄₈₃ | L_{b132} | 944 | Lₐ₄₈₅ | L_{b132} |
| 945 | Lₐ₄₈₈ | L_{b132} | 946 | Lₐ₄₉₁ | L_{b132} |
| 947 | Lₐ₄₉₄ | L_{b132} | 948 | Lₐ₅₀₆ | L_{b132} |
| 949 | Lₐ₅₁₂ | L_{b132} | 950 | Lₐ₅₂₄ | L_{b132} |
| 951 | Lₐ₅₂₇ | L_{b132} | 952 | Lₐ₅₃₀ | L_{b132} |
| 953 | Lₐ₅₃₃ | L_{b132} | 954 | Lₐ₅₃₆ | L_{b132} |
| 955 | Lₐ₅₄₂ | L_{b132} | 956 | Lₐ₅₄₅ | L_{b132} |
| 957 | Lₐ₅₅₄ | L_{b132} | 958 | Lₐ₅₆₃ | L_{b132} |
| 959 | Lₐ₅₇₂ | L_{b132} | 960 | Lₐ₅₇₈ | L_{b132} |
| 961 | Lₐ₅₈₀ | L_{b132} | 962 | Lₐ₅₈₃ | L_{b132} |
| 963 | Lₐ₅₈₆ | L_{b132} | 964 | Lₐ₅₉₀ | L_{b132} |
| 965 | Lₐ₅₉₉ | L_{b132} | 966 | Lₐ₆₀₈ | L_{b132} |
| 967 | Lₐ₆₁₇ | L_{b132} | 968 | Lₐ₆₄₆ | L_{b132} |
| 969 | Lₐ₆₅₀ | L_{b132} | 970 | Lₐ₆₅₃ | L_{b132} |
| 971 | Lₐ₆₅₆ | L_{b132} | 972 | Lₐ₆₅₉ | L_{b132} |
| 973 | Lₐ₆₆₅ | L_{b132} | 974 | Lₐ₆₇₁ | L_{b132} |
| 975 | Lₐ₆₇₇ | L_{b132} | 976 | Lₐ₆₈₃ | L_{b132} |
| 977 | Lₐ₆₈₉ | L_{b132} | 978 | Lₐ₆₉₂ | L_{b132} |
| 979 | Lₐ₆₉₅ | L_{b132} | 980 | Lₐ₆₉₈ | L_{b132} |
| 981 | Lₐ₇₀₄ | L_{b132} | 982 | Lₐ₇₂₈ | L_{b132} |
| 983 | Lₐ₇₃₁ | L_{b132} | 984 | Lₐ₇₃₄ | L_{b132} |
| 985 | Lₐ₇₃₇ | L_{b132} | 986 | Lₐ₇₄₀ | L_{b132} |
| 987 | Lₐ₇₄₃ | L_{b132} | 988 | Lₐ₇₄₉ | L_{b132} |
| 989 | Lₐ₇₅₅ | L_{b132} | 990 | Lₐ₇₅₇ | L_{b132} |
| 991 | Lₐ₇₆₁ | L_{b132} | 992 | Lₐ₇₆₄ | L_{b132} |
| 993 | Lₐ₇₆₅ | L_{b132} | 994 | Lₐ₈₀₆ | L_{b132} |
| 995 | Lₐ₈₀₉ | L_{b132} | 996 | Lₐ₈₁₂ | L_{b132} |
| 997 | Lₐ₈₁₈ | L_{b132} | 998 | Lₐ₈₄₈ | L_{b132} |
| 999 | Lₐ₈₅₁ | L_{b132} | 1000 | Lₐ₈₈₄ | L_{b132} |
| 1001 | Lₐ₈₈₇ | L_{b132} | 1002 | Lₐ₈₉₀ | L_{b132} |
| 1003 | Lₐ₈₉₃ | L_{b132} | 1004 | Lₐ₈₉₆ | L_{b132} |
| 1005 | Lₐ₈₉₉ | L_{b132} | 1006 | Lₐ₉₀₃ | L_{b132} |
| 1007 | Lₐ₉₀₅ | L_{b132} | 1008 | Lₐ₉₀₉ | L_{b132} |
| 1009 | Lₐ₉₁₁ | L_{b132} | 1010 | Lₐ₉₁₄ | L_{b132} |
| 1011 | Lₐ₉₁₇ | L_{b132} | 1012 | Lₐ₉₂₀ | L_{b132} |
| 1013 | Lₐ₉₂₁ | L_{b132} | 1014 | Lₐ₉₆₂ | L_{b132} |
| 1015 | Lₐ₉₆₃ | L_{b132} | 1016 | Lₐ₉₆₅ | L_{b132} |
| 1017 | Lₐ₉₆₉ | L_{b132} | 1018 | Lₐ₉₇₁ | L_{b132} |
| 1019 | Lₐ₉₇₄ | L_{b132} | 1020 | Lₐ₉₇₇ | L_{b132} |
| 1021 | Lₐ₉₈₀ | L_{b132} | 1022 | Lₐ₉₈₁ | L_{b132} |
| 1023 | Lₐ₉₈₇ | L_{b132} | 1024 | Lₐ₉₈₉ | L_{b132} |
| 1025 | Lₐ₉₉₃ | L_{b132} | 1026 | Lₐ₉₉₅ | L_{b132} |
| 1027 | Lₐ₉₉₈ | L_{b132} | 1028 | Lₐ₉₉₉ | L_{b132} |
| 1029 | Lₐ₁₀₀₀ | L_{b132} | 1030 | Lₐ₁₀₄₀ | L_{b132} |
| 1031 | Lₐ₁₀₄₃ | L_{b132} | 1032 | Lₐ₁₀₄₆ | L_{b132} |
| 1033 | Lₐ₁₂₈₆ | L_{b132} | 1034 | Lₐ₁₂₉₂ | L_{b132} |
| 1035 | Lₐ₁₂₉₃ | L_{b132} | 1036 | Lₐ₁₃₀₄ | L_{b132} |
| 1037 | Lₐ₁₃₁₆ | L_{b132} | 1038 | Lₐ₁₃₂₈ | L_{b132} |
| 1039 | Lₐ₁₃₆₄ | L_{b132} | 1040 | Lₐ₁₃₆₅ | L_{b132} |
| 1041 | Lₐ₁₃₈₅ | L_{b132} | 1042 | Lₐ₁₃₈₆ | L_{b132} |
| 1043 | Lₐ₁₄₀₀ | L_{b132} | 1044 | Lₐ₁₄₀₁ | L_{b132} |
| 1045 | Lₐ₂₈₉ | L_{b133} | 1046 | Lₐ₂₉₆ | L_{b133} |
| 1047 | Lₐ₃₀₄ | L_{b133} | 1048 | Lₐ₃₁₁ | L_{b133} |
| 1049 | Lₐ₃₁₆ | L_{b133} | 1050 | Lₐ₃₃₂ | L_{b133} |
| 1051 | Lₐ₄₄₆ | L_{b133} | 1052 | Lₐ₄₄₉ | L_{b133} |
| 1053 | Lₐ₄₅₂ | L_{b133} | 1054 | Lₐ₄₅₅ | L_{b133} |
| 1055 | Lₐ₄₆₇ | L_{b133} | 1056 | Lₐ₄₇₀ | L_{b133} |
| 1057 | Lₐ₄₇₃ | L_{b133} | 1058 | Lₐ₄₈₂ | L_{b133} |
| 1059 | Lₐ₄₈₃ | L_{b133} | 1060 | Lₐ₄₈₅ | L_{b133} |
| 1061 | Lₐ₄₈₈ | L_{b133} | 1062 | Lₐ₄₉₁ | L_{b133} |
| 1063 | Lₐ₄₉₄ | L_{b133} | 1064 | Lₐ₅₀₆ | L_{b133} |
| 1065 | Lₐ₅₁₂ | L_{b133} | 1066 | Lₐ₅₂₄ | L_{b133} |
| 1067 | Lₐ₅₂₇ | L_{b133} | 1068 | Lₐ₅₃₀ | L_{b133} |
| 1069 | Lₐ₅₃₃ | L_{b133} | 1070 | Lₐ₅₃₆ | L_{b133} |
| 1071 | Lₐ₅₄₂ | L_{b133} | 1072 | Lₐ₅₄₅ | L_{b133} |
| 1073 | Lₐ₅₅₄ | L_{b133} | 1074 | Lₐ₅₆₃ | L_{b133} |
| 1075 | Lₐ₅₇₂ | L_{b133} | 1076 | Lₐ₅₇₈ | L_{b133} |
| 1077 | Lₐ₅₈₀ | L_{b133} | 1078 | Lₐ₅₈₃ | L_{b133} |
| 1079 | Lₐ₅₈₆ | L_{b133} | 1080 | Lₐ₅₉₀ | L_{b133} |
| 1081 | Lₐ₅₉₉ | L_{b133} | 1082 | Lₐ₆₀₈ | L_{b133} |
| 1083 | Lₐ₆₁₇ | L_{b133} | 1084 | Lₐ₆₄₆ | L_{b133} |
| 1085 | Lₐ₆₅₀ | L_{b133} | 1086 | Lₐ₆₅₃ | L_{b133} |
| 1087 | Lₐ₆₅₆ | L_{b133} | 1088 | Lₐ₆₅₉ | L_{b133} |
| 1089 | Lₐ₆₆₅ | L_{b133} | 1090 | Lₐ₆₇₁ | L_{b133} |
| 1091 | Lₐ₆₇₇ | L_{b133} | 1092 | Lₐ₆₈₃ | L_{b133} |
| 1093 | Lₐ₆₈₉ | L_{b133} | 1094 | Lₐ₆₉₂ | L_{b133} |
| 1095 | Lₐ₆₉₅ | L_{b133} | 1096 | Lₐ₆₉₈ | L_{b133} |
| 1097 | Lₐ₇₀₄ | L_{b133} | 1098 | Lₐ₇₂₈ | L_{b133} |
| 1099 | Lₐ₇₃₁ | L_{b133} | 1100 | Lₐ₇₃₄ | L_{b133} |
| 1101 | Lₐ₇₃₇ | L_{b133} | 1102 | Lₐ₇₄₀ | L_{b133} |
| 1103 | Lₐ₇₄₃ | L_{b133} | 1104 | Lₐ₇₄₉ | L_{b133} |
| 1105 | Lₐ₇₅₅ | L_{b133} | 1106 | Lₐ₇₅₇ | L_{b133} |
| 1107 | Lₐ₇₆₁ | L_{b133} | 1108 | Lₐ₇₆₄ | L_{b133} |
| 1109 | Lₐ₇₆₅ | L_{b133} | 1110 | Lₐ₈₀₆ | L_{b133} |
| 1111 | Lₐ₈₀₉ | L_{b133} | 1112 | Lₐ₈₁₂ | L_{b133} |
| 1113 | Lₐ₈₁₈ | L_{b133} | 1114 | Lₐ₈₄₈ | L_{b133} |
| 1115 | Lₐ₈₅₁ | L_{b133} | 1116 | Lₐ₈₈₄ | L_{b133} |
| 1117 | Lₐ₈₈₇ | L_{b133} | 1118 | Lₐ₈₉₀ | L_{b133} |
| 1119 | Lₐ₈₉₃ | L_{b133} | 1120 | Lₐ₈₉₆ | L_{b133} |
| 1121 | Lₐ₈₉₉ | L_{b133} | 1122 | Lₐ₉₀₃ | L_{b133} |
| 1123 | Lₐ₉₀₅ | L_{b133} | 1124 | Lₐ₉₀₉ | L_{b133} |
| 1125 | Lₐ₉₁₁ | L_{b133} | 1126 | Lₐ₉₁₄ | L_{b133} |
| 1127 | Lₐ₉₁₇ | L_{b133} | 1128 | Lₐ₉₂₀ | L_{b133} |
| 1129 | Lₐ₉₂₁ | L_{b133} | 1130 | Lₐ₉₆₂ | L_{b133} |
| 1131 | Lₐ₉₆₃ | L_{b133} | 1132 | Lₐ₉₆₅ | L_{b133} |
| 1133 | Lₐ₉₆₉ | L_{b133} | 1134 | Lₐ₉₇₁ | L_{b133} |
| 1135 | Lₐ₉₇₄ | L_{b133} | 1136 | Lₐ₉₇₇ | L_{b133} |
| 1137 | Lₐ₉₈₀ | L_{b133} | 1138 | Lₐ₉₈₁ | L_{b133} |
| 1139 | Lₐ₉₈₇ | L_{b133} | 1140 | Lₐ₉₈₉ | L_{b133} |
| 1141 | Lₐ₉₉₃ | L_{b133} | 1142 | Lₐ₉₉₅ | L_{b133} |
| 1143 | Lₐ₉₉₈ | L_{b133} | 1144 | Lₐ₉₉₉ | L_{b133} |
| 1145 | Lₐ₁₀₀₀ | L_{b133} | 1146 | Lₐ₁₀₄₀ | L_{b133} |
| 1147 | Lₐ₁₀₄₃ | L_{b133} | 1148 | Lₐ₁₀₄₆ | L_{b133} |
| 1149 | Lₐ₁₂₈₆ | L_{b133} | 1150 | Lₐ₁₂₉₂ | L_{b133} |
| 1151 | Lₐ₁₂₉₃ | L_{b133} | 1152 | Lₐ₁₃₀₄ | L_{b133} |
| 1153 | Lₐ₁₃₁₆ | L_{b133} | 1154 | Lₐ₁₃₂₈ | L_{b133} |
| 1155 | Lₐ₁₃₆₄ | L_{b133} | 1156 | Lₐ₁₃₆₅ | L_{b133} |
| 1157 | Lₐ₁₃₈₅ | L_{b133} | 1158 | Lₐ₁₃₈₆ | L_{b133} |
| 1159 | Lₐ₁₄₀₀ | L_{b133} | 1160 | Lₐ₁₄₀₁ | L_{b133} |
| 1161 | Lₐ₂₈₉ | L_{b135} | 1162 | Lₐ₂₉₆ | L_{b135} |
| 1163 | Lₐ₃₀₄ | L_{b135} | 1164 | Lₐ₃₁₁ | L_{b135} |
| 1165 | Lₐ₃₁₆ | L_{b135} | 1166 | Lₐ₃₃₂ | L_{b135} |
| 1167 | Lₐ₄₄₆ | L_{b135} | 1168 | Lₐ₄₄₉ | L_{b135} |
| 1169 | Lₐ₄₅₂ | L_{b135} | 1170 | Lₐ₄₅₅ | L_{b135} |
| 1171 | Lₐ₄₆₇ | L_{b135} | 1172 | Lₐ₄₇₀ | L_{b135} |
| 1173 | Lₐ₄₇₃ | L_{b135} | 1174 | Lₐ₄₈₂ | L_{b135} |
| 1175 | Lₐ₄₈₃ | L_{b135} | 1176 | Lₐ₄₈₅ | L_{b135} |
| 1177 | Lₐ₄₈₈ | L_{b135} | 1178 | Lₐ₄₉₁ | L_{b135} |
| 1179 | Lₐ₄₉₄ | L_{b135} | 1180 | Lₐ₅₀₆ | L_{b135} |
| 1181 | Lₐ₅₁₂ | L_{b135} | 1182 | Lₐ₅₂₄ | L_{b135} |
| 1183 | Lₐ₅₂₇ | L_{b135} | 1184 | Lₐ₅₃₀ | L_{b135} |
| 1185 | Lₐ₅₃₃ | L_{b135} | 1186 | Lₐ₅₃₆ | L_{b135} |
| 1187 | Lₐ₅₄₂ | L_{b135} | 1188 | Lₐ₅₄₅ | L_{b135} |
| 1189 | Lₐ₅₅₄ | L_{b135} | 1190 | Lₐ₅₆₃ | L_{b135} |
| 1191 | Lₐ₅₇₂ | L_{b135} | 1192 | Lₐ₅₇₈ | L_{b135} |
| 1193 | Lₐ₅₈₀ | L_{b135} | 1194 | Lₐ₅₈₃ | L_{b135} |
| 1195 | Lₐ₅₈₆ | L_{b135} | 1196 | Lₐ₅₉₀ | L_{b135} |
| 1197 | Lₐ₅₉₉ | L_{b135} | 1198 | Lₐ₆₀₈ | L_{b135} |
| 1199 | Lₐ₆₁₇ | L_{b135} | 1200 | Lₐ₆₄₆ | L_{b135} |
| 1201 | Lₐ₆₅₀ | L_{b135} | 1202 | Lₐ₆₅₃ | L_{b135} |
| 1203 | Lₐ₆₅₆ | L_{b135} | 1204 | Lₐ₆₅₉ | L_{b135} |
| 1205 | Lₐ₆₆₅ | L_{b135} | 1206 | Lₐ₆₇₁ | L_{b135} |
| 1207 | Lₐ₆₇₇ | L_{b135} | 1208 | Lₐ₆₈₃ | L_{b135} |
| 1209 | Lₐ₆₈₉ | L_{b135} | 1210 | Lₐ₆₉₂ | L_{b135} |
| 1211 | Lₐ₆₉₅ | L_{b135} | 1212 | Lₐ₆₉₈ | L_{b135} |
| 1213 | Lₐ₇₀₄ | L_{b135} | 1214 | Lₐ₇₂₈ | L_{b135} |
| 1215 | Lₐ₇₃₁ | L_{b135} | 1216 | Lₐ₇₃₄ | L_{b135} |
| 1217 | Lₐ₇₃₇ | L_{b135} | 1218 | Lₐ₇₄₀ | L_{b135} |
| 1219 | Lₐ₇₄₃ | L_{b135} | 1220 | Lₐ₇₄₉ | L_{b135} |
| 1221 | Lₐ₇₅₅ | L_{b135} | 1222 | Lₐ₇₅₇ | L_{b135} |
| 1223 | Lₐ₇₆₁ | L_{b135} | 1224 | Lₐ₇₆₄ | L_{b135} |
| 1225 | Lₐ₇₆₅ | L_{b135} | 1226 | Lₐ₈₀₆ | L_{b135} |
| 1227 | Lₐ₈₀₉ | L_{b135} | 1228 | Lₐ₈₁₂ | L_{b135} |
| 1229 | Lₐ₈₁₈ | L_{b135} | 1230 | Lₐ₈₄₈ | L_{b135} |
| 1231 | Lₐ₈₅₁ | L_{b135} | 1232 | Lₐ₈₈₄ | L_{b135} |
| 1233 | Lₐ₈₈₇ | L_{b135} | 1234 | Lₐ₈₉₀ | L_{b135} |
| 1235 | Lₐ₈₉₃ | L_{b135} | 1236 | Lₐ₈₉₆ | L_{b135} |
| 1237 | Lₐ₈₉₉ | L_{b135} | 1238 | Lₐ₉₀₃ | L_{b135} |
| 1239 | Lₐ₉₀₅ | L_{b135} | 1240 | Lₐ₉₀₉ | L_{b135} |
| 1241 | Lₐ₉₁₁ | L_{b135} | 1242 | Lₐ₉₁₄ | L_{b135} |
| 1243 | Lₐ₉₁₇ | L_{b135} | 1244 | Lₐ₉₂₀ | L_{b135} |
| 1245 | Lₐ₉₂₁ | L_{b135} | 1246 | Lₐ₉₆₂ | L_{b135} |
| 1247 | Lₐ₉₆₃ | L_{b135} | 1248 | Lₐ₉₆₅ | L_{b135} |
| 1249 | Lₐ₉₆₉ | L_{b135} | 1250 | Lₐ₉₇₁ | L_{b135} |
| 1251 | Lₐ₉₇₄ | L_{b135} | 1252 | Lₐ₉₇₇ | L_{b135} |
| 1253 | Lₐ₉₈₀ | L_{b135} | 1254 | Lₐ₉₈₁ | L_{b135} |
| 1255 | Lₐ₉₈₇ | L_{b135} | 1256 | Lₐ₉₈₉ | L_{b135} |
| 1257 | Lₐ₉₉₃ | L_{b135} | 1258 | Lₐ₉₉₅ | L_{b135} |
| 1259 | Lₐ₉₉₈ | L_{b135} | 1260 | Lₐ₉₉₉ | L_{b135} |
| 1261 | Lₐ₁₀₀₀ | L_{b135} | 1262 | Lₐ₁₀₄₀ | L_{b135} |
| 1263 | Lₐ₁₀₄₃ | L_{b135} | 1264 | Lₐ₁₀₄₆ | L_{b135} |
| 1265 | Lₐ₁₂₈₆ | L_{b135} | 1266 | Lₐ₁₂₉₂ | L_{b135} |
| 1267 | Lₐ₁₂₉₃ | L_{b135} | 1268 | Lₐ₁₃₀₄ | L_{b135} |
| 1269 | Lₐ₁₃₁₆ | L_{b135} | 1270 | Lₐ₁₃₂₈ | L_{b135} |
| 1271 | Lₐ₁₃₆₄ | L_{b135} | 1272 | Lₐ₁₃₆₅ | L_{b135} |
| 1273 | Lₐ₁₃₈₅ | L_{b135} | 1274 | Lₐ₁₃₈₆ | L_{b135} |
| 1275 | Lₐ₁₄₀₀ | L_{b135} | 1276 | Lₐ₁₄₀₁ | L_{b135} |
| 1277 | Lₐ₂₈₉ | L_{b159} | 1278 | Lₐ₂₉₆ | L_{b159} |
| 1279 | Lₐ₃₀₄ | L_{b159} | 1280 | Lₐ₃₁₁ | L_{b159} |
| 1281 | Lₐ₃₁₆ | L_{b159} | 1282 | Lₐ₃₃₂ | L_{b159} |
| 1283 | Lₐ₄₄₆ | L_{b159} | 1284 | Lₐ₄₄₉ | L_{b159} |
| 1285 | Lₐ₄₅₂ | L_{b159} | 1286 | Lₐ₄₅₅ | L_{b159} |
| 1287 | Lₐ₄₆₇ | L_{b159} | 1288 | Lₐ₄₇₀ | L_{b159} |
| 1289 | Lₐ₄₇₃ | L_{b159} | 1290 | Lₐ₄₈₂ | L_{b159} |
| 1291 | Lₐ₄₈₃ | L_{b159} | 1292 | Lₐ₄₈₅ | L_{b159} |
| 1293 | Lₐ₄₈₈ | L_{b159} | 1294 | Lₐ₄₉₁ | L_{b159} |
| 1295 | Lₐ₄₉₄ | L_{b159} | 1296 | Lₐ₅₀₆ | L_{b159} |
| 1297 | Lₐ₅₁₂ | L_{b159} | 1298 | Lₐ₅₂₄ | L_{b159} |
| 1299 | Lₐ₅₂₇ | L_{b159} | 1300 | Lₐ₅₃₀ | L_{b159} |
| 1301 | Lₐ₅₃₃ | L_{b159} | 1302 | Lₐ₅₃₆ | L_{b159} |
| 1303 | Lₐ₅₄₂ | L_{b159} | 1304 | Lₐ₅₄₅ | L_{b159} |
| 1305 | Lₐ₅₅₄ | L_{b159} | 1306 | Lₐ₅₆₃ | L_{b159} |
| 1307 | Lₐ₅₇₂ | L_{b159} | 1308 | Lₐ₅₇₈ | L_{b159} |
| 1309 | Lₐ₅₈₀ | L_{b159} | 1310 | Lₐ₅₈₃ | L_{b159} |
| 1311 | Lₐ₅₈₆ | L_{b159} | 1312 | Lₐ₅₉₀ | L_{b159} |
| 1313 | Lₐ₅₉₉ | L_{b159} | 1314 | Lₐ₆₀₈ | L_{b159} |
| 1315 | Lₐ₆₁₇ | L_{b159} | 1316 | Lₐ₆₄₆ | L_{b159} |
| 1317 | Lₐ₆₅₀ | L_{b159} | 1318 | Lₐ₆₅₃ | L_{b159} |
| 1319 | Lₐ₆₅₆ | L_{b159} | 1320 | Lₐ₆₅₉ | L_{b159} |
| 1321 | Lₐ₆₆₅ | L_{b159} | 1322 | Lₐ₆₇₁ | L_{b159} |
| 1323 | Lₐ₆₇₇ | L_{b159} | 1324 | Lₐ₆₈₃ | L_{b159} |
| 1325 | Lₐ₆₈₉ | L_{b159} | 1326 | Lₐ₆₉₂ | L_{b159} |
| 1327 | Lₐ₆₉₅ | L_{b159} | 1328 | Lₐ₆₉₈ | L_{b159} |
| 1329 | Lₐ₇₀₄ | L_{b159} | 1330 | Lₐ₇₂₈ | L_{b159} |
| 1331 | Lₐ₇₃₁ | L_{b159} | 1332 | Lₐ₇₃₄ | L_{b159} |
| 1333 | Lₐ₇₃₇ | L_{b159} | 1334 | Lₐ₇₄₀ | L_{b159} |
| 1335 | Lₐ₇₄₃ | L_{b159} | 1336 | Lₐ₇₄₉ | L_{b159} |
| 1337 | Lₐ₇₅₅ | L_{b159} | 1338 | Lₐ₇₅₇ | L_{b159} |
| 1339 | Lₐ₇₆₁ | L_{b159} | 1340 | Lₐ₇₆₄ | L_{b159} |
| 1341 | Lₐ₇₆₅ | L_{b159} | 1342 | Lₐ₈₀₆ | L_{b159} |
| 1343 | Lₐ₈₀₉ | L_{b159} | 1344 | Lₐ₈₁₂ | L_{b159} |
| 1345 | Lₐ₈₁₈ | L_{b159} | 1346 | Lₐ₈₄₈ | L_{b159} |
| 1347 | Lₐ₈₅₁ | L_{b159} | 1348 | Lₐ₈₈₄ | L_{b159} |
| 1349 | Lₐ₈₈₇ | L_{b159} | 1350 | Lₐ₈₉₀ | L_{b159} |
| 1351 | Lₐ₈₉₃ | L_{b159} | 1352 | Lₐ₈₉₆ | L_{b159} |
| 1353 | Lₐ₈₉₉ | L_{b159} | 1354 | Lₐ₉₀₃ | L_{b159} |
| 1355 | Lₐ₉₀₅ | L_{b159} | 1356 | Lₐ₉₀₉ | L_{b159} |
| 1357 | Lₐ₉₁₁ | L_{b159} | 1358 | Lₐ₉₁₄ | L_{b159} |
| 1359 | Lₐ₉₁₇ | L_{b159} | 1360 | Lₐ₉₂₀ | L_{b159} |
| 1361 | Lₐ₉₂₁ | L_{b159} | 1362 | Lₐ₉₆₂ | L_{b159} |
| 1363 | Lₐ₉₆₃ | L_{b159} | 1364 | Lₐ₉₆₅ | L_{b159} |
| 1365 | Lₐ₉₆₉ | L_{b159} | 1366 | Lₐ₉₇₁ | L_{b159} |
| 1367 | Lₐ₉₇₄ | L_{b159} | 1368 | Lₐ₉₇₇ | L_{b159} |
| 1369 | Lₐ₉₈₀ | L_{b159} | 1370 | Lₐ₉₈₁ | L_{b159} |
| 1371 | Lₐ₉₈₇ | L_{b159} | 1372 | Lₐ₉₈₉ | L_{b159} |
| 1373 | Lₐ₉₉₃ | L_{b159} | 1374 | Lₐ₉₉₅ | L_{b159} |
| 1375 | Lₐ₉₉₈ | L_{b159} | 1376 | Lₐ₉₉₉ | L_{b159} |
| 1377 | Lₐ₁₀₀₀ | L_{b159} | 1378 | Lₐ₁₀₄₀ | L_{b159} |
| 1379 | Lₐ₁₀₄₃ | L_{b159} | 1380 | Lₐ₁₀₄₆ | L_{b159} |
| 1381 | Lₐ₁₂₈₆ | L_{b159} | 1382 | Lₐ₁₂₉₂ | L_{b159} |
| 1383 | Lₐ₁₂₉₃ | L_{b159} | 1384 | Lₐ₁₃₀₄ | L_{b159} |
| 1385 | Lₐ₁₃₁₆ | L_{b159} | 1386 | Lₐ₁₃₂₈ | L_{b159} |
| 1387 | Lₐ₁₃₆₄ | L_{b159} | 1388 | Lₐ₁₃₆₅ | L_{b159} |
| 1389 | Lₐ₁₃₈₅ | L_{b159} | 1390 | Lₐ₁₃₈₆ | L_{b159} |
| 1391 | Lₐ₁₄₀₀ | L_{b159} | 1392 | Lₐ₁₄₀₁ | L_{b159} |
| 1393 | Lₐ₂₈₉ | L_{b160} | 1394 | Lₐ₂₉₆ | L_{b160} |
| 1395 | Lₐ₃₀₄ | L_{b160} | 1396 | Lₐ₃₁₁ | L_{b160} |
| 1397 | Lₐ₃₁₆ | L_{b160} | 1398 | Lₐ₃₃₂ | L_{b160} |
| 1399 | Lₐ₄₄₆ | L_{b160} | 1400 | Lₐ₄₄₉ | L_{b160} |
| 1401 | Lₐ₄₅₂ | L_{b160} | 1402 | Lₐ₄₅₅ | L_{b160} |
| 1403 | Lₐ₄₆₇ | L_{b160} | 1404 | Lₐ₄₇₀ | L_{b160} |
| 1405 | Lₐ₄₇₃ | L_{b160} | 1406 | Lₐ₄₈₂ | L_{b160} |
| 1407 | Lₐ₄₈₃ | L_{b160} | 1408 | Lₐ₄₈₅ | L_{b160} |
| 1409 | Lₐ₄₈₈ | L_{b160} | 1410 | Lₐ₄₉₁ | L_{b160} |
| 1411 | Lₐ₄₉₄ | L_{b160} | 1412 | Lₐ₅₀₆ | L_{b160} |
| 1413 | Lₐ₅₁₂ | L_{b160} | 1414 | Lₐ₅₂₄ | L_{b160} |
| 1415 | Lₐ₅₂₇ | L_{b160} | 1416 | Lₐ₅₃₀ | L_{b160} |
| 1417 | Lₐ₅₃₃ | L_{b160} | 1418 | Lₐ₅₃₆ | L_{b160} |
| 1419 | Lₐ₅₄₂ | L_{b160} | 1420 | Lₐ₅₄₅ | L_{b160} |
| 1421 | Lₐ₅₅₄ | L_{b160} | 1422 | Lₐ₅₆₃ | L_{b160} |
| 1423 | Lₐ₅₇₂ | L_{b160} | 1424 | Lₐ₅₇₈ | L_{b160} |
| 1425 | Lₐ₅₈₀ | L_{b160} | 1426 | Lₐ₅₈₃ | L_{b160} |
| 1427 | Lₐ₅₈₆ | L_{b160} | 1428 | Lₐ₅₉₀ | L_{b160} |
| 1429 | Lₐ₅₉₉ | L_{b160} | 1430 | Lₐ₆₀₈ | L_{b160} |
| 1431 | Lₐ₆₁₇ | L_{b160} | 1432 | Lₐ₆₄₆ | L_{b160} |
| 1433 | Lₐ₆₅₀ | L_{b160} | 1434 | Lₐ₆₅₃ | L_{b160} |
| 1435 | Lₐ₆₅₆ | L_{b160} | 1436 | Lₐ₆₅₉ | L_{b160} |
| 1437 | Lₐ₆₆₅ | L_{b160} | 1438 | Lₐ₆₇₁ | L_{b160} |
| 1439 | Lₐ₆₇₇ | L_{b160} | 1440 | Lₐ₆₈₃ | L_{b160} |
| 1441 | Lₐ₆₈₉ | L_{b160} | 1442 | Lₐ₆₉₂ | L_{b160} |
| 1443 | Lₐ₆₉₅ | L_{b160} | 1444 | Lₐ₆₉₈ | L_{b160} |
| 1445 | Lₐ₇₀₄ | L_{b160} | 1446 | Lₐ₇₂₈ | L_{b160} |
| 1447 | Lₐ₇₃₁ | L_{b160} | 1448 | Lₐ₇₃₄ | L_{b160} |
| 1449 | Lₐ₇₃₇ | L_{b160} | 1450 | Lₐ₇₄₀ | L_{b160} |
| 1451 | Lₐ₇₄₃ | L_{b160} | 1452 | Lₐ₇₄₉ | L_{b160} |
| 1453 | Lₐ₇₅₅ | L_{b160} | 1454 | Lₐ₇₅₇ | L_{b160} |
| 1455 | Lₐ₇₆₁ | L_{b160} | 1456 | Lₐ₇₆₄ | L_{b160} |
| 1457 | Lₐ₇₆₅ | L_{b160} | 1458 | Lₐ₈₀₆ | L_{b160} |
| 1459 | Lₐ₈₀₉ | L_{b160} | 1460 | Lₐ₈₁₂ | L_{b160} |
| 1461 | Lₐ₈₁₈ | L_{b160} | 1462 | Lₐ₈₄₈ | L_{b160} |
| 1463 | Lₐ₈₅₁ | L_{b160} | 1464 | Lₐ₈₈₄ | L_{b160} |
| 1465 | Lₐ₈₈₇ | L_{b160} | 1466 | Lₐ₈₉₀ | L_{b160} |
| 1467 | Lₐ₈₉₃ | L_{b160} | 1468 | Lₐ₈₉₆ | L_{b160} |
| 1469 | Lₐ₈₉₉ | L_{b160} | 1470 | Lₐ₉₀₃ | L_{b160} |
| 1471 | Lₐ₉₀₅ | L_{b160} | 1472 | Lₐ₉₀₉ | L_{b160} |
| 1473 | Lₐ₉₁₁ | L_{b160} | 1474 | Lₐ₉₁₄ | L_{b160} |
| 1475 | Lₐ₉₁₇ | L_{b160} | 1476 | Lₐ₉₂₀ | L_{b160} |
| 1477 | Lₐ₉₂₁ | L_{b160} | 1478 | Lₐ₉₆₂ | L_{b160} |
| 1479 | Lₐ₉₆₃ | L_{b160} | 1480 | Lₐ₉₆₅ | L_{b160} |
| 1481 | Lₐ₉₆₉ | L_{b160} | 1482 | Lₐ₉₇₁ | L_{b160} |
| 1483 | Lₐ₉₇₄ | L_{b160} | 1484 | Lₐ₉₇₇ | L_{b160} |
| 1485 | Lₐ₉₈₀ | L_{b160} | 1486 | Lₐ₉₈₁ | L_{b160} |
| 1487 | Lₐ₉₈₇ | L_{b160} | 1488 | Lₐ₉₈₉ | L_{b160} |
| 1489 | Lₐ₉₉₃ | L_{b160} | 1490 | Lₐ₉₉₅ | L_{b160} |
| 1491 | Lₐ₉₉₈ | L_{b160} | 1492 | Lₐ₉₉₉ | L_{b160} |
| 1493 | Lₐ₁₀₀₀ | L_{b160} | 1494 | Lₐ₁₀₄₀ | L_{b160} |
| 1495 | Lₐ₁₀₄₃ | L_{b160} | 1496 | Lₐ₁₀₄₆ | L_{b160} |
| 1497 | Lₐ₁₂₈₆ | L_{b160} | 1498 | Lₐ₁₂₉₂ | L_{b160} |
| 1499 | Lₐ₁₂₉₃ | L_{b160} | 1500 | Lₐ₁₃₀₄ | L_{b160} |
| 1501 | Lₐ₁₃₁₆ | L_{b160} | 1502 | Lₐ₁₃₂₈ | L_{b160} |
| 1503 | Lₐ₁₃₆₄ | L_{b160} | 1504 | Lₐ₁₃₆₅ | L_{b160} |
| 1505 | Lₐ₁₃₈₅ | L_{b160} | 1506 | Lₐ₁₃₈₆ | L_{b160} |
| 1507 | Lₐ₁₄₀₀ | L_{b160} | 1508 | Lₐ₁₄₀₁ | L_{b160} |
| 1509 | Lₐ₁₄₂₀ | L_{b72} | 1510 | Lₐ₁₄₂₉ | L_{b72} |
| 1511 | Lₐ₁₄₂₀ | L_{b123} | 1512 | Lₐ₁₄₂₉ | L_{b123} |
| 1513 | Lₐ₁₄₂₀ | L_{b52} | 1514 | Lₐ₁₄₂₉ | L_{b52} |
| 1515 | Lₐ₁₄₂₀ | L_{b135} | 1516 | Lₐ₁₄₂₉ | L_{b135} |

14. The organic electroluminescent device according to claim 1, wherein E₁ to E₄ are, at each occurrence identically or differently, selected from C or CR_{c}; and/or V₁ to V₅ are, at each occurrence identically or differently, selected from CRᵥ, and/or W₁ to W₈ are, at each occurrence identically or differently, selected from CR_{wr}.

15. The organic electroluminescent device according to claim 1, wherein Ar₁ and Ar₂ are, at each occurrence identically or differently, selected from substituted or unsubstituted aryl having 6 to 20 carbon atoms, substituted or unsubstituted heteroaryl having 3 to 20 carbon atoms, or a combination thereof;
preferably, Ar₁ and Ar₂ are, at each occurrence identically or differently, selected from the group consisting of: substituted or unsubstituted phenyl, substituted or unsubstituted naphthyl, substituted or unsubstituted phenanthryl, substituted or unsubstituted biphenyl, substituted or unsubstituted terphenyl, substituted or unsubstituted triphenylene, substituted or unsubstituted fluorenyl, substituted or unsubstituted carbazolyl, substituted or unsubstituted dibenzofuryl, substituted or unsubstituted dibenzothienyl, and combinations thereof.

16. The organic electroluminescent device according to claim 1, wherein L₁ and L₂ are, at each occurrence identically or differently, selected from a single bond, substituted or unsubstituted arylene having 6 to 20 carbon atoms, substituted or unsubstituted heteroarylene having 3 to 20 carbon atoms, or a combination thereof;
preferably, L₁ and L₂ are, at each occurrence identically or differently, selected from a single bond, substituted or unsubstituted phenylene, substituted or unsubstituted biphenylene, substituted or unsubstituted naphthylene, substituted or unsubstituted pyridylene, or a combination thereof;
more preferably, L₁ and L₂ are, at each occurrence identically or differently, selected from a single bond, substituted or unsubstituted phenylene, or a combination thereof.

17. The organic electroluminescent device according to claim 1, wherein R_{c}, Rᵥ, and R_{w}, are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 20 carbon atoms, substituted or unsubstituted heteroaryl having 3 to 20 carbon atoms, cyano, and combinations thereof;
preferably, R_{c}, Rᵥ, and R_{w} are, at each occurrence identically or differently, selected from the group consisting of: hydrogen, deuterium, fluorine, substituted or unsubstituted phenyl, substituted or unsubstituted naphthyl, substituted or unsubstituted biphenyl, substituted or unsubstituted terphenyl, substituted or unsubstituted triphenylene, substituted or unsubstituted fluorenyl, substituted or unsubstituted carbazolyl, substituted or unsubstituted dibenzofuryl, substituted or unsubstituted dibenzothienyl, cyano, and combinations thereof.

18. The organic electroluminescent device according to claim 1, wherein the first compound is selected from the group consisting of Compound B-1 to Compound B-230, and Compound B-1 to Compound B-230 are selected from the following structures: 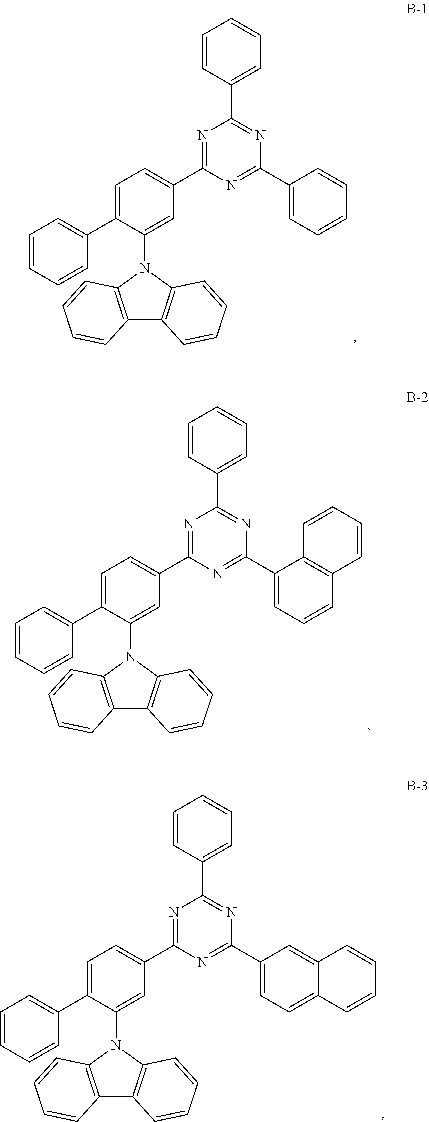 [SMILES: c1ccc(-c2nc(-c3ccccc3)nc(-c3ccc(-c4ccccc4)c(-n4c5ccccc5c5ccccc54)c3)n2)cc1 ; c1ccc(-c2nc(-c3ccc(-c4ccccc4)c(-n4c5ccccc5c5ccccc54)c3)nc(-c3cccc4ccccc34)n2)cc1 ; c1ccc(-c2nc(-c3ccc(-c4ccccc4)c(-n4c5ccccc5c5ccccc54)c3)nc(-c3ccc4ccccc4c3)n2)cc1] 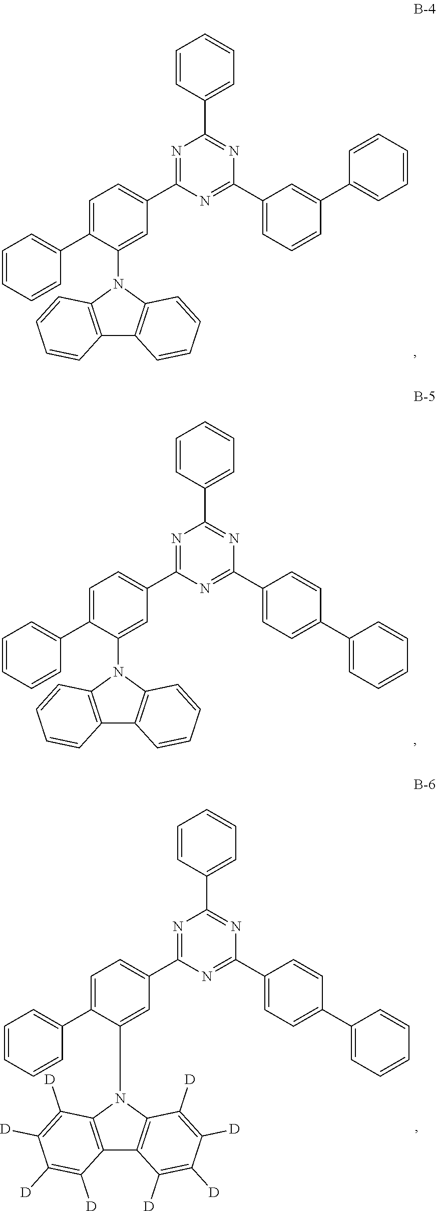 [SMILES: c1ccc(-c2cccc(-c3nc(-c4ccccc4)nc(-c4ccc(-c5ccccc5)c(-n5c6ccccc6c6ccccc65)c4)n3)c2)cc1 ; c1ccc(-c2ccc(-c3nc(-c4ccccc4)nc(-c4ccc(-c5ccccc5)c(-n5c6ccccc6c6ccccc65)c4)n3)cc2)cc1 ; [2H]c1c([2H])c([2H])c2c(c1[2H])c1c([2H])c([2H])c([2H])c([2H])c1n2-c1cc(-c2nc(-c3ccccc3)nc(-c3ccc(-c4ccccc4)cc3)n2)ccc1-c1ccccc1] 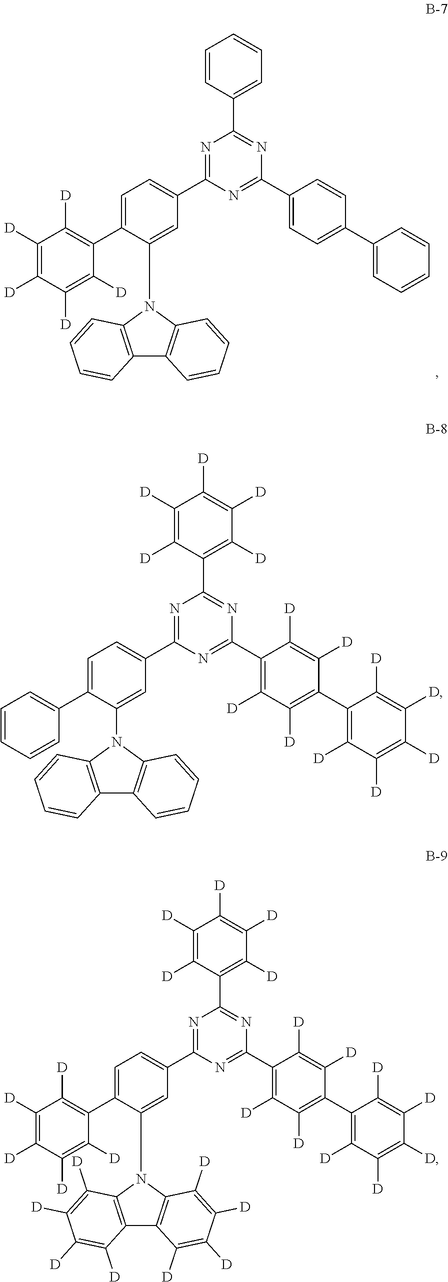 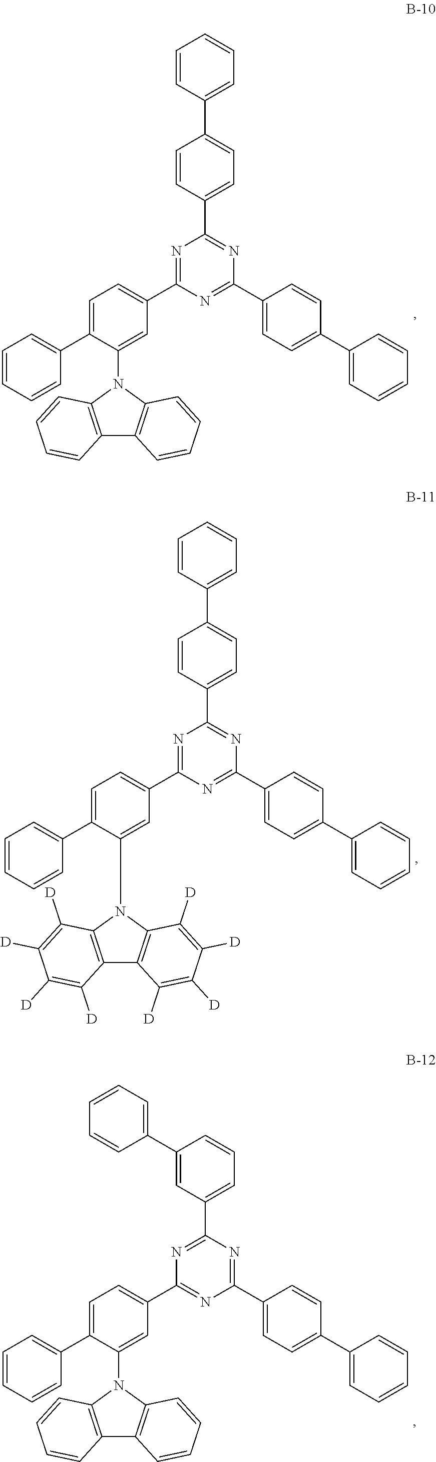 [SMILES: c1ccc(-c2ccc(-c3nc(-c4ccc(-c5ccccc5)cc4)nc(-c4ccc(-c5ccccc5)c(-n5c6ccccc6c6ccccc65)c4)n3)cc2)cc1 ; [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3ccc(-c4ccccc4)cc3)n2)ccc1-c1ccccc1 ; c1ccc(-c2ccc(-c3nc(-c4cccc(-c5ccccc5)c4)nc(-c4ccc(-c5ccccc5)c(-n5c6ccccc6c6ccccc65)c4)n3)cc2)cc1] 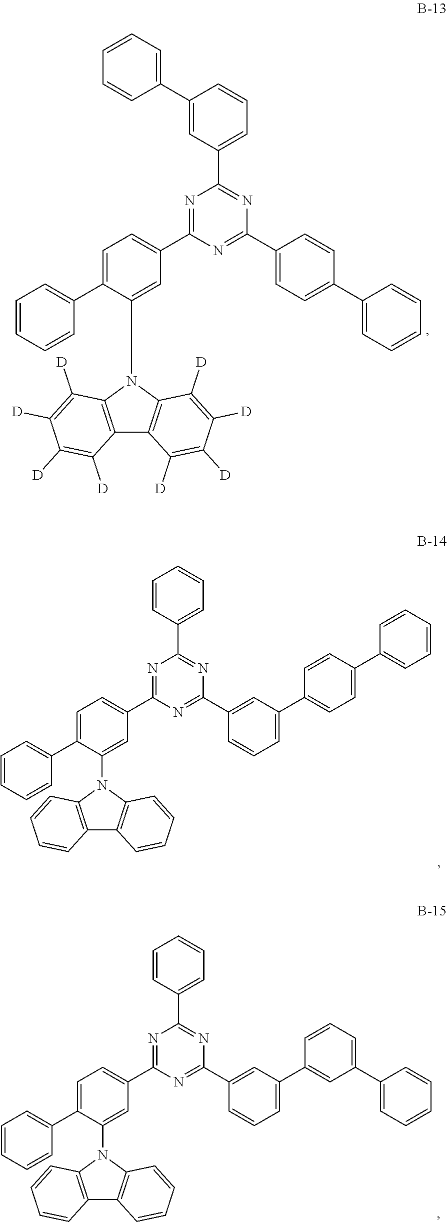 [SMILES: [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3cccc(-c4ccccc4)c3)n2)ccc1-c1ccccc1 ; c1ccc(-c2ccc(-c3cccc(-c4nc(-c5ccccc5)nc(-c5ccc(-c6ccccc6)c(-n6c7ccccc7c7ccccc76)c5)n4)c3)cc2)cc1 ; c1ccc(-c2cccc(-c3cccc(-c4nc(-c5ccccc5)nc(-c5ccc(-c6ccccc6)c(-n6c7ccccc7c7ccccc76)c5)n4)c3)c2)cc1] 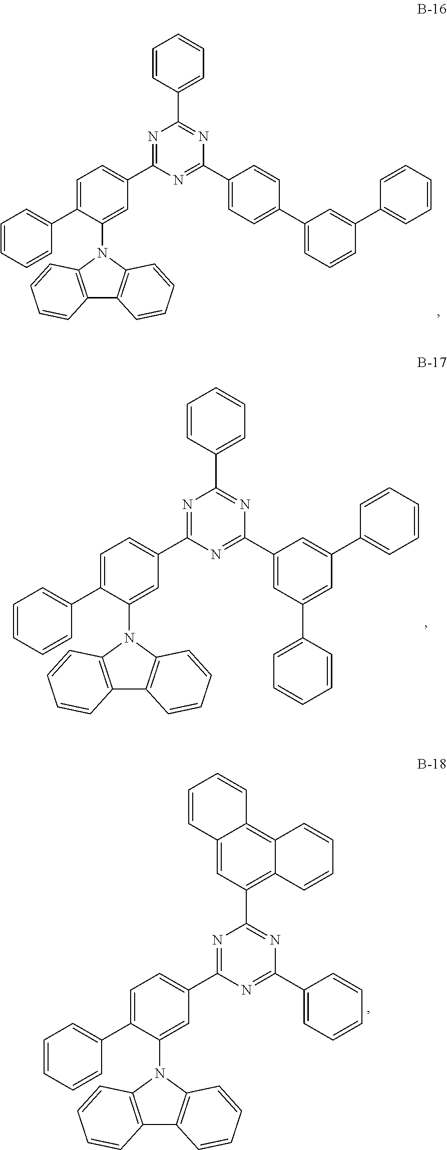 [SMILES: c1ccc(-c2cccc(-c3ccc(-c4nc(-c5ccccc5)nc(-c5ccc(-c6ccccc6)c(-n6c7ccccc7c7ccccc76)c5)n4)cc3)c2)cc1 ; c1ccc(-c2cc(-c3ccccc3)cc(-c3nc(-c4ccccc4)nc(-c4ccc(-c5ccccc5)c(-n5c6ccccc6c6ccccc65)c4)n3)c2)cc1 ; c1ccc(-c2nc(-c3ccc(-c4ccccc4)c(-n4c5ccccc5c5ccccc54)c3)nc(-c3cc4ccccc4c4ccccc34)n2)cc1] 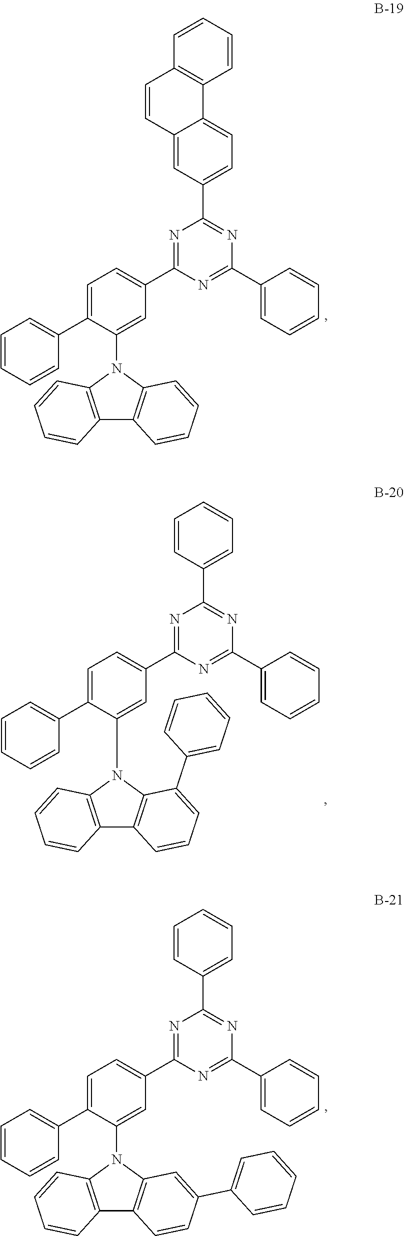 [SMILES: c1ccc(-c2nc(-c3ccc(-c4ccccc4)c(-n4c5ccccc5c5ccccc54)c3)nc(-c3ccc4c(ccc5ccccc54)c3)n2)cc1 ; c1ccc(-c2nc(-c3ccccc3)nc(-c3ccc(-c4ccccc4)c(-n4c5ccccc5c5cccc(-c6ccccc6)c54)c3)n2)cc1 ; c1ccc(-c2ccc3c4ccccc4n(-c4cc(-c5nc(-c6ccccc6)nc(-c6ccccc6)n5)ccc4-c4ccccc4)c3c2)cc1] 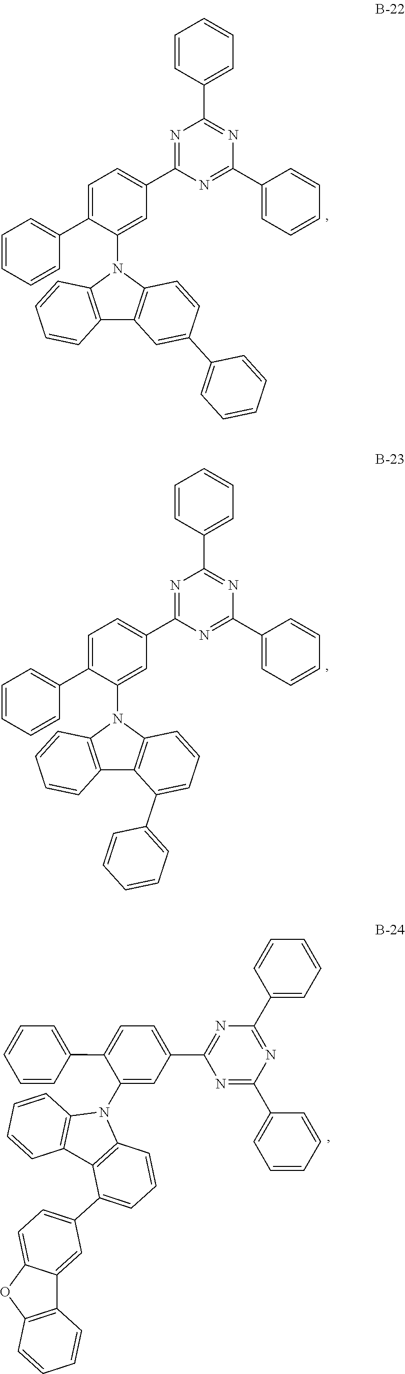 [SMILES: c1ccc(-c2ccc3c(c2)c2ccccc2n3-c2cc(-c3nc(-c4ccccc4)nc(-c4ccccc4)n3)ccc2-c2ccccc2)cc1 ; c1ccc(-c2nc(-c3ccccc3)nc(-c3ccc(-c4ccccc4)c(-n4c5ccccc5c5c(-c6ccccc6)cccc54)c3)n2)cc1 ; c1ccc(-c2nc(-c3ccccc3)nc(-c3ccc(-c4ccccc4)c(-n4c5ccccc5c5c(-c6ccc7oc8ccccc8c7c6)cccc54)c3)n2)cc1] 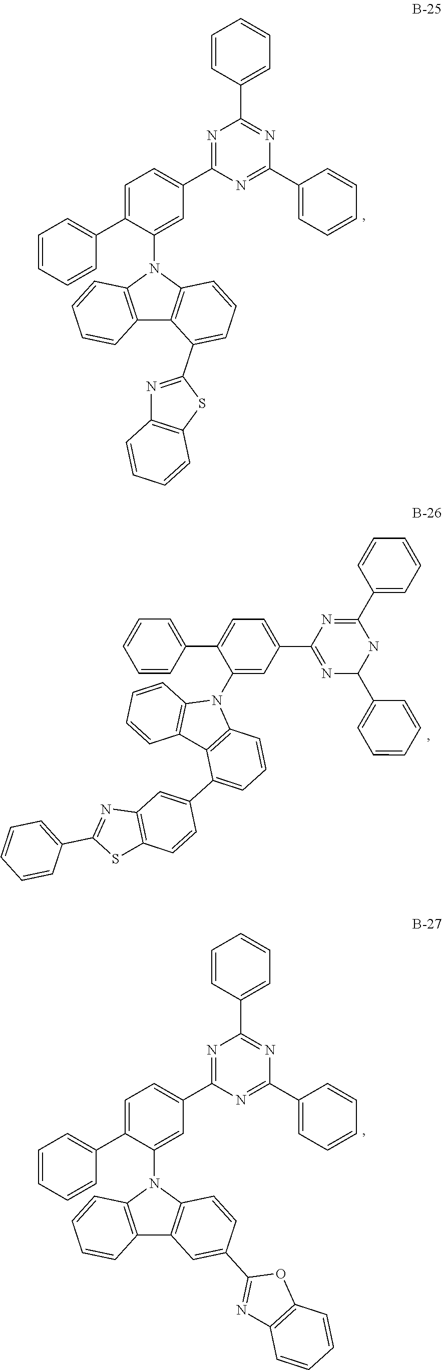 [SMILES: c1ccc(-c2nc(-c3ccccc3)nc(-c3ccc(-c4ccccc4)c(-n4c5ccccc5c5c(-c6nc7ccccc7s6)cccc54)c3)n2)cc1 ; c1ccc(C2=NC(c3ccc(-c4ccccc4)c(-n4c5ccccc5c5c(-c6ccc7sc(-c8ccccc8)nc7c6)cccc54)c3)=NC(c3ccccc3)N2)cc1 ; c1ccc(-c2nc(-c3ccccc3)nc(-c3ccc(-c4ccccc4)c(-n4c5ccccc5c5cc(-c6nc7ccccc7o6)ccc54)c3)n2)cc1] 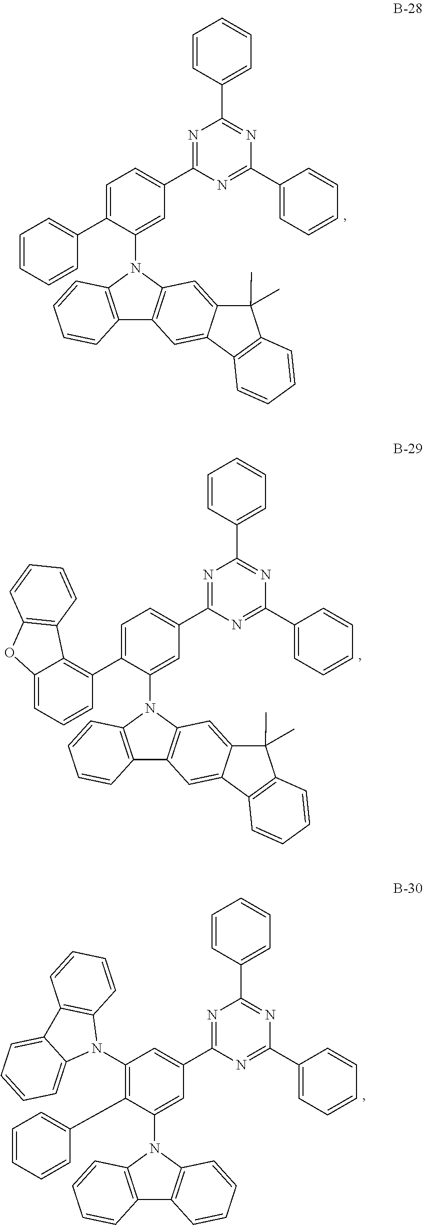 [SMILES: CC1(C)c2ccccc2-c2cc3c4ccccc4n(-c4cc(-c5nc(-c6ccccc6)nc(-c6ccccc6)n5)ccc4-c4ccccc4)c3cc21 ; CC1(C)c2ccccc2-c2cc3c4ccccc4n(-c4cc(-c5nc(-c6ccccc6)nc(-c6ccccc6)n5)ccc4-c4cccc5oc6ccccc6c45)c3cc21 ; c1ccc(-c2nc(-c3ccccc3)nc(-c3cc(-n4c5ccccc5c5ccccc54)c(-c4ccccc4)c(-n4c5ccccc5c5ccccc54)c3)n2)cc1] 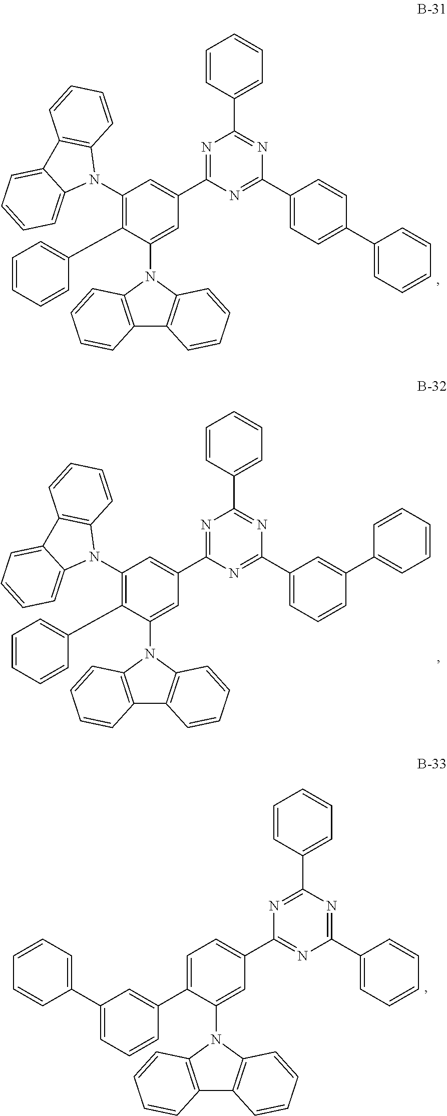 [SMILES: c1ccc(-c2ccc(-c3nc(-c4ccccc4)nc(-c4cc(-n5c6ccccc6c6ccccc65)c(-c5ccccc5)c(-n5c6ccccc6c6ccccc65)c4)n3)cc2)cc1 ; c1ccc(-c2cccc(-c3nc(-c4ccccc4)nc(-c4cc(-n5c6ccccc6c6ccccc65)c(-c5ccccc5)c(-n5c6ccccc6c6ccccc65)c4)n3)c2)cc1 ; c1ccc(-c2cccc(-c3ccc(-c4nc(-c5ccccc5)nc(-c5ccccc5)n4)cc3-n3c4ccccc4c4ccccc43)c2)cc1] 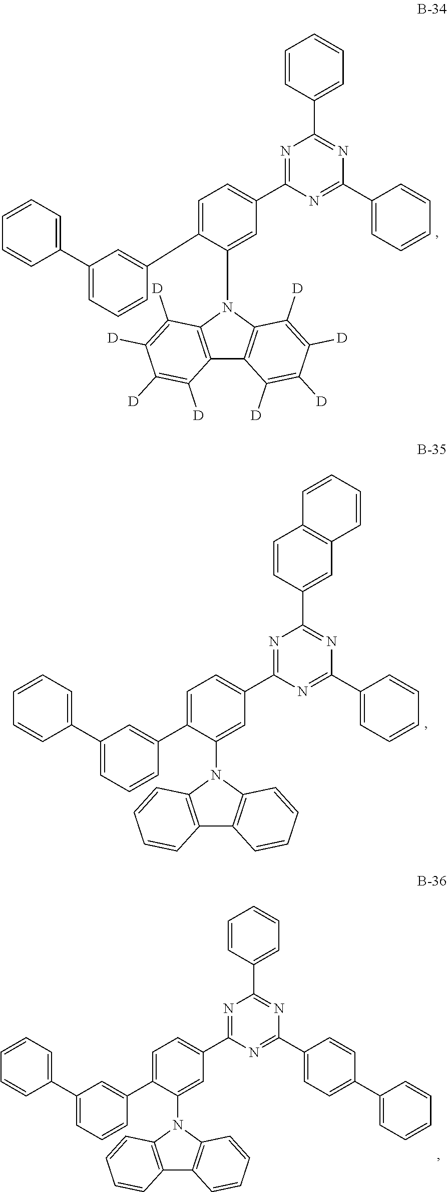 [SMILES: [2H]c1c([2H])c([2H])c2c(c1[2H])c1c([2H])c([2H])c([2H])c([2H])c1n2-c1cc(-c2nc(-c3ccccc3)nc(-c3ccccc3)n2)ccc1-c1cccc(-c2ccccc2)c1 ; c1ccc(-c2cccc(-c3ccc(-c4nc(-c5ccccc5)nc(-c5ccc6ccccc6c5)n4)cc3-n3c4ccccc4c4ccccc43)c2)cc1 ; c1ccc(-c2ccc(-c3nc(-c4ccccc4)nc(-c4ccc(-c5cccc(-c6ccccc6)c5)c(-n5c6ccccc6c6ccccc65)c4)n3)cc2)cc1] 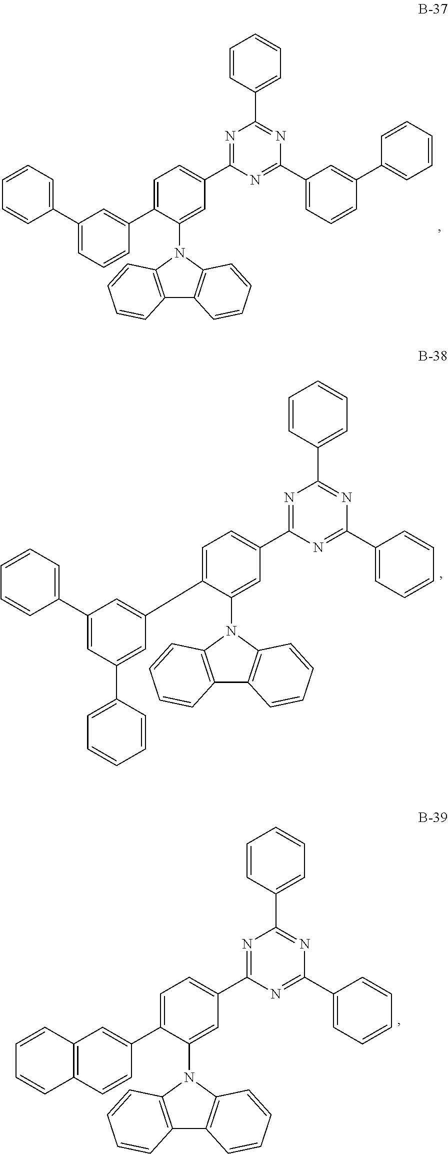 [SMILES: c1ccc(-c2cccc(-c3nc(-c4ccccc4)nc(-c4ccc(-c5cccc(-c6ccccc6)c5)c(-n5c6ccccc6c6ccccc65)c4)n3)c2)cc1 ; c1ccc(-c2cc(-c3ccccc3)cc(-c3ccc(-c4nc(-c5ccccc5)nc(-c5ccccc5)n4)cc3-n3c4ccccc4c4ccccc43)c2)cc1 ; c1ccc(-c2nc(-c3ccccc3)nc(-c3ccc(-c4ccc5ccccc5c4)c(-n4c5ccccc5c5ccccc54)c3)n2)cc1] 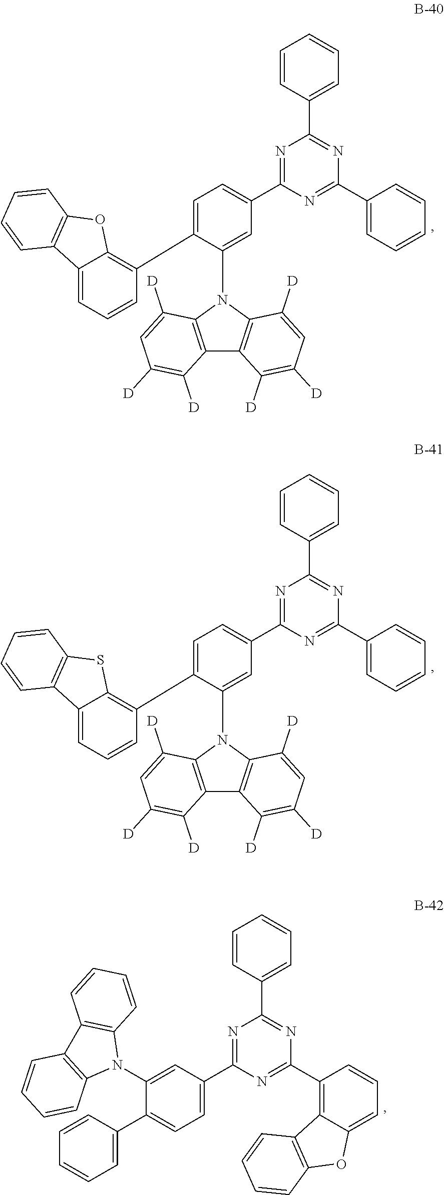 [SMILES: [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1oc1ccccc12 ; [2H]c1cc([2H])c2c(c1[2H])c1c([2H])c([2H])cc([2H])c1n2-c1cc(-c2nc(-c3ccccc3)nc(-c3ccccc3)n2)ccc1-c1cccc2c1sc1ccccc12 ; c1ccc(-c2nc(-c3ccc(-c4ccccc4)c(-n4c5ccccc5c5ccccc54)c3)nc(-c3cccc4oc5ccccc5c34)n2)cc1] 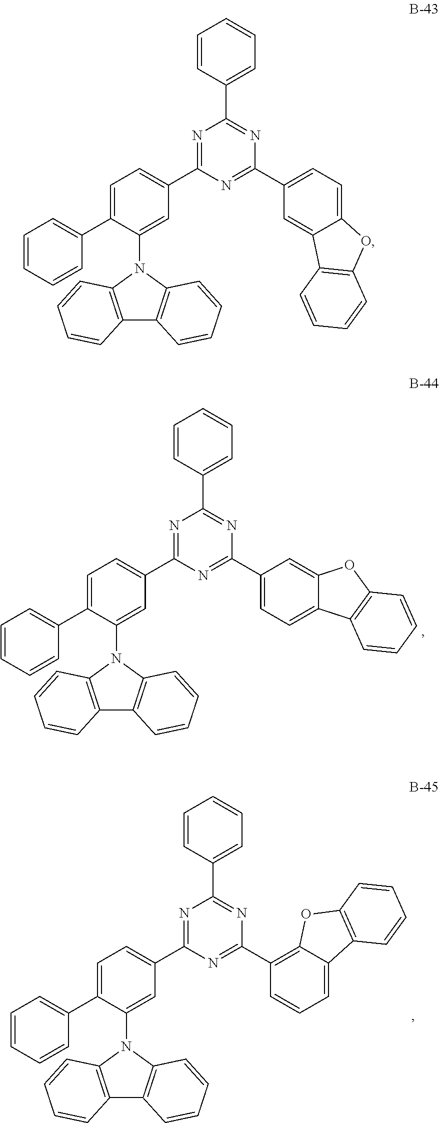 [SMILES: c1ccc(-c2nc(-c3ccc(-c4ccccc4)c(-n4c5ccccc5c5ccccc54)c3)nc(-c3ccc4oc5ccccc5c4c3)n2)cc1 ; c1ccc(-c2nc(-c3ccc(-c4ccccc4)c(-n4c5ccccc5c5ccccc54)c3)nc(-c3ccc4c(c3)oc3ccccc34)n2)cc1 ; "," ; c1ccc(-c2nc(-c3ccc(-c4ccccc4)c(-n4c5ccccc5c5ccccc54)c3)nc(-c3cccc4c3oc3ccccc34)n2)cc1] 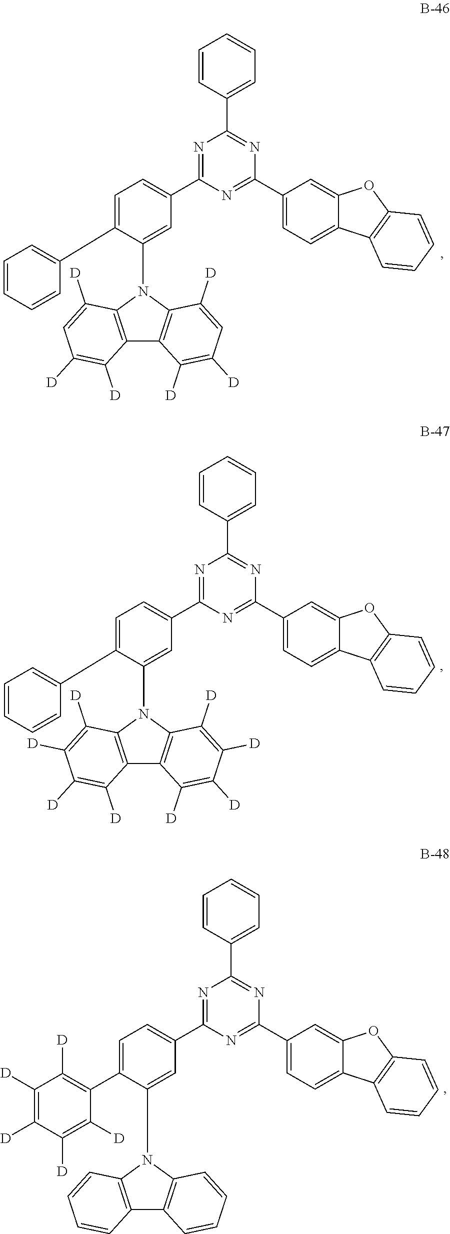 [SMILES: [2H]c1cc([2H])c2c(c1[2H])c1c([2H])c([2H])cc([2H])c1n2-c1cc(-c2nc(-c3ccccc3)nc(-c3ccc4c(c3)oc3ccccc34)n2)ccc1-c1ccccc1 ; [2H]c1c([2H])c([2H])c2c(c1[2H])c1c([2H])c([2H])c([2H])c([2H])c1n2-c1cc(-c2nc(-c3ccccc3)nc(-c3ccc4c(c3)oc3ccccc34)n2)ccc1-c1ccccc1 ; [2H]c1c([2H])c([2H])c(-c2ccc(-c3nc(-c4ccccc4)nc(-c4ccc5c(c4)oc4ccccc45)n3)cc2-n2c3ccccc3c3ccccc32)c([2H])c1[2H]] 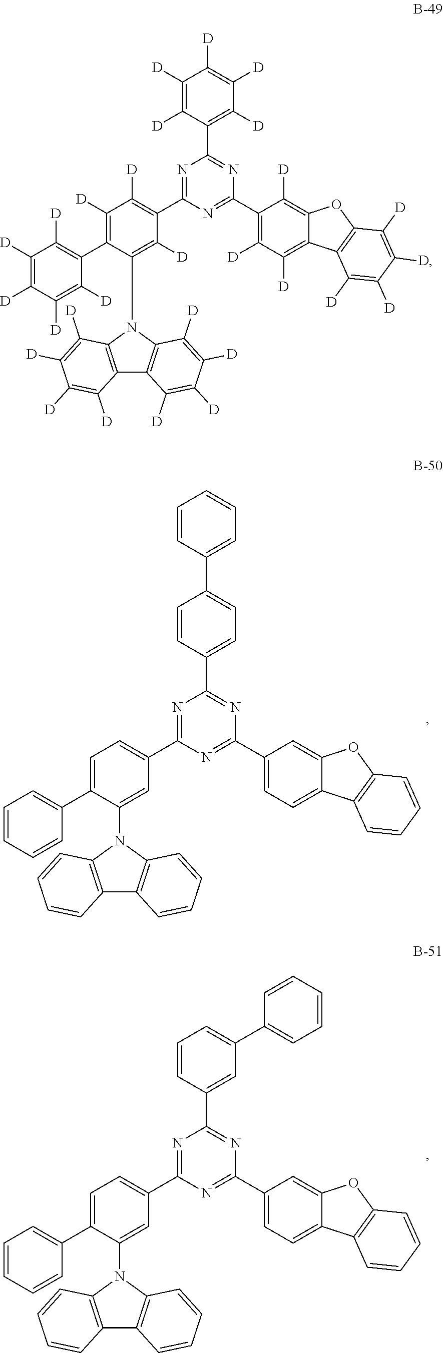 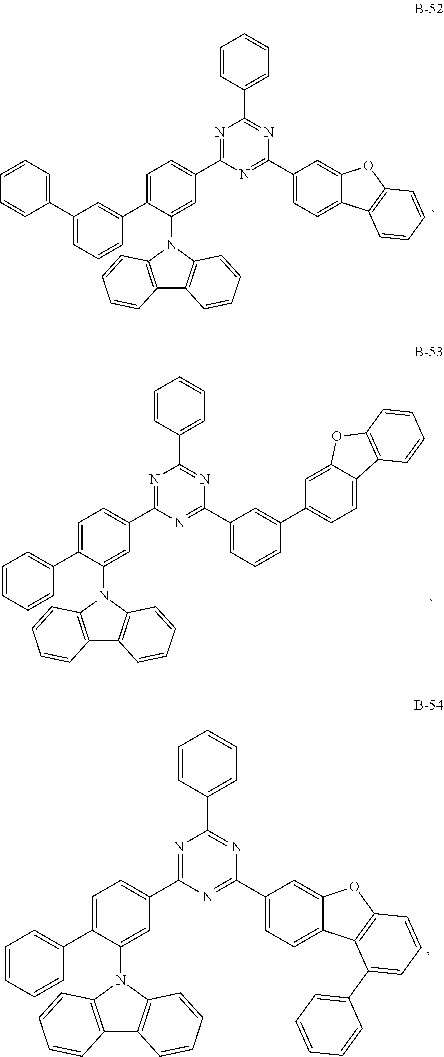 [SMILES: c1ccc(-c2cccc(-c3ccc(-c4nc(-c5ccccc5)nc(-c5ccc6c(c5)oc5ccccc56)n4)cc3-n3c4ccccc4c4ccccc43)c2)cc1 ; c1ccc(-c2nc(-c3cccc(-c4ccc5c(c4)oc4ccccc45)c3)nc(-c3ccc(-c4ccccc4)c(-n4c5ccccc5c5ccccc54)c3)n2)cc1 ; c1ccc(-c2nc(-c3ccc(-c4ccccc4)c(-n4c5ccccc5c5ccccc54)c3)nc(-c3ccc4c(c3)oc3cccc(-c5ccccc5)c34)n2)cc1] 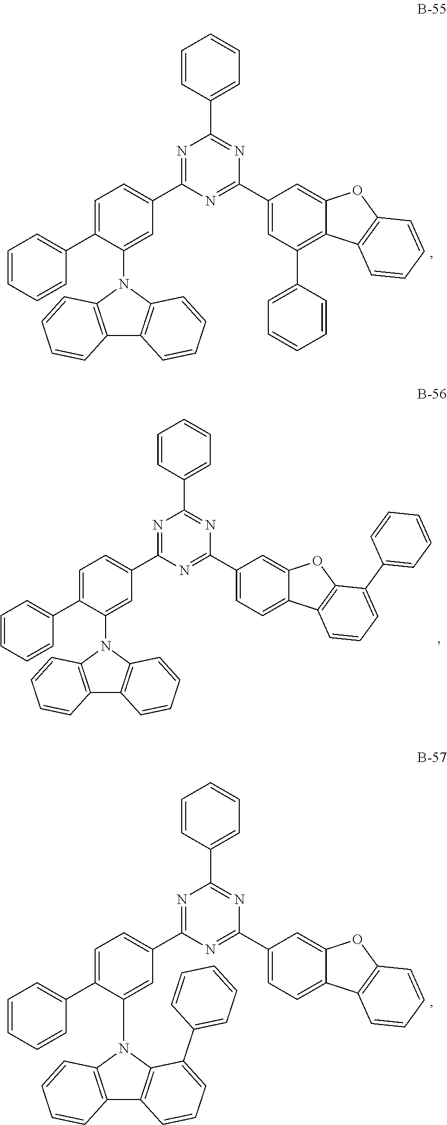 [SMILES: c1ccc(-c2nc(-c3ccc(-c4ccccc4)c(-n4c5ccccc5c5ccccc54)c3)nc(-c3cc(-c4ccccc4)c4c(c3)oc3ccccc34)n2)cc1 ; c1ccc(-c2nc(-c3ccc(-c4ccccc4)c(-n4c5ccccc5c5ccccc54)c3)nc(-c3ccc4c(c3)oc3c(-c5ccccc5)cccc34)n2)cc1 ; c1ccc(-c2nc(-c3ccc(-c4ccccc4)c(-n4c5ccccc5c5cccc(-c6ccccc6)c54)c3)nc(-c3ccc4c(c3)oc3ccccc34)n2)cc1] 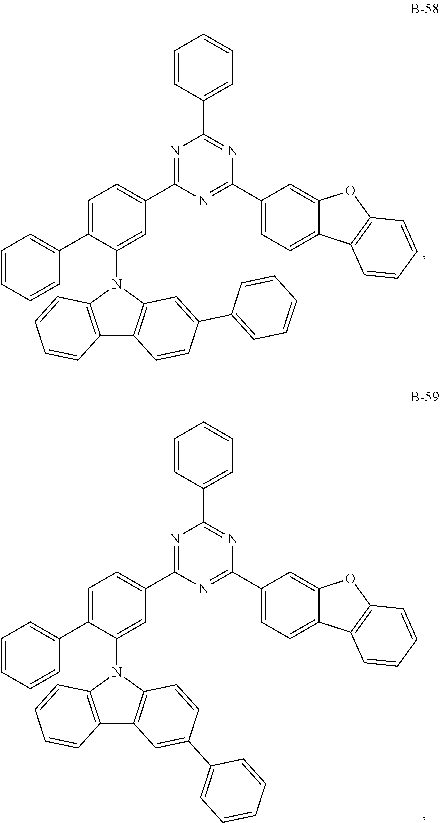 [SMILES: c1ccc(-c2ccc3c4ccccc4n(-c4cc(-c5nc(-c6ccccc6)nc(-c6ccc7c(c6)oc6ccccc67)n5)ccc4-c4ccccc4)c3c2)cc1 ; c1ccc(-c2ccc3c(c2)c2ccccc2n3-c2cc(-c3nc(-c4ccccc4)nc(-c4ccc5c(c4)oc4ccccc45)n3)ccc2-c2ccccc2)cc1] 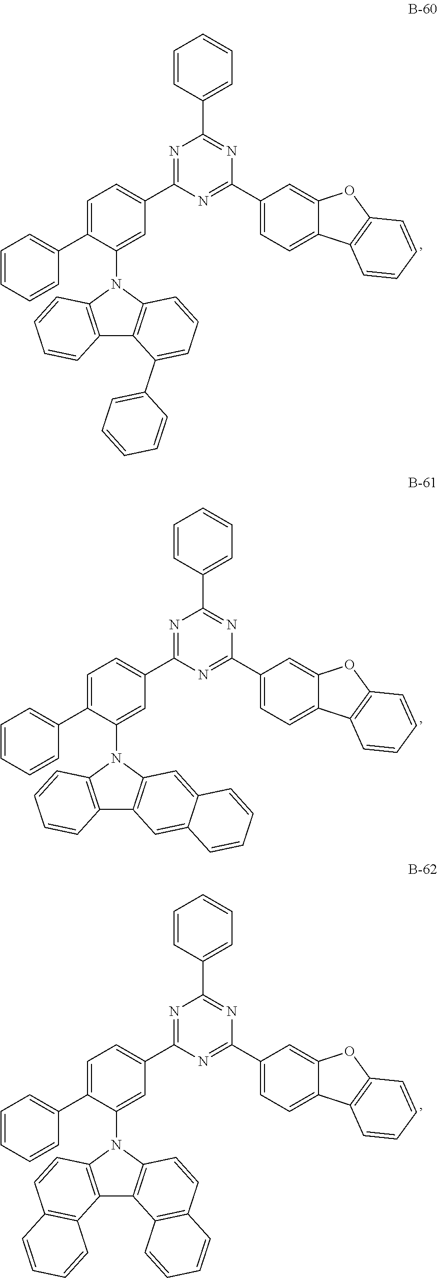 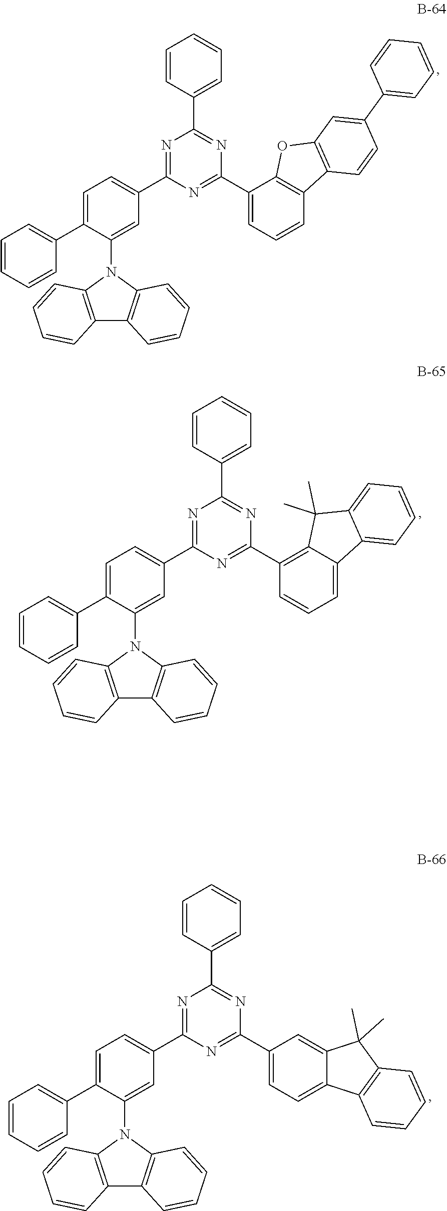 [SMILES: c1ccc(-c2ccc3c(c2)oc2c(-c4nc(-c5ccccc5)nc(-c5ccc(-c6ccccc6)c(-n6c7ccccc7c7ccccc76)c5)n4)cccc23)cc1 ; CC1(C)c2ccccc2-c2cccc(-c3nc(-c4ccccc4)nc(-c4ccc(-c5ccccc5)c(-n5c6ccccc6c6ccccc65)c4)n3)c21 ; CC1(C)c2ccccc2-c2ccc(-c3nc(-c4ccccc4)nc(-c4ccc(-c5ccccc5)c(-n5c6ccccc6c6ccccc65)c4)n3)cc21] 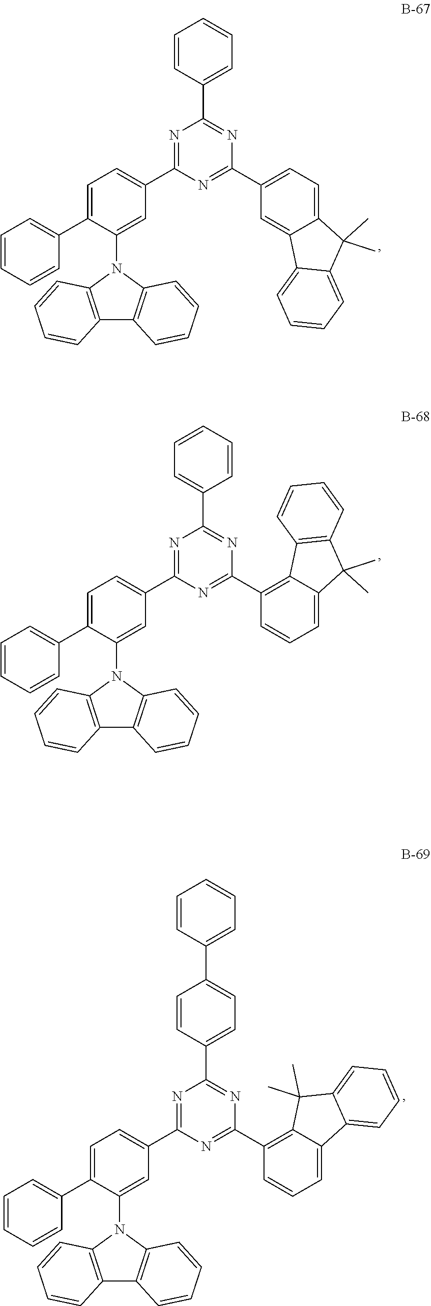 [SMILES: CC1(C)c2ccccc2-c2cc(-c3nc(-c4ccccc4)nc(-c4ccc(-c5ccccc5)c(-n5c6ccccc6c6ccccc65)c4)n3)ccc21 ; CC1(C)c2ccccc2-c2c(-c3nc(-c4ccccc4)nc(-c4ccc(-c5ccccc5)c(-n5c6ccccc6c6ccccc65)c4)n3)cccc21 ; CC1(C)c2ccccc2-c2cccc(-c3nc(-c4ccc(-c5ccccc5)cc4)nc(-c4ccc(-c5ccccc5)c(-n5c6ccccc6c6ccccc65)c4)n3)c21] 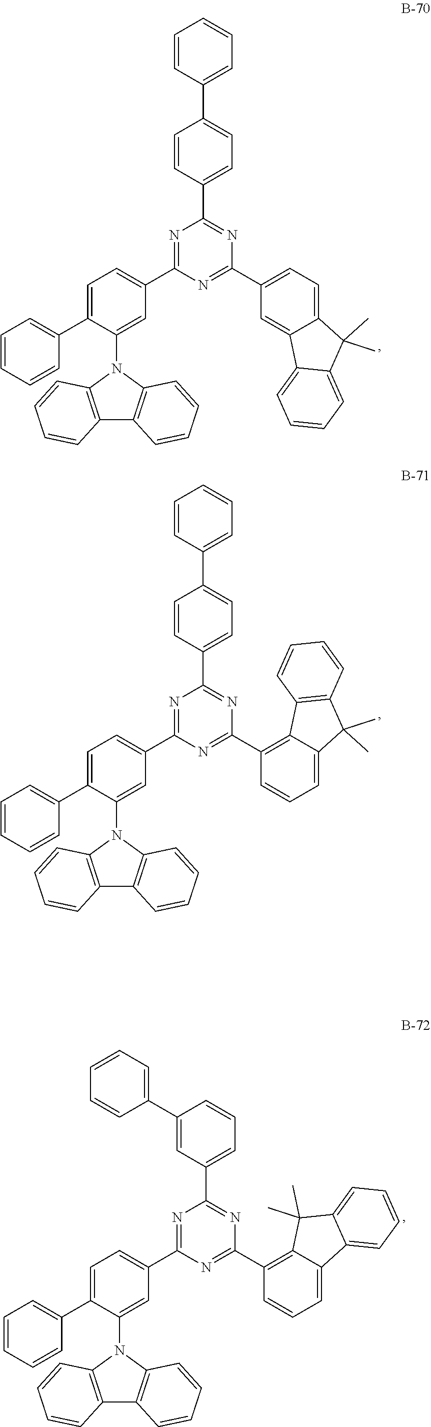 [SMILES: CC1(C)c2ccccc2-c2cc(-c3nc(-c4ccc(-c5ccccc5)cc4)nc(-c4ccc(-c5ccccc5)c(-n5c6ccccc6c6ccccc65)c4)n3)ccc21 ; CC1(C)c2ccccc2-c2c(-c3nc(-c4ccc(-c5ccccc5)cc4)nc(-c4ccc(-c5ccccc5)c(-n5c6ccccc6c6ccccc65)c4)n3)cccc21 ; CC1(C)c2ccccc2-c2cccc(-c3nc(-c4cccc(-c5ccccc5)c4)nc(-c4ccc(-c5ccccc5)c(-n5c6ccccc6c6ccccc65)c4)n3)c21] 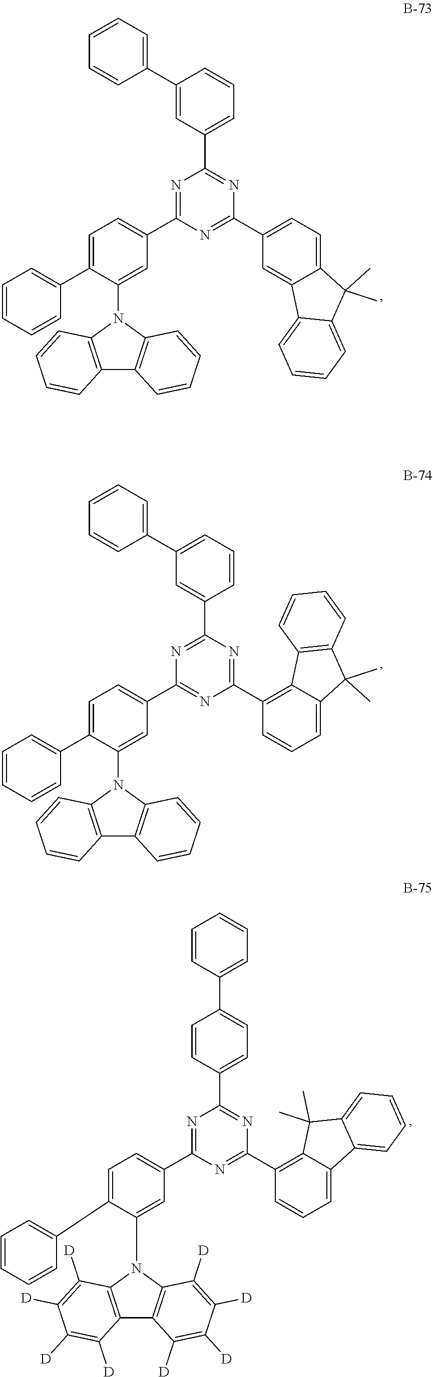 [SMILES: CC1(C)c2ccccc2-c2cc(-c3nc(-c4cccc(-c5ccccc5)c4)nc(-c4ccc(-c5ccccc5)c(-n5c6ccccc6c6ccccc65)c4)n3)ccc21 ; CC1(C)c2ccccc2-c2c(-c3nc(-c4cccc(-c5ccccc5)c4)nc(-c4ccc(-c5ccccc5)c(-n5c6ccccc6c6ccccc65)c4)n3)cccc21 ; [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3cccc4c3C(C)(C)c3ccccc3-4)n2)ccc1-c1ccccc1] 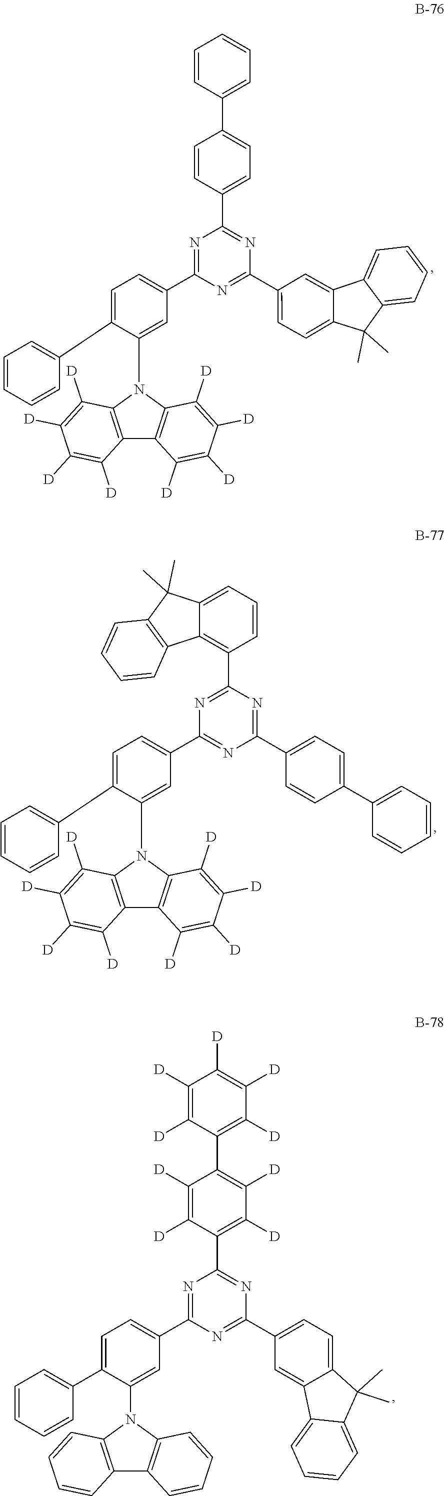 [SMILES: [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3ccc4c(c3)-c3ccccc3C4(C)C)n2)ccc1-c1ccccc1 ; [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3cccc4c3-c3ccccc3C4(C)C)n2)ccc1-c1ccccc1 ; [2H]c1c([2H])c([2H])c(-c2c([2H])c([2H])c(-c3nc(-c4ccc5c(c4)-c4ccccc4C5(C)C)nc(-c4ccc(-c5ccccc5)c(-n5c6ccccc6c6ccccc65)c4)n3)c([2H])c2[2H])c([2H])c1[2H]] 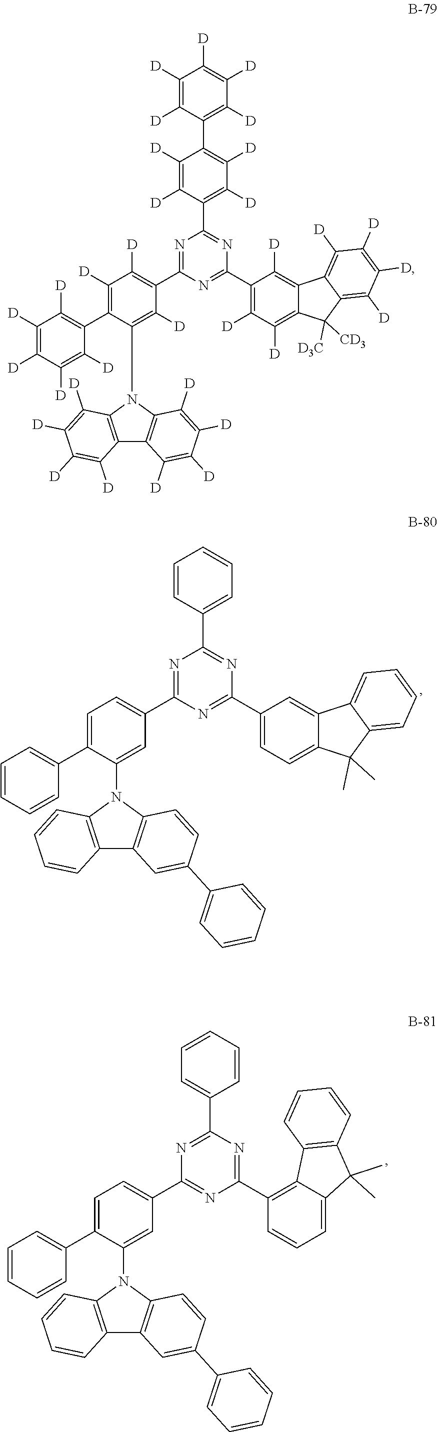 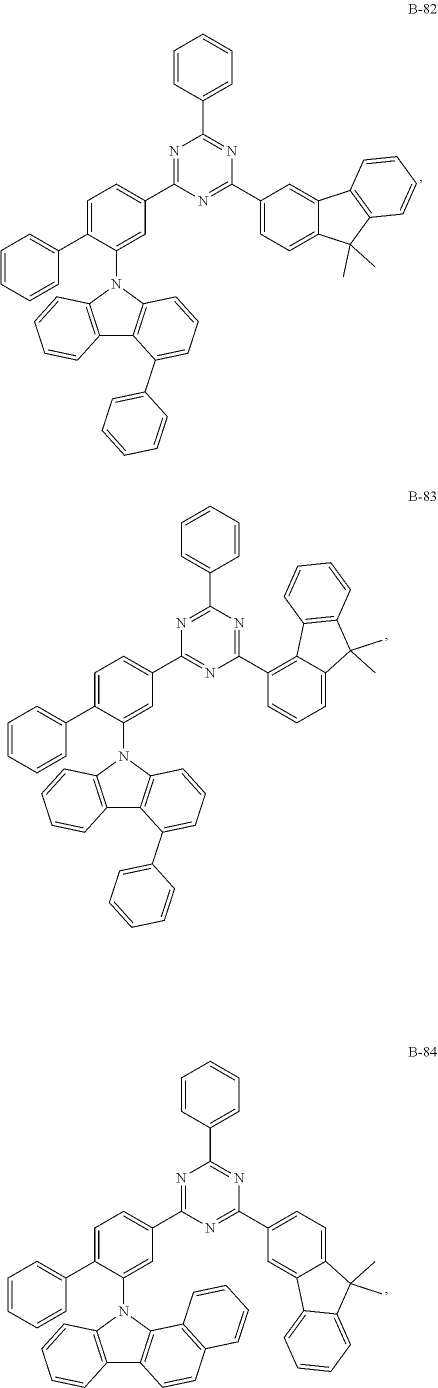 [SMILES: CC1(C)c2ccccc2-c2cc(-c3nc(-c4ccccc4)nc(-c4ccc(-c5ccccc5)c(-n5c6ccccc6c6c(-c7ccccc7)cccc65)c4)n3)ccc21 ; CC1(C)c2ccccc2-c2c(-c3nc(-c4ccccc4)nc(-c4ccc(-c5ccccc5)c(-n5c6ccccc6c6c(-c7ccccc7)cccc65)c4)n3)cccc21 ; CC1(C)c2ccccc2-c2cc(-c3nc(-c4ccccc4)nc(-c4ccc(-c5ccccc5)c(-n5c6ccccc6c6ccc7ccccc7c65)c4)n3)ccc21] 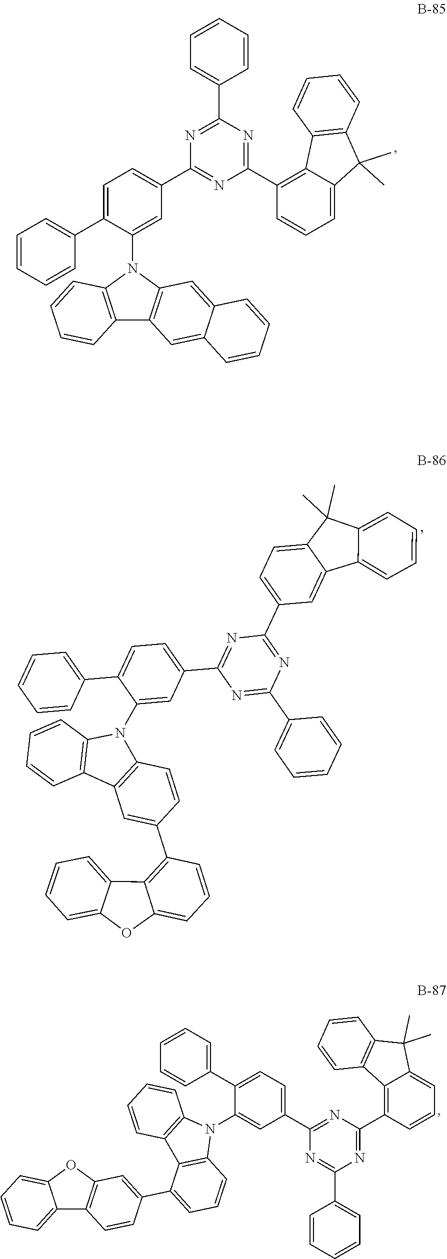 [SMILES: CC1(C)c2ccccc2-c2c(-c3nc(-c4ccccc4)nc(-c4ccc(-c5ccccc5)c(-n5c6ccccc6c6cc7ccccc7cc65)c4)n3)cccc21 ; CC1(C)c2ccccc2-c2cc(-c3nc(-c4ccccc4)nc(-c4ccc(-c5ccccc5)c(-n5c6ccccc6c6cc(-c7cccc8oc9ccccc9c78)ccc65)c4)n3)ccc21 ; CC1(C)c2ccccc2-c2c(-c3nc(-c4ccccc4)nc(-c4ccc(-c5ccccc5)c(-n5c6ccccc6c6c(-c7ccc8c(c7)oc7ccccc78)cccc65)c4)n3)cccc21] 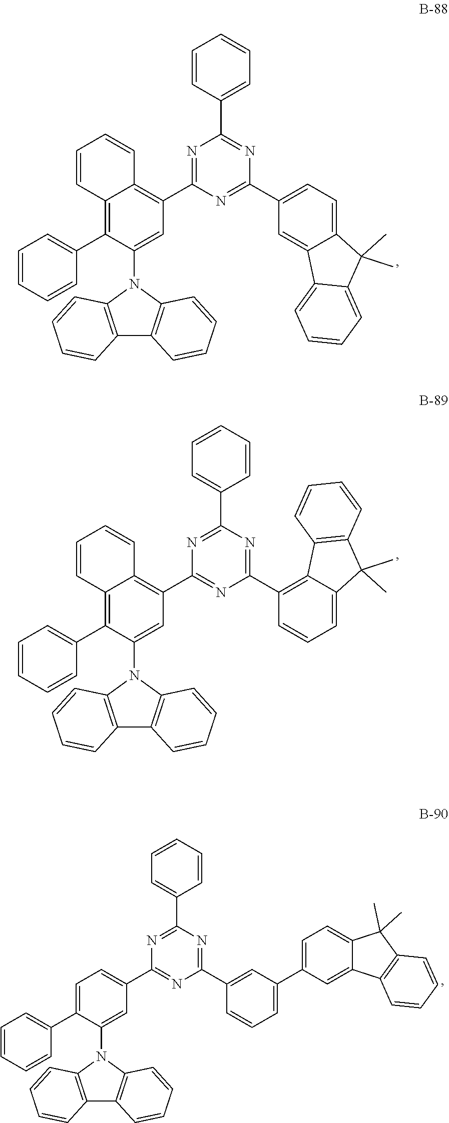 [SMILES: CC1(C)c2ccccc2-c2cc(-c3nc(-c4ccccc4)nc(-c4cc(-n5c6ccccc6c6ccccc65)c(-c5ccccc5)c5ccccc45)n3)ccc21 ; CC1(C)c2ccccc2-c2c(-c3nc(-c4ccccc4)nc(-c4cc(-n5c6ccccc6c6ccccc65)c(-c5ccccc5)c5ccccc45)n3)cccc21 ; CC1(C)c2ccccc2-c2cc(-c3cccc(-c4nc(-c5ccccc5)nc(-c5ccc(-c6ccccc6)c(-n6c7ccccc7c7ccccc76)c5)n4)c3)ccc21] 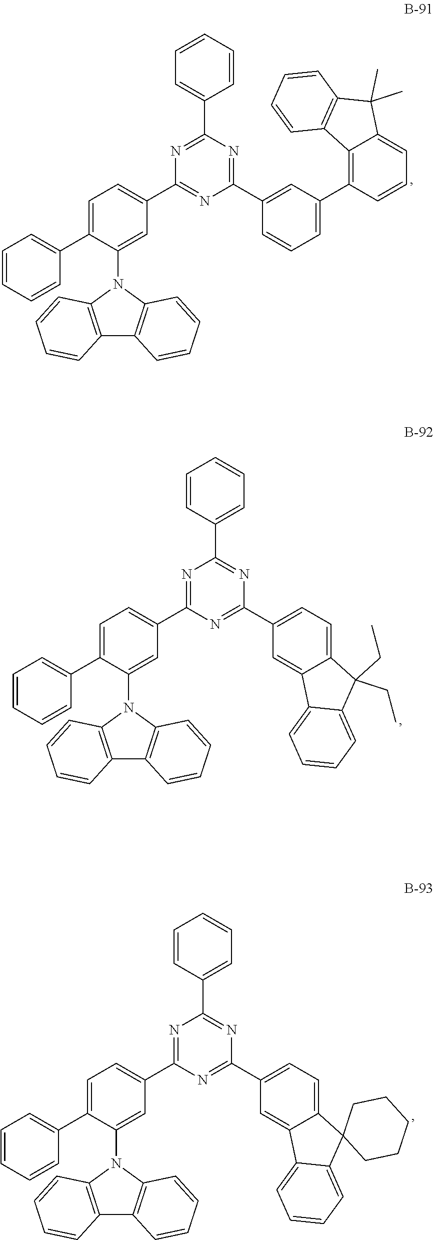 [SMILES: CC1(C)c2ccccc2-c2c(-c3cccc(-c4nc(-c5ccccc5)nc(-c5ccc(-c6ccccc6)c(-n6c7ccccc7c7ccccc76)c5)n4)c3)cccc21 ; CCC1(CC)c2ccccc2-c2cc(-c3nc(-c4ccccc4)nc(-c4ccc(-c5ccccc5)c(-n5c6ccccc6c6ccccc65)c4)n3)ccc21 ; c1ccc(-c2nc(-c3ccc4c(c3)-c3ccccc3C43CCCCC3)nc(-c3ccc(-c4ccccc4)c(-n4c5ccccc5c5ccccc54)c3)n2)cc1] 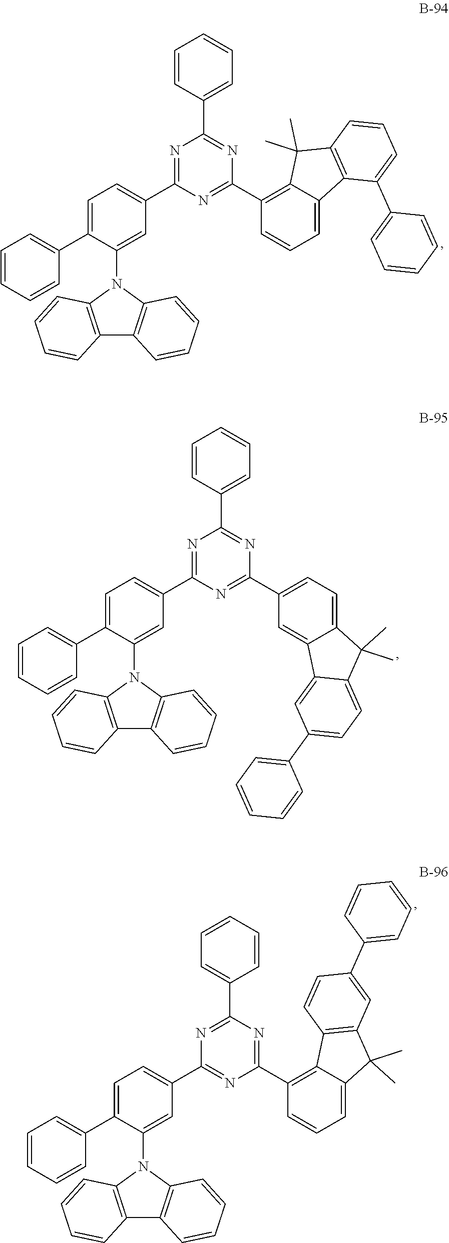 [SMILES: CC1(C)c2cccc(-c3ccccc3)c2-c2cccc(-c3nc(-c4ccccc4)nc(-c4ccc(-c5ccccc5)c(-n5c6ccccc6c6ccccc65)c4)n3)c21 ; CC1(C)c2ccc(-c3ccccc3)cc2-c2cc(-c3nc(-c4ccccc4)nc(-c4ccc(-c5ccccc5)c(-n5c6ccccc6c6ccccc65)c4)n3)ccc21 ; CC1(C)c2cc(-c3ccccc3)ccc2-c2c(-c3nc(-c4ccccc4)nc(-c4ccc(-c5ccccc5)c(-n5c6ccccc6c6ccccc65)c4)n3)cccc21] 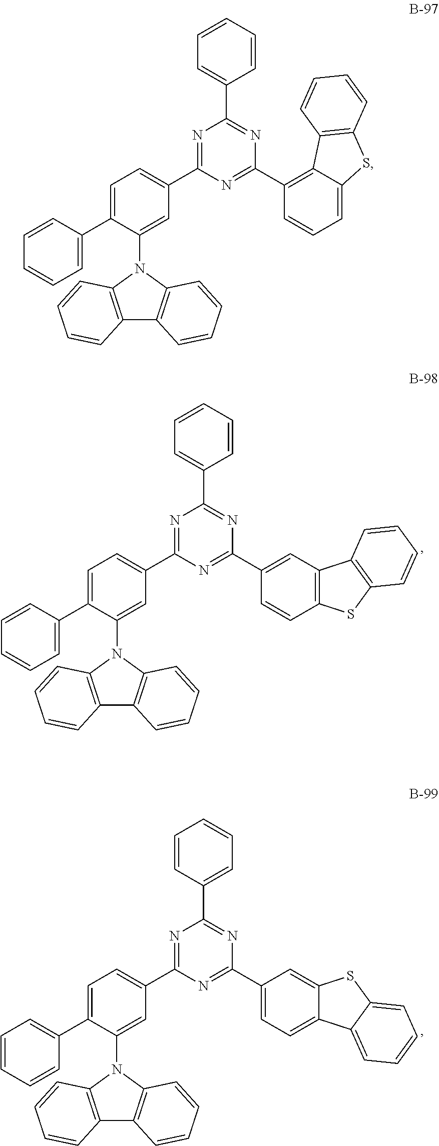 [SMILES: c1ccc(-c2nc(-c3ccc(-c4ccccc4)c(-n4c5ccccc5c5ccccc54)c3)nc(-c3cccc4sc5ccccc5c34)n2)cc1 ; c1ccc(-c2nc(-c3ccc(-c4ccccc4)c(-n4c5ccccc5c5ccccc54)c3)nc(-c3ccc4sc5ccccc5c4c3)n2)cc1 ; c1ccc(-c2nc(-c3ccc(-c4ccccc4)c(-n4c5ccccc5c5ccccc54)c3)nc(-c3ccc4c(c3)sc3ccccc34)n2)cc1] 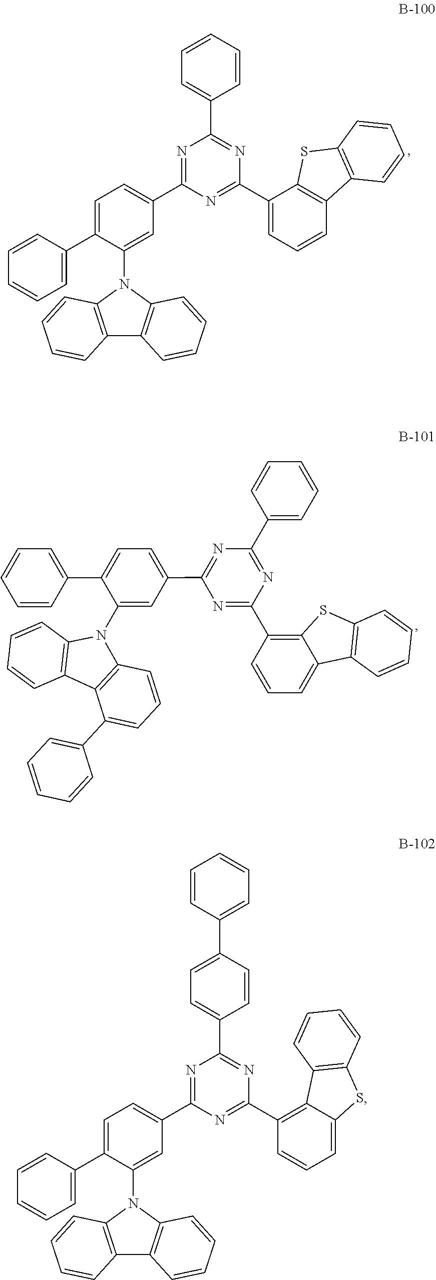 [SMILES: c1ccc(-c2nc(-c3ccc(-c4ccccc4)c(-n4c5ccccc5c5ccccc54)c3)nc(-c3cccc4c3sc3ccccc34)n2)cc1 ; c1ccc(-c2nc(-c3ccc(-c4ccccc4)c(-n4c5ccccc5c5c(-c6ccccc6)cccc54)c3)nc(-c3cccc4c3sc3ccccc34)n2)cc1 ; c1ccc(-c2ccc(-c3nc(-c4ccc(-c5ccccc5)c(-n5c6ccccc6c6ccccc65)c4)nc(-c4cccc5sc6ccccc6c45)n3)cc2)cc1] 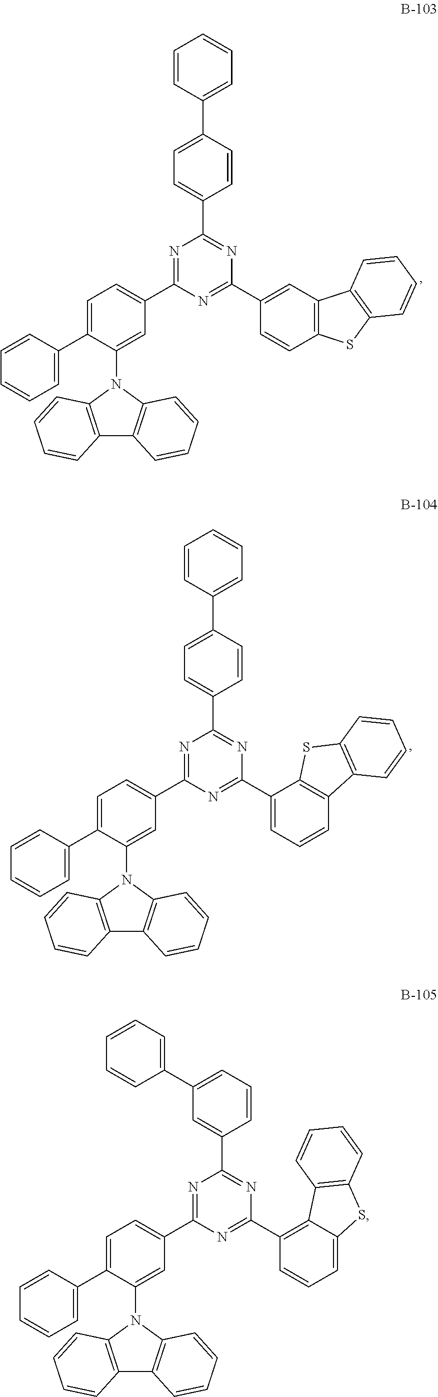 [SMILES: c1ccc(-c2ccc(-c3nc(-c4ccc(-c5ccccc5)c(-n5c6ccccc6c6ccccc65)c4)nc(-c4ccc5sc6ccccc6c5c4)n3)cc2)cc1 ; c1ccc(-c2ccc(-c3nc(-c4ccc(-c5ccccc5)c(-n5c6ccccc6c6ccccc65)c4)nc(-c4cccc5c4sc4ccccc45)n3)cc2)cc1 ; c1ccc(-c2cccc(-c3nc(-c4ccc(-c5ccccc5)c(-n5c6ccccc6c6ccccc65)c4)nc(-c4cccc5sc6ccccc6c45)n3)c2)cc1] 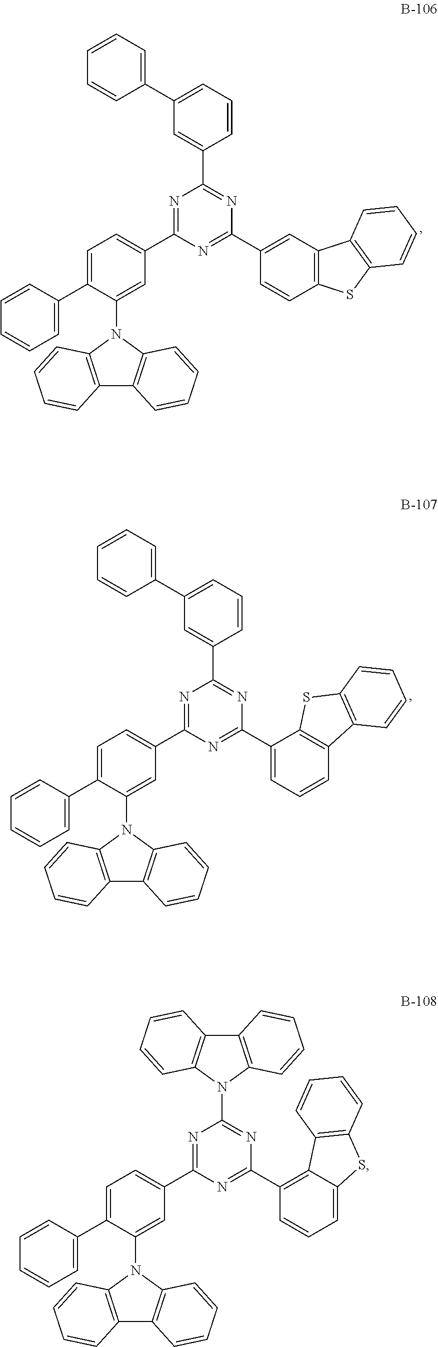 [SMILES: c1ccc(-c2cccc(-c3nc(-c4ccc(-c5ccccc5)c(-n5c6ccccc6c6ccccc65)c4)nc(-c4ccc5sc6ccccc6c5c4)n3)c2)cc1 ; c1ccc(-c2cccc(-c3nc(-c4ccc(-c5ccccc5)c(-n5c6ccccc6c6ccccc65)c4)nc(-c4cccc5c4sc4ccccc45)n3)c2)cc1 ; c1ccc(-c2ccc(-c3nc(-c4cccc5sc6ccccc6c45)nc(-n4c5ccccc5c5ccccc54)n3)cc2-n2c3ccccc3c3ccccc32)cc1] 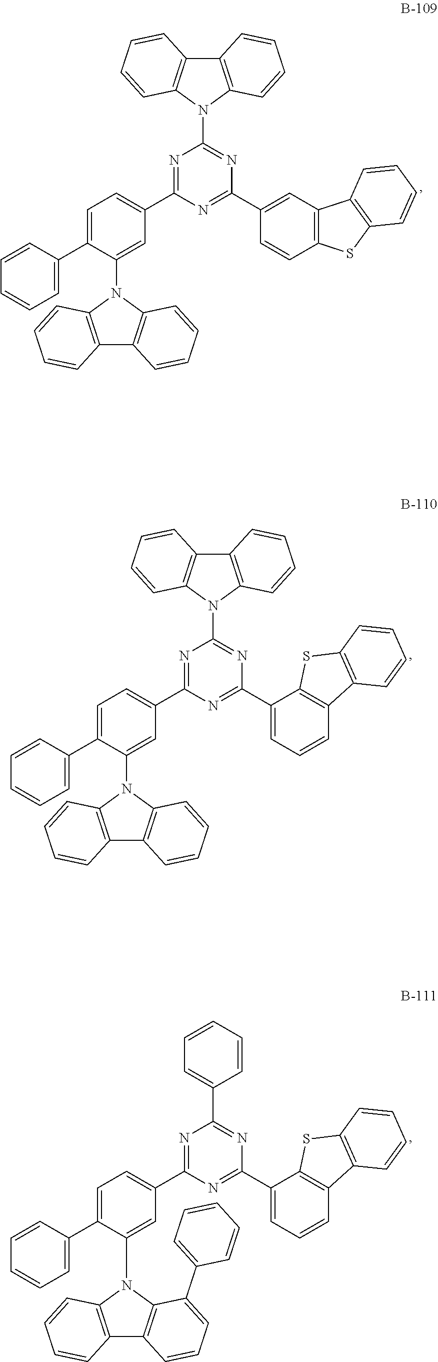 [SMILES: c1ccc(-c2ccc(-c3nc(-c4ccc5sc6ccccc6c5c4)nc(-n4c5ccccc5c5ccccc54)n3)cc2-n2c3ccccc3c3ccccc32)cc1 ; c1ccc(-c2ccc(-c3nc(-c4cccc5c4sc4ccccc45)nc(-n4c5ccccc5c5ccccc54)n3)cc2-n2c3ccccc3c3ccccc32)cc1 ; c1ccc(-c2nc(-c3ccc(-c4ccccc4)c(-n4c5ccccc5c5cccc(-c6ccccc6)c54)c3)nc(-c3cccc4c3sc3ccccc34)n2)cc1] 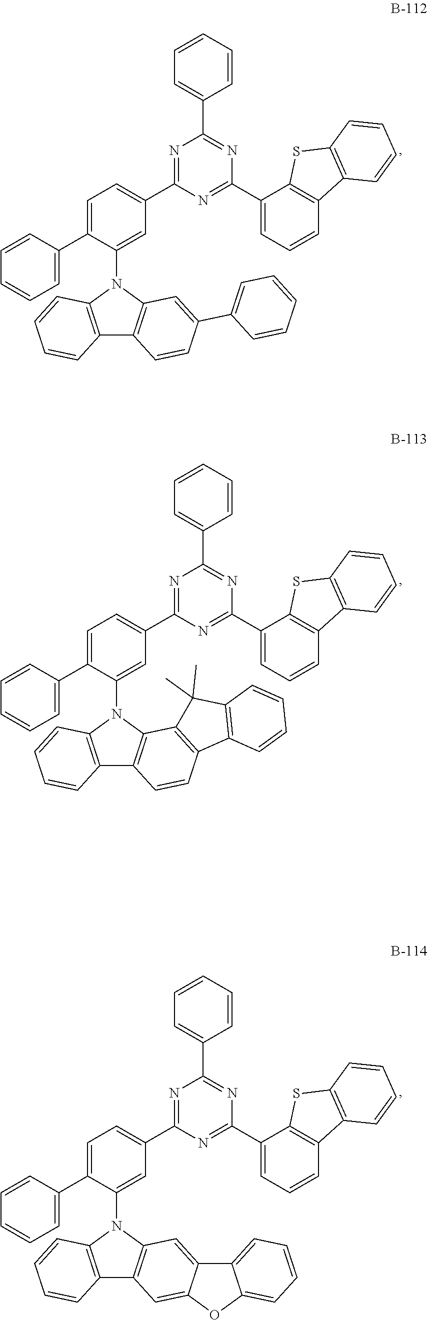 [SMILES: c1ccc(-c2ccc3c4ccccc4n(-c4cc(-c5nc(-c6ccccc6)nc(-c6cccc7c6sc6ccccc67)n5)ccc4-c4ccccc4)c3c2)cc1 ; CC1(C)c2ccccc2-c2ccc3c4ccccc4n(-c4cc(-c5nc(-c6ccccc6)nc(-c6cccc7c6sc6ccccc67)n5)ccc4-c4ccccc4)c3c21 ; c1ccc(-c2nc(-c3ccc(-c4ccccc4)c(-n4c5ccccc5c5cc6oc7ccccc7c6cc54)c3)nc(-c3cccc4c3sc3ccccc34)n2)cc1] 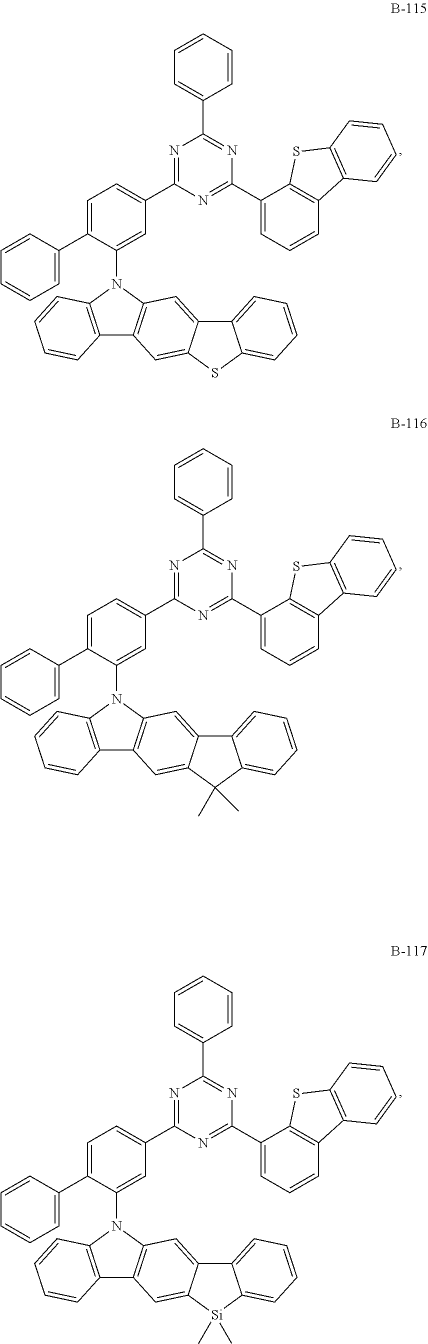 [SMILES: c1ccc(-c2nc(-c3ccc(-c4ccccc4)c(-n4c5ccccc5c5cc6sc7ccccc7c6cc54)c3)nc(-c3cccc4c3sc3ccccc34)n2)cc1 ; CC1(C)c2ccccc2-c2cc3c(cc21)c1ccccc1n3-c1cc(-c2nc(-c3ccccc3)nc(-c3cccc4c3sc3ccccc34)n2)ccc1-c1ccccc1 ; C[Si]1(C)c2ccccc2-c2cc3c(cc21)c1ccccc1n3-c1cc(-c2nc(-c3ccccc3)nc(-c3cccc4c3sc3ccccc34)n2)ccc1-c1ccccc1] 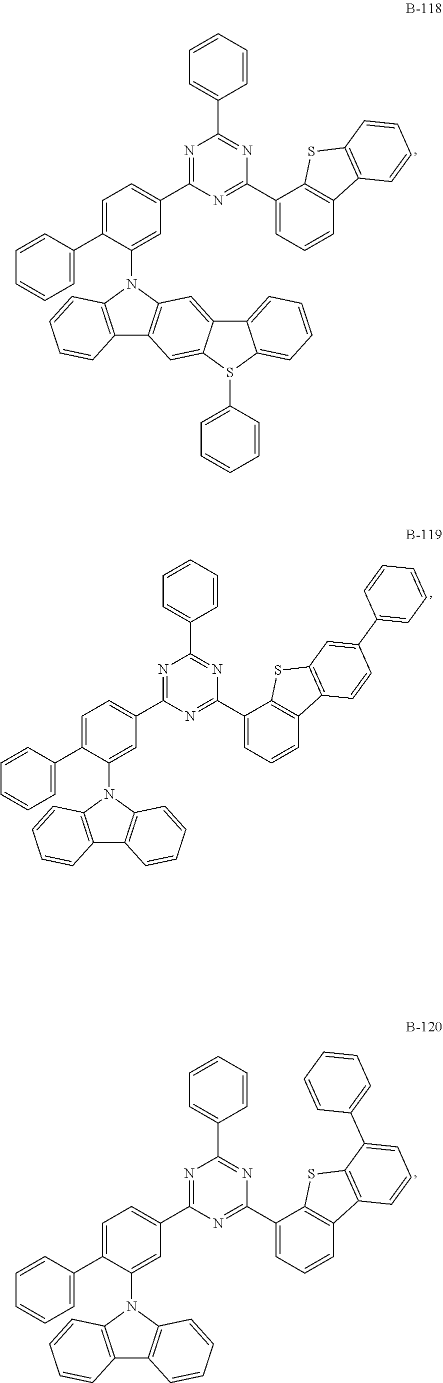 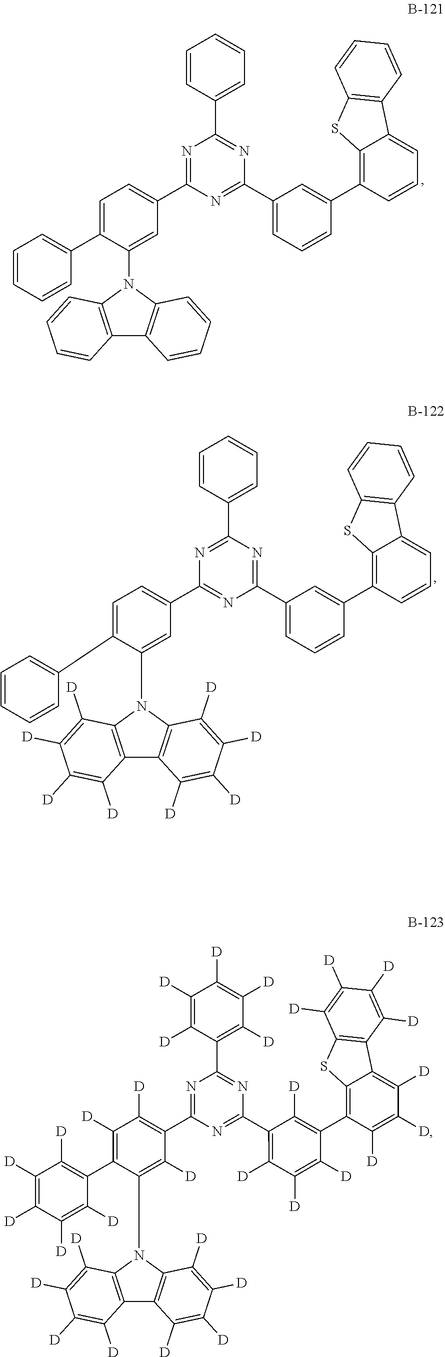 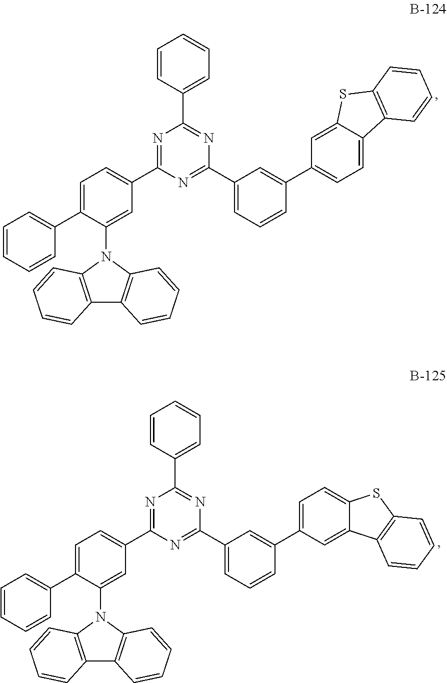 [SMILES: c1ccc(-c2nc(-c3cccc(-c4ccc5c(c4)sc4ccccc45)c3)nc(-c3ccc(-c4ccccc4)c(-n4c5ccccc5c5ccccc54)c3)n2)cc1 ; c1ccc(-c2nc(-c3cccc(-c4ccc5sc6ccccc6c5c4)c3)nc(-c3ccc(-c4ccccc4)c(-n4c5ccccc5c5ccccc54)c3)n2)cc1] 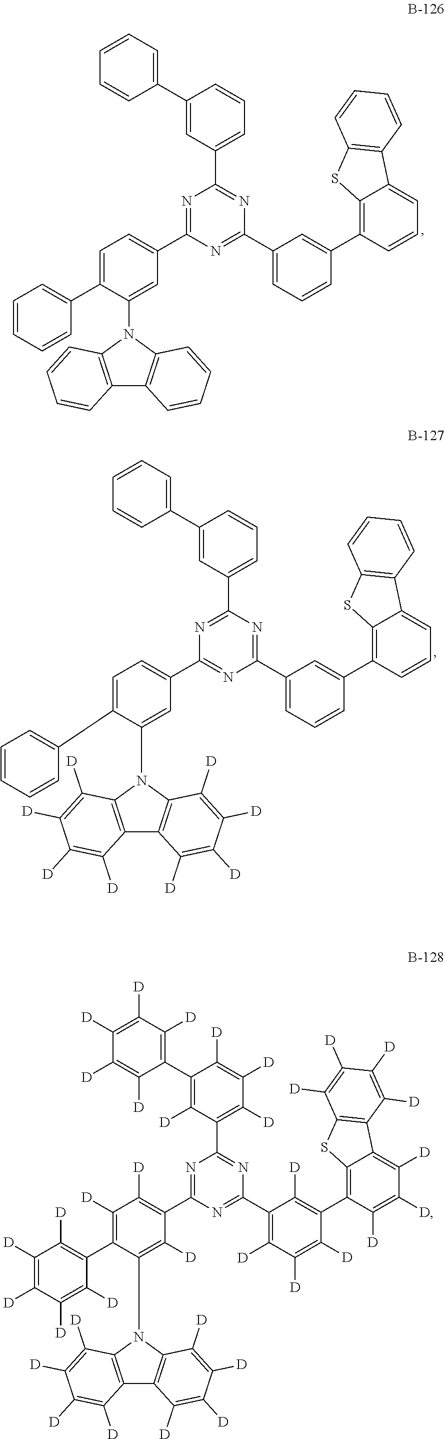 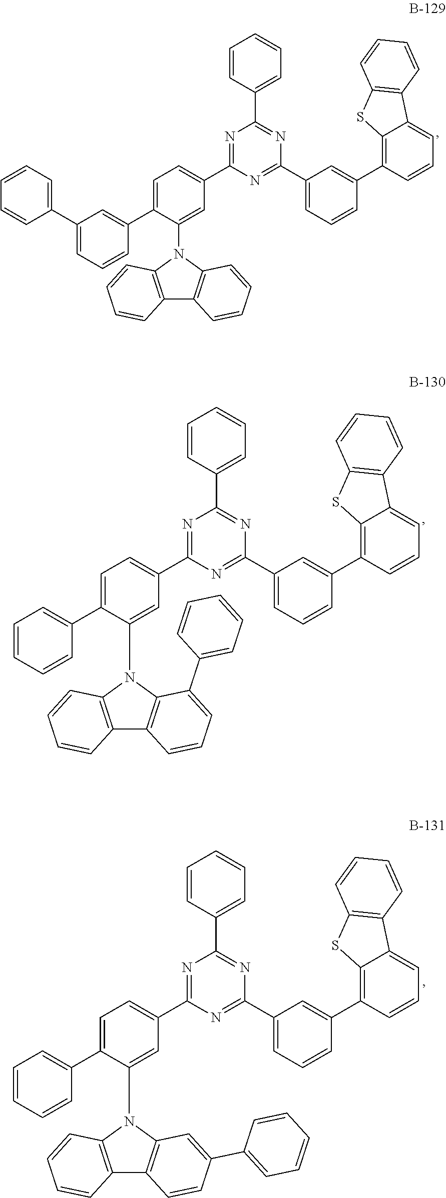 [SMILES: c1ccc(-c2cccc(-c3ccc(-c4nc(-c5ccccc5)nc(-c5cccc(-c6cccc7c6sc6ccccc67)c5)n4)cc3-n3c4ccccc4c4ccccc43)c2)cc1 ; c1ccc(-c2nc(-c3cccc(-c4cccc5c4sc4ccccc45)c3)nc(-c3ccc(-c4ccccc4)c(-n4c5ccccc5c5cccc(-c6ccccc6)c54)c3)n2)cc1 ; c1ccc(-c2ccc3c4ccccc4n(-c4cc(-c5nc(-c6ccccc6)nc(-c6cccc(-c7cccc8c7sc7ccccc78)c6)n5)ccc4-c4ccccc4)c3c2)cc1] 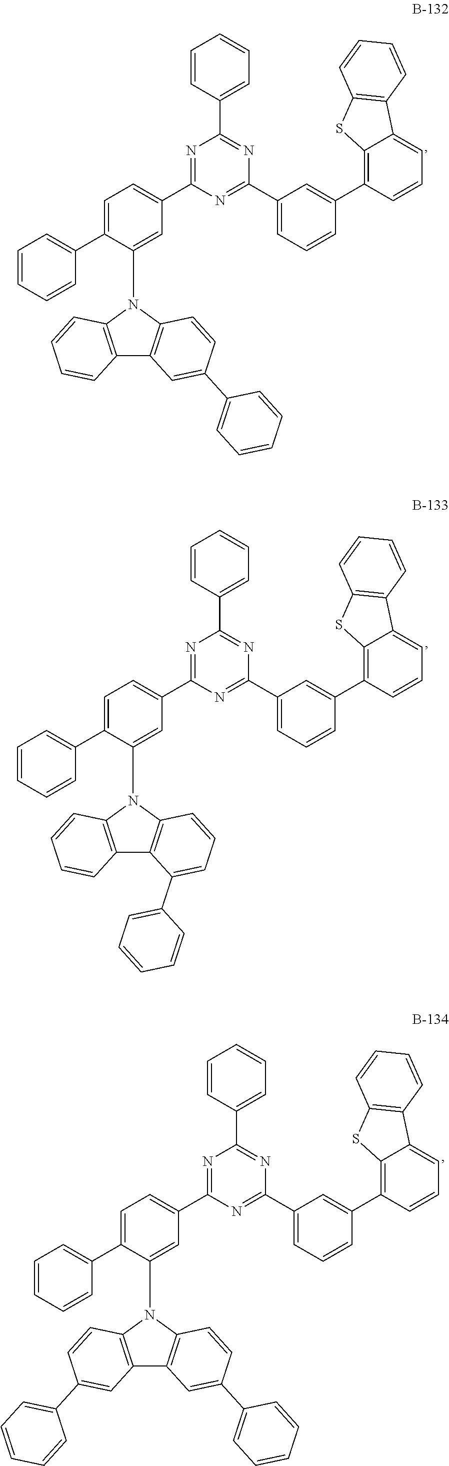 [SMILES: c1ccc(-c2ccc3c(c2)c2ccccc2n3-c2cc(-c3nc(-c4ccccc4)nc(-c4cccc(-c5cccc6c5sc5ccccc56)c4)n3)ccc2-c2ccccc2)cc1 ; c1ccc(-c2nc(-c3cccc(-c4cccc5c4sc4ccccc45)c3)nc(-c3ccc(-c4ccccc4)c(-n4c5ccccc5c5c(-c6ccccc6)cccc54)c3)n2)cc1 ; c1ccc(-c2ccc3c(c2)c2cc(-c4ccccc4)ccc2n3-c2cc(-c3nc(-c4ccccc4)nc(-c4cccc(-c5cccc6c5sc5ccccc56)c4)n3)ccc2-c2ccccc2)cc1] 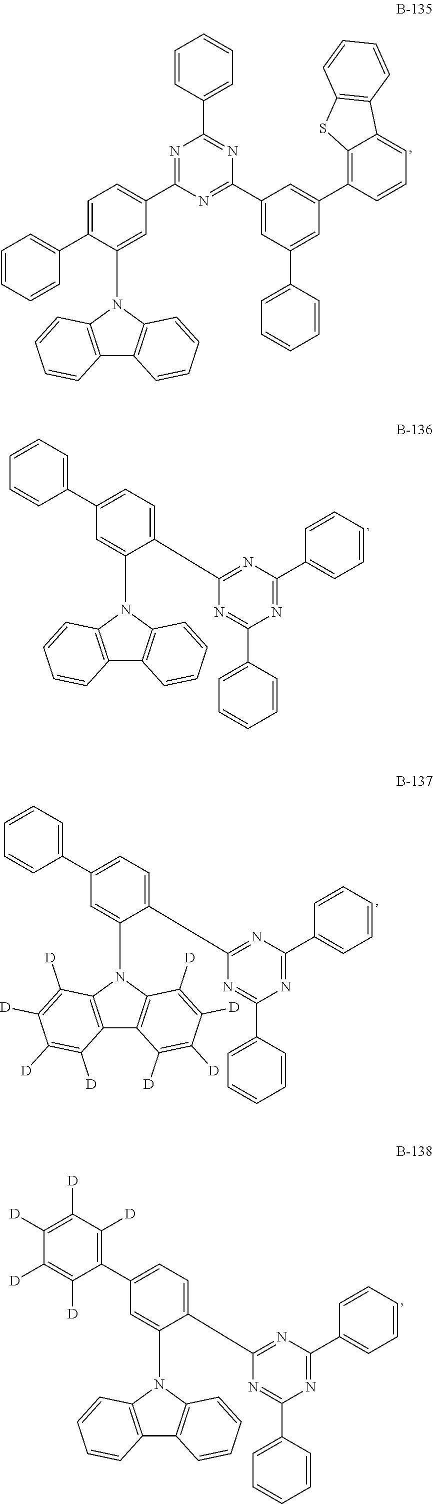 [SMILES: c1ccc(-c2cc(-c3nc(-c4ccccc4)nc(-c4ccc(-c5ccccc5)c(-n5c6ccccc6c6ccccc65)c4)n3)cc(-c3cccc4c3sc3ccccc34)c2)cc1 ; c1ccc(-c2ccc(-c3nc(-c4ccccc4)nc(-c4ccccc4)n3)c(-n3c4ccccc4c4ccccc43)c2)cc1 ; [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2ccccc2)n1 ; [2H]c1c([2H])c([2H])c(-c2ccc(-c3nc(-c4ccccc4)nc(-c4ccccc4)n3)c(-n3c4ccccc4c4ccccc43)c2)c([2H])c1[2H]] 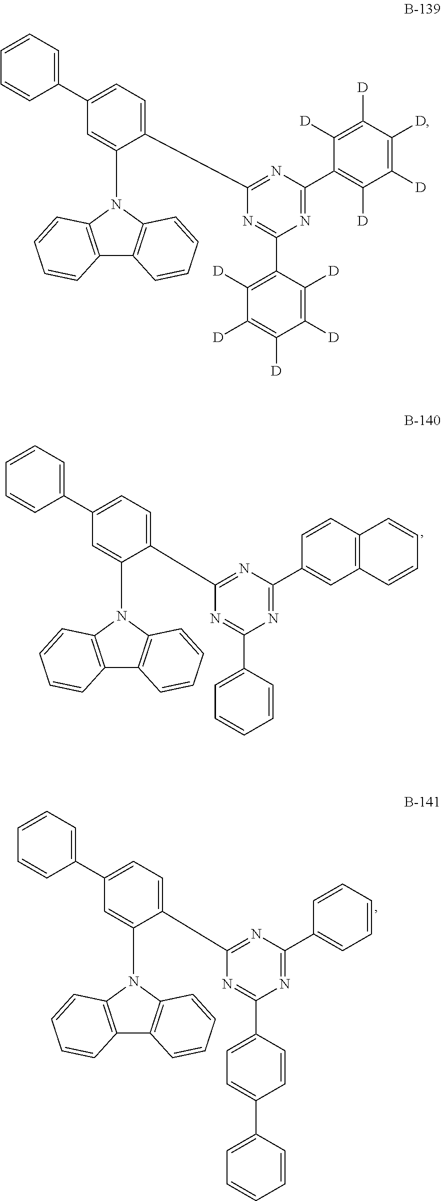 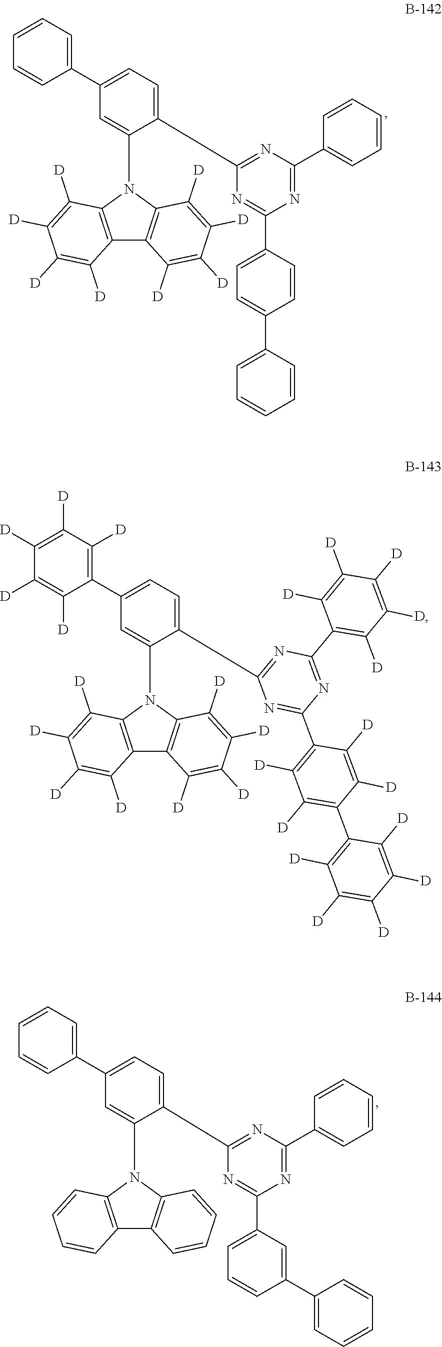 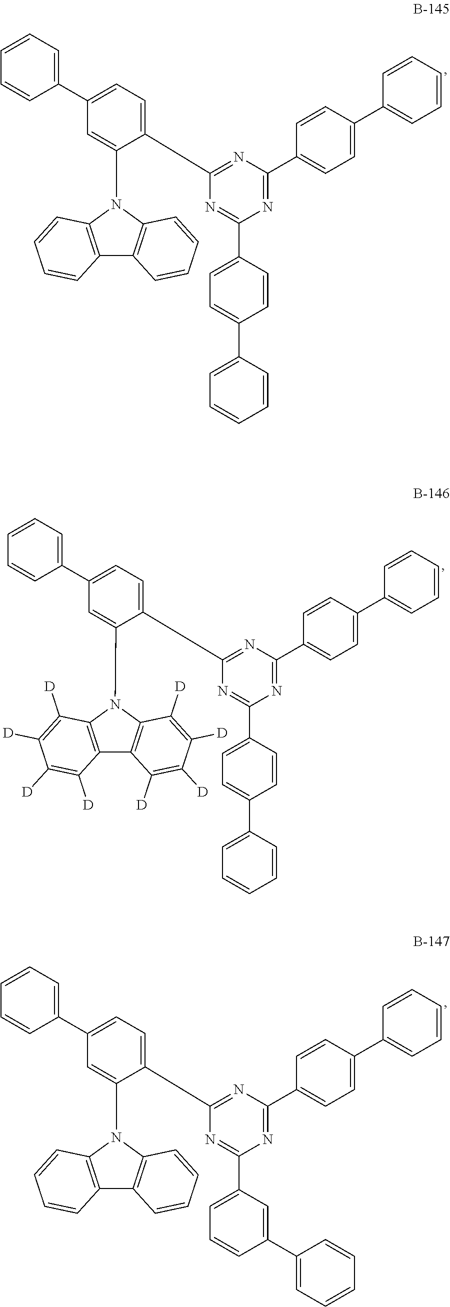 [SMILES: c1ccc(-c2ccc(-c3nc(-c4ccc(-c5ccccc5)cc4)nc(-c4ccc(-c5ccccc5)cc4-n4c5ccccc5c5ccccc54)n3)cc2)cc1 ; [2H]c1c([2H])c([2H])c2c(c1[2H])c1c([2H])c([2H])c([2H])c([2H])c1n2-c1cc(-c2ccccc2)ccc1-c1nc(-c2ccc(-c3ccccc3)cc2)nc(-c2ccc(-c3ccccc3)cc2)n1 ; c1ccc(-c2ccc(-c3nc(-c4cccc(-c5ccccc5)c4)nc(-c4ccc(-c5ccccc5)cc4-n4c5ccccc5c5ccccc54)n3)cc2)cc1] 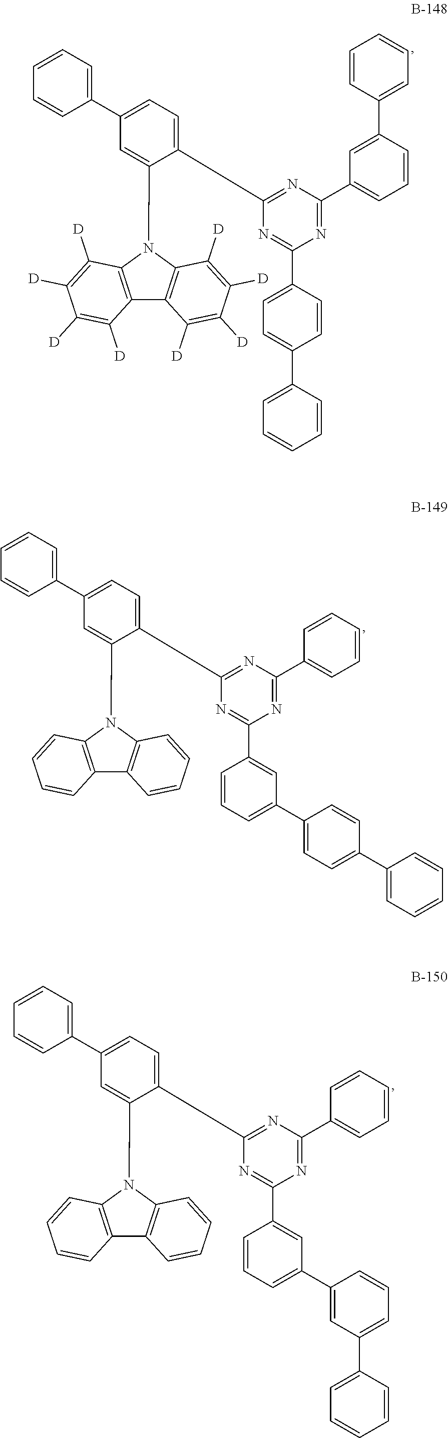 [SMILES: [2H]c1c([2H])c([2H])c2c(c1[2H])c1c([2H])c([2H])c([2H])c([2H])c1n2-c1cc(-c2ccccc2)ccc1-c1nc(-c2ccc(-c3ccccc3)cc2)nc(-c2cccc(-c3ccccc3)c2)n1 ; c1ccc(-c2ccc(-c3cccc(-c4nc(-c5ccccc5)nc(-c5ccc(-c6ccccc6)cc5-n5c6ccccc6c6ccccc65)n4)c3)cc2)cc1 ; c1ccc(-c2cccc(-c3cccc(-c4nc(-c5ccccc5)nc(-c5ccc(-c6ccccc6)cc5-n5c6ccccc6c6ccccc65)n4)c3)c2)cc1] 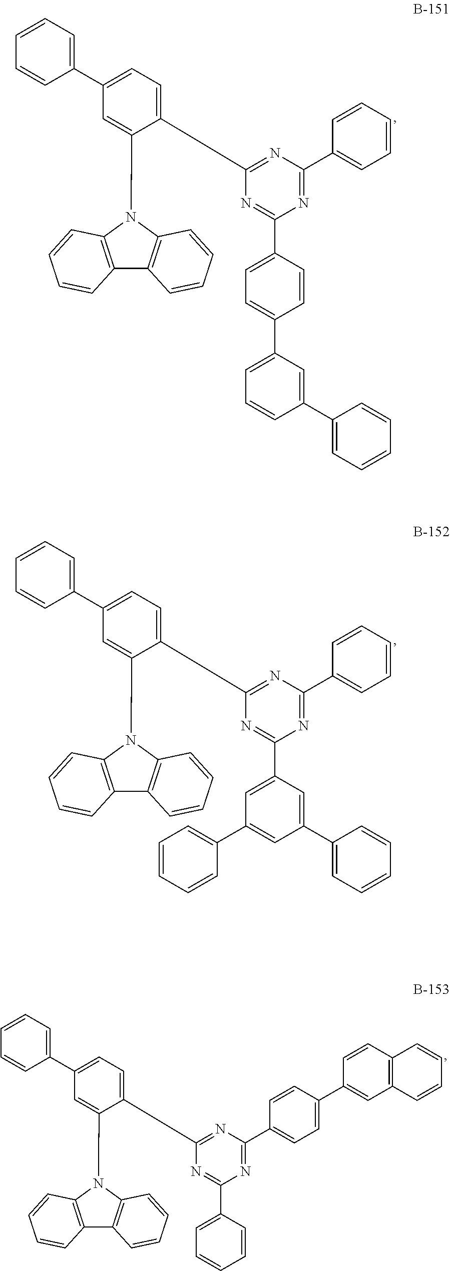 [SMILES: c1ccc(-c2cccc(-c3ccc(-c4nc(-c5ccccc5)nc(-c5ccc(-c6ccccc6)cc5-n5c6ccccc6c6ccccc65)n4)cc3)c2)cc1 ; c1ccc(-c2cc(-c3ccccc3)cc(-c3nc(-c4ccccc4)nc(-c4ccc(-c5ccccc5)cc4-n4c5ccccc5c5ccccc54)n3)c2)cc1 ; c1ccc(-c2ccc(-c3nc(-c4ccccc4)nc(-c4ccc(-c5ccc6ccccc6c5)cc4)n3)c(-n3c4ccccc4c4ccccc43)c2)cc1] 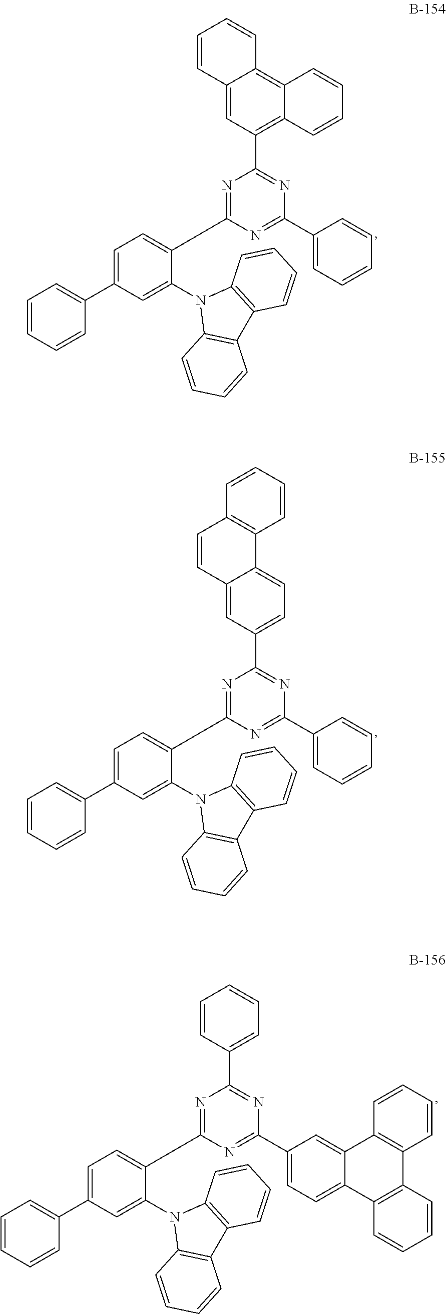 [SMILES: c1ccc(-c2ccc(-c3nc(-c4ccccc4)nc(-c4cc5ccccc5c5ccccc45)n3)c(-n3c4ccccc4c4ccccc43)c2)cc1 ; c1ccc(-c2ccc(-c3nc(-c4ccccc4)nc(-c4ccc5c(ccc6ccccc65)c4)n3)c(-n3c4ccccc4c4ccccc43)c2)cc1 ; c1ccc(-c2ccc(-c3nc(-c4ccccc4)nc(-c4ccc5c6ccccc6c6ccccc6c5c4)n3)c(-n3c4ccccc4c4ccccc43)c2)cc1] 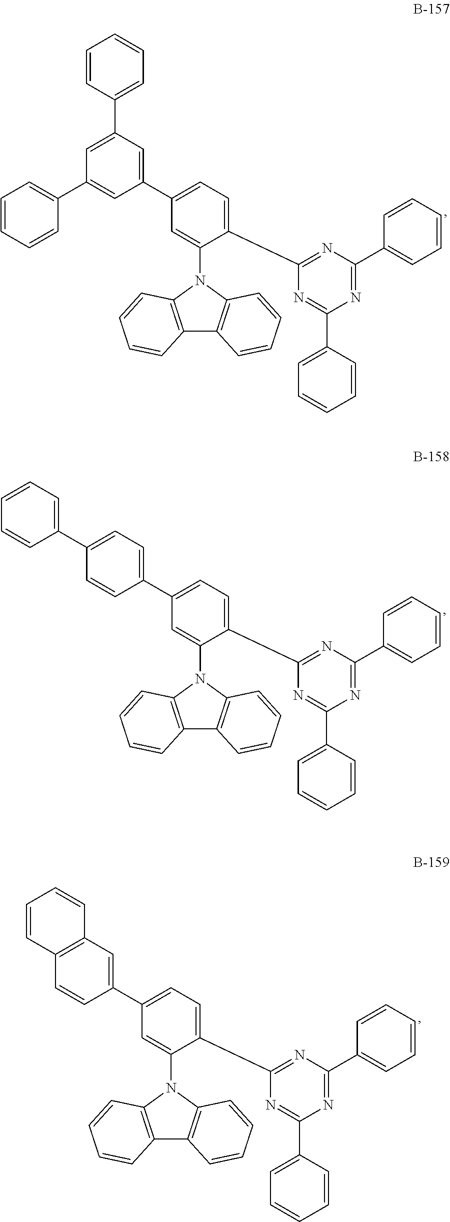 [SMILES: c1ccc(-c2cc(-c3ccccc3)cc(-c3ccc(-c4nc(-c5ccccc5)nc(-c5ccccc5)n4)c(-n4c5ccccc5c5ccccc54)c3)c2)cc1 ; c1ccc(-c2ccc(-c3ccc(-c4nc(-c5ccccc5)nc(-c5ccccc5)n4)c(-n4c5ccccc5c5ccccc54)c3)cc2)cc1 ; c1ccc(-c2nc(-c3ccccc3)nc(-c3ccc(-c4ccc5ccccc5c4)cc3-n3c4ccccc4c4ccccc43)n2)cc1] 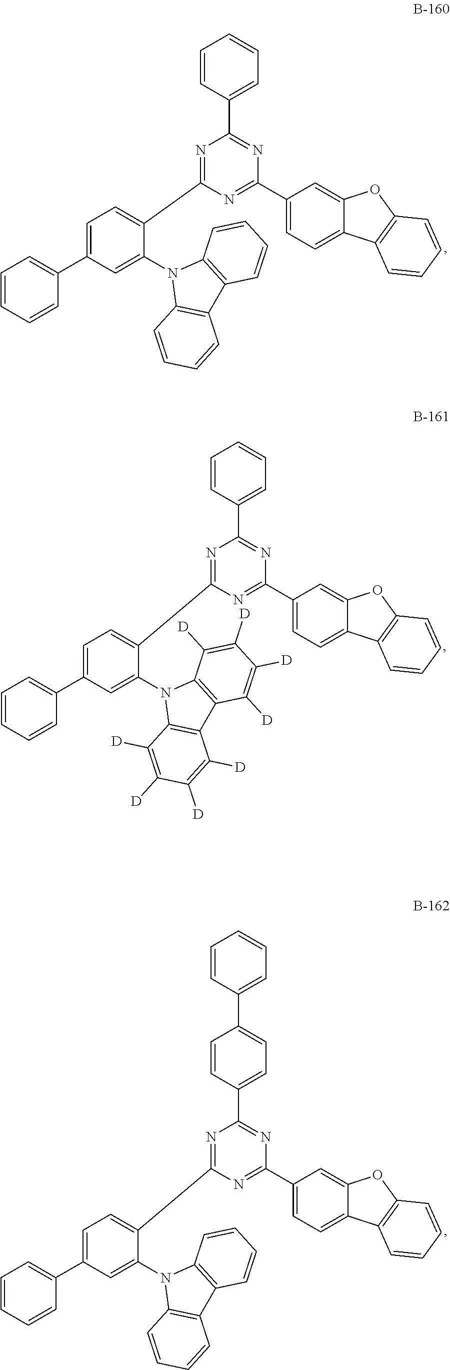 [SMILES: c1ccc(-c2ccc(-c3nc(-c4ccccc4)nc(-c4ccc5c(c4)oc4ccccc45)n3)c(-n3c4ccccc4c4ccccc43)c2)cc1 ; [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2ccc3c(c2)oc2ccccc23)n1 ; c1ccc(-c2ccc(-c3nc(-c4ccc5c(c4)oc4ccccc45)nc(-c4ccc(-c5ccccc5)cc4-n4c5ccccc5c5ccccc54)n3)cc2)cc1] 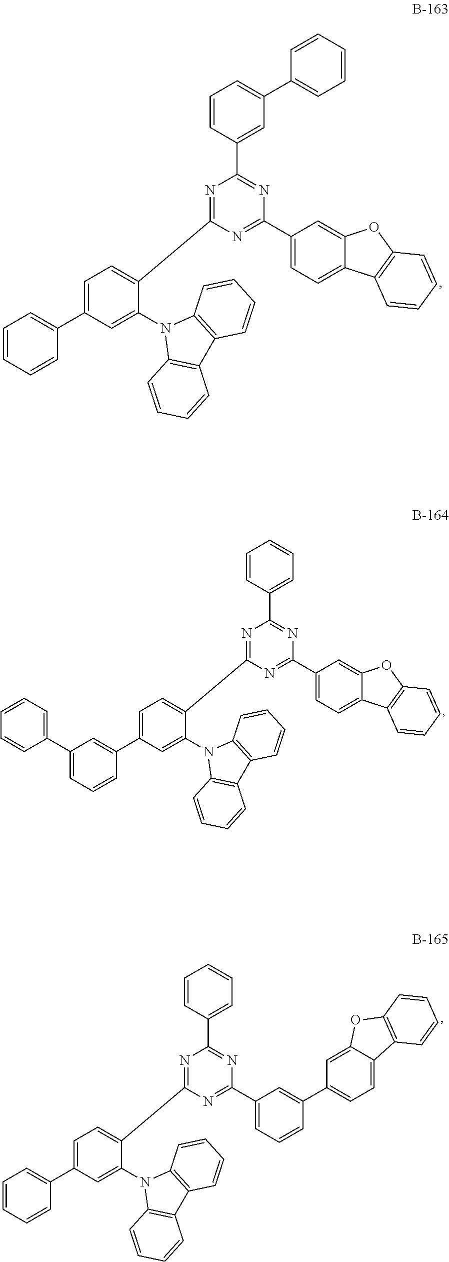 [SMILES: c1ccc(-c2cccc(-c3nc(-c4ccc5c(c4)oc4ccccc45)nc(-c4ccc(-c5ccccc5)cc4-n4c5ccccc5c5ccccc54)n3)c2)cc1 ; c1ccc(-c2cccc(-c3ccc(-c4nc(-c5ccccc5)nc(-c5ccc6c(c5)oc5ccccc56)n4)c(-n4c5ccccc5c5ccccc54)c3)c2)cc1 ; c1ccc(-c2ccc(-c3nc(-c4ccccc4)nc(-c4cccc(-c5ccc6c(c5)oc5ccccc56)c4)n3)c(-n3c4ccccc4c4ccccc43)c2)cc1] 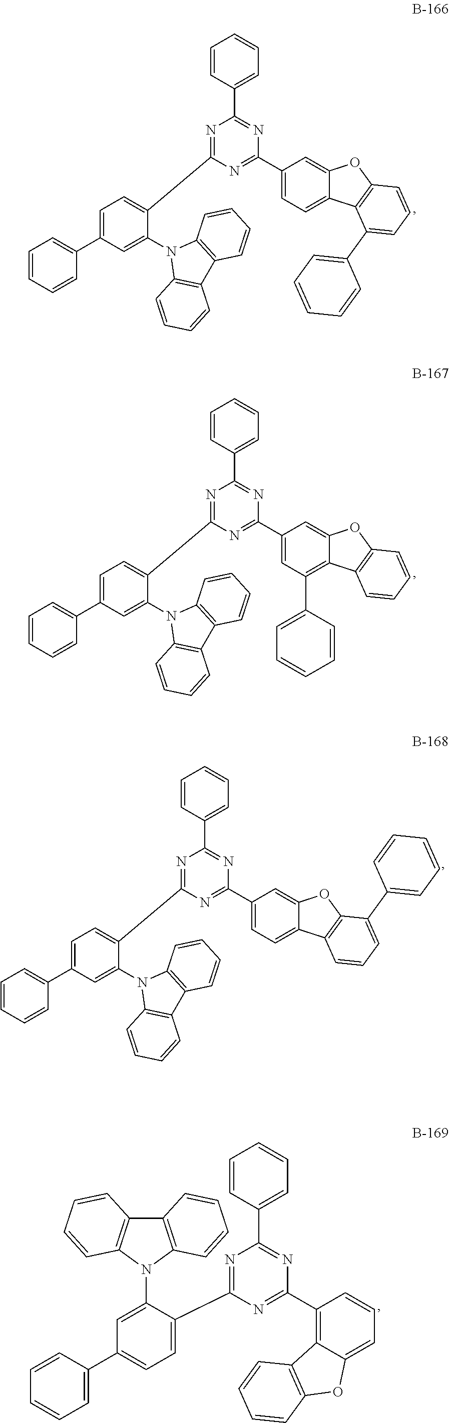 [SMILES: c1ccc(-c2ccc(-c3nc(-c4ccccc4)nc(-c4ccc5c(c4)oc4cccc(-c6ccccc6)c45)n3)c(-n3c4ccccc4c4ccccc43)c2)cc1 ; c1ccc(-c2ccc(-c3nc(-c4ccccc4)nc(-c4cc(-c5ccccc5)c5c(c4)oc4ccccc45)n3)c(-n3c4ccccc4c4ccccc43)c2)cc1 ; c1ccc(-c2ccc(-c3nc(-c4ccccc4)nc(-c4ccc5c(c4)oc4c(-c6ccccc6)cccc45)n3)c(-n3c4ccccc4c4ccccc43)c2)cc1 ; c1ccc(-c2ccc(-c3nc(-c4ccccc4)nc(-c4cccc5oc6ccccc6c45)n3)c(-n3c4ccccc4c4ccccc43)c2)cc1] 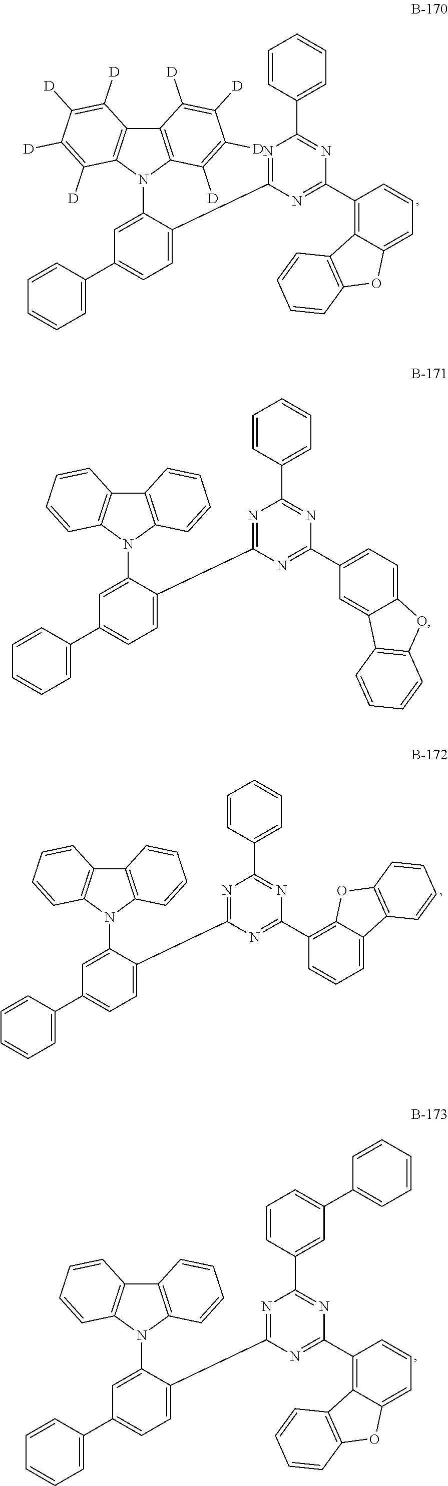 [SMILES: [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2cccc3oc4ccccc4c23)n1 ; c1ccc(-c2ccc(-c3nc(-c4ccccc4)nc(-c4ccc5oc6ccccc6c5c4)n3)c(-n3c4ccccc4c4ccccc43)c2)cc1 ; c1ccc(-c2ccc(-c3nc(-c4ccccc4)nc(-c4cccc5c4oc4ccccc45)n3)c(-n3c4ccccc4c4ccccc43)c2)cc1 ; c1ccc(-c2cccc(-c3nc(-c4ccc(-c5ccccc5)cc4-n4c5ccccc5c5ccccc54)nc(-c4cccc5oc6ccccc6c45)n3)c2)cc1] 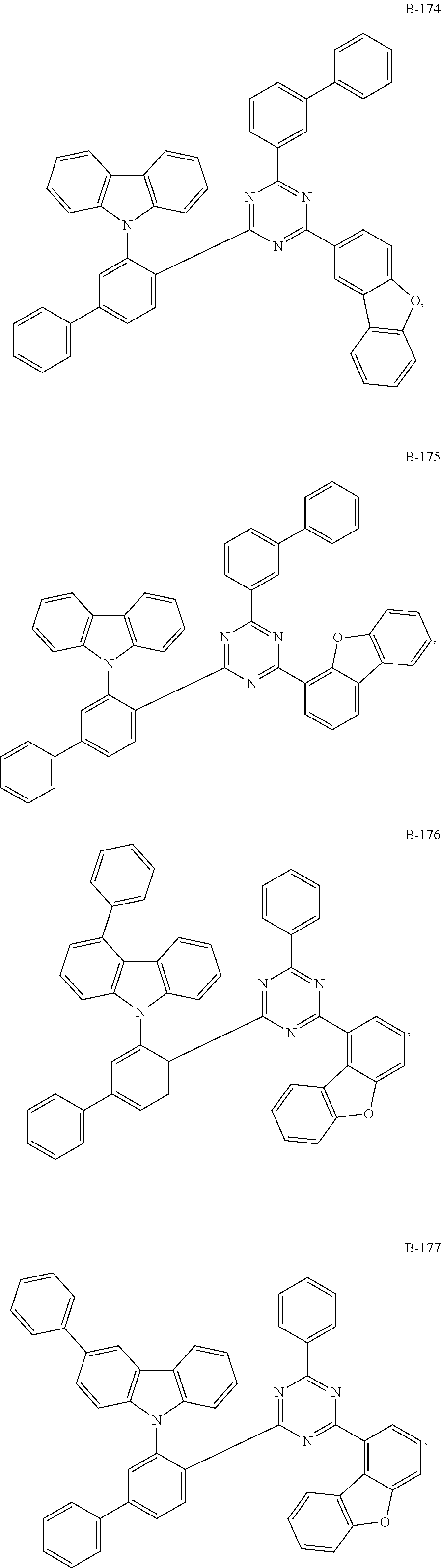 [SMILES: c1ccc(-c2cccc(-c3nc(-c4ccc5oc6ccccc6c5c4)nc(-c4ccc(-c5ccccc5)cc4-n4c5ccccc5c5ccccc54)n3)c2)cc1 ; c1ccc(-c2cccc(-c3nc(-c4ccc(-c5ccccc5)cc4-n4c5ccccc5c5ccccc54)nc(-c4cccc5c4oc4ccccc45)n3)c2)cc1 ; c1ccc(-c2ccc(-c3nc(-c4ccccc4)nc(-c4cccc5oc6ccccc6c45)n3)c(-n3c4ccccc4c4c(-c5ccccc5)cccc43)c2)cc1 ; c1ccc(-c2ccc(-c3nc(-c4ccccc4)nc(-c4cccc5oc6ccccc6c45)n3)c(-n3c4ccccc4c4cc(-c5ccccc5)ccc43)c2)cc1] 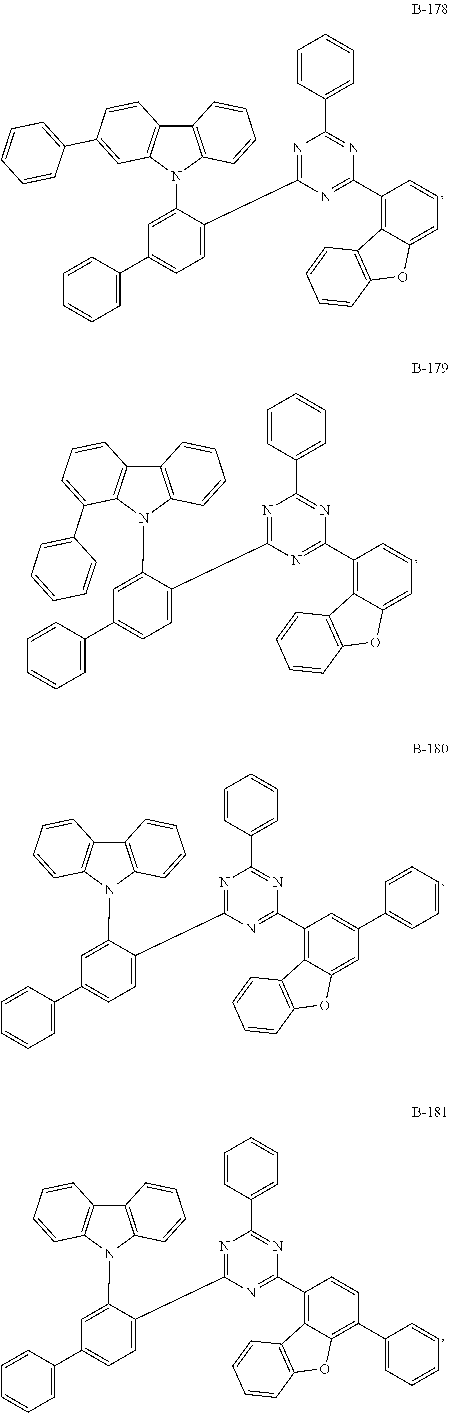 [SMILES: c1ccc(-c2ccc(-c3nc(-c4ccccc4)nc(-c4cccc5oc6ccccc6c45)n3)c(-n3c4ccccc4c4ccc(-c5ccccc5)cc43)c2)cc1 ; c1ccc(-c2ccc(-c3nc(-c4ccccc4)nc(-c4cccc5oc6ccccc6c45)n3)c(-n3c4ccccc4c4cccc(-c5ccccc5)c43)c2)cc1 ; c1ccc(-c2ccc(-c3nc(-c4ccccc4)nc(-c4cc(-c5ccccc5)cc5oc6ccccc6c45)n3)c(-n3c4ccccc4c4ccccc43)c2)cc1 ; c1ccc(-c2ccc(-c3nc(-c4ccccc4)nc(-c4ccc(-c5ccccc5)c5oc6ccccc6c45)n3)c(-n3c4ccccc4c4ccccc43)c2)cc1] 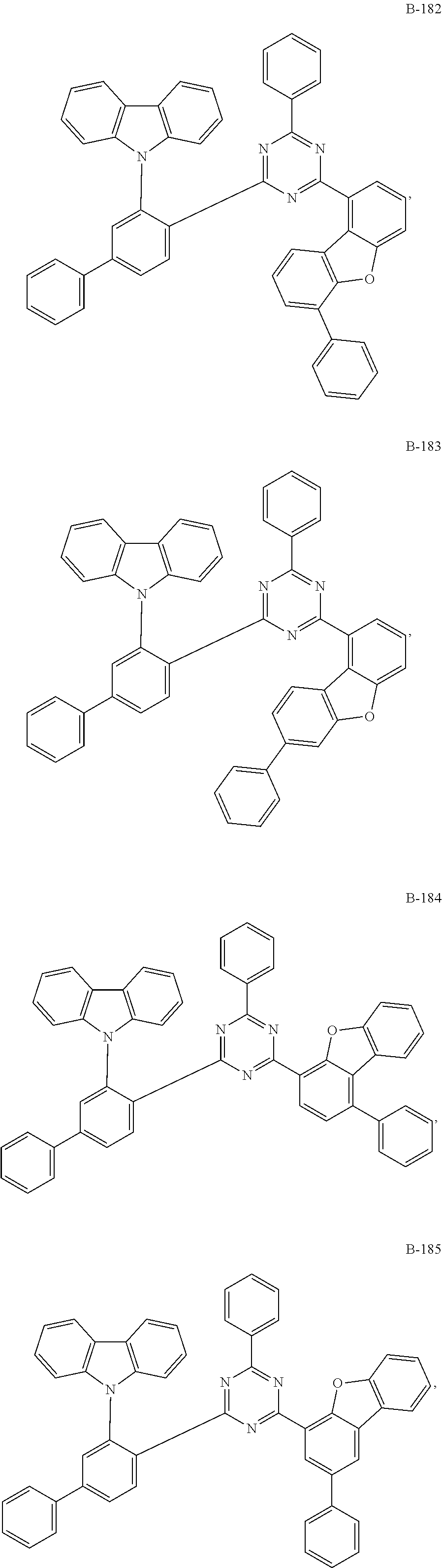 [SMILES: c1ccc(-c2ccc(-c3nc(-c4ccccc4)nc(-c4cccc5oc6c(-c7ccccc7)cccc6c45)n3)c(-n3c4ccccc4c4ccccc43)c2)cc1 ; c1ccc(-c2ccc(-c3nc(-c4ccccc4)nc(-c4cccc5oc6cc(-c7ccccc7)ccc6c45)n3)c(-n3c4ccccc4c4ccccc43)c2)cc1 ; c1ccc(-c2ccc(-c3nc(-c4ccccc4)nc(-c4ccc(-c5ccccc5)c5c4oc4ccccc45)n3)c(-n3c4ccccc4c4ccccc43)c2)cc1 ; c1ccc(-c2ccc(-c3nc(-c4ccccc4)nc(-c4cc(-c5ccccc5)cc5c4oc4ccccc45)n3)c(-n3c4ccccc4c4ccccc43)c2)cc1] 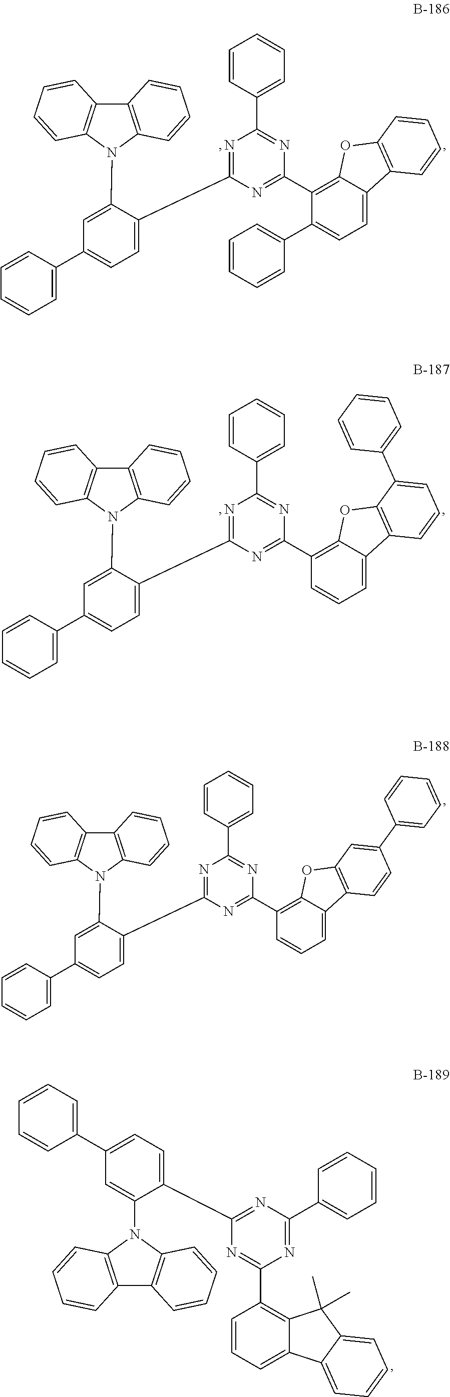 [SMILES: c1ccc(-c2ccc(-c3nc(-c4ccccc4)nc(-c4c(-c5ccccc5)ccc5c4oc4ccccc45)n3)c(-n3c4ccccc4c4ccccc43)c2)cc1 ; c1ccc(-c2ccc(-c3nc(-c4ccccc4)nc(-c4cccc5c4oc4c(-c6ccccc6)cccc45)n3)c(-n3c4ccccc4c4ccccc43)c2)cc1 ; c1ccc(-c2ccc(-c3nc(-c4ccccc4)nc(-c4cccc5c4oc4cc(-c6ccccc6)ccc45)n3)c(-n3c4ccccc4c4ccccc43)c2)cc1 ; CC1(C)c2ccccc2-c2cccc(-c3nc(-c4ccccc4)nc(-c4ccc(-c5ccccc5)cc4-n4c5ccccc5c5ccccc54)n3)c21] 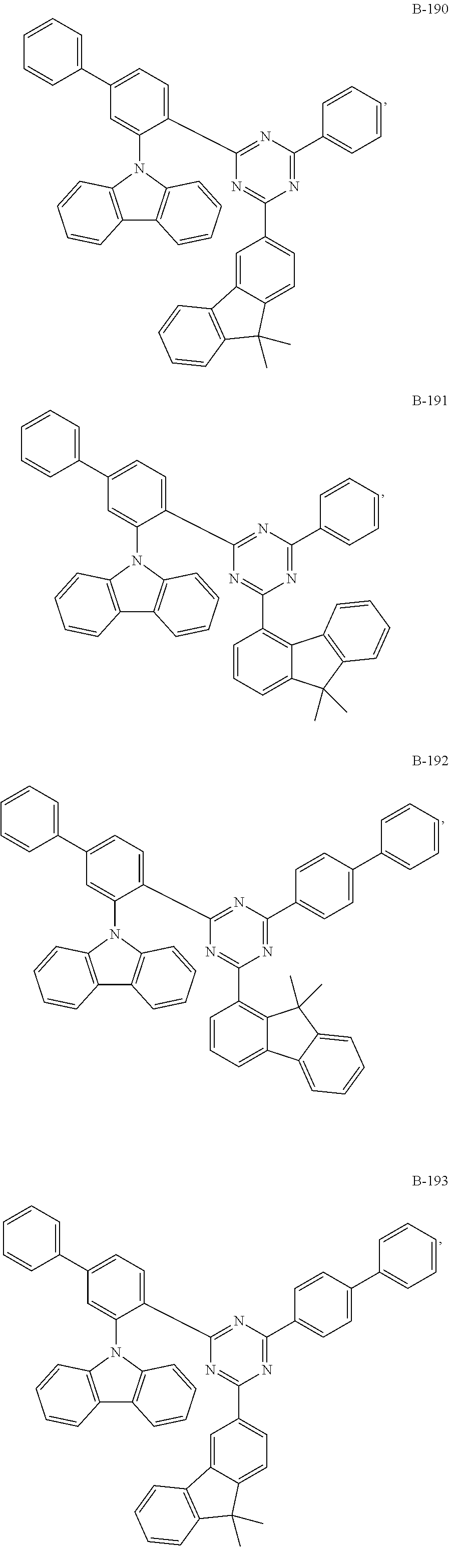 [SMILES: CC1(C)c2ccccc2-c2cc(-c3nc(-c4ccccc4)nc(-c4ccc(-c5ccccc5)cc4-n4c5ccccc5c5ccccc54)n3)ccc21 ; CC1(C)c2ccccc2-c2c(-c3nc(-c4ccccc4)nc(-c4ccc(-c5ccccc5)cc4-n4c5ccccc5c5ccccc54)n3)cccc21 ; CC1(C)c2ccccc2-c2cccc(-c3nc(-c4ccc(-c5ccccc5)cc4)nc(-c4ccc(-c5ccccc5)cc4-n4c5ccccc5c5ccccc54)n3)c21 ; CC1(C)c2ccccc2-c2cc(-c3nc(-c4ccc(-c5ccccc5)cc4)nc(-c4ccc(-c5ccccc5)cc4-n4c5ccccc5c5ccccc54)n3)ccc21] 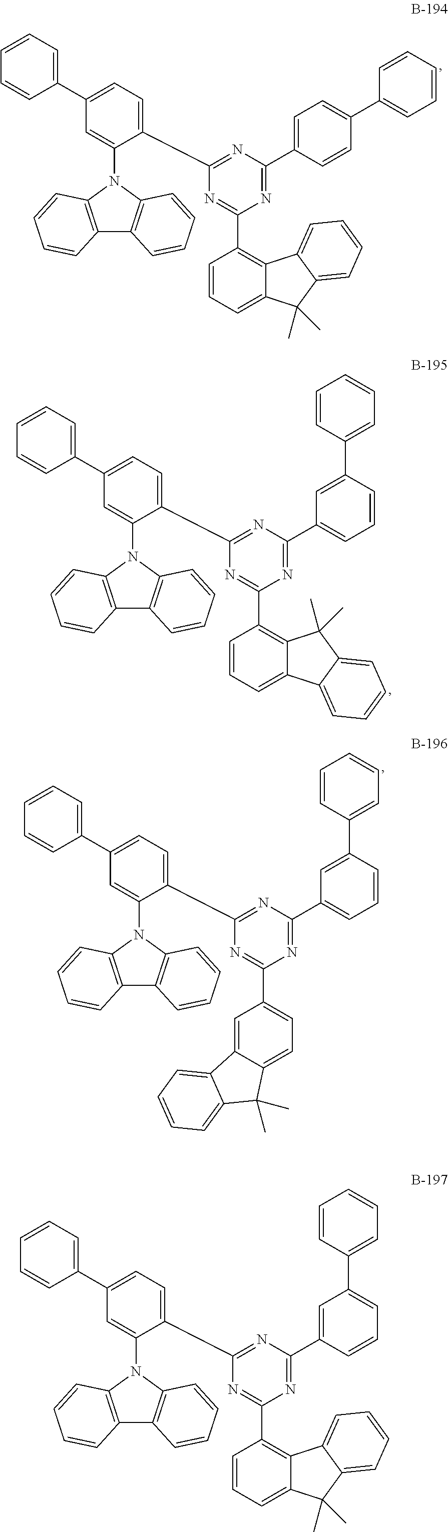 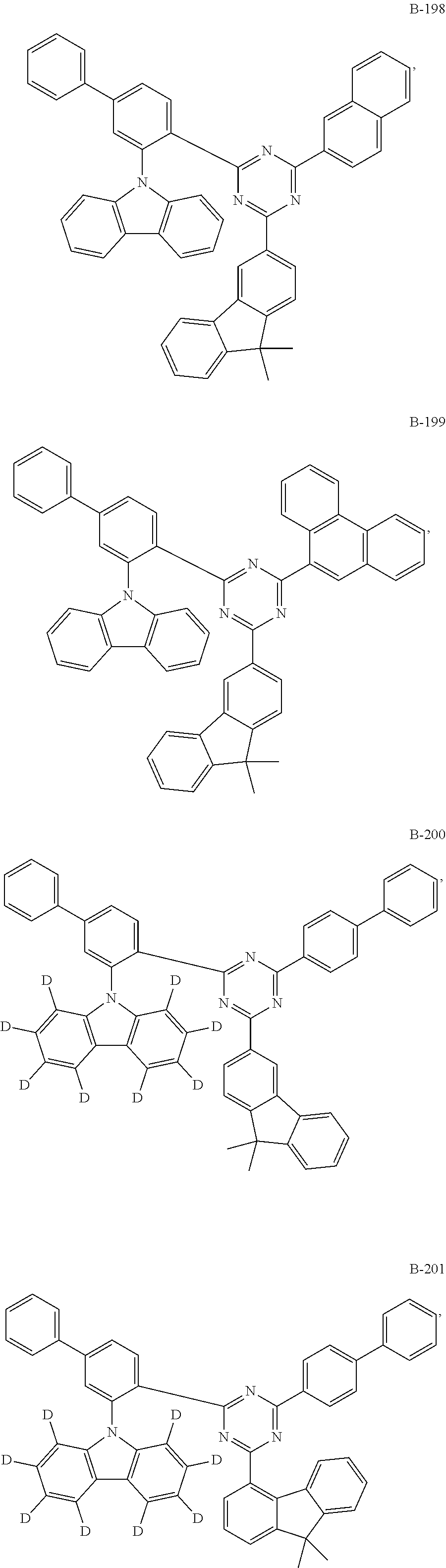 [SMILES: CC1(C)c2ccccc2-c2cc(-c3nc(-c4ccc5ccccc5c4)nc(-c4ccc(-c5ccccc5)cc4-n4c5ccccc5c5ccccc54)n3)ccc21 ; CC1(C)c2ccccc2-c2cc(-c3nc(-c4ccc(-c5ccccc5)cc4-n4c5ccccc5c5ccccc54)nc(-c4cc5ccccc5c5ccccc45)n3)ccc21 ; [2H]c1c([2H])c([2H])c2c(c1[2H])c1c([2H])c([2H])c([2H])c([2H])c1n2-c1cc(-c2ccccc2)ccc1-c1nc(-c2ccc(-c3ccccc3)cc2)nc(-c2ccc3c(c2)-c2ccccc2C3(C)C)n1 ; [2H]c1c([2H])c([2H])c2c(c1[2H])c1c([2H])c([2H])c([2H])c([2H])c1n2-c1cc(-c2ccccc2)ccc1-c1nc(-c2ccc(-c3ccccc3)cc2)nc(-c2cccc3c2-c2ccccc2C3(C)C)n1] 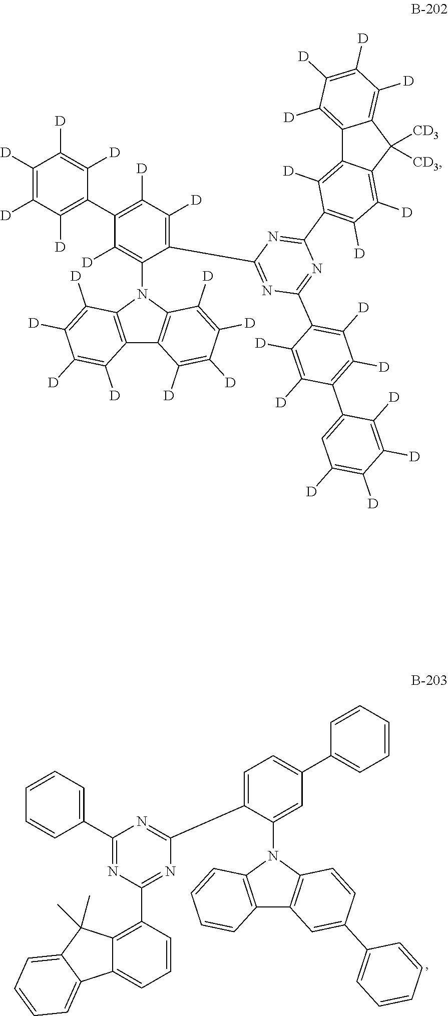 [SMILES: [2H]c1cc(-c2c([2H])c([2H])c(-c3nc(-c4c([2H])c([2H])c5c(c4[2H])-c4c([2H])c([2H])c([2H])c([2H])c4C5(C([2H])([2H])[2H])C([2H])([2H])[2H])nc(-c4c([2H])c([2H])c(-c5c([2H])c([2H])c([2H])c([2H])c5[2H])c([2H])c4-n4c5c([2H])c([2H])c([2H])c([2H])c5c5c([2H])c([2H])c([2H])c([2H])c54)n3)c([2H])c2[2H])c([2H])c([2H])c1[2H] ; CC1(C)c2ccccc2-c2cccc(-c3nc(-c4ccccc4)nc(-c4ccc(-c5ccccc5)cc4-n4c5ccccc5c5cc(-c6ccccc6)ccc54)n3)c21] 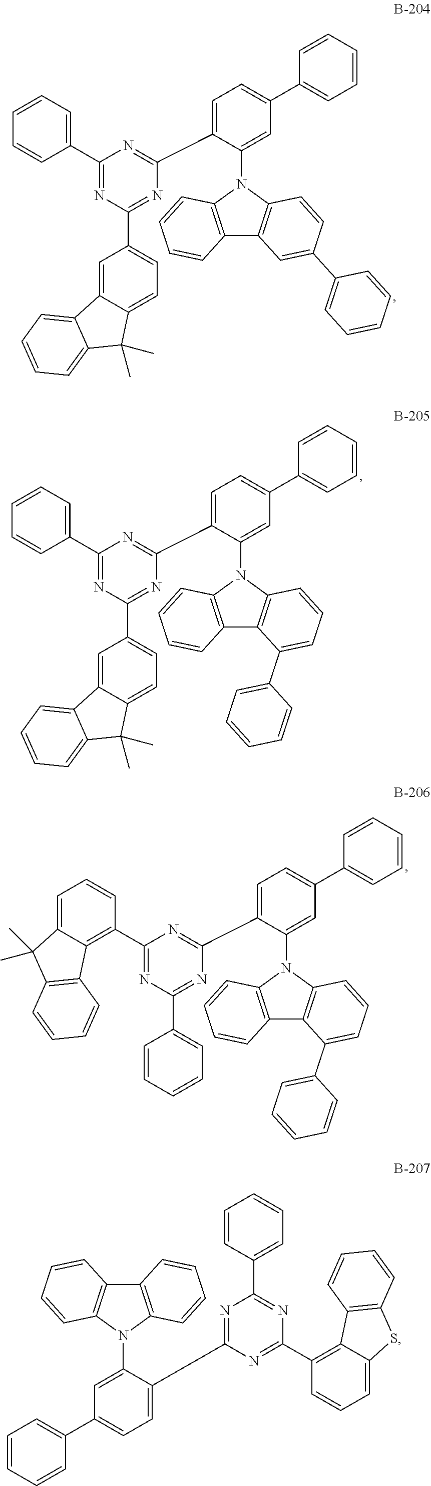 [SMILES: CC1(C)c2ccccc2-c2cc(-c3nc(-c4ccccc4)nc(-c4ccc(-c5ccccc5)cc4-n4c5ccccc5c5cc(-c6ccccc6)ccc54)n3)ccc21 ; CC1(C)c2ccccc2-c2cc(-c3nc(-c4ccccc4)nc(-c4ccc(-c5ccccc5)cc4-n4c5ccccc5c5c(-c6ccccc6)cccc54)n3)ccc21 ; CC1(C)c2ccccc2-c2c(-c3nc(-c4ccccc4)nc(-c4ccc(-c5ccccc5)cc4-n4c5ccccc5c5c(-c6ccccc6)cccc54)n3)cccc21 ; c1ccc(-c2ccc(-c3nc(-c4ccccc4)nc(-c4cccc5sc6ccccc6c45)n3)c(-n3c4ccccc4c4ccccc43)c2)cc1] 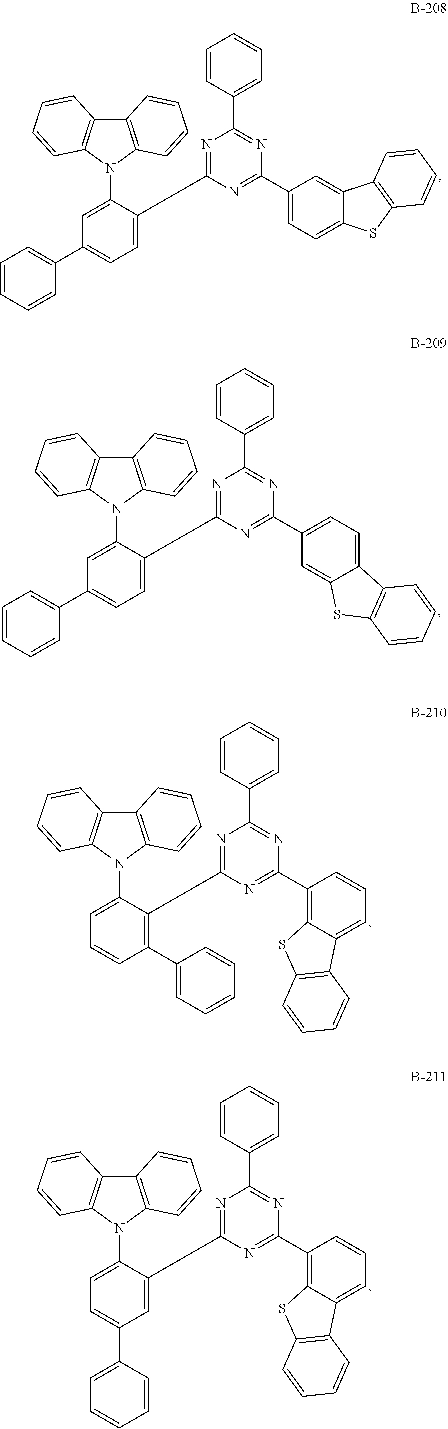 [SMILES: c1ccc(-c2ccc(-c3nc(-c4ccccc4)nc(-c4ccc5sc6ccccc6c5c4)n3)c(-n3c4ccccc4c4ccccc43)c2)cc1 ; c1ccc(-c2ccc(-c3nc(-c4ccccc4)nc(-c4ccc5c(c4)sc4ccccc45)n3)c(-n3c4ccccc4c4ccccc43)c2)cc1 ; c1ccc(-c2nc(-c3c(-c4ccccc4)cccc3-n3c4ccccc4c4ccccc43)nc(-c3cccc4c3sc3ccccc34)n2)cc1 ; c1ccc(-c2ccc(-n3c4ccccc4c4ccccc43)c(-c3nc(-c4ccccc4)nc(-c4cccc5c4sc4ccccc45)n3)c2)cc1] 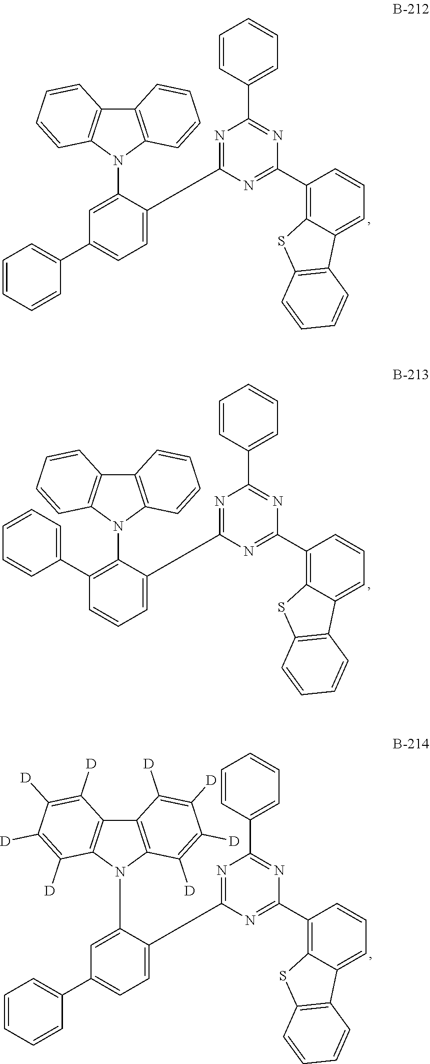 [SMILES: c1ccc(-c2ccc(-c3nc(-c4ccccc4)nc(-c4cccc5c4sc4ccccc45)n3)c(-n3c4ccccc4c4ccccc43)c2)cc1 ; c1ccc(-c2nc(-c3cccc(-c4ccccc4)c3-n3c4ccccc4c4ccccc43)nc(-c3cccc4c3sc3ccccc34)n2)cc1 ; [2H]c1c([2H])c([2H])c2c(c1[2H])c1c([2H])c([2H])c([2H])c([2H])c1n2-c1cc(-c2ccccc2)ccc1-c1nc(-c2ccccc2)nc(-c2cccc3c2sc2ccccc23)n1] 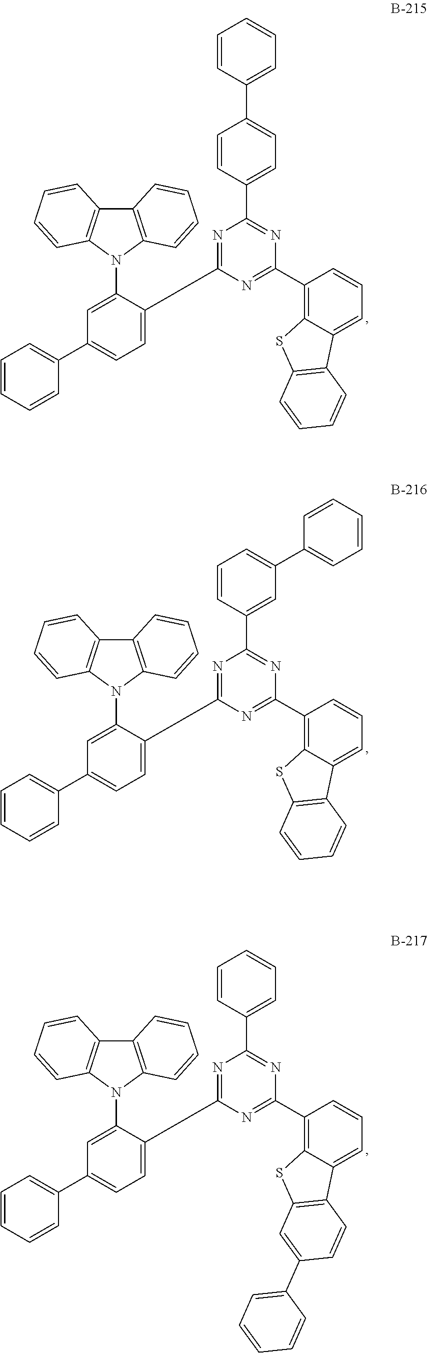 [SMILES: c1ccc(-c2ccc(-c3nc(-c4ccc(-c5ccccc5)cc4-n4c5ccccc5c5ccccc54)nc(-c4cccc5c4sc4ccccc45)n3)cc2)cc1 ; c1ccc(-c2cccc(-c3nc(-c4ccc(-c5ccccc5)cc4-n4c5ccccc5c5ccccc54)nc(-c4cccc5c4sc4ccccc45)n3)c2)cc1 ; c1ccc(-c2ccc(-c3nc(-c4ccccc4)nc(-c4cccc5c4sc4cc(-c6ccccc6)ccc45)n3)c(-n3c4ccccc4c4ccccc43)c2)cc1] 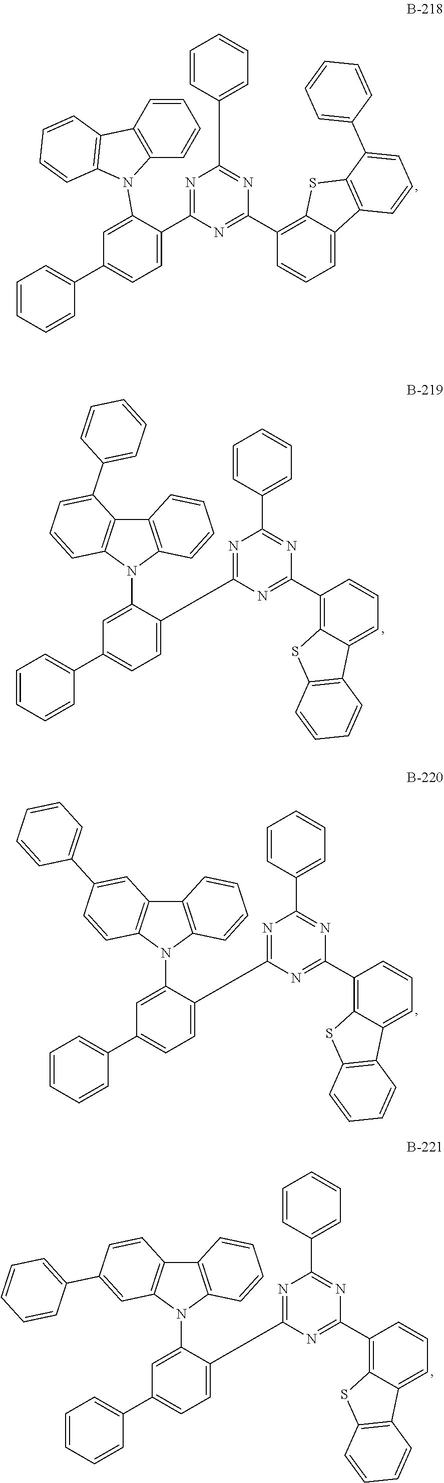 [SMILES: c1ccc(-c2ccc(-c3nc(-c4ccccc4)nc(-c4cccc5c4sc4c(-c6ccccc6)cccc45)n3)c(-n3c4ccccc4c4ccccc43)c2)cc1 ; c1ccc(-c2ccc(-c3nc(-c4ccccc4)nc(-c4cccc5c4sc4ccccc45)n3)c(-n3c4ccccc4c4c(-c5ccccc5)cccc43)c2)cc1 ; c1ccc(-c2ccc(-c3nc(-c4ccccc4)nc(-c4cccc5c4sc4ccccc45)n3)c(-n3c4ccccc4c4cc(-c5ccccc5)ccc43)c2)cc1 ; c1ccc(-c2ccc(-c3nc(-c4ccccc4)nc(-c4cccc5c4sc4ccccc45)n3)c(-n3c4ccccc4c4ccc(-c5ccccc5)cc43)c2)cc1] 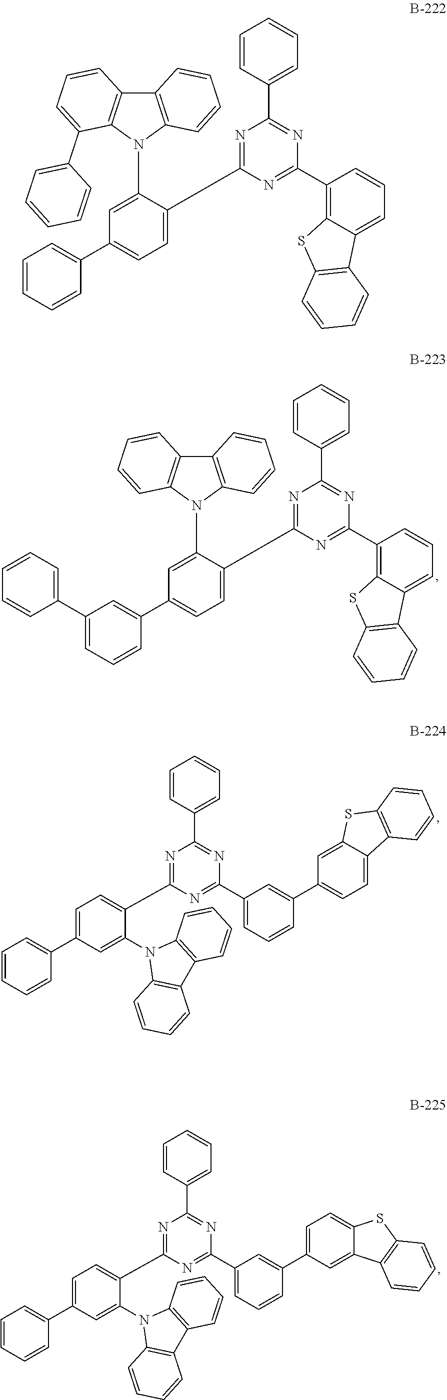 [SMILES: c1ccc(-c2ccc(-c3nc(-c4ccccc4)nc(-c4cccc5c4sc4ccccc45)n3)c(-n3c4ccccc4c4cccc(-c5ccccc5)c43)c2)cc1 ; c1ccc(-c2cccc(-c3ccc(-c4nc(-c5ccccc5)nc(-c5cccc6c5sc5ccccc56)n4)c(-n4c5ccccc5c5ccccc54)c3)c2)cc1 ; c1ccc(-c2ccc(-c3nc(-c4ccccc4)nc(-c4cccc(-c5ccc6c(c5)sc5ccccc56)c4)n3)c(-n3c4ccccc4c4ccccc43)c2)cc1 ; c1ccc(-c2ccc(-c3nc(-c4ccccc4)nc(-c4cccc(-c5ccc6sc7ccccc7c6c5)c4)n3)c(-n3c4ccccc4c4ccccc43)c2)cc1] 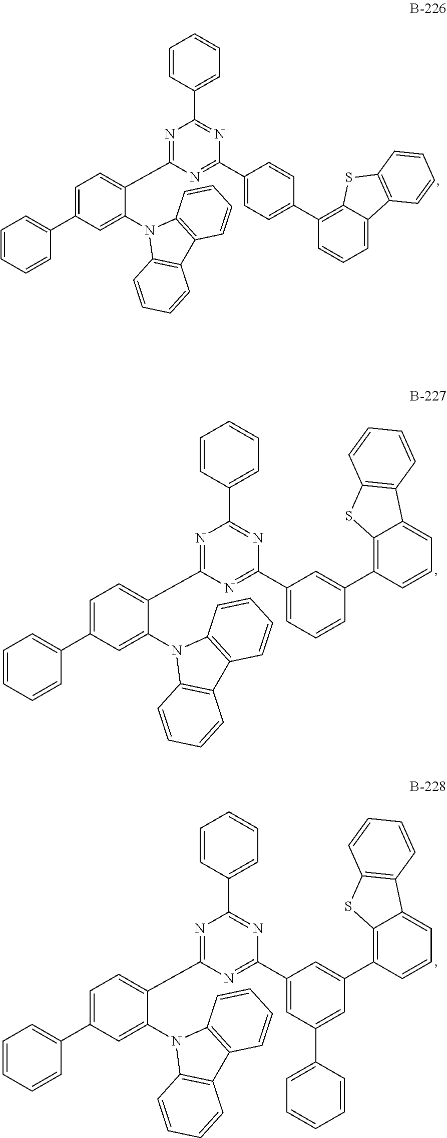 [SMILES: c1ccc(-c2ccc(-c3nc(-c4ccccc4)nc(-c4ccc(-c5cccc6c5sc5ccccc56)cc4)n3)c(-n3c4ccccc4c4ccccc43)c2)cc1 ; c1ccc(-c2ccc(-c3nc(-c4ccccc4)nc(-c4cccc(-c5cccc6c5sc5ccccc56)c4)n3)c(-n3c4ccccc4c4ccccc43)c2)cc1 ; c1ccc(-c2cc(-c3nc(-c4ccccc4)nc(-c4ccc(-c5ccccc5)cc4-n4c5ccccc5c5ccccc54)n3)cc(-c3cccc4c3sc3ccccc34)c2)cc1] 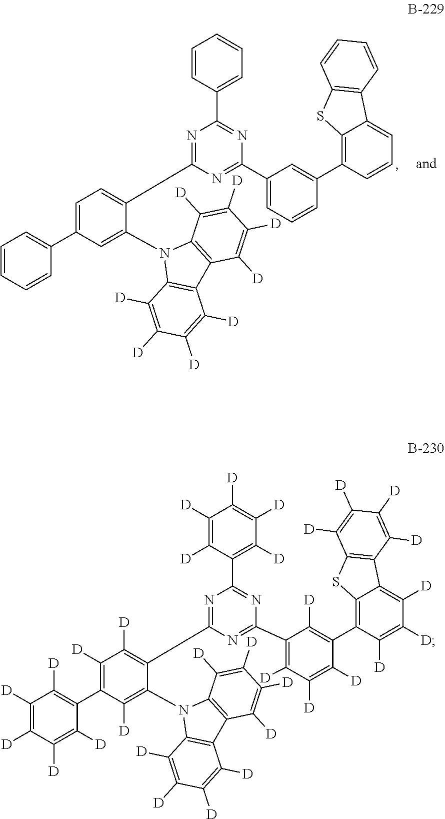
wherein optionally, hydrogens in Compound B-1 to Compound B-230 can be partially or fully substituted with deuterium.

19. The organic electroluminescent device according to claim 1, wherein the organic layer further comprises a second compound, and the second compound comprises at least one chemical group selected from the group consisting of: benzene, pyridine, arylamine, carbazole, azacarbazole, indolocarbazole, dibenzothiophene, azadibenzothiophene, dibenzofuran, azadibenzofuran, dibenzoselenophene, triphenylene, fluorene, silafluorene, naphthalene, phenanthrene, and combinations thereof;
preferably, the second compound comprises at least one chemical group selected from the group consisting of: benzene, arylamine, carbazole, indolocarbazole, fluorene, dibenzothiophene, dibenzofuran, and combinations thereof.

20. The organic electroluminescent device according to claim 19, wherein the second compound has a structure represented by Formula 3 or Formula 4: 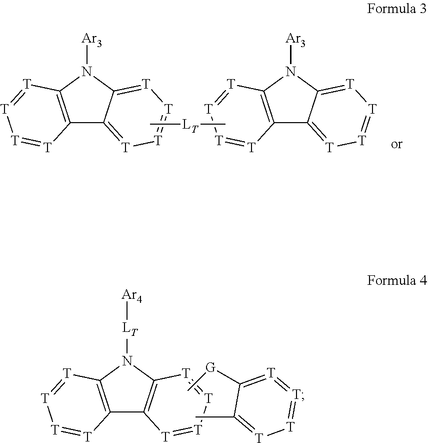
wherein
G is, at each occurrence identically or differently, selected from C(R_{g})₂, NR_{g}, O, or S;
L_{T} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
T is, at each occurrence identically or differently, selected from C, CRₜ, or N;
Rₜ and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₃ and Ar₄ are, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents Rₜ, R_{g} can be optionally joined to form a ring.

21. The organic electroluminescent device according to claim 19, wherein the second compound is selected from the group consisting of Compound PH-1 to Compound PH-115: 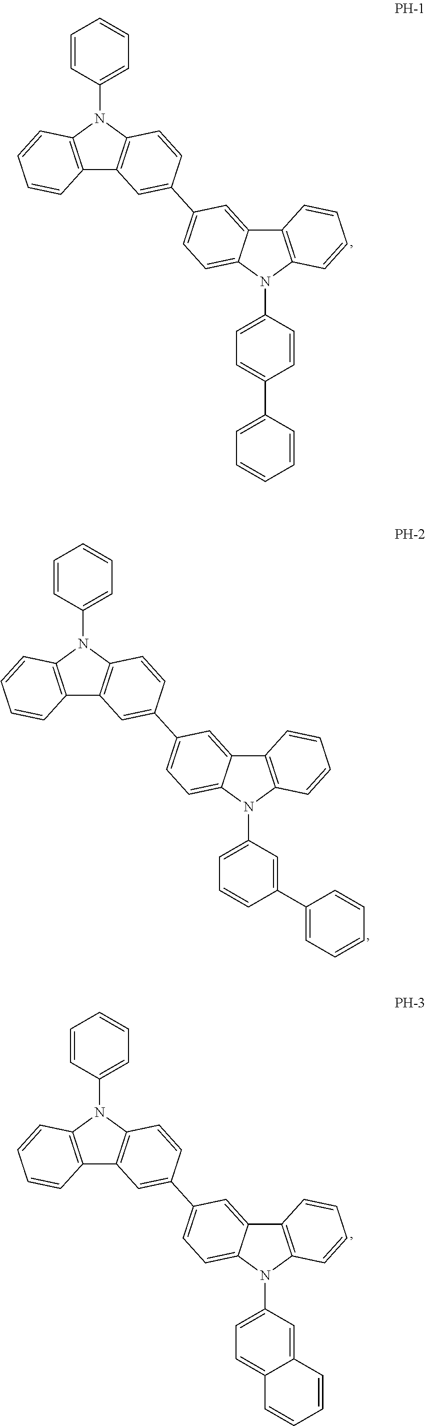 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1] 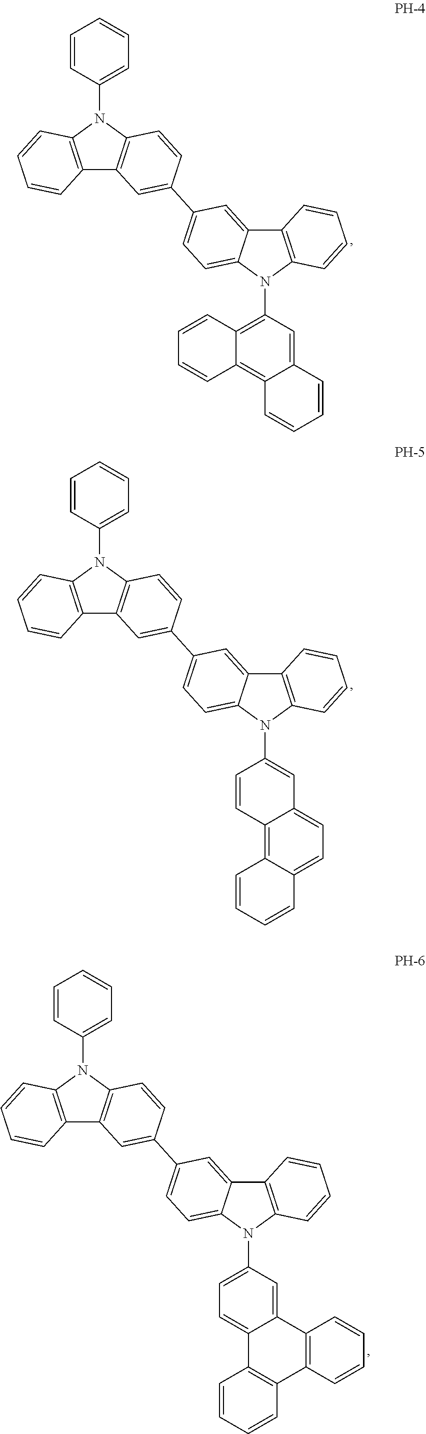 [SMILES: c1ccc(-n2c3ccccc3c3cc(-c4ccc5c(c4)c4ccccc4n5-c4cc5ccccc5c5ccccc45)ccc32)cc1 ; c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1] 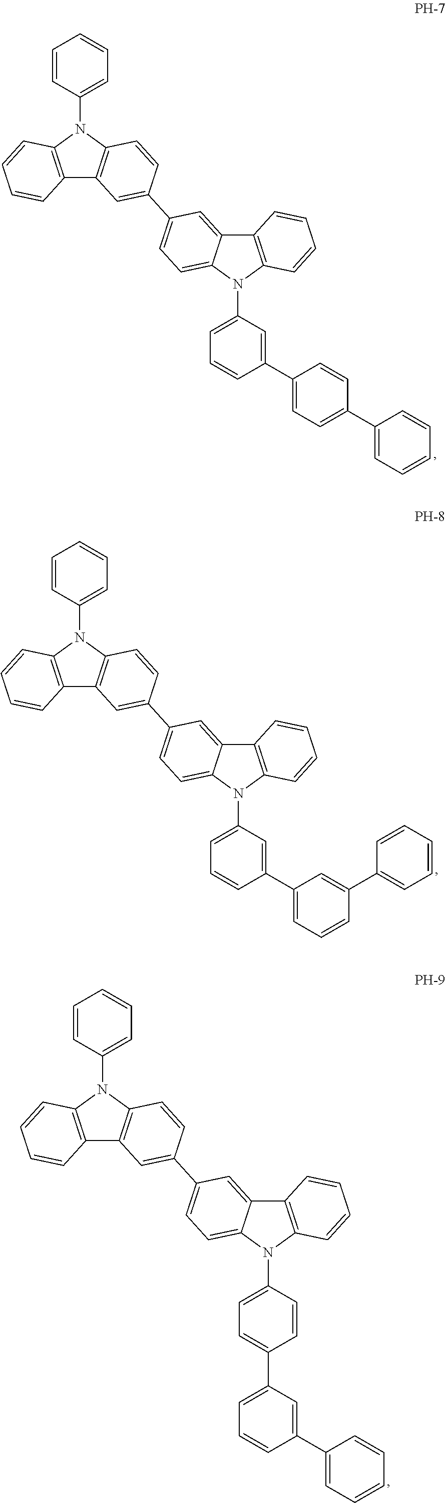 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1] 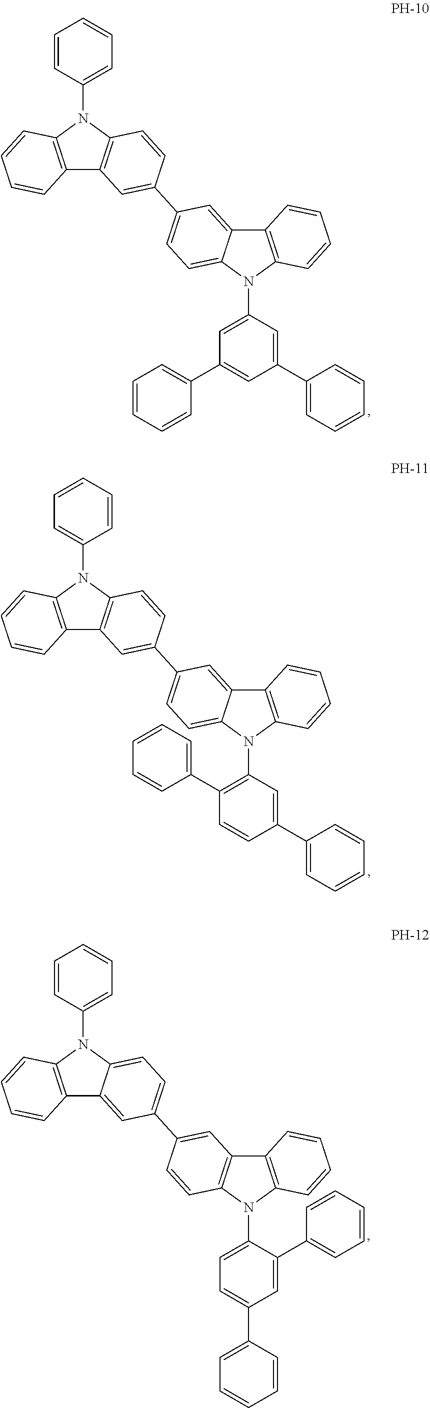 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1] 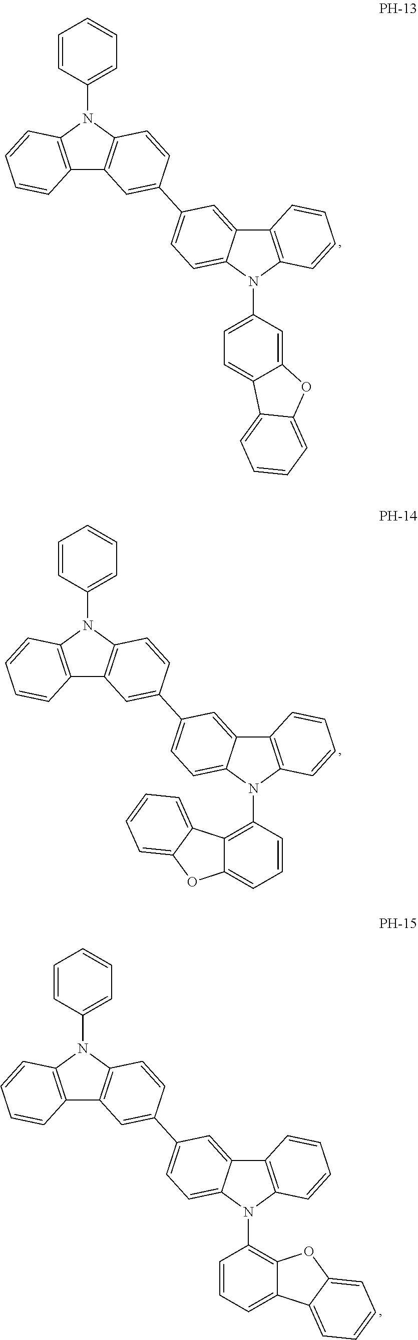 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1 ; c1ccc(-n2c3ccccc3c3cc(-c4ccc5c(c4)c4ccccc4n5-c4cccc5c4oc4ccccc45)ccc32)cc1] 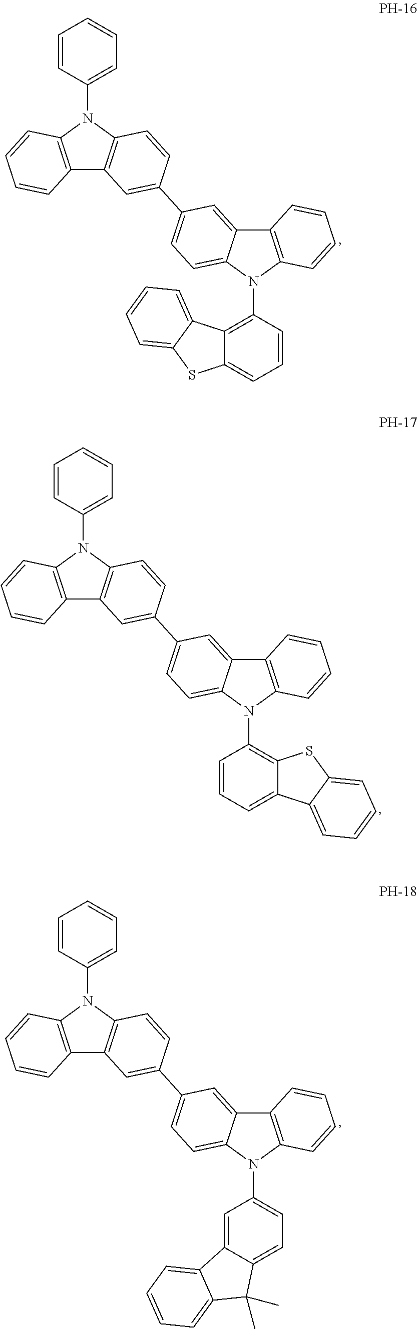 [SMILES: c1ccc(-n2c3ccccc3c3cc(-c4ccc5c(c4)c4ccccc4n5-c4cccc5sc6ccccc6c45)ccc32)cc1 ; c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21] 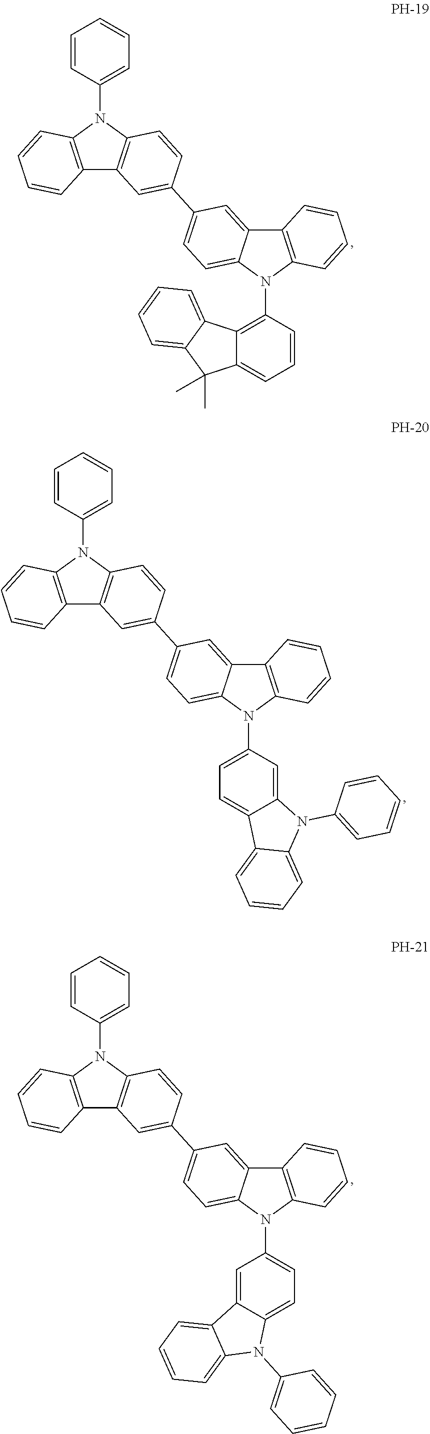 [SMILES: CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1] 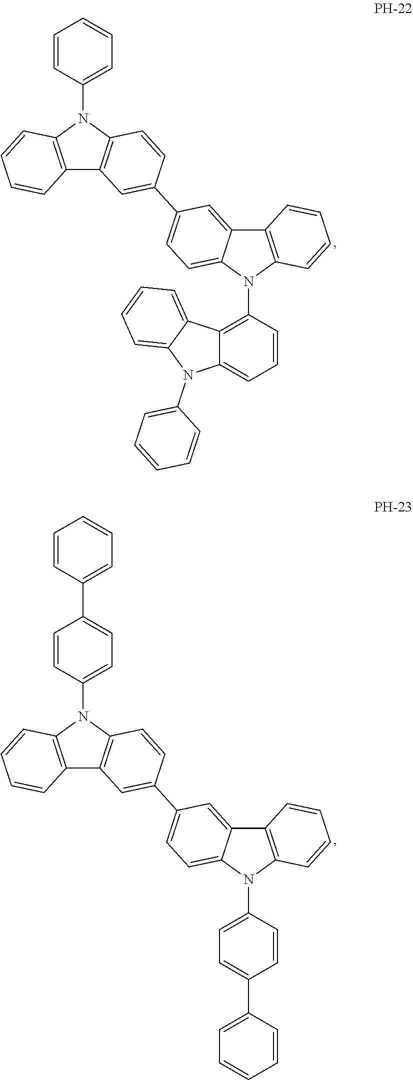 [SMILES: c1ccc(-n2c3ccccc3c3cc(-c4ccc5c(c4)c4ccccc4n5-c4cccc5c4c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1] 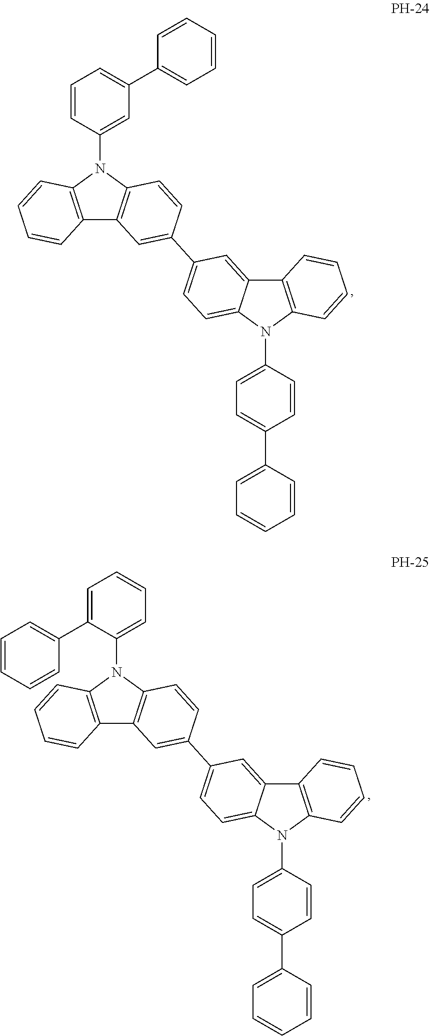 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5-c5ccccc5)ccc43)cc2)cc1] 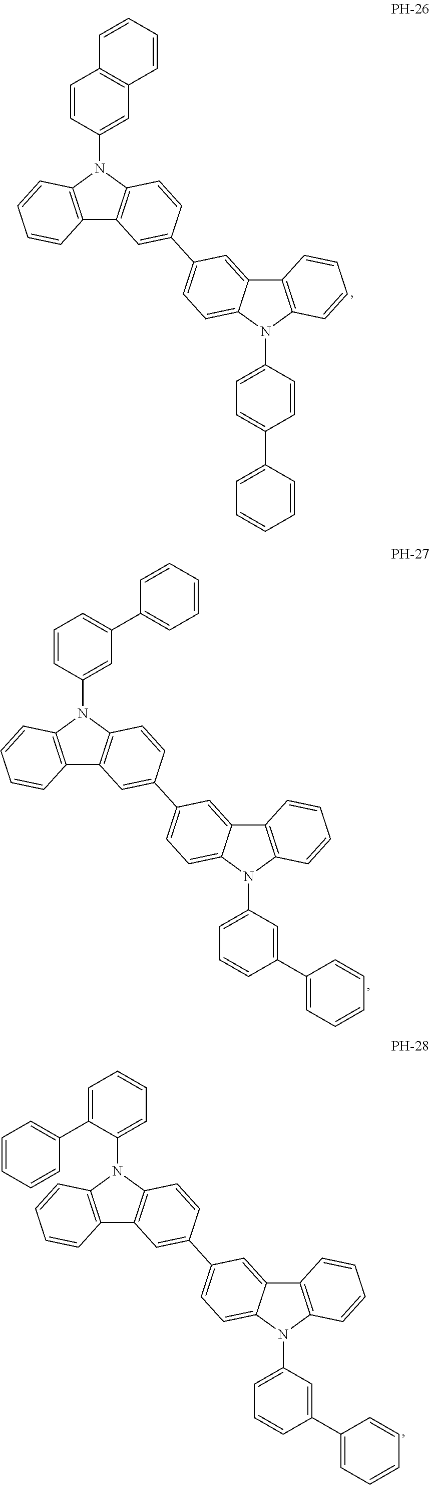 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1] 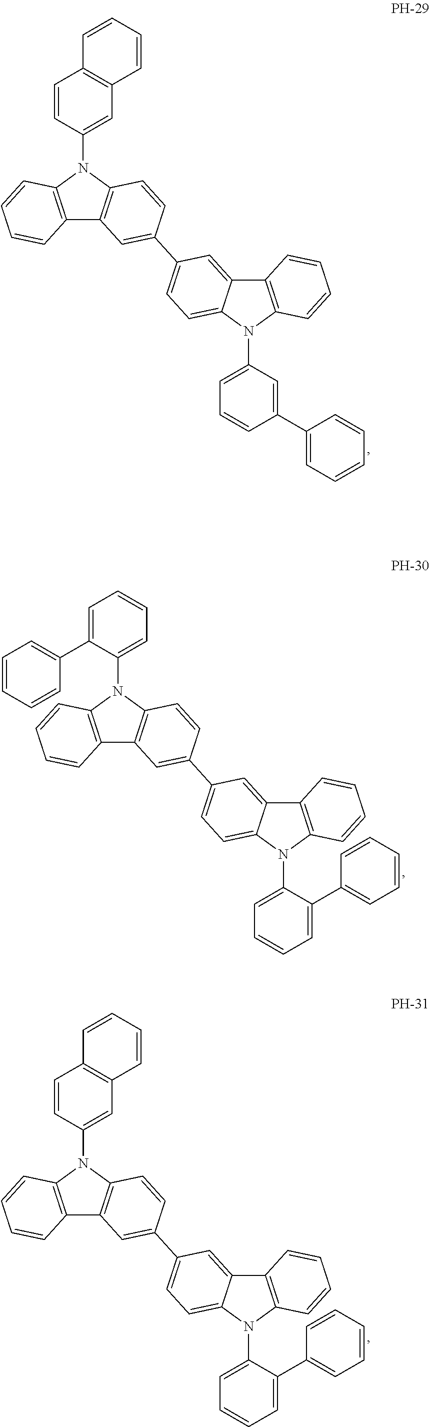 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1] 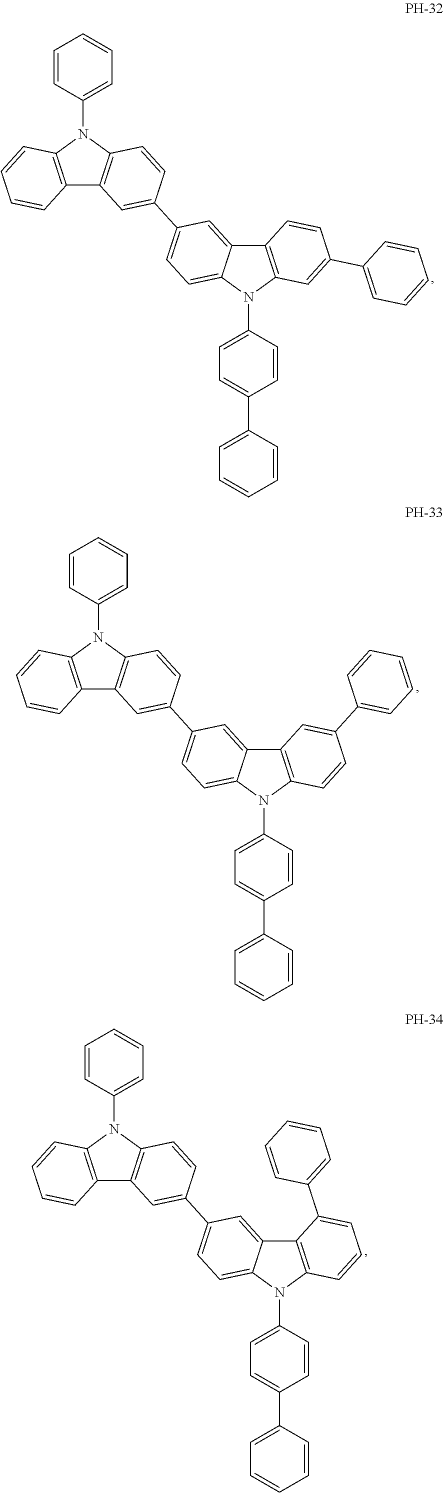 [SMILES: c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1] 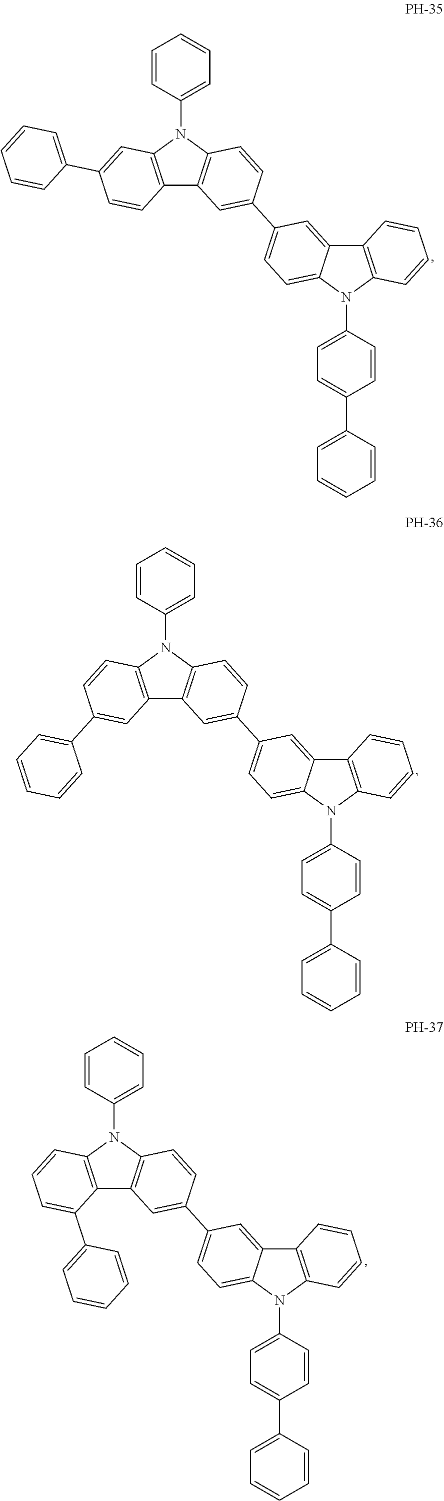 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1 ; c1ccc(-c2ccc(-n3c4ccccc4c4cc(-c5ccc6c(c5)c5c(-c7ccccc7)cccc5n6-c5ccccc5)ccc43)cc2)cc1] 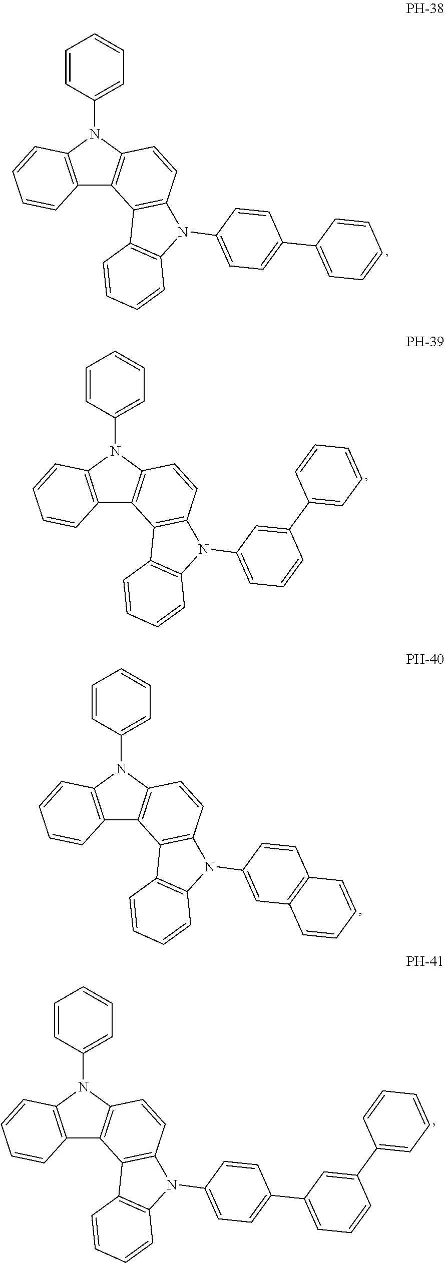 [SMILES: c1ccc(-c2ccc(-n3c4ccccc4c4c5c6ccccc6n(-c6ccccc6)c5ccc43)cc2)cc1 ; c1ccc(-c2cccc(-n3c4ccccc4c4c5c6ccccc6n(-c6ccccc6)c5ccc43)c2)cc1 ; c1ccc(-n2c3ccccc3c3c4c5ccccc5n(-c5ccc6ccccc6c5)c4ccc32)cc1 ; c1ccc(-c2cccc(-c3ccc(-n4c5ccccc5c5c6c7ccccc7n(-c7ccccc7)c6ccc54)cc3)c2)cc1] 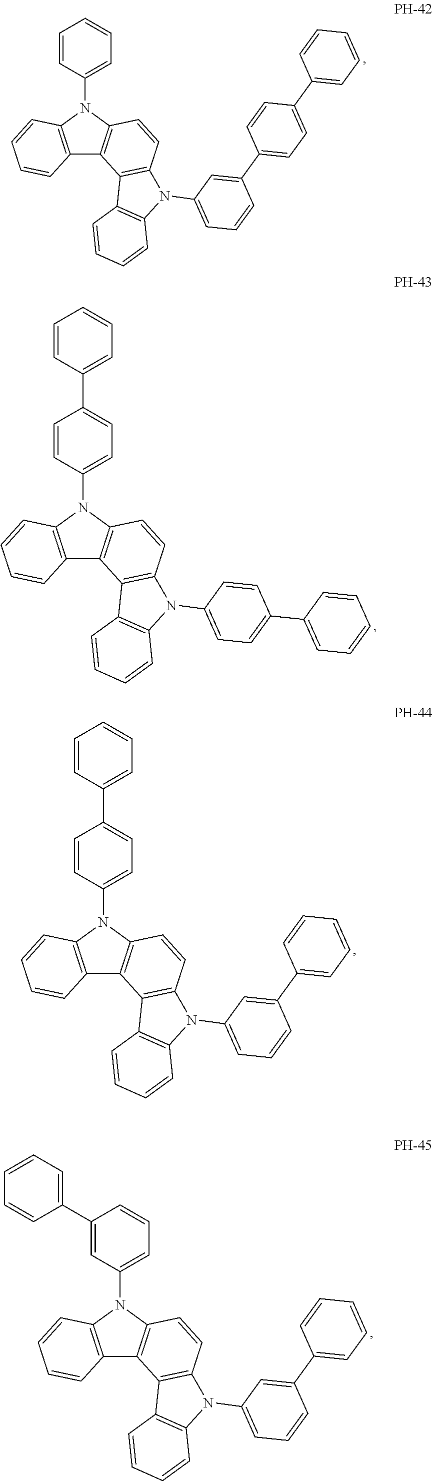 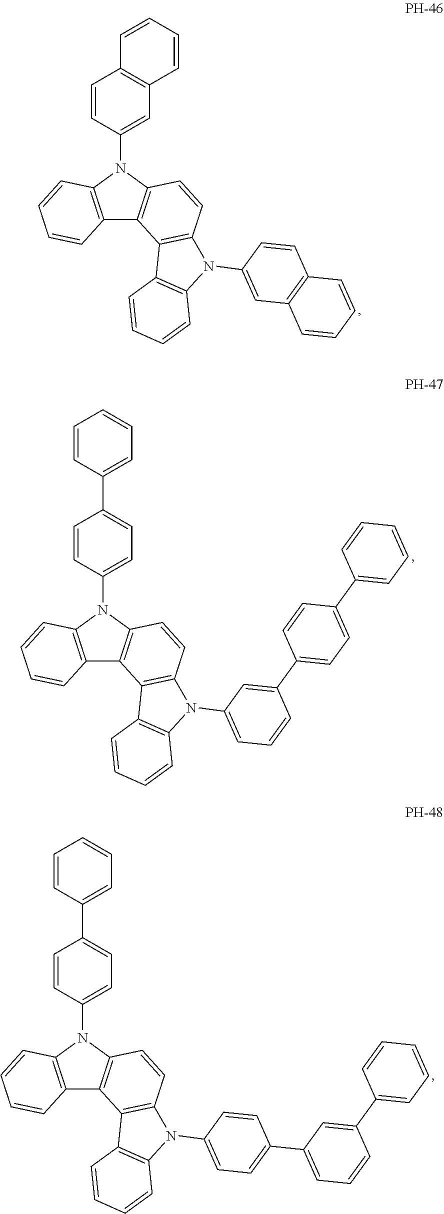 [SMILES: c1ccc2cc(-n3c4ccccc4c4c5c6ccccc6n(-c6ccc7ccccc7c6)c5ccc43)ccc2c1 ; c1ccc(-c2ccc(-c3cccc(-n4c5ccccc5c5c6c7ccccc7n(-c7ccc(-c8ccccc8)cc7)c6ccc54)c3)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1] 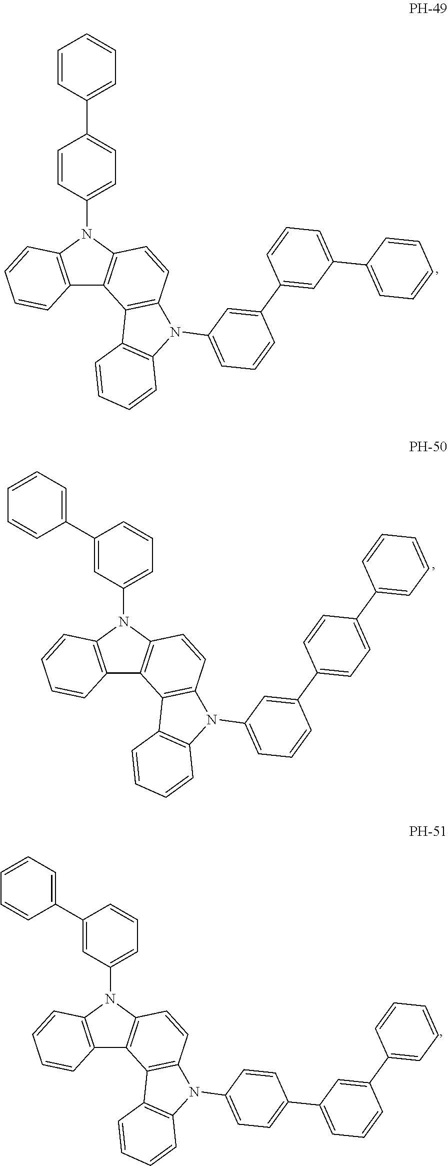 [SMILES: c1ccc(-c2ccc(-n3c4ccccc4c4c5c6ccccc6n(-c6cccc(-c7cccc(-c8ccccc8)c7)c6)c5ccc43)cc2)cc1 ; c1ccc(-c2ccc(-c3cccc(-n4c5ccccc5c5c6c7ccccc7n(-c7cccc(-c8ccccc8)c7)c6ccc54)c3)cc2)cc1 ; c1ccc(-c2cccc(-c3ccc(-n4c5ccccc5c5c6c7ccccc7n(-c7cccc(-c8ccccc8)c7)c6ccc54)cc3)c2)cc1] 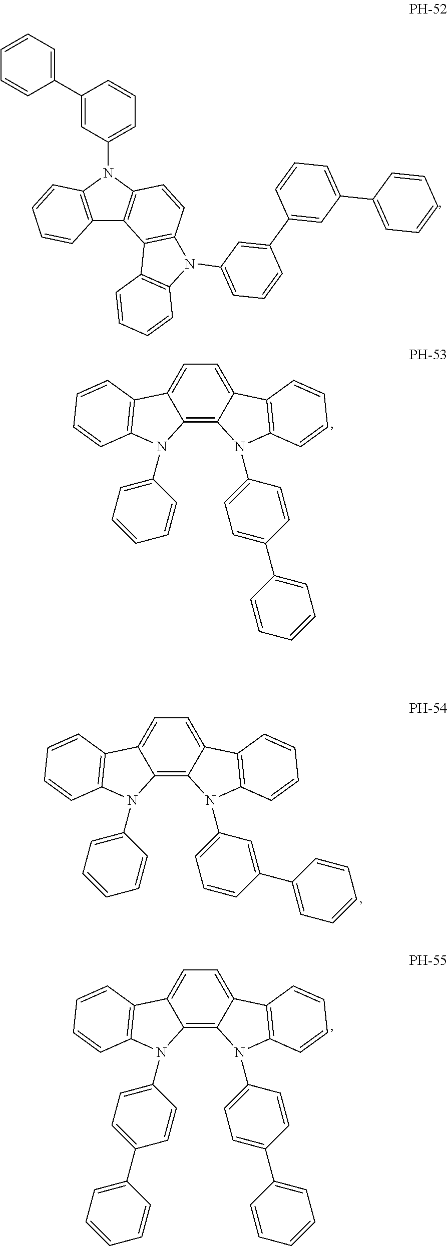 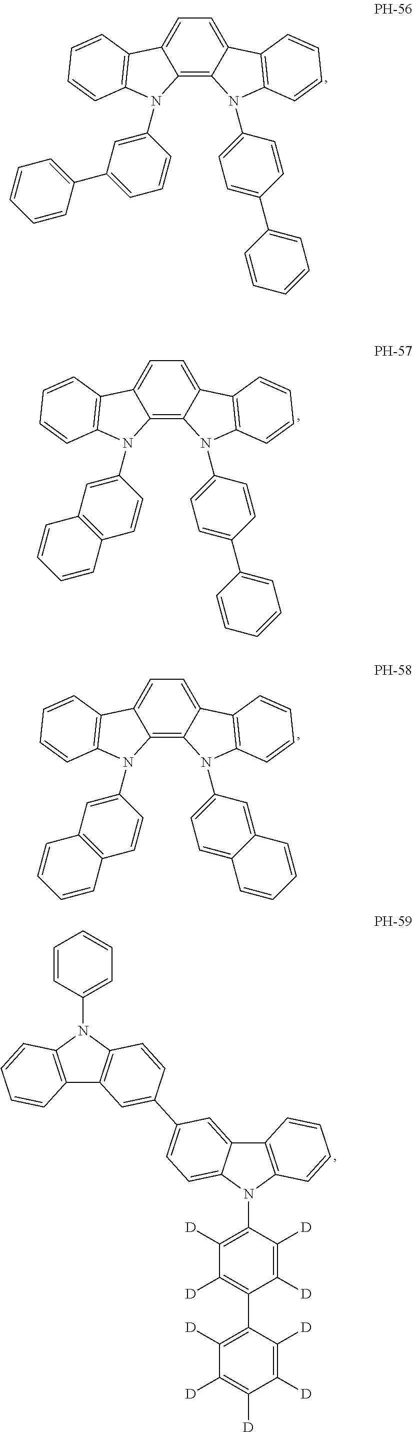 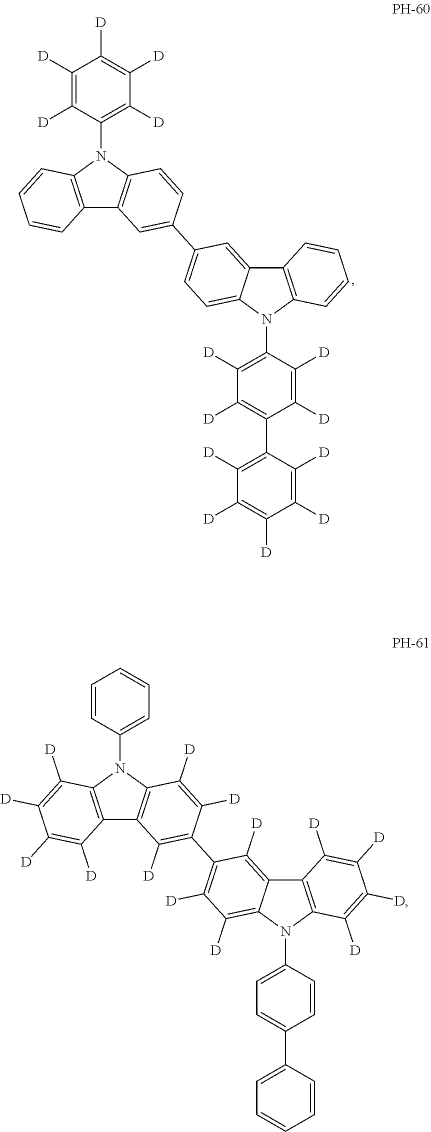 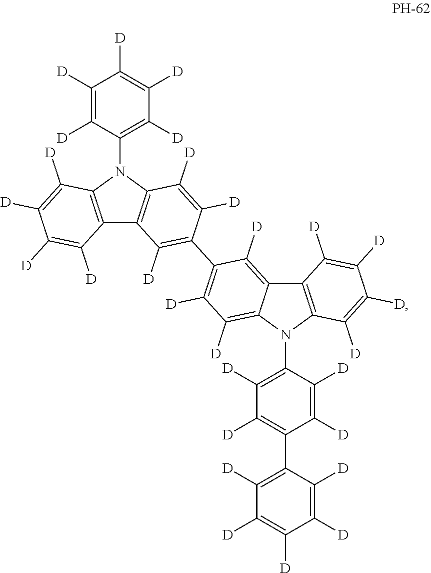 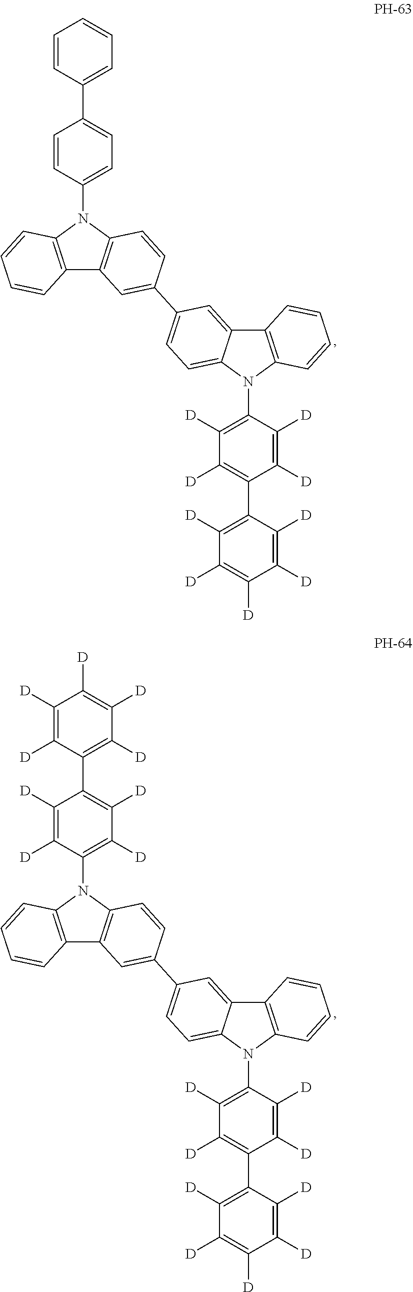 [SMILES: [2H]c1c([2H])c([2H])c(-c2c([2H])c([2H])c(-n3c4ccccc4c4cc(-c5ccc6c(c5)c5ccccc5n6-c5ccc(-c6ccccc6)cc5)ccc43)c([2H])c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c(-c6c([2H])c([2H])c([2H])c([2H])c6[2H])c([2H])c5[2H])ccc43)c([2H])c2[2H])c([2H])c1[2H]] 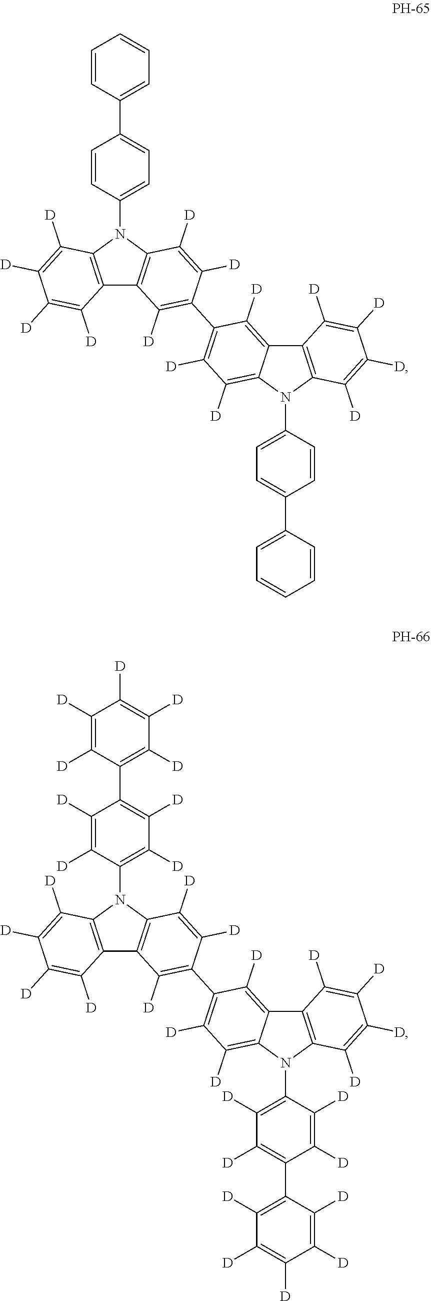 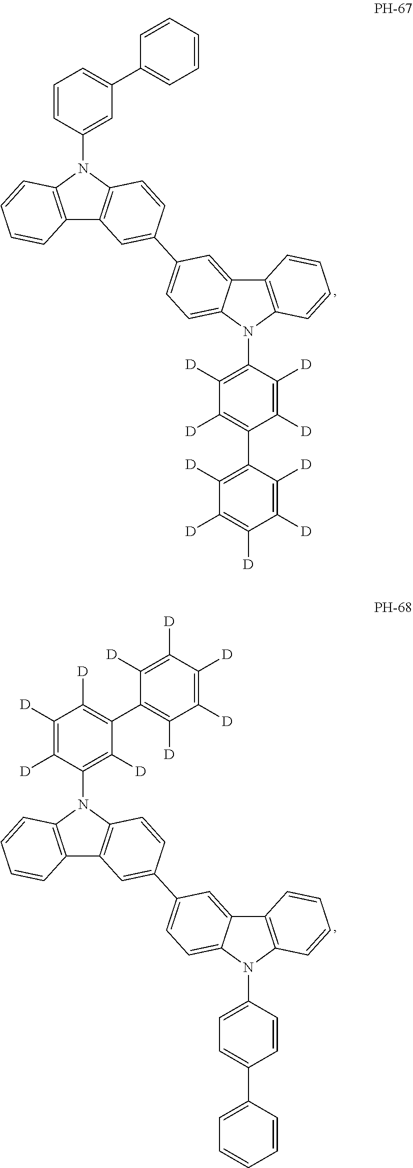 [SMILES: [2H]c1c([2H])c([2H])c(-c2c([2H])c([2H])c(-n3c4ccccc4c4cc(-c5ccc6c(c5)c5ccccc5n6-c5cccc(-c6ccccc6)c5)ccc43)c([2H])c2[2H])c([2H])c1[2H] ; [2H]c1c([2H])c([2H])c(-c2c([2H])c([2H])c([2H])c(-n3c4ccccc4c4cc(-c5ccc6c(c5)c5ccccc5n6-c5ccc(-c6ccccc6)cc5)ccc43)c2[2H])c([2H])c1[2H]] 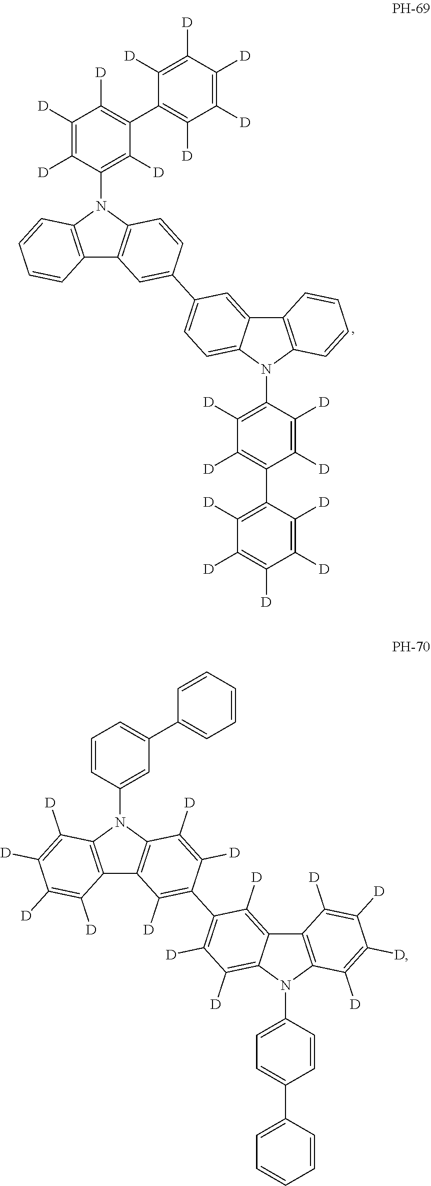 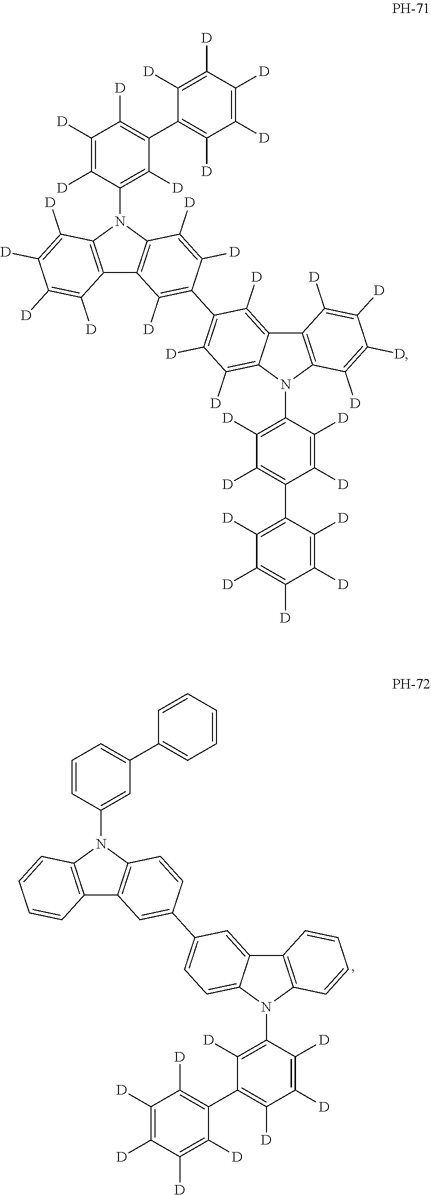 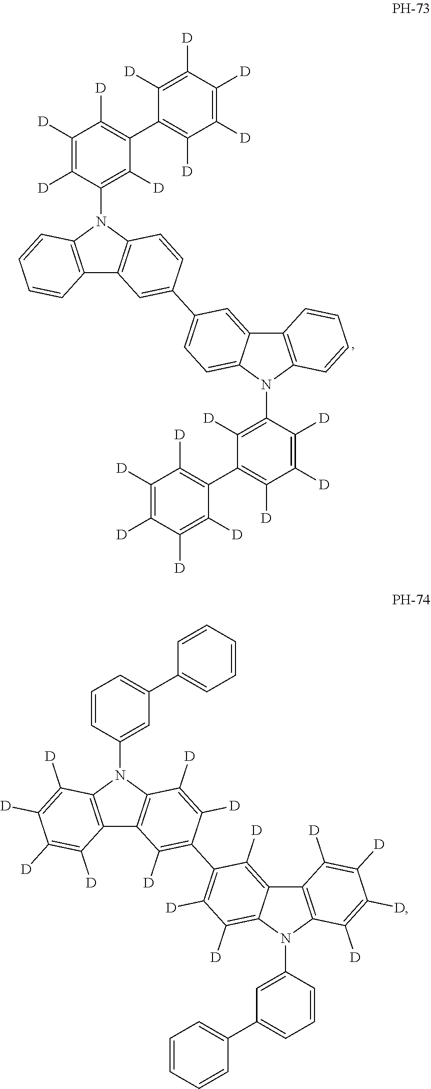 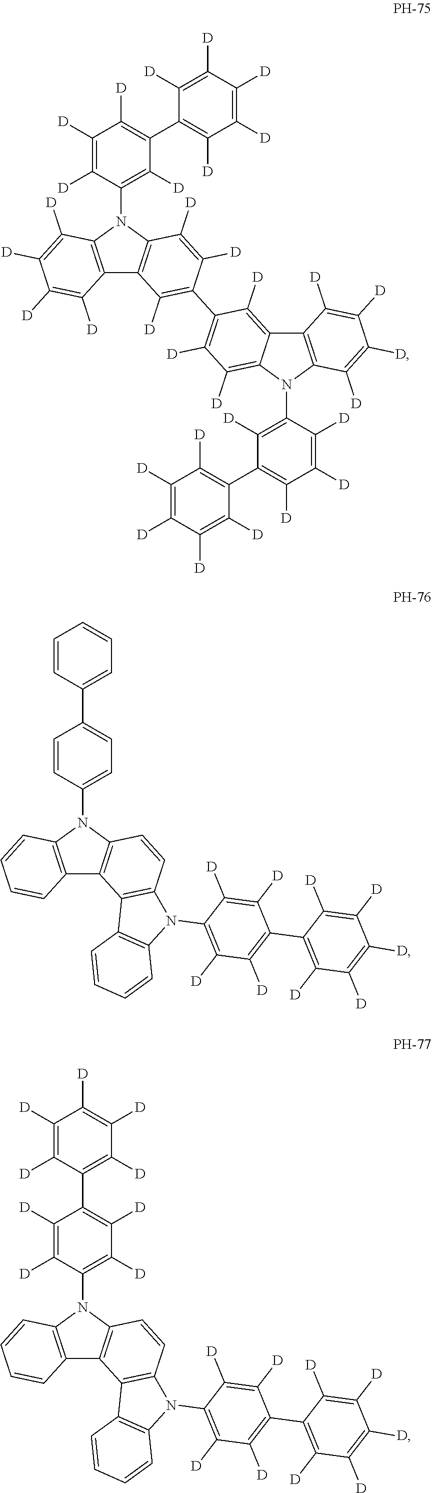 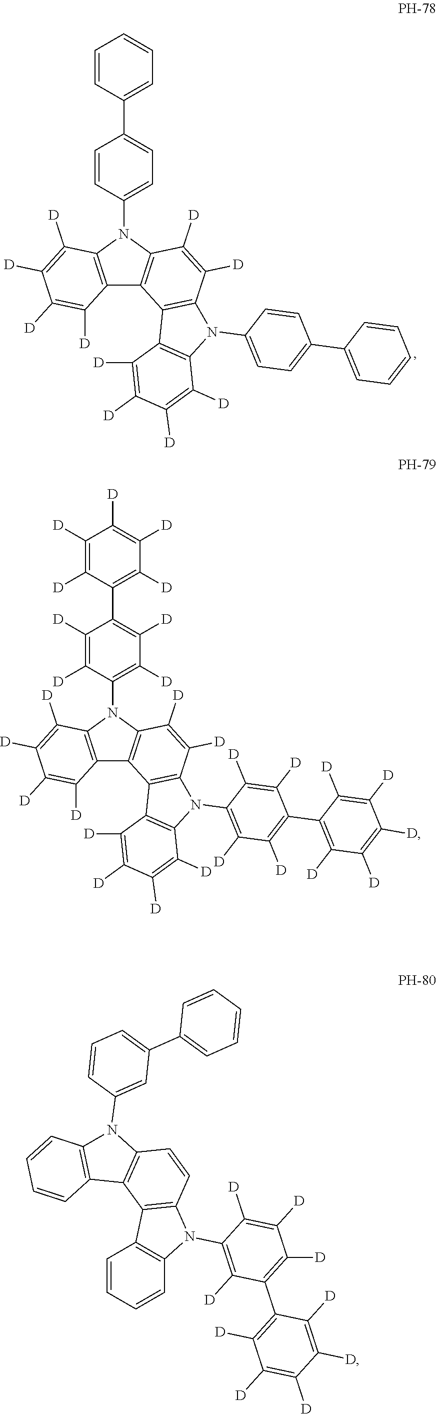 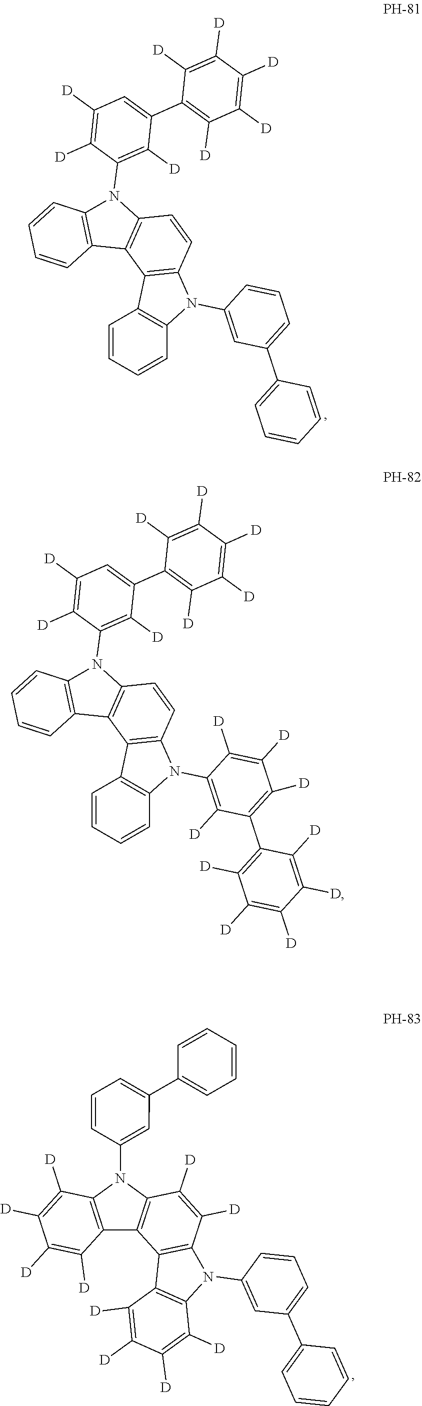 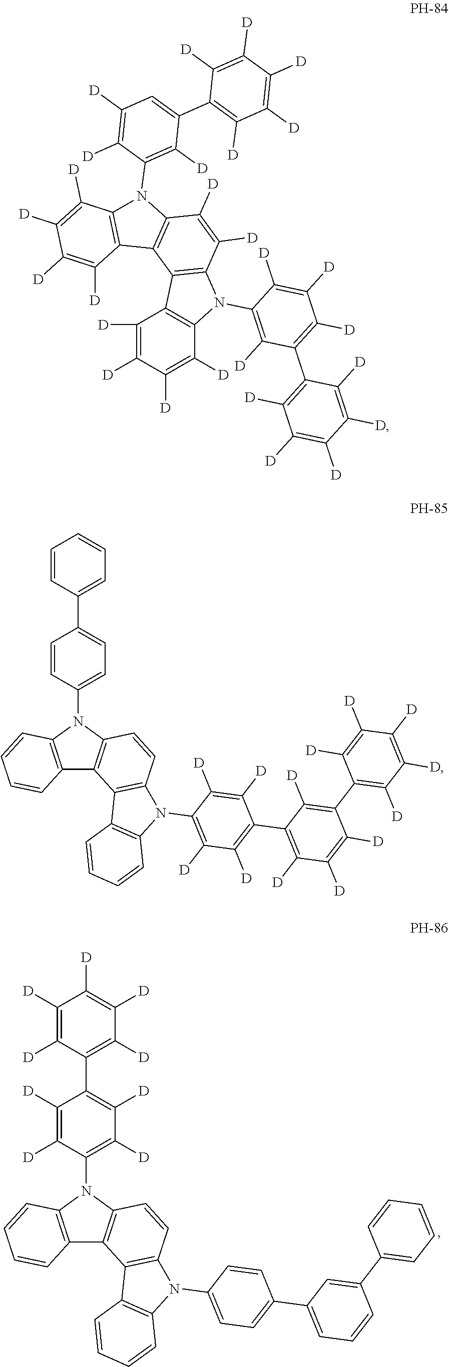 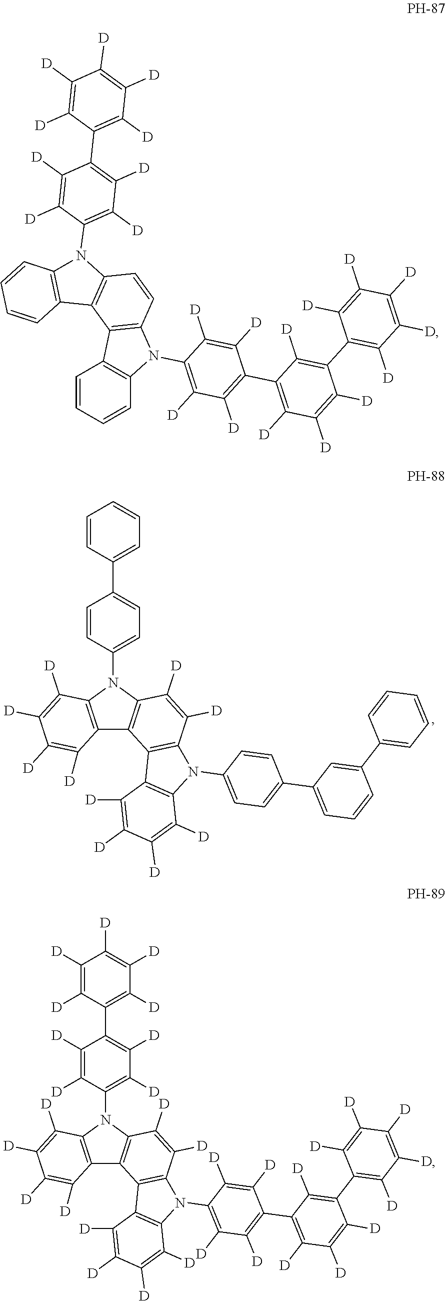 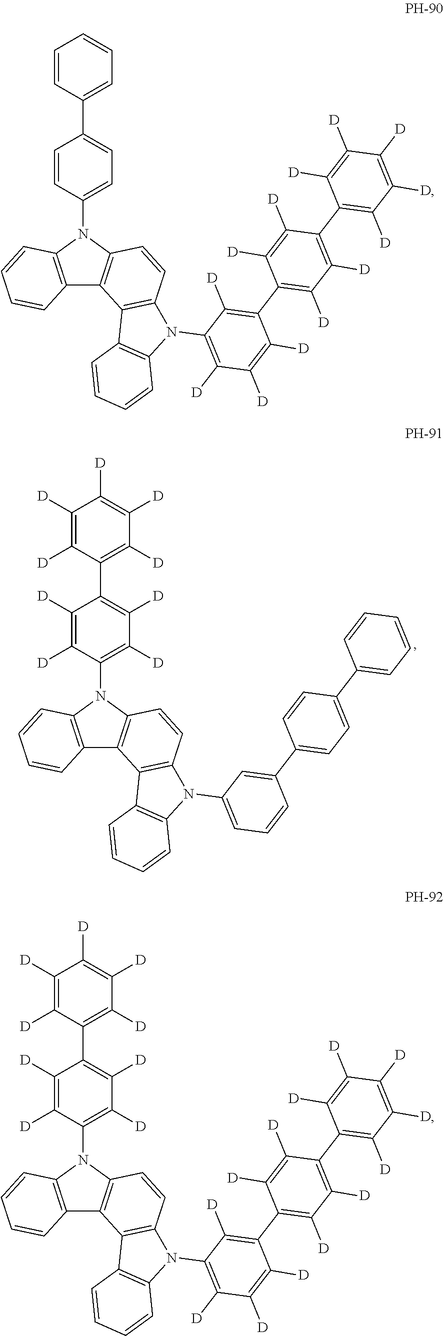 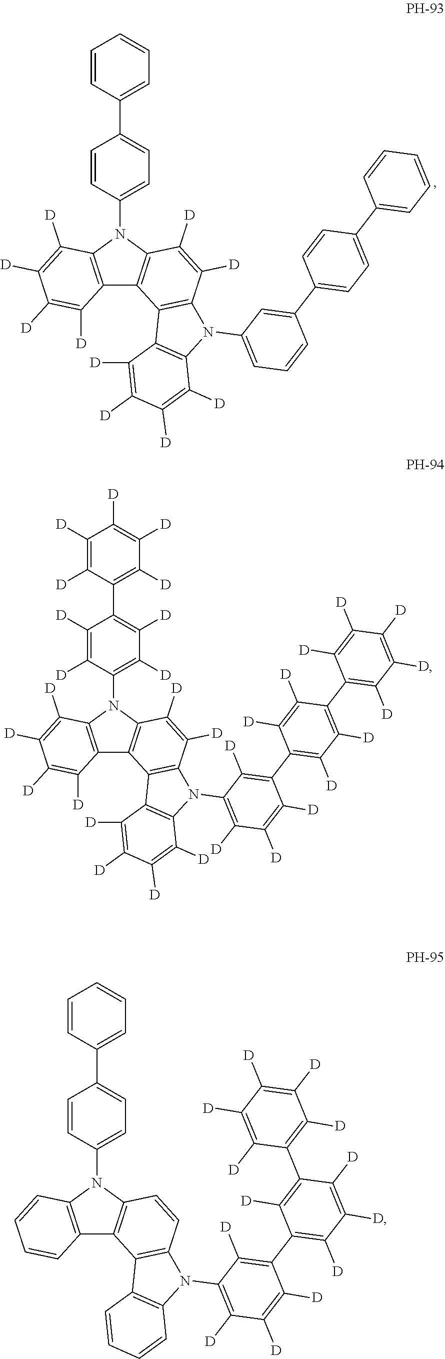 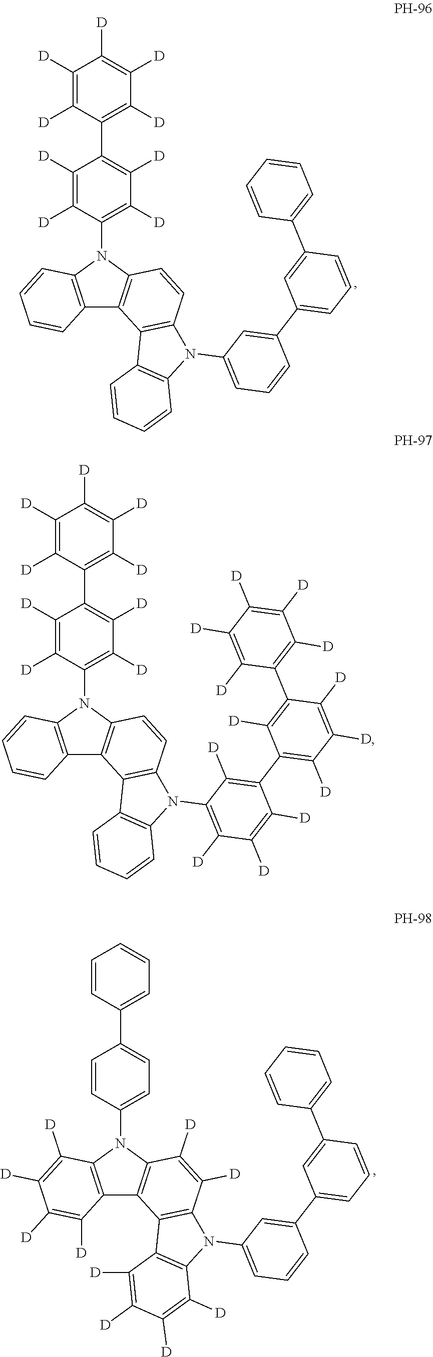 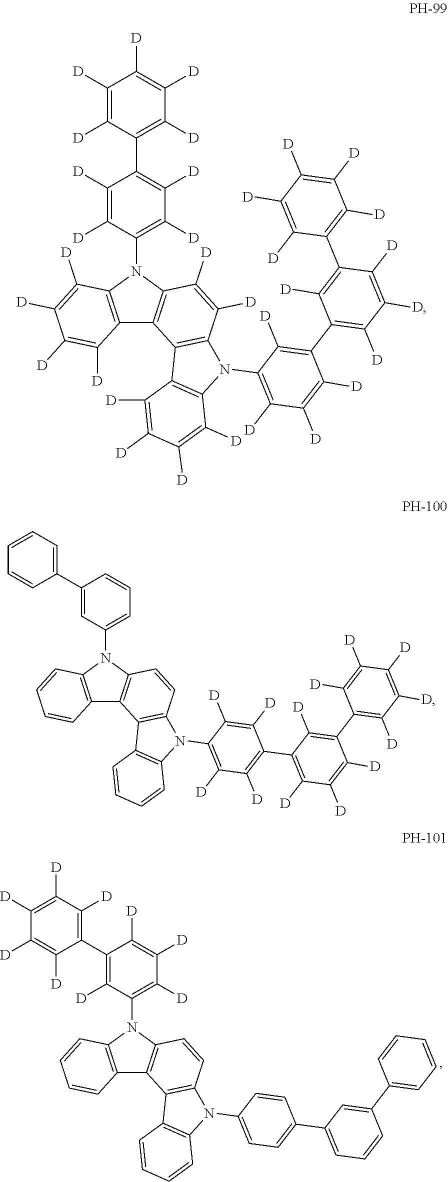 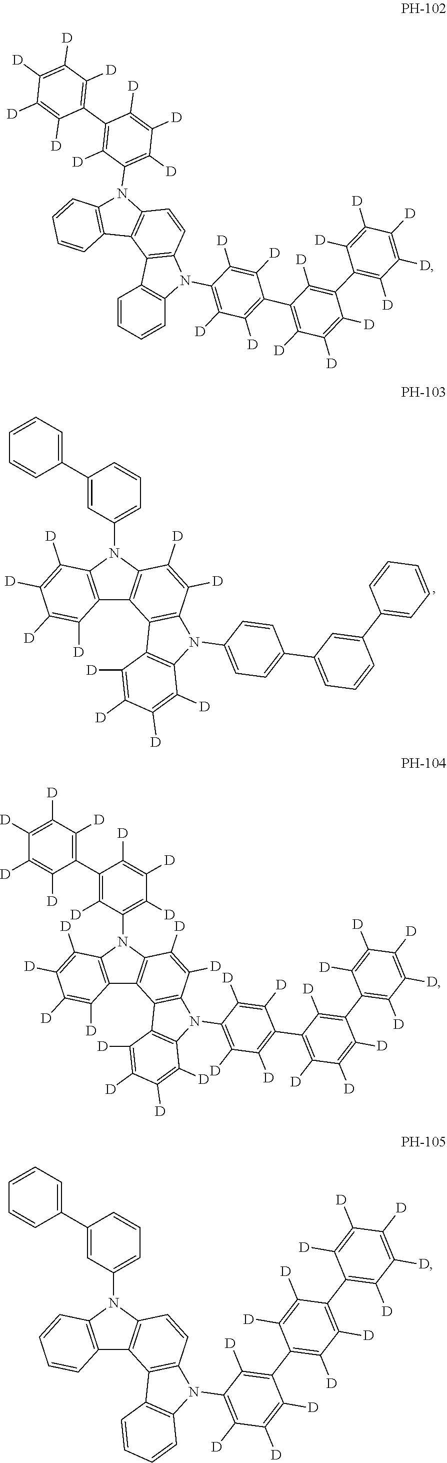 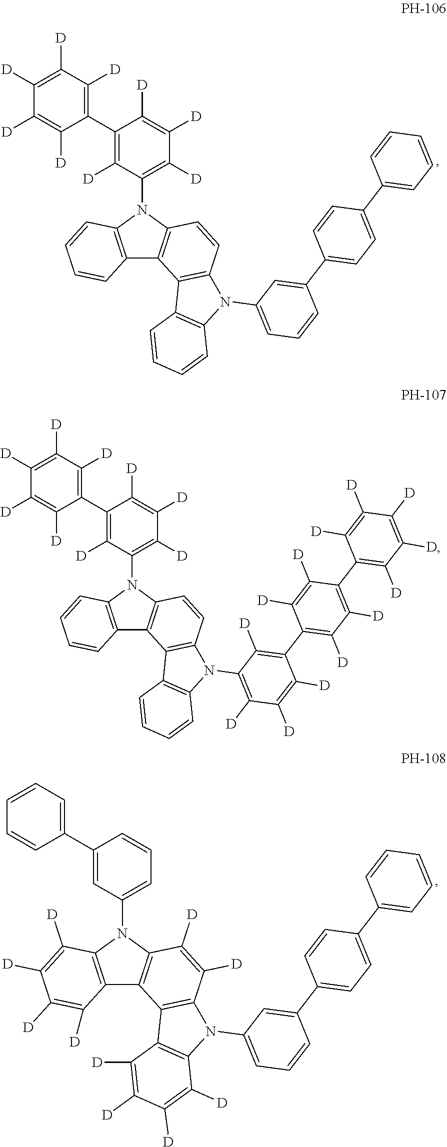 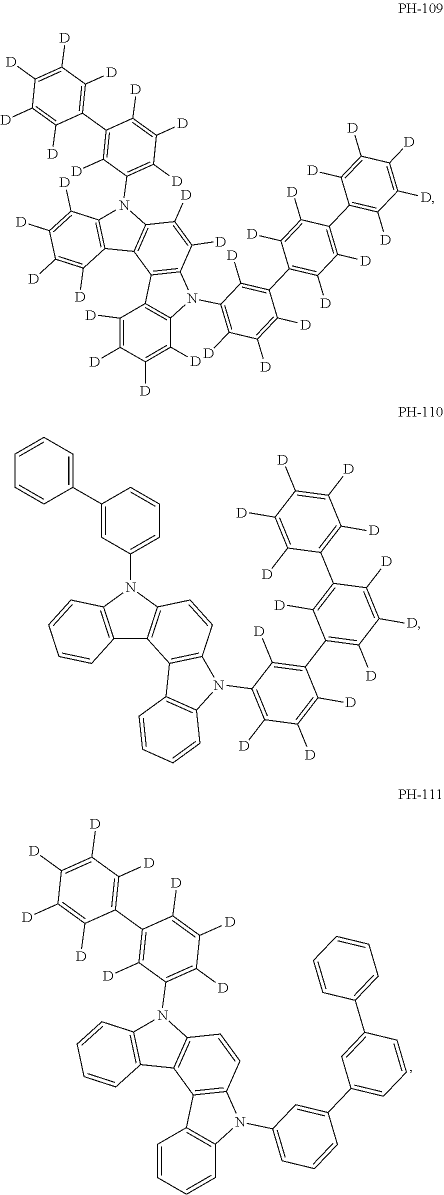 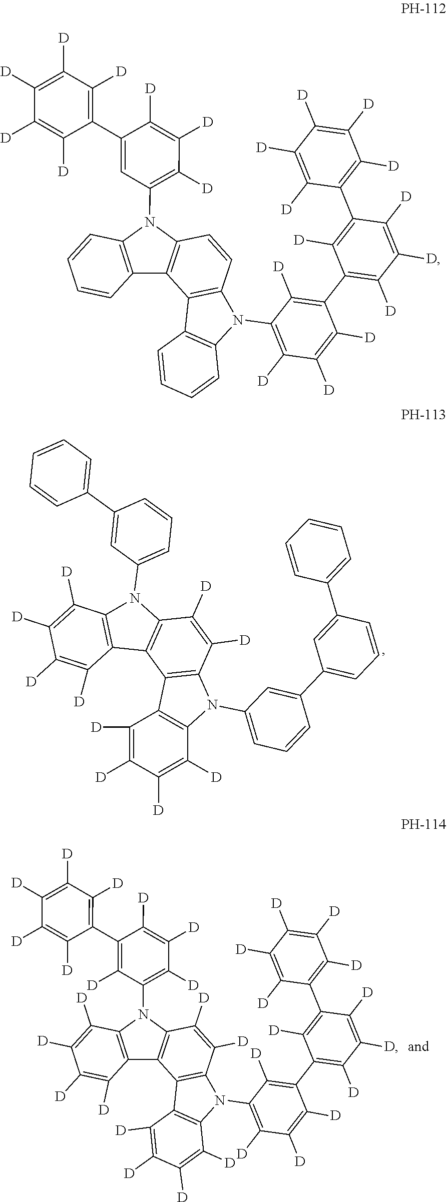 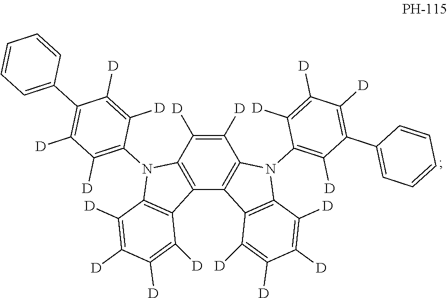 [SMILES: [2H]c1c([2H])c(-c2ccccc2)c([2H])c(-n2c3c([2H])c([2H])c([2H])c([2H])c3c3c4c5c([2H])c([2H])c([2H])c([2H])c5n(-c5c([2H])c([2H])c(-c6ccccc6)c([2H])c5[2H])c4c([2H])c([2H])c32)c1[2H]]
wherein optionally, hydrogens in Compound PH-1 to Compound PH-115 can be partially or fully substituted with deuterium.

22. A composition, comprising a first metal complex and a first compound, wherein the first metal complex comprises a metal M and a ligand Lₐ coordinated to the metal M, and Lₐ has a structure represented by Formula 1: 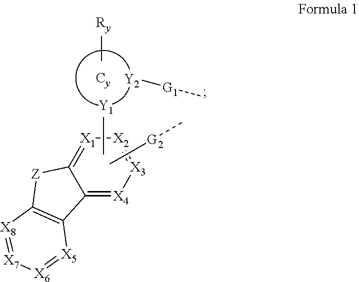
Wherein the metal M is selected from a metal with a relative atomic mass greater than 40;
C_{y} is, at each occurrence identically or differently, selected from an aromatic ring having 6 to 24 ring atoms and comprising Y₁ and Y₂, a heteroaromatic ring having 5 to 24 ring atoms and comprising Y₁ and Y₂, or a combination thereof;
G₁ and G₂ are, at each occurrence identically or differently, selected from a single bond, O, or S;
X₁ to X₄ are, at each occurrence identically or differently, selected from C, CRₓ, or N, and one of X₁ to X₄ is selected from C and joined to Y₁;
when X₁, X₂, X₃ or X₄ joined to G₂ is selected from N, G₂ is selected from a single bond, and X₁, X₂, X₃, or X₄ is joined to the metal by forming a metal-nitrogen bond through G₂; or
when X₁, X₂, X₃ or X₄ joined to G₂ is selected from C, G₂ is selected from a single bond, O, or S, and X₁, X₂, X₃, or X₄ is joined to the metal through G₂;
X₅ to X₈ are, at each occurrence identically or differently, selected from CRₓ, or N;
Z is, at each occurrence identically or differently, selected from the group consisting of O, S, Se, NR′, CR′R′, SiR′R′, and GeR′R′; when two R′ are present at the same time, the two R are the same or different;
Y₁ and Y₂ are, at each occurrence identically or differently, selected from C or N;
R_{y} represents, at each occurrence identically or differently, mono-substitution or multiple substitutions; when a plurality of R_{y} are present, the plurality of R_{y} are the same or different;
Rₓ, R′, and R_{y} are, at each occurrence identically or differently, selected from the group consisting of; hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one R_{y} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{y} can be optionally joined to form a ring;
adjacent substituents R′, Rₓ can be optionally joined to form a ring; and
the metal complex is not 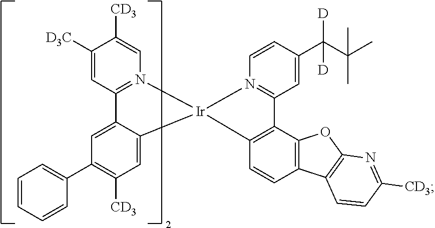
wherein the first compound has a structure represented by Formula 2: 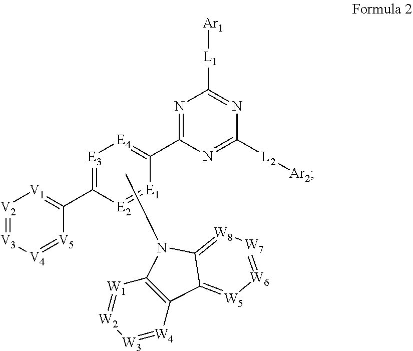
wherein in Formula 2, E₁ to E₄ are, at each occurrence identically or differently, selected from C, CR_{c}, or N;
V₁ to V₅ are, at each occurrence identically or differently, selected from CRᵥ or N,
W₁ to W₈ are, at each occurrence identically or differently, selected from CR_{w} or N;
L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms, or a combination thereof;
R_{c}, Rᵥ, and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{c} can be optionally joined to form a ring, adjacent substituents Rᵥ can be optionally joined to form a ring, and adjacent substituents R_{w} can be optionally joined to form a ring.

23. An organic layer, comprising the composition according to claim 22.

24. A display assembly, comprising the organic electroluminescent device according to claim 1.

25. An electronic device, comprising the organic electroluminescent device according to claim 1.
